(19) United States
(12) Patent Application Publication
(10) Pub. No.: US 2024/0008355 A1
(43) Pub. Date: Jan. 4, 2024

(54) Light-Emitting Device, Light-Emitting Apparatus, Electronic Device, and Lighting Device

(71) Applicant: Semiconductor Energy Laboratory Co., Ltd., Kanagawa-ken (JP)

(72) Inventors: Toshiki Sasaki, Kawasaki (JP); Hiromitsu Kido, Atsugi (JP); Tsunenori Suzuki, Yokohama (JP); Nobuharu Ohsawa, Zama (JP); Hideko Yoshizumi, Atsugi (JP); Satoshi Seo, Sagamihara (JP); Satoko Numata, Atsugi (JP); Eriko Aoyama, Atsugi (JP); Yui Yoshiyasu, Atsugi (JP)

(73) Assignee: Semiconductor Energy Laboratory Co., Ltd., Kanagawa-ken (JP)

(21) Appl. No.: 18/214,796

(22) Filed: Jun. 27, 2023

(30) Foreign Application Priority Data
Jun. 29, 2022 (JP) 2022-104863
Jun. 12, 2023 (JP) 2023-096181

(51) Int. Cl. H10K 85/30; C07F 15/00; C09K 11/06

(52) U.S. Cl. CPC H10K 85/342; C07F 15/0033; C09K 11/06; H10K 50/11

(57) ABSTRACT

A light-emitting device includes a light-emitting layer containing a light-emitting substance and a first organic compound. The light-emitting substance is an organometallic complex containing a central metal and ligands. One of the ligands includes a skeleton formed by a ring A¹ and a pyridine ring bonded to each other. The ring A¹ represents an aromatic ring or a heteroaromatic ring. The pyridine ring includes an alkyl group having 1 to 6 carbon atoms and being substituted with deuterium. The first organic compound includes an electron-transport skeleton and first and second substituents that are bonded to the electron-transport skeleton. The electron-transport skeleton includes a heteroaromatic ring having two or more nitrogen atoms. The first substituent includes one or both of an aromatic ring and a heteroaromatic ring. The second substituent includes a skeleton having a hole-transport property. The lowest triplet excited state of the first organic compound is locally distributed in the first substituent.

### BACKGROUND OF THE INVENTION

### 1. Field of the Invention

One embodiment of the present invention relates to a light-emitting device, a light-emitting apparatus, an electronic device, and a lighting device. Note that one embodiment of the present invention is not limited to the above technical field. The technical field of one embodiment of the invention disclosed in this specification and the like relates to an object, a method, or a manufacturing method. One embodiment of the present invention relates to a process, a machine, manufacture, or a composition of matter. Specifically, examples of the technical field of one embodiment of the present invention disclosed in this specification include a semiconductor device, a display apparatus, a liquid crystal display apparatus, a light-emitting apparatus, a lighting device, a power storage device, a memory device, an imaging device, a driving method thereof, and a manufacturing method thereof.

### 2. Description of the Related Art

Light-emitting devices (organic EL elements) including organic compounds and utilizing electroluminescence (EL) have been put into more practical use. In the basic structure of such light-emitting devices, an organic compound layer containing a light-emitting material (an EL layer) is located between a pair of electrodes. Carriers are injected by application of a voltage to the element, and recombination energy of the carriers is used, whereby light emission can be obtained from the light-emitting material.

Such light-emitting devices are of self-emission type and thus are suitably used for pixels of a display, in which case the display can have higher visibility than a liquid crystal display. Displays including such light-emitting devices are also highly advantageous in that they can be thin and lightweight because a backlight is not needed. Moreover, such light-emitting devices also have a feature of extremely fast response speed.

Since light-emitting layers of such light-emitting devices can be successively formed two-dimensionally, planar light emission can be achieved. This feature is difficult to realize with point light sources typified by incandescent lamps or LEDs or linear light sources typified by fluorescent lamps; thus, such light-emitting devices also have great potential as planar light sources, which can be applied to lighting devices and the like.

Displays or lighting devices including light-emitting devices can be suitably used for a variety of electronic devices as described above, and research and development of light-emitting devices has progressed for higher efficiency or longer lifetimes.

Although the characteristics of light-emitting devices have been improved considerably, advanced requirements for various characteristics including efficiency and durability are not yet satisfied. In particular, to solve a problem such as burn-in that still remains as an issue peculiar to organic EL, it is preferable to suppress a reduction in efficiency due to degradation as much as possible.

Since the characteristics of a light-emitting device greatly depend on a light-emitting substance and peripheral materials, the light-emitting substances and the peripheral materials have been actively developed (see Patent Document 1, for example).

### REFERENCES

[Patent Document 1] Japanese Published Patent Application No. 2009-023938
[Non-Patent Document 1] Nicholas J. Turro, V. Ramamurthy, J. C. Scaiano, “MODERN MOLECULAR PHOTOCHEMISTRY OF ORGANIC MOLECULES”, UNIVERSITY SCIENCE BOOKS, 2010.02.10, pp. 204-208
[Non-Patent Document 2] Daisaku TANAKA et. al., “Ultra High Efficiency Green Organic Light-Emitting Devices”, Japanese Journal of Applied Physics, Vol. 46, No. 1, 2007, pp. L10-L12

### SUMMARY OF THE INVENTION

Although light-emitting substances and host materials that exhibit excellent characteristics have been actively developed as reported in the above Patent Document, development of materials and light-emitting devices exhibiting better characteristics has been desired.

In view of this, an object of one embodiment of the present invention is to provide a highly reliable light-emitting device. Another object is to provide a light-emitting device having high emission efficiency. Another object is to provide a novel light-emitting device.

Another object is to provide a light-emitting apparatus, an electronic device, or a lighting device having a long lifetime. Another object is to provide a light-emitting apparatus, an electronic device, or a lighting device having low power consumption. Another object is to provide a novel light-emitting apparatus, a novel electronic device, or a novel lighting device.

Note that the description of these objects does not preclude the existence of other objects. One embodiment of the present invention does not need to achieve all of these objects. Other objects can be derived from the description of the specification, the drawings, and the claims.

One embodiment of the present invention is a light-emitting device including an anode, a cathode, and a light-emitting layer. The light-emitting layer is positioned between the anode and the cathode. The light-emitting layer includes a light-emitting substance and a first organic compound. The light-emitting substance is an organometallic complex including a central metal and ligands. At least one of the ligands includes a skeleton formed by a ring A¹ and a pyridine ring bonded to each other. The ring A¹ represents an aromatic ring or a heteroaromatic ring. The pyridine ring includes an alkyl group having 1 to 6 carbon atoms and being substituted with deuterium. The ligand is coordinated to the central metal with any atom of the ring A¹ and nitrogen of the pyridine ring. The first organic compound includes an electron-transport skeleton and first and second substituents each being bonded to the electron-transport skeleton. The electron-transport skeleton includes a heteroaromatic ring having two or more nitrogen atoms. The first substituent is a group including one or both of an aromatic ring and a heteroaromatic ring. The second substituent includes a skeleton having a hole-transport property, and a lowest triplet excited state of the first organic compound is locally distributed in the first substituent.

Another embodiment is a light-emitting device including an anode, a cathode, and a light-emitting layer. The light-emitting layer is positioned between the anode and the cathode. The light-emitting layer includes a light-emitting substance and a first organic compound. The light-emitting substance is an organometallic complex including a central metal and ligands. At least one of the ligands includes a structure represented by General Formula (L1). The first organic compound is an organic compound represented by General Formula (G10).

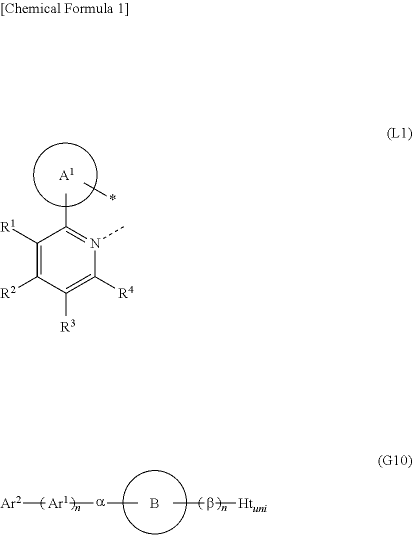

In General Formula (L1), * represents a bond for the central metal; a dashed line represents coordination to the central metal; a ring A¹ represents an aromatic ring or a heteroaromatic ring; at least one of R¹ to R⁴ is an alkyl group having 1 to 6 carbon atoms and being substituted with deuterium; each of the others of R¹ to R⁴ independently represents any of hydrogen (including deuterium), an alkyl group having 1 to 6 carbon atoms, and a substituted or unsubstituted aryl group having 6 to 13 carbon atoms in a ring. In General Formula (G10), a ring B represents a heteroaromatic ring having two or more nitrogen atoms; each of Ar¹ and Ar² independently represents an aromatic ring or a heteroaromatic ring; each of α and β independently represents a substituted or unsubstituted phenyl group; Htᵤₙᵢ represents a skeleton having a hole-transport property; and each of n and m independently represents an integer of 0 to 4.

Another embodiment of the present invention is a light-emitting device including an anode, a cathode, and a light-emitting layer. The light-emitting layer is positioned between the anode and the cathode. The light-emitting layer includes a light-emitting substance and a first organic compound. The light-emitting substance is an organometallic complex represented by General Formula (G1). The first organic compound is an organic compound represented by General Formula (G10).

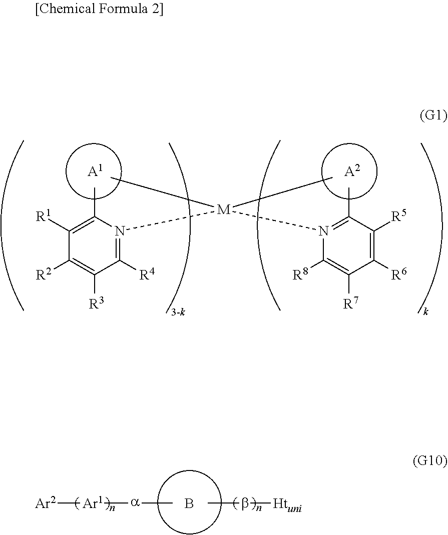

In General Formula (G1), M represents a central metal, a dashed line represents coordination; each of a ring A¹ and a ring A² independently represents an aromatic ring or a heteroaromatic ring; at least one of R¹ to R⁴ is an alkyl group having 1 to 6 carbon atoms and being substituted with deuterium; each of the others of R¹ to R⁴ independently represents any of hydrogen (including deuterium), an alkyl group having 1 to 6 carbon atoms, and a substituted or unsubstituted aryl group having 6 to 13 carbon atoms in a ring; each of R⁵ to R⁸ independently represents any of hydrogen (including deuterium), an alkyl group having 1 to 6 carbon atoms, and a substituted or unsubstituted aryl group having 6 to 13 carbon atoms in a ring; and k represents an integer of 0 to 2. In General Formula (G10), a ring B represents a heteroaromatic ring having two or more nitrogen atoms; each of Ar¹ and Ar² independently represents an aromatic ring or a heteroaromatic ring; each of α and β independently represents a substituted or unsubstituted phenyl group; Htᵤₙᵢ represents a skeleton having a hole-transport property; and each of n and m independently represents an integer of 0 to 4.

Another embodiment of the present invention is a light-emitting device including an anode, a cathode, and a light-emitting layer. The light-emitting layer is positioned between the anode and the cathode. The light-emitting layer includes a light-emitting substance and a first organic compound. The light-emitting substance is an organometallic complex represented by General Formula (G2). The first organic compound is an organic compound represented by General Formula (G10).

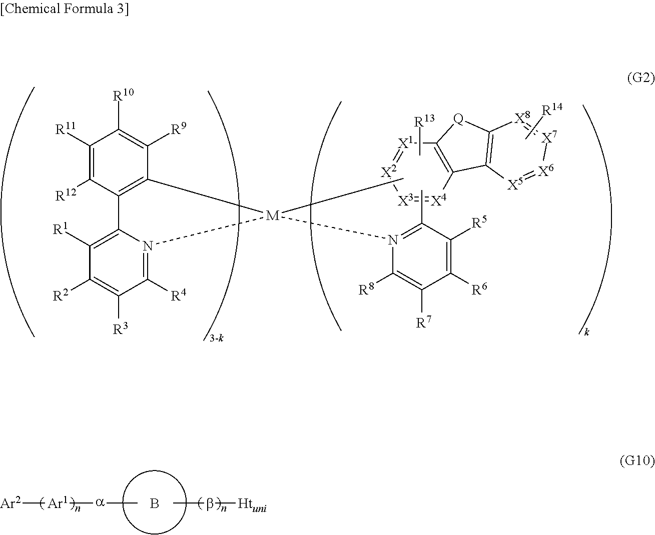

In General Formula (G2), M represents a central metal; a dashed line represents coordination; Q represents oxygen or sulfur; each of X¹ to X⁸ independently represents any of nitrogen and carbon (including CH); at least one of R¹ to R⁴ is an alkyl group having 1 to 6 carbon atoms and being substituted with deuterium; each of the others of R¹ to R⁴ independently represents hydrogen (including deuterium), an alkyl group having 1 to 6 carbon atoms, or a substituted or unsubstituted aryl group having 6 to 13 carbon atoms in a ring; each of R⁵ to R¹⁴ independently represents hydrogen (including deuterium), an alkyl group having 1 to 6 carbon atoms, or a substituted or unsubstituted aryl group having 6 to 13 carbon atoms in a ring; and k represents an integer of 0 to 2. In General Formula (G10), a ring B represents a heteroaromatic ring having two or more nitrogen atoms; each of Ar¹ and Ar² independently represents an aromatic ring or a heteroaromatic ring; each of α and β independently represents a substituted or unsubstituted phenyl group; Htᵤₙᵢ represents a skeleton having a hole-transport property; and each of n and m independently represents an integer of 0 to 4.

Another embodiment of the present invention is any of the above light-emitting devices in which the lowest triplet excitation energy of the first organic compound is higher than the lowest triplet excitation energy of the organometallic complex.

Another embodiment of the present invention is any of the above light-emitting devices in which a difference between the lowest triplet excitation energy of the first organic compound and the lowest triplet excitation energy of the organometallic complex is greater than 0 eV and less than or equal to 0.40 eV.

Another embodiment of the present invention is any of the above light-emitting devices in which the central metal is iridium.

Another embodiment of the present invention is any of the above light-emitting devices in which the heteroaromatic ring having two or more nitrogen atoms is any of Structural Formulae (B-1) to (B-32).

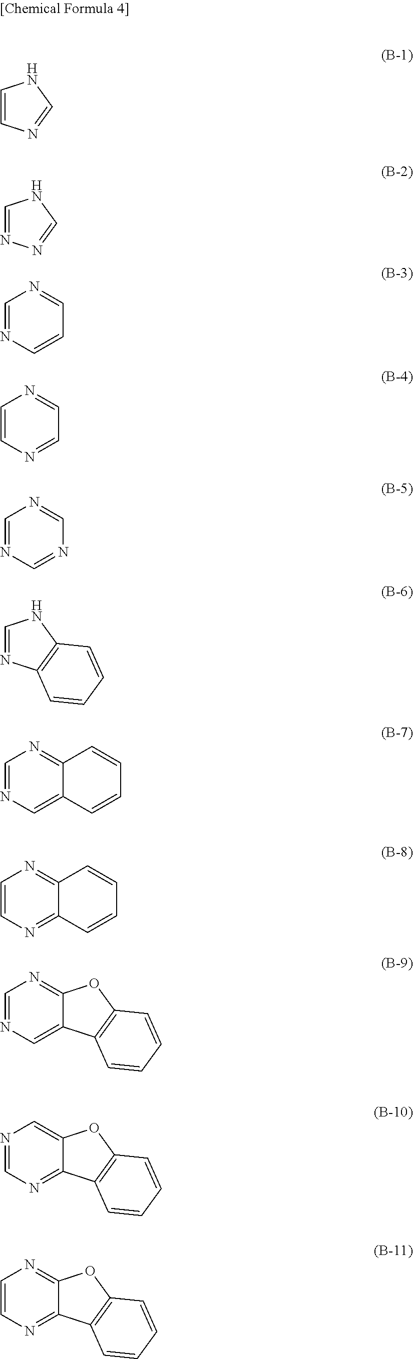

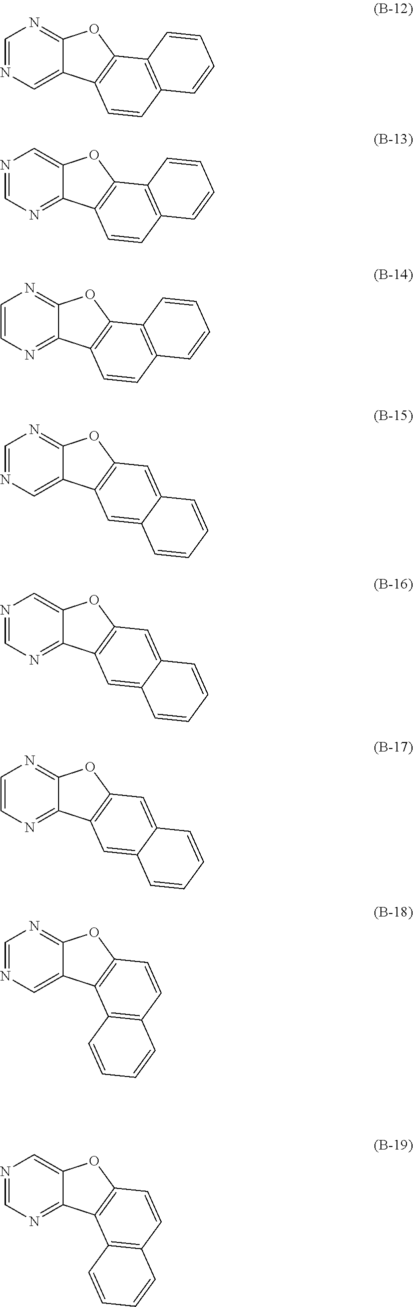

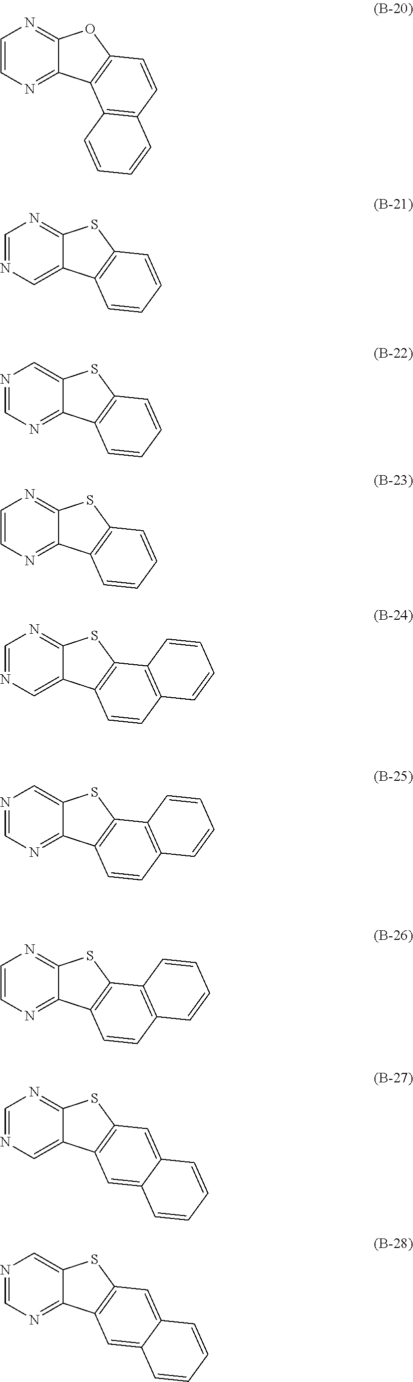

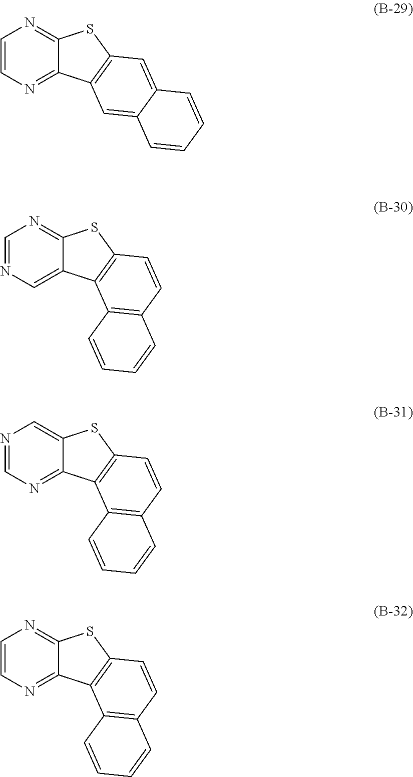 [SMILES: c1ccc2cc3c(cc2c1)sc1nccnc13 ; c1ccc2c(c1)ccc1sc3ncncc3c12 ; c1ccc2c(c1)ccc1sc3cncnc3c12 ; c1ccc2c(c1)ccc1sc3nccnc3c12]

Another embodiment of the present invention is a light-emitting apparatus including any of the above light-emitting devices, and a transistor or a substrate.

Another embodiment of the present invention is an electronic device including the above light-emitting apparatus, and a sensor unit, an input unit, or a communication unit.

Another embodiment of the present invention is a lighting device including the above light-emitting apparatus and a housing.

One embodiment of the present invention can provide a highly reliable light-emitting device. Another embodiment of the present invention can provide a light-emitting device having high emission efficiency. Another embodiment of the present invention can provide a novel light-emitting device.

Another embodiment of the present invention can provide a light-emitting apparatus, an electronic device, or a lighting device having a long lifetime. Another embodiment of the present invention can provide a light-emitting apparatus, an electronic device, or a lighting device having low power consumption. Another embodiment of the present invention can provide a novel light-emitting device, a novel electronic device, or a novel lighting device.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

In the accompanying drawings:

FIGS. 1A to 1E illustrate structures of light-emitting devices of an embodiment;

FIGS. 2A to 2D illustrate a light-emitting apparatus of an embodiment;

FIGS. 3A to 3C illustrate a manufacturing method of a light-emitting apparatus of an embodiment;

FIGS. 4A to 4C illustrate a manufacturing method of a light-emitting apparatus of an embodiment;

FIGS. 5A to 5D illustrate a manufacturing method of a light-emitting apparatus of an embodiment; FIGS. 6A to 6C illustrate a manufacturing method of a light-emitting apparatus of an embodiment;

FIGS. 7A to 7F illustrate a light-emitting apparatus of an embodiment;

FIGS. 8A and 8B illustrate a light-emitting apparatus of an embodiment;

FIGS. 9A to 9E illustrate electronic devices of an embodiment;

FIGS. 10A to 10E illustrate electronic devices of an embodiment;

FIGS. 11A and 11B illustrate electronic devices of an embodiment;

FIGS. 12A and 12B illustrate a lighting device of an embodiment;

FIG. 13 illustrates a lighting device of an embodiment;

FIGS. 14A to 14C each illustrate a light-emitting device and a light-receiving device of an embodiment;

FIG. 15 shows the luminance-current density characteristics of a light-emitting device 1 and a light-emitting device 2;

FIG. 16 shows the current efficiency-luminance characteristics of the light-emitting devices 1 and 2;

FIG. 17 shows the luminance-voltage characteristics of the light-emitting devices 1 and 2;

FIG. 18 shows the current-voltage characteristics of the light-emitting devices 1 and 2;

FIG. 19 shows the electroluminescence spectra of the light-emitting devices 1 and 2;

FIG. 20 shows a luminance change over driving time of the light-emitting devices 1 and 2;

FIG. 21 shows the luminance-current density characteristics of a light-emitting device 3 and a comparative light-emitting device 4 to a comparative light-emitting device 6;

FIG. 22 shows the current efficiency-luminance characteristics of the light-emitting device 3 and the comparative light-emitting devices 4 to 6;

FIG. 23 shows the luminance-voltage characteristics of the light-emitting device 3 and the comparative light-emitting devices 4 to 6;

FIG. 24 shows the current-voltage characteristics of the light-emitting device 3 and the comparative light-emitting devices 4 to 6;

FIG. 25 shows the electroluminescence spectra of the light-emitting device 3 and the comparative light-emitting devices 4 to 6;

FIG. 26 shows the luminance-current density characteristics of the light-emitting device 3, the comparative light-emitting device 4, a comparative light-emitting device 7, and a comparative light-emitting device 8;

FIG. 27 shows the current efficiency-luminance characteristics of the light-emitting device 3 and the comparative light-emitting devices 4, 7, and 8;

FIG. 28 shows the luminance-voltage characteristics of the light-emitting device 3 and the comparative light-emitting devices 4, 7, and 8;

FIG. 29 shows the current-voltage characteristics of the light-emitting device 3 and the comparative light-emitting devices 4, 7, and 8;

FIG. 30 shows the electroluminescence spectra of the light-emitting device 3 and the comparative light-emitting devices 4, 7, and 8;

FIG. 31 shows a luminance change over driving time of the light-emitting device 3 and the comparative light-emitting devices 4 to 6;

FIG. 32 shows a luminance change over driving time of the light-emitting device 3 and the comparative light-emitting devices 4, 7, and 8;

FIGS. 33A to 33C show results of analysis by calculation performed on 8mpTP-4mDBtPBfpm;

FIGS. 34A to 34C show results of analysis by calculation performed on an organic compound represented by Structural Formula (216);

FIGS. 35A to 35C show results of analysis by calculation performed on 8BP-4mDBtPBfpm;

FIG. 36 shows measurement results of emission spectra of 8mpTP-4mDBtPBfpm and 8mpTP-4mDBtPBfpm-d₂₃;

FIG. 37 shows measurement results of an emission spectrum of 8mpTP-4mDBtPBfpm-d₁₃;

FIG. 38 shows measurement results of an emission spectrum of 8mpTP-4mDBtPBfpm-d₁₀;

FIG. 39 shows measurement results of emission lifetimes of 8mpTP-4mDBtPBfpm and 8mpTP-4mDBtPBfpm-d₂₃;

FIG. 40 shows the luminance-current density characteristics of a light-emitting device 9 and a light-emitting device 10;

FIG. 41 shows the current efficiency-luminance characteristics of the light-emitting devices 9 and 10;

FIG. 42 shows the luminance-voltage characteristics of the light-emitting devices 9 and 10;

FIG. 43 shows the current-voltage characteristics of the light-emitting devices 9 and 10;

FIG. 44 shows the electroluminescence spectra of the light-emitting devices 9 and 10; and

FIG. 45 shows a luminance change over driving time of the light-emitting devices 9 and 10.

### DETAILED DESCRIPTION OF THE INVENTION

Embodiments will be described in detail with reference to the drawings. Note that the embodiments of the present invention are not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not denoted by specific reference numerals in some cases.

The position, size, range, or the like of each component illustrated in drawings does not represent the actual position, size, range, or the like in some cases for easy understanding. Therefore, the disclosed invention is not necessarily limited to the position, size, range, or the like disclosed in the drawings.

Note that the terms “film” and “layer” can be used interchangeably depending on the case or the circumstances. For example, the term “conductive layer” can be replaced with the term “conductive film”. As another example, the term “insulating film” can be replaced with the term “insulating layer”.

In this specification and the like, a device formed using a metal mask or a fine metal mask (FMM) is sometimes referred to as a device having a metal mask (MM) structure. In this specification and the like, a device formed without using a metal mask or an FMM is sometimes referred to as a device having a metal maskless (MML) structure.

In this specification and the like, a hole or an electron is sometimes referred to as a carrier. Specifically, a hole-injection layer or an electron-injection layer may be referred to as a carrier-injection layer, a hole-transport layer or an electron-transport layer may be referred to as a carrier-transport layer, and a hole-blocking layer or an electron-blocking layer may be referred to as a carrier-blocking layer. Note that the above-described carrier-injection layer, carrier-transport layer, and carrier-blocking layer cannot be distinguished from each other depending on the cross-sectional shape or properties in some cases. One layer may have two or three functions of the carrier-injection layer, the carrier-transport layer, and the carrier-blocking layer in some cases.

In this specification and the like, a light-emitting device (also referred to as a light-emitting element) includes an EL layer between a pair of electrodes. The EL layer includes at least a light-emitting layer. In this specification and the like, a light-receiving device (also referred to as a light-receiving element) includes at least an active layer functioning as a photoelectric conversion layer between a pair of electrodes. In this specification and the like, one of the pair of electrodes may be referred to as a pixel electrode and the other may be referred to as a common electrode.

In this specification and the like, a tapered shape indicates a shape in which at least part of a side surface of a component is inclined to a substrate surface. For example, a tapered shape preferably includes a region where the angle between the inclined side surface and the substrate surface (such an angle is also referred to as a taper angle) is less than 90°. Note that the side surface of the component and the substrate surface is not necessarily completely flat, and may have a substantially planar shape with a small curvature or slight unevenness.

Note that the light-emitting apparatus in this specification includes, in its category, an image display device that uses a light-emitting device. The light-emitting apparatus may also include a module in which a light-emitting device is provided with a connector such as an anisotropic conductive film or a tape carrier package (TCP), a module in which a printed wiring board is provided at the end of a TCP, and a module in which an integrated circuit (IC) is directly mounted on a light-emitting device by a chip on glass (COG) method. Furthermore, a lighting device or the like may include the light-emitting apparatus.

### Embodiment 1

In this embodiment, a light-emitting device of one embodiment of the present invention will be described. With a device structure described in this embodiment, a highly reliable light-emitting device can be provided.

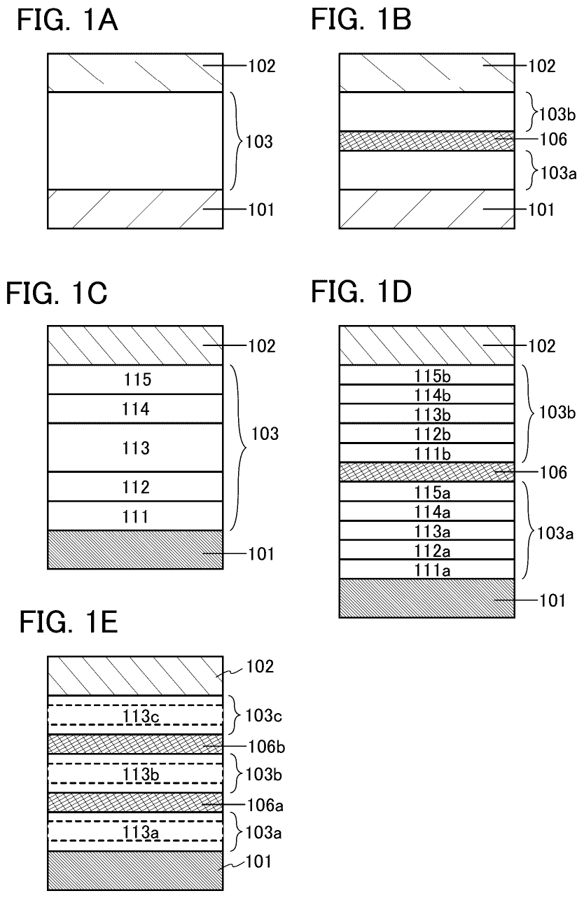

FIG. 1A is a schematic cross-sectional view of a light-emitting device 100 including, between a pair of electrodes, an EL layer including a light-emitting layer. Specifically, the light-emitting device 100 has a structure where an EL layer 103 is interposed between a first electrode 101 and a second electrode 102. The EL layer 103 includes at least a light-emitting layer.

The light-emitting layer contains at least a light-emitting substance and a host material. The light-emitting substance and the host material that are preferably used for the light-emitting device of one embodiment of the present invention are described below.

<<Light-Emitting Substance>>

As the light-emitting substance, it is possible to use an organometallic complex containing a central metal and ligands, in which at least one of the ligands includes a skeleton formed by a ring A¹ and a pyridine ring bonded to each other, the ring A¹ represents an aromatic ring or a heteroaromatic ring, and the pyridine ring includes an alkyl group having 1 to 6 carbon atoms. The alkyl group having 1 to 6 carbon atoms is preferably substituted with deuterium. The ligand is preferably coordinated to the central metal of the organometallic complex with any atom in the ring A¹ and nitrogen of the pyridine ring.

Note that in this specification and the like, coordination means arrangement of atoms, molecules, or ions around an atom or an ion.

In this specification and the like, an aromatic ring includes not only a monocyclic aromatic ring, but also a polycyclic aromatic ring formed by condensation of a plurality of monocyclic aromatic rings. The heteroaromatic ring includes not only a monocyclic heteroaromatic ring, but also a polycyclic heteroaromatic ring formed by condensation of a plurality of monocyclic heteroaromatic rings and a polycyclic heteroaromatic ring formed by condensation of one or more monocyclic aromatic rings and another one or more monocyclic heteroaromatic rings.

The organometallic complex emits phosphorescent light. The use of such an organometallic complex for the light-emitting layer enables the light-emitting device 100 to function as a phosphorescent light-emitting device.

In the organometallic complex, the pyridine ring included in at least one of the ligands that are coordinated to the central metal includes an alkyl group (hereinafter, such a pyridine ring is sometimes simply referred to as a pyridine ring). An alkyl group is an electron-donating group, and thus can increase the electron density of the pyridine ring when introduced thereto. The increase in electron density increases a distance between the nitrogen of the pyridine ring and the central metal, so that the highest occupied molecular orbital (HOMO) level and the lowest unoccupied molecular orbital (LUMO) level of the organometallic complex become high (shallow). The use of the organometallic complex with a shallow HOMO level as the light-emitting substance of the light-emitting layer can reduce a hole-injection barrier in the light-emitting layer and promotes hole injection to the light-emitting layer, thereby decreasing the driving voltage of the light-emitting device 100. Thus, a drive load on the light-emitting device 100 is reduced and the reliability of the light-emitting device can be improved. In addition, when an alkyl group is introduced into the organometallic complex, the light emission characteristics of the organometallic complex can be adjusted.

Note that in the case where the alkyl group included in the pyridine ring of the above organometallic complex has too many carbon atoms, the sublimation property might decrease. Therefore, the alkyl group introduced into the pyridine ring preferably has 1 to 6 carbon atoms, to prevent a decrease in sublimation property of the organometallic complex.

In addition, in the organometallic complex, the alkyl group having 1 to 6 carbon atoms included in the pyridine ring is preferably substituted with deuterium. The bond dissociation energy of a bond between carbon and deuterium is higher than that of a bond between carbon and protium, and thus is stable and not easily cut. Accordingly, introducing an alkyl group substituted with deuterium into the ligand can make the ligand more stable than the case of introducing an alkyl group not substituted with deuterium.

Furthermore, in the organometallic complex, the nitrogen of the pyridine ring including an alkyl group having 1 to 6 carbon atoms is coordinated to the central metal. This can stabilize not only the ligand but also coordination of the ligand to the central metal, thereby stabilizing the organometallic complex including the ligand. Thus, the use of the organometallic complex can improve the reliability of the light-emitting device.

In this specification and the like, the term “deuterated” or “substituted with deuterium” is used when there is a need to specify that the proportion of deuterium in hydrogen contained in a certain compound, partial structure, or group (atomic group) is at least 100 times as high as the proportion at the natural abundance level. In addition, “alkyl group substituted with deuterium” means that at least one hydrogen atom in the alkyl group is replaced with deuterium.

Next, more specific structures of the organometallic complex are described using chemical formulae. Note that descriptions of an effect and the like related to the organometallic complex are applied to the specific structures of the organometallic complex described below.

As the organometallic complex, for example, it is possible to use an organometallic complex containing a central metal and ligands, in which at least one of the ligands has a structure represented by General Formula (L1).

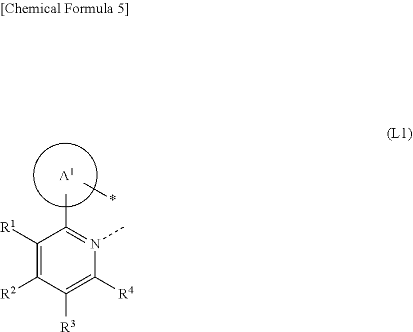

In General Formula (L1), * represents a bond for a central metal; a dashed line represents coordination to the central metal; the ring A¹ represents an aromatic ring or a heteroaromatic ring; at least one of R¹ to R⁴ is an alkyl group having 1 to 6 carbon atoms and being substituted with deuterium; and each of the others of R¹ to R⁴ independently represents any of hydrogen (including deuterium), an alkyl group having 1 to 6 carbon atoms, and a substituted or unsubstituted aryl group having 6 to 13 carbon atoms in a ring.

In the ligand represented by General Formula (L1), each of R¹ and R⁴ is preferably hydrogen (including deuterium). It is further preferable that R³ be an alkyl group having 1 to 6 carbon atoms and being substituted with deuterium. In this case, coordination to the central metal can be prevented from being unstabilized by a three-dimensional effect of the substituents, so that the organic metallic complex can be more stable.

Alternatively, as the organometallic complex, an organic metallic complex represented by General Formula (G1) can be used, for example.

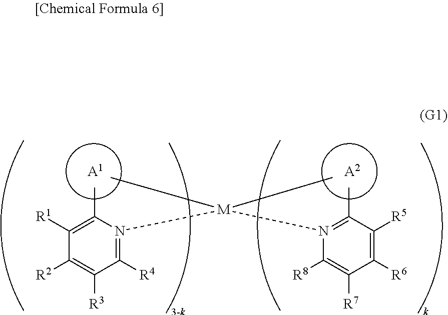

In General Formula (G1), M represents a central metal; a dashed line represents coordination; each of the ring A¹ and a ring A² independently represents an aromatic ring or a heteroaromatic ring; at least one of R¹ to R⁴ is an alkyl group having 1 to 6 carbon atoms and being substituted with deuterium; each of the others of R¹ to R⁴ independently represents any of hydrogen (including deuterium), an alkyl group having 1 to 6 carbon atoms, and a substituted or unsubstituted aryl group having 6 to 13 carbon atoms in a ring; each of R⁵ to R⁸ independently represents any of hydrogen (including deuterium), an alkyl group having 1 to 6 carbon atoms, and a substituted or unsubstituted aryl group having 6 to 13 carbon atoms in a ring; and k represents an integer of 0 to 2.

In the organometallic complex represented by General Formula (G1), each of R¹ and R⁴ is preferably hydrogen (including deuterium). It is further preferable that R³ be an alkyl group having 1 to 6 carbon atoms and being substituted with deuterium. In this case, coordination to the central metal can be prevented from being unstabilized by a three-dimensional effect of the substituents, so that the organic metallic complex can be more stable.

Specific examples of the aromatic ring and the heteroaromatic ring that can be used as the ring A¹ in the ligand represented by General Formula (L1) and the rings A¹ and A² in the organometallic complex represented by General Formula (G1) are an aromatic ring having 6 to 13 carbon atoms and a heteroaromatic ring having 2 to 13 carbon atoms. Other specific examples of the aromatic ring and the heteroaromatic ring that can be used as the rings A¹ and A² are Structural Formulae (A-1) to (A-29). When there are a plurality of rings A¹ or rings A², the rings A¹ or the rings A² may be the same or different from each other.

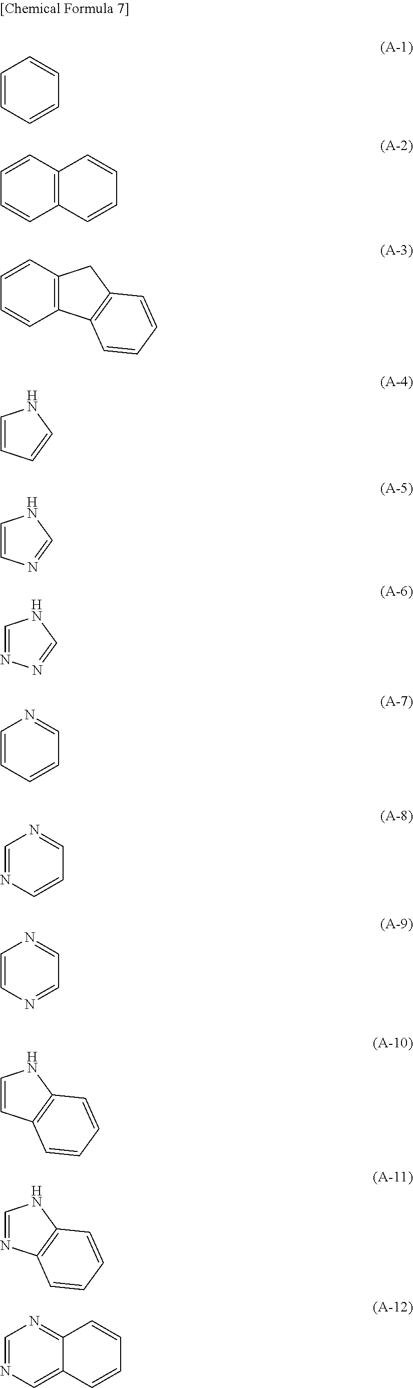

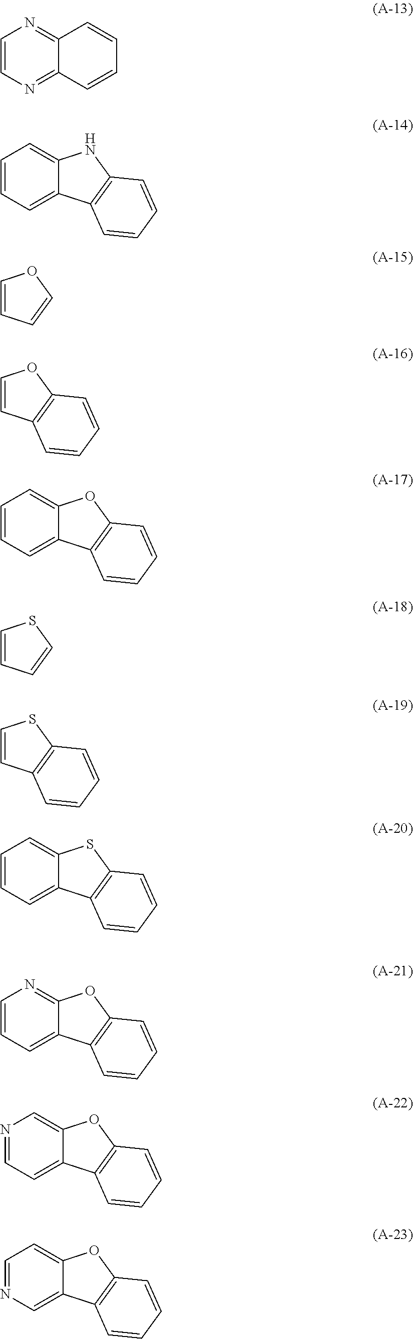

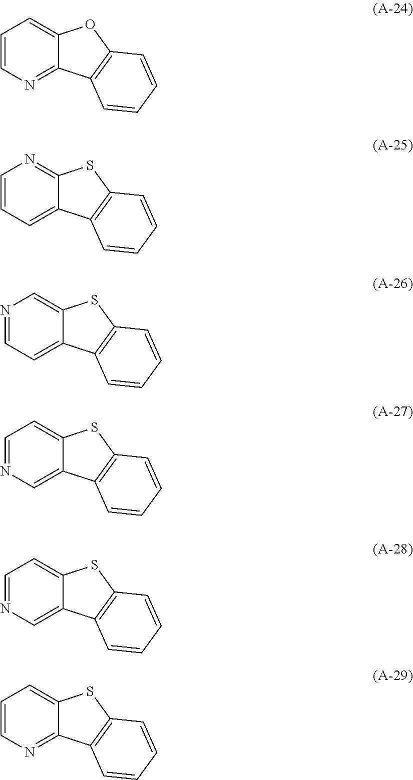

Although the aromatic rings and the heteroaromatic rings represented by Structural Formulae (A-1) to (A-29) are specific examples of the rings A¹ and A², the aromatic ring and the heteroaromatic ring that can be used as the rings A¹ and A² are not limited thereto. In addition, the aromatic rings and the heteroaromatic rings represented by Structural Formulae (A-1) to (A-29) may each be substituted with deuterium.

Note that the ring A¹ or A² may further include a substituent. In the case where the ring A¹ or A² includes a substituent, specific examples of the substituent are an alkyl group having 1 to 6 carbon atoms and an aryl group having 6 to 13 carbon atoms. In the case where the substituent is an alkyl group having 1 to 6 carbon atoms, the alkyl group having 1 to 6 carbon atoms is preferably substituted with deuterium. In this case, an effect similar to the effect of introducing an alkyl group having 1 to 6 carbon atoms and being substituted with deuterium into a pyridine ring can be obtained.

Alternatively, as the organometallic complex, an organometallic complex represented by General Formula (G2) can be used, for example.

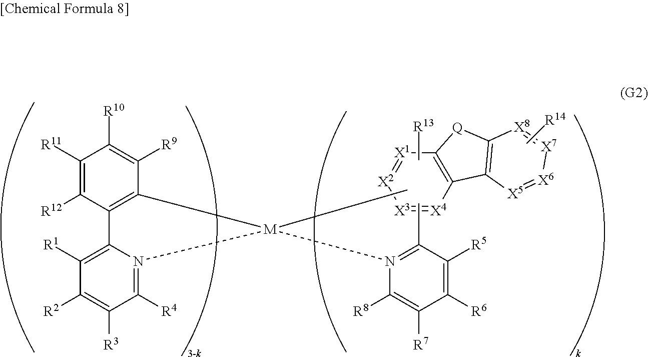

In General Formula (G2), M represents a central metal; a dashed line represents coordination; Q represents oxygen or sulfur, each of X¹ to X⁸ independently represents nitrogen or carbon (including CH); at least one of R¹ to R⁴ is an alkyl group having 1 to 6 carbon atoms and being substituted with deuterium; each of the others of R¹ to R⁴ independently represents hydrogen (including deuterium), an alkyl group having 1 to 6 carbon atoms, or a substituted or unsubstituted aryl group having 6 to 13 carbon atoms in a ring; each of R⁵ to R¹⁴ independently represents hydrogen (including deuterium), an alkyl group having 1 to 6 carbon atoms, or a substituted or unsubstituted aryl group having 6 to 13 carbon atoms in a ring; and k represents an integer of 0 to 2.

In the organometallic complex represented by General Formula (G2), each of R¹ and R⁴ is preferably hydrogen (including deuterium). It is further preferable that R³ be an alkyl group having 1 to 6 carbon atoms and being substituted with deuterium. In this case, coordination to the central metal can be prevented from being unstabilized by a three-dimensional effect of the substituents, so that the organic metallic complex can be more stable.

For more efficient phosphorescent emission of the organometallic complex, the central metal M is preferably a heavy metal in terms of a heavy atom effect. Thus, in the above organometallic complexes, one preferable embodiment is an organometallic complex in which the central metal M is iridium or platinum. It is further preferable that iridium be used as the central metal M, in which case the thermal and chemical stabilities of the organometallic complex can be improved.

In the organometallic complex, specific examples of the alkyl group having 1 to 6 carbon atoms are a methyl group, an ethyl group, a propyl group, an isopropyl group, a butyl group, an isobutyl group, a sec-butyl group, a tert-butyl group, a pentyl group, an isopentyl group, and a hexyl group. Note that these groups may each be substituted with deuterium, regardless of whether or not there is a statement that deuterium substitution is preferable.

In the organometallic complex, specific examples of the alkyl group having 1 to 6 carbon atoms and being substituted with deuterium are a methyl-d₃ group, an ethyl-d₅ group, a propyl-d₇ group, a 2-propyl-2-d group, an isopropyl-d₇ group, a butyl-d₉ group, a 2-methyl-1-propyl-1,1-d₂ group, an isobutyl-d₉ group, a sec-butyl-d₉ group, a tert-butyl-d₉ group, a pentyl-d₁₁ group, an isopentyl-d₁₁ group, and a hexyl-d₁₃ group.

In the organic metallic complex, specific examples of the aryl group having 6 to 13 carbon atoms in a ring are a phenyl group, a tolyl group, a xylyl group, a biphenyl group, an indenyl group, a naphthyl group, and a fluorenyl group. Note that these groups may each be substituted with deuterium.

In the organometallic complex, when the aryl group having 6 to 13 carbon atoms in a ring further includes a substituent, specific examples of the substituent are an alkyl group having 1 to 6 carbon atoms and an aryl group having 6 to 13 carbon atoms in a ring. Note that these groups may each be substituted with deuterium.

Specific structural formulae of the organometallic complex that can be used as the light-emitting substance in the light-emitting device 100 are shown below. Note that the present invention is not limited to these formulae.

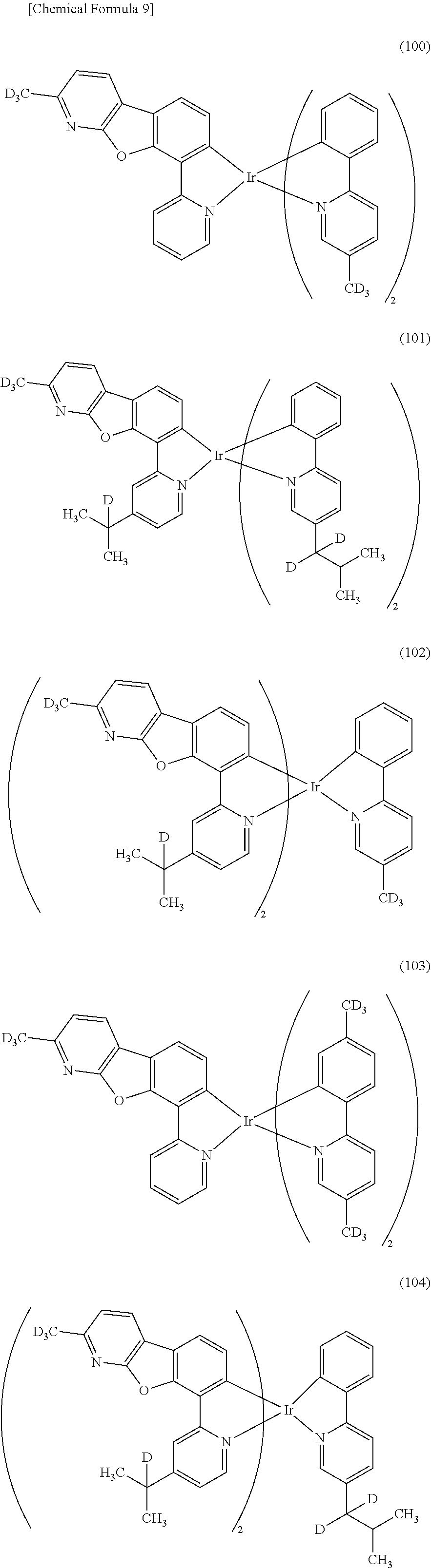

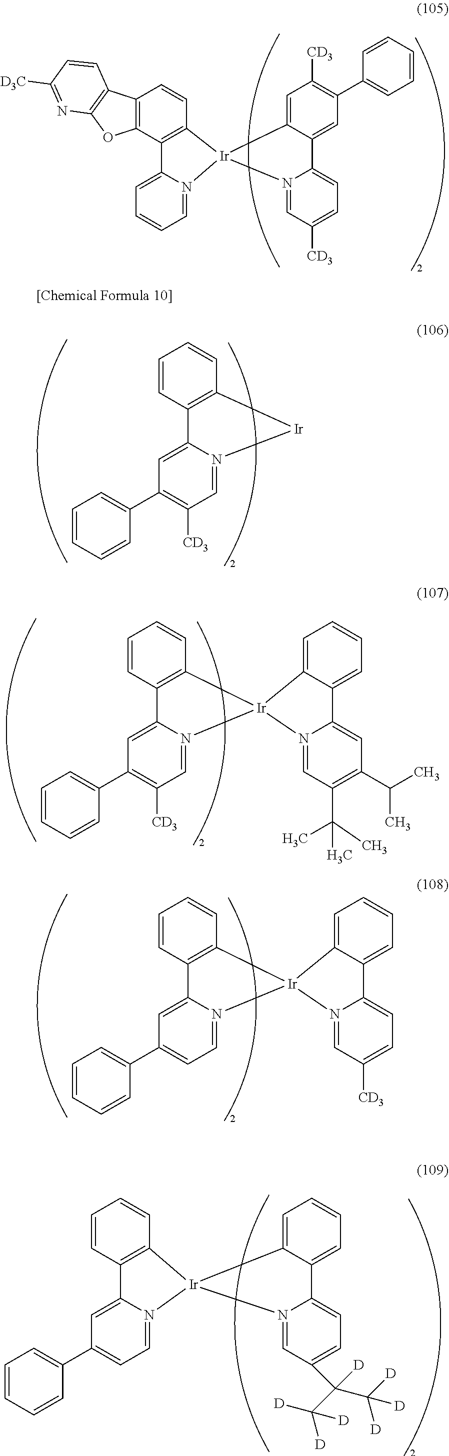

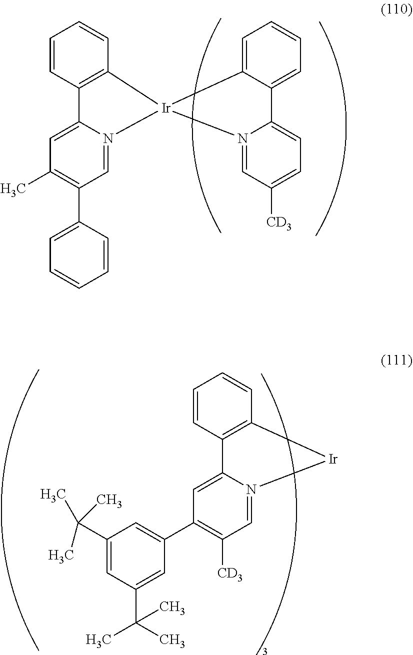

### <<Host Material>>

As the host material, it is possible to use an organic compound including an electron-transport skeleton and first and second substituents that are bonded to the electron-transport skeleton. In the organic compound, the electron-transport skeleton preferably includes a heteroaromatic ring having two or more nitrogen atoms, and the first substituent preferably includes one or both of an aromatic ring and a heteroaromatic ring. In the organic compound, the second substituent preferably includes a hole-transport skeleton. In the organic compound, the lowest triplet excited state (i.e., triplet exciton) is preferably locally distributed in the first substituent. Hereinafter, an organic compound having such a structure is referred to as a first organic compound.

The lowest triplet excitation energy (an energy difference between a ground state (S₀) and the lowest triplet excited state (T₁), hereinafter referred to as the T₁ level) of the first organic compound is higher than that of the above-described organometallic complex that can be used as the light-emitting substance. When the first organic compound is used as the host material together with the light-emitting substance in the light-emitting layer, energy can be transferred from the first organic compound in a triplet excited state to the light-emitting substance, whereby the light-emitting substance can emit light efficiently.

In the case where v=0→v=0 transfer (0→0 band) between vibration levels of a ground state and an excited state is clearly observed in a fluorescent spectrum or a phosphorescent spectrum, the Si level (an energy difference between a ground state (S₀) and the lowest singlet excited state (S₁)) or the T₁ level of the organic compound is preferably calculated using the 0→0 band (see Non-Patent Document 1, for example). In the case where the 0→0 band is unclear, the energy level at an intersection between the horizontal axis (representing wavelength) or the base line and a tangent with the highest inclination drawn at a point on the short-wavelength side of a peak of a fluorescent spectrum is used as the S₁ level. In addition, the energy level at an intersection between the horizontal axis (representing wavelength) or the base line and a tangent with the highest inclination drawn at a point on the short-wavelength side of a peak of a phosphorescent spectrum is used as the T₁ level (see Non-patent document 2, for example). In this specification, the levels are measured by the latter method. In the case where the levels are compared, the levels calculated by the same method are used.

When the T₁ level of the first organic compound used as the host material is much larger than that of the light-emitting substance, the energy transfer becomes incomplete and the efficiency and reliability of the light-emitting device are likely to decrease. Thus, a difference between the T₁ level of the host material and that of the light-emitting substance is preferably greater than or equal to 0 eV and less than or equal to 0.40 eV, further preferably greater than or equal to 0 eV and less than or equal to 0.20 eV. This can improve the efficiency and reliability of the light-emitting device.

Note that the first organic compound includes an electron-transport skeleton and the second substituent having a hole-transport skeleton. Thus, it can be said that the first organic compound is an electron-transport material, a hole-transport material, and a bipolar material having both an electron-transport property and a hole-transport property.

In the first organic compound, the lowest triplet excited state is locally distributed in the first substituent. Thus, the lowest triplet excited state is less likely to be distributed in the electron-transport skeleton and the hole-transport skeleton (the second substituent). Therefore, in the case where the first organic compound is used as a host material of a light-emitting device, deterioration of the electron-transport skeleton and the hole-transport skeleton included in the first organic compound is inhibited. The use of the first organic compound can improve the reliability of the light-emitting device.

In addition, in the first organic compound having the above structure, the LUMO tends to be distributed in the electron-transport skeleton. Since the lowest triplet excited state is locally distributed in the first substituent as described above, a position where LUMO is distributed is different from a position where the lowest triplet excited state is locally distributed. This can increase the stability of the light-emitting device that uses the first organic compound, thereby improving the reliability of the light-emitting device.

However, when the position where LUMO is distributed is too apart from the position where the lowest triplet excited state is locally distributed in the first organic compound, the property of the first organic compound as the host material might be insufficient. Thus, it is preferable that the position where the LUMO is distributed and the position where the lowest triplet excited state is locally distributed be adjacent to each other and do not overlap with each other, in which case the organic compound can have a favorable property as the host material and high stability.

In this specification and the like, the lowest triplet excited state (i.e., triplet exciton) can be regarded as being locally distributed in a partial structure of the most stable structure of the organic compound in the lowest triplet excited state, in which the spin density is distributed. Since the amplitude structure of the organic compound is derived from the partial structure where the lowest triplet excited state is locally distributed, the partial structure of the organic compound where the lowest triplet excited state is locally distributed can be found from the waveform of the emission spectrum of the organic compound, in some cases.

Next, more specific structures of the organometallic complex are described using chemical formulae. Note that descriptions of an effect or the like related to the first organic compound are applied to the specific structures of the first organic compound described below.

As the first organic compound, an organic compound represented by General Formula (G10) can be used, for example.

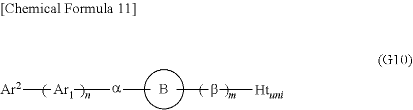

In General Formula (G10), the ring B represents a heteroaromatic ring having two or more nitrogen atoms, α represents either a substituted or unsubstituted o-phenylene group or a substituted or unsubstituted m-phenylene group, each of Ar¹ and Ar² independently represents an aromatic ring or a heteroaromatic ring, β represents a substituted or unsubstituted phenylene group, Htᵤₙᵢ represents a skeleton having a hole-transport property, and each of n and m independently represents an integer of 0 to 4.

Note that the ring B that is a partial structure of General Formula (G10) corresponds to an electron-transport skeleton, a substituent represented by General Formula (S1) corresponds to the first substituent, and a substituent represented by General Formula (S2) corresponds to the second substituent. Although General Formula (G10) shows a structure where one first substituent and one second substituent are bonded to the ring B, the present invention is not limited thereto. When one or more first substituents and one or more second substituents are bonded to the ring B, the compound can be used as the first organic compound.

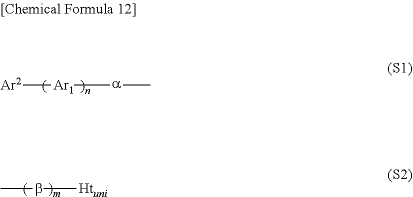

Next, the partial structures (the electron-transport skeleton, the first substituent, and the second substituent) of the first organic compound will be described in detail.

### <Electron-Transport Skeleton>

As the electron-transport skeleton (the ring B), a π-electron deficient heteroaromatic ring can be used. Specifically, as the electron-transport skeleton (the ring B), a heteroaromatic ring having two or more nitrogen atoms can be used. More specifically, the heteroaromatic ring having two or more nitrogen atoms is preferably a heteroaromatic ring having two or more nitrogen atoms and having 2 to 15 carbon atoms in a ring. Specific examples of a π-electron deficient heteroaromatic ring that can be used as the electron-transport skeleton are heteroaromatic rings represented by Structural Formulae (B-1) to (B-32).

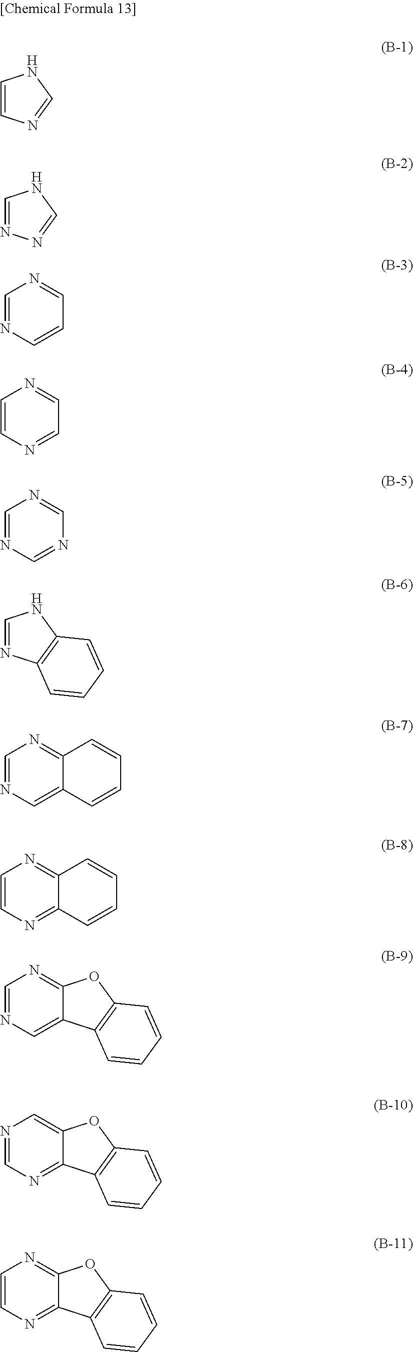

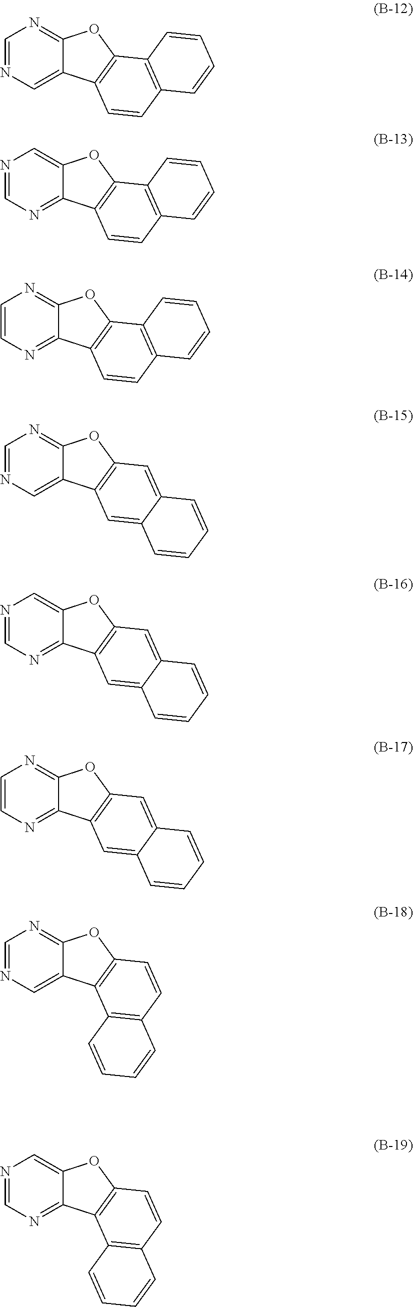

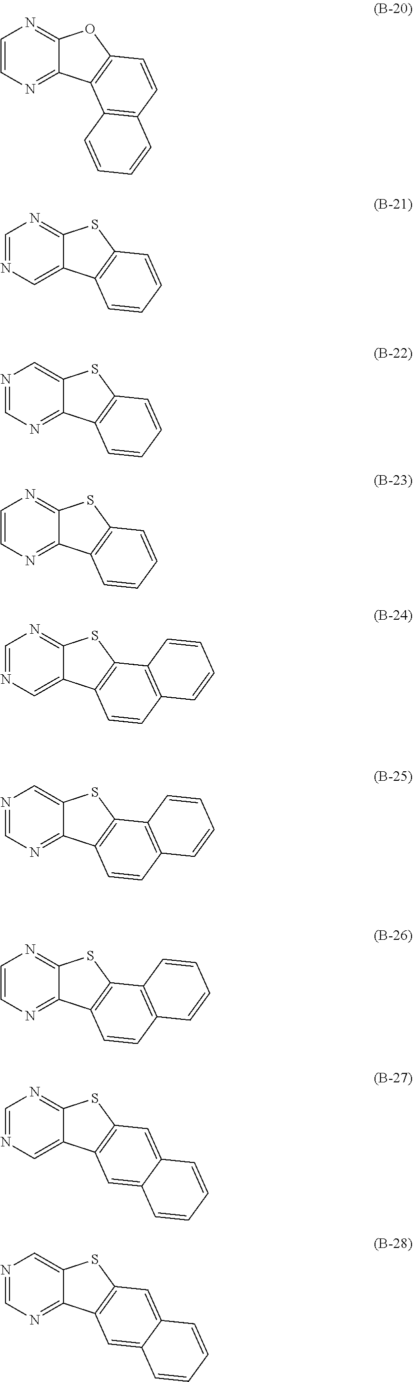

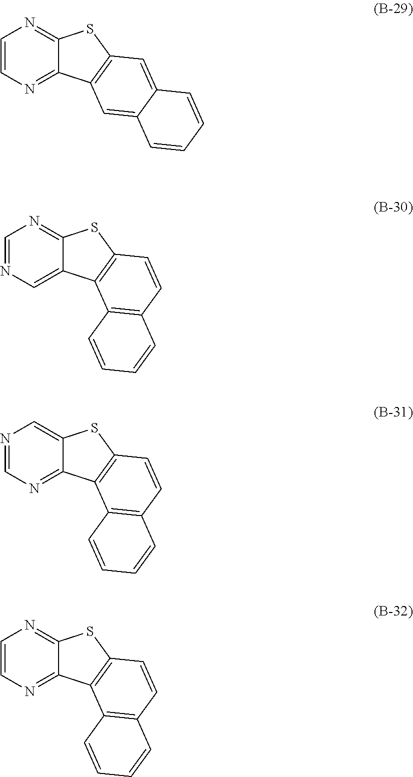 [SMILES: c1ccc2cc3c(cc2c1)sc1nccnc13 ; c1ccc2c(c1)ccc1sc3ncncc3c12 ; c1ccc2c(c1)ccc1sc3cncnc3c12 ; c1ccc2c(c1)ccc1sc3nccnc3c12]

Although the heteroaromatic rings each having two or more nitrogen atoms and being represented by Structural Formulae (B-1) to (B-32) are specific examples of the ring B, the ring B is not limited to these examples. Note that these rings may each be substituted with deuterium. Alternatively, the ring B may further include a substituent in addition to the first substituent and the second substituent. In the case where the heteroaromatic ring having two or more nitrogen atoms includes a substituent, specific examples of the substituent are an alkyl group having 1 to 6 carbon atoms and an aryl group having 6 to 13 carbon atoms in a ring.

In General Formula (G10), a benzofuropyrimidine ring (Structural Formulae (B-9) and (B-10)), a benzothienopyrimidine ring (Structural Formulae (B-21) and (B-22)), or a triazine ring (Structural Formula (B-5)) is preferably used as the ring B. In this case, the electron-transport property of the first organic compound can be further increased. In particular, it is further preferable to use a benzofuropyrimidine ring (Structural Formulae (B-9) and (B-10)) or a benzothienopyrimidine ring (Structural Formulae (B-21) and (B-22)) as the ring B, in which case the stability can be further improved.

In the case where a benzofuropyrimidine ring (benzofuro[3,2-d]pyrimidine ring) represented by Structural Formula (B-10) and a benzothienopyrimidine ring (benzothieno[3,2-d]pyrimidine ring) represented by Structural Formula (B-22) are used as the ring B, the first substituent is preferably bonded to the 8-position and the second substituent is preferably bonded to the 4-position. This can further increase the stability of the organic compound.

### <First Substituent>

In the first substituent (a substituent represented by General Formula (S1)), the lowest triplet excited state is locally distributed. The first substituent preferably includes one or both of an aromatic ring and a heteroaromatic ring. It is particularly preferable that the first substituent have a structure where a substituted or unsubstituted o-phenylene group or a substituted or unsubstituted m-phenylene group is bonded to the electron-transport skeleton (the ring B) and an aromatic ring or a heteroaromatic ring is bonded to the o-phenylene group or the m-phenylene group. When the o-phenylene group or the m-phenylene group in the first substituent is bonded to the electron-transport skeleton, the first substituent and the electron-transport skeleton can be prevented from forming a planar structure, whereby a conjugated system can be inhibited from extending between the first substituent and the electron-transport skeleton. Accordingly, in the first organic compound, the position where the LUMO is distributed and the position where the lowest triplet excited state is locally distributed are likely to be different, leading to a higher stability of the first organic compound and higher reliability of the light-emitting device.

As the aromatic ring and the heteroaromatic ring that can be used as Ar¹ and Ar² in the first substituent, specifically, an aromatic ring having 6 to 13 carbon atoms and a heteroaromatic ring having 2 to 13 carbon atoms are preferable. With the use of such a ring, adequate sublimability can be maintained, and accordingly decomposition in sublimation purification or vacuum evaporation can be inhibited. In the case where there are a plurality of Ar¹s, the Ar¹s may be the same or different from each other.

Specific examples of the aromatic ring that can be used as Ar¹ and Ar² are a benzene ring, a naphthalene ring, and a fluorene ring, and the specific examples of the heteroaromatic ring that can be used as Ar¹ and Ar² are a dibenzofuran ring, a dibenzothiophene ring, and a carbazole ring. In the case where the aromatic ring or the heteroaromatic ring further includes a substituent, specific examples of the substituent are an alkyl group having 1 to 6 carbon atoms, an alkoxyl group having 1 to 6 carbon atoms, a monocyclic saturated hydrocarbon group having 5 to 7 carbon atoms, a polycyclic saturated hydrocarbon group having 7 to 10 carbon atoms, and a cyano group.

A portion of the first substituent which is formed by Ar¹ and Ar² preferably has a straight line structure. Specifically, Ar¹ is preferably a para-substituted benzene ring. This makes the conjugation systems in the first substituent be easily connected to each other and the lowest triplet excited state be locally distributed in the first substituent.

In the first substituent, a, Ar¹, and Ar² may be condensed. For example, by formation of a new bond through oxygen or nitrogen, any two or all of a, Ar¹, and Ar² can be condensed. This makes the conjugation systems in the first substituent be easily connected to each other and the lowest triplet excited state be locally distributed in the first substituent.

Thus, the first substituent further preferably has a structure represented by General Formula (S1-A) or (S1-B). Note that these groups may each be substituted with deuterium.

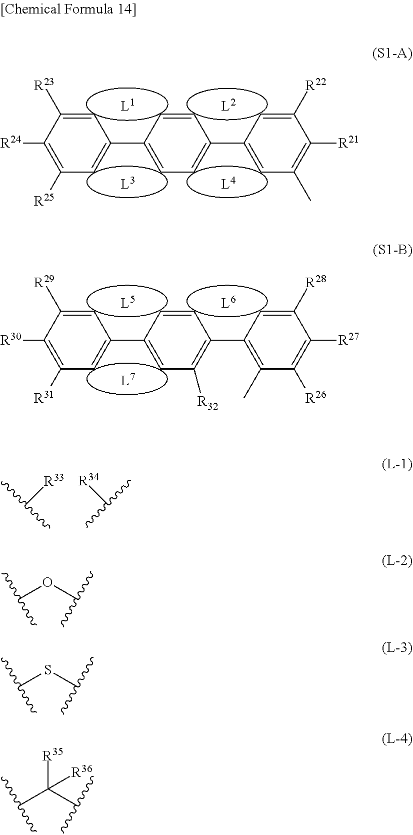

In General Formulae (S1-A) and (S1-B), each of L¹ to L⁷ is independently a partial structure represented by any one of General Formulae (L-1) to (L-4), and each of R²¹ to R³⁶ independently represents any of hydrogen (including deuterium), an alkyl group having 1 to 6 carbon atoms, an alkoxyl group having 1 to 6 carbon atoms, a monocyclic saturated hydrocarbon group having 5 to 7 carbon atoms, a polycyclic saturated hydrocarbon group having 7 to 10 carbon atoms, a cyano group, and an aryl group having 6 to 13 carbon atoms in a ring.

Specific examples of the first substituent (General Formulae (S1), (S1-A), and (S1-B)) are Structural Formulae (S1-1) to (S1-28). These groups may each be substituted with deuterium. Note that the present invention is not limited to these formulae.

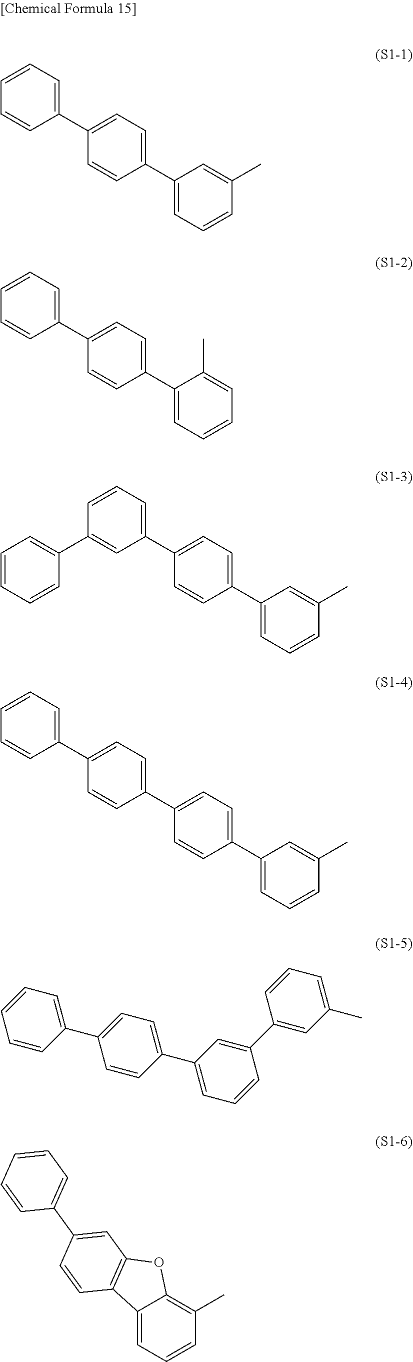

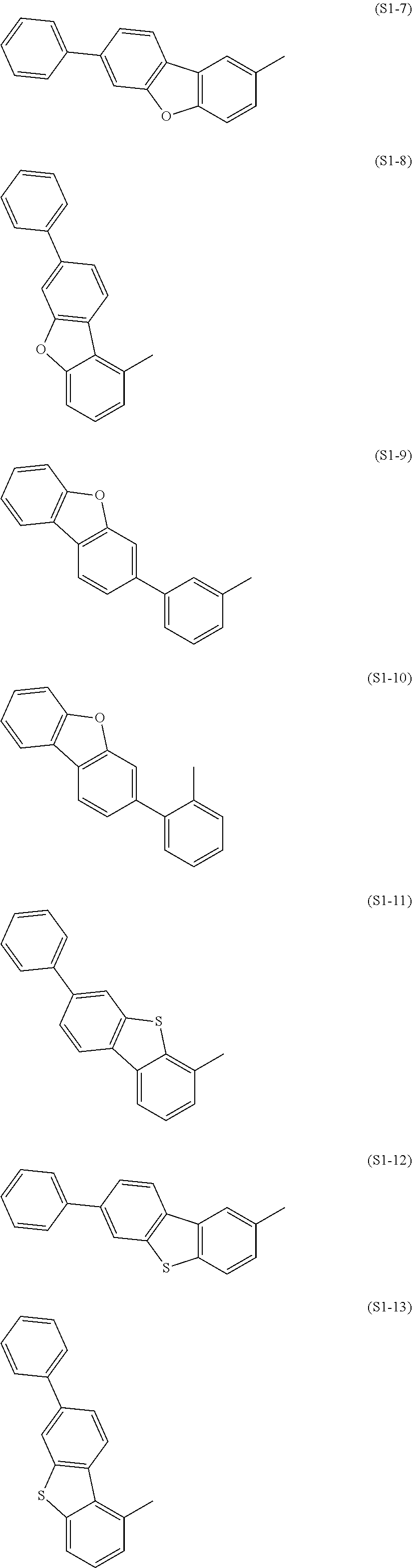

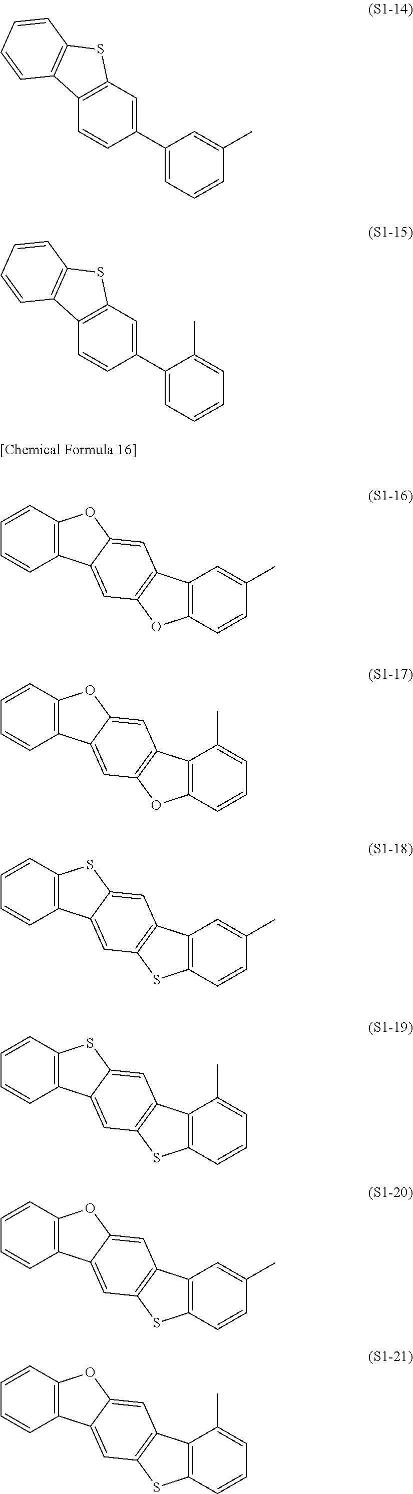

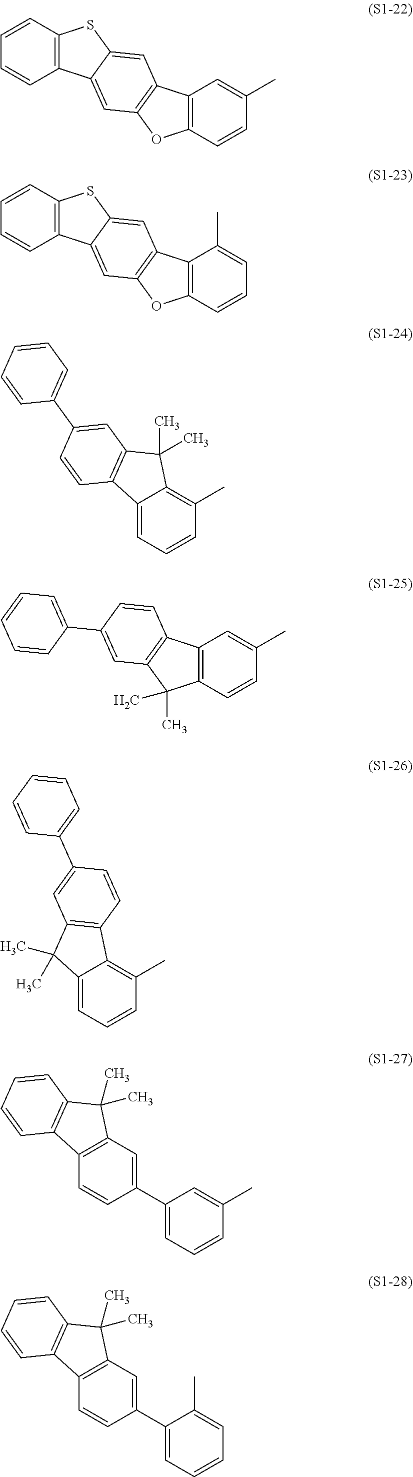

### <Second Substituent>

The second substituent (a substituent represented by General Formula (S2)) includes a hole-transport skeleton, and a group that can give a hole-transport property to the first organic compound is preferably used as the second substituent.

In the case where α is a substituted phenyl group in a substituent represented by General Formula (S2), specific examples of the substituent are an alkyl group having 1 to 6 carbon atoms and a substituted or unsubstituted phenyl group. Note that these groups may each be substituted with deuterium.

As the hole-transport skeleton, a π-electron rich heteroaromatic ring can be used. In General Formula (G10) and General Formula (S2), Htᵤₙᵢ represents a hole-transport skeleton. Specific examples of the hole-transport skeleton (Htᵤₙᵢ) are General Formulae (Ht-1) to (Ht-15). Note that these groups may each be substituted with deuterium. Note that the present invention is not limited to these formulae.

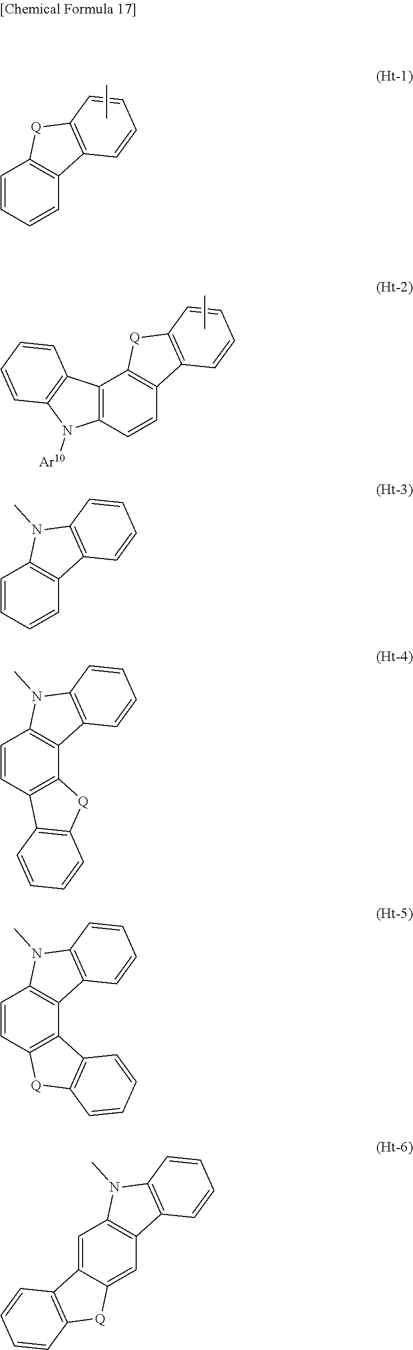

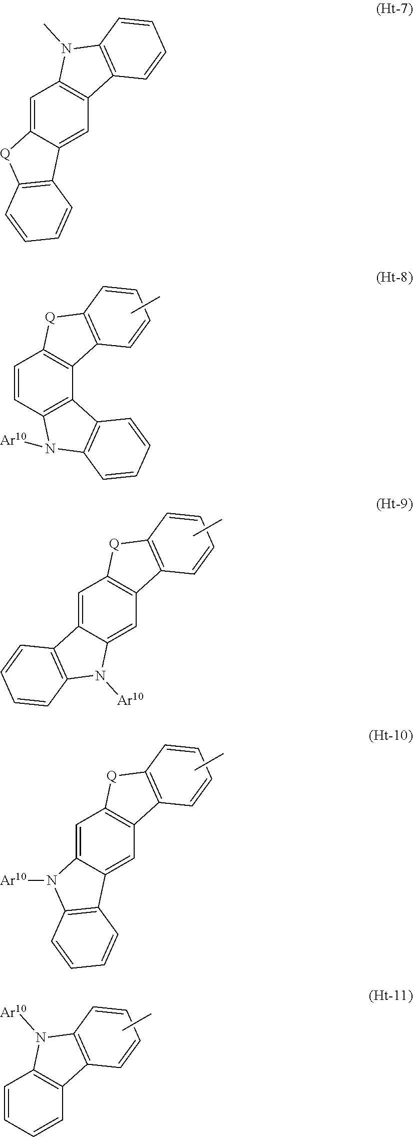

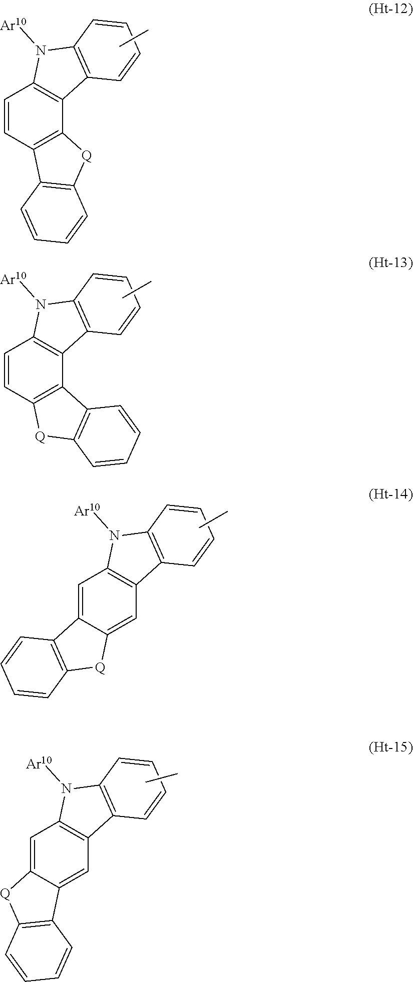

In General Formulae (Ht-1) to (Ht-15), Q represents oxygen or sulfur. Ar¹⁰ represents a substituted or unsubstituted aryl group having 6 to 13 carbon atoms. In addition, General Formulae (Ht-1) to (Ht-15) may each further include a substituent, and specific examples of the substituent are an alkyl group having 1 to 6 carbon atoms and a substituted or unsubstituted phenyl group.

The above is the details of the partial structures (the electron-transport skeleton, the first substituent, and the second substituent) of the first organic compound.

Note that specific examples of the alkyl group having 1 to 6 carbon atoms and the aryl group having 6 to 13 carbon atoms in a ring which can be used in the first organic compound are similar to those of the alkyl group having 1 to 6 carbon atoms and the aryl group having 6 to 13 carbon atoms in a ring which can be used in the organometallic complex.

In the first organic compound, specific examples of the alkoxyl group having 1 to 6 carbon atoms are a methoxy group, an ethoxy group, an n-propoxy group, an isopropoxy group, an n-butoxy group, a sec-butoxy group, an isobutoxy group, a tert-butoxy group, an n-pentyloxy group, an isopentyloxy group, a sec-pentyloxy group, a tert-pentyloxy group, a neo-pentyloxy group, an n-hexyloxy group, an isohexyloxy group, a sec-hexyloxy group, a tert-hexyloxy group, a neo-hexyloxy group, and a cyclohexyloxy group. Note that these groups may each be substituted with deuterium.

In the first organic compound, specific examples of the monocyclic saturated hydrocarbon group having 5 to 7 carbon atoms are a cyclopropyl group, a cyclobutyl group, a cyclopentyl group, a cyclohexyl group, a 1-methylcyclohexyl group, and a cycloheptyl group. Note that these groups may each be substituted with deuterium.

In the first organic compound, specific examples of the polycyclic saturated hydrocarbon group having 7 to 10 carbon atoms are a norbornyl group, an adamantyl group, a decalin group, and a tricyclodecyl group. Note that these groups may each be substituted with deuterium.

In the first organic compound, it is further preferable that any one or more of the electron-transport skeleton, the first substituent, and the second substituent be substituted with deuterium. As described above, the bond dissociation energy of a bond between carbon and deuterium is higher than the bond dissociation energy of a bond between carbon and protium, and thus is stable and not easily cut. Accordingly, substituting any one or more of the electron-transport skeleton, the first substituent, and the second substituent with deuterium can make the first organic compound more stable. Thus, the reliability of the light-emitting device can be improved.

As described above, the lowest triplet excited state is locally distributed in the first substituent of the first organic compound, and thus the first substituent is preferably substituted with deuterium. Although the carbon-hydrogen bond is sometimes easily dissociated due to the lowest triplet excitation, when the first substituent is substituted with deuterium, the dissociation of the carbon-hydrogen bond due to the lowest triplet excitation can be prevented. Accordingly, the deuterated first substituent can effectively prevent deterioration of the first organic compound. Thus, the reliability of the light-emitting device can be improved.

Since deuterium is an atom heavier than protium, the vibration amplitude of the carbon-deuterium bond is smaller than that of the carbon-protium bond. Accordingly, substituting the first substituent with deuterium inhibits intramolecular vibration in the lowest triplet excited state. This can accordingly lower the speed of thermal deactivation (non-radiative transition) of the first organic compound from the triplet excited state; thus, when the first substituent is substituted with deuterium, energy can be efficiently transferred from the first organic compound to the light-emitting substance in the light-emitting layer. Accordingly, deterioration of the first organic compound can be inhibited and the reliability of the light-emitting device can be improved.

When the first organic compound is used as the host material, the hole-transport skeleton included in the second substituent sometimes receives holes; thus, the second substituent is preferably substituted with deuterium. Although the carbon-hydrogen bond is sometimes easily dissociated due to hole donation and acceptance, when the second substituent is substituted with deuterium, the dissociation of the carbon-hydrogen bond due to hole donation and acceptance can be prevented.

Note that synthesis of the first organic compound whose partial structures are entirely deuterated has a problem such as a complicated synthesis pathway or requirement of high temperature and high voltage. In view of this, an organic compound in which only one or both of the first and second substituents are selectively deuterated, which is easily synthesized, is used as the first organic compound, whereby the manufacturing cost of the light-emitting device can be reduced.

Specific structural formulae of an organic compound that can be used as the host material of the light-emitting device 100 are shown below. Note that the present invention is not limited to these formulae.

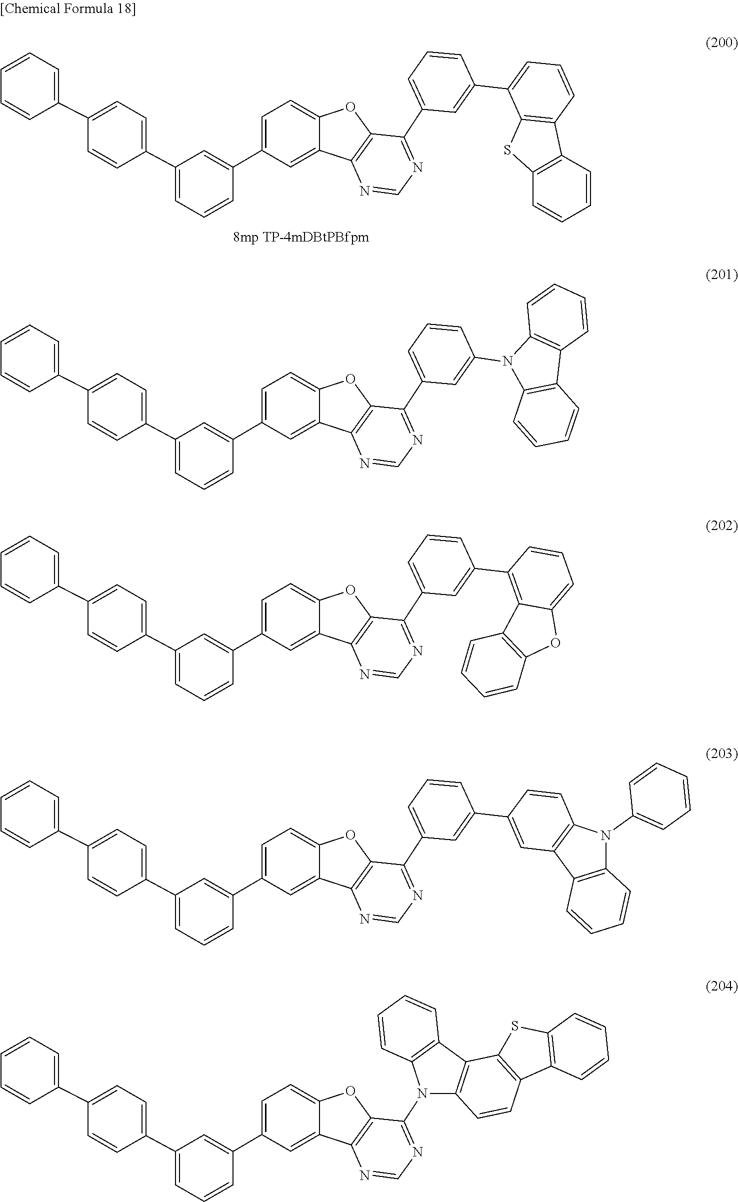 [SMILES: c1ccc(-c2ccc(-c3cccc(-c4ccc5oc6c(-c7cccc(-c8cccc9c8sc8ccccc89)c7)ncnc6c5c4)c3)cc2)cc1 ; c1ccc(-c2ccc(-c3cccc(-c4ccc5oc6c(-c7cccc(-n8c9ccccc9c9ccccc98)c7)ncnc6c5c4)c3)cc2)cc1 ; c1ccc(-c2ccc(-c3cccc(-c4ccc5oc6c(-c7cccc(-c8cccc9oc%10ccccc%10c89)c7)ncnc6c5c4)c3)cc2)cc1 ; c1ccc(-c2ccc(-c3cccc(-c4ccc5oc6c(-c7cccc(-c8ccc9c(c8)c8ccccc8n9-c8ccccc8)c7)ncnc6c5c4)c3)cc2)cc1 ; c1ccc(-c2ccc(-c3cccc(-c4ccc5oc6c(-n7c8ccccc8c8c9sc%10ccccc%10c9ccc87)ncnc6c5c4)c3)cc2)cc1]

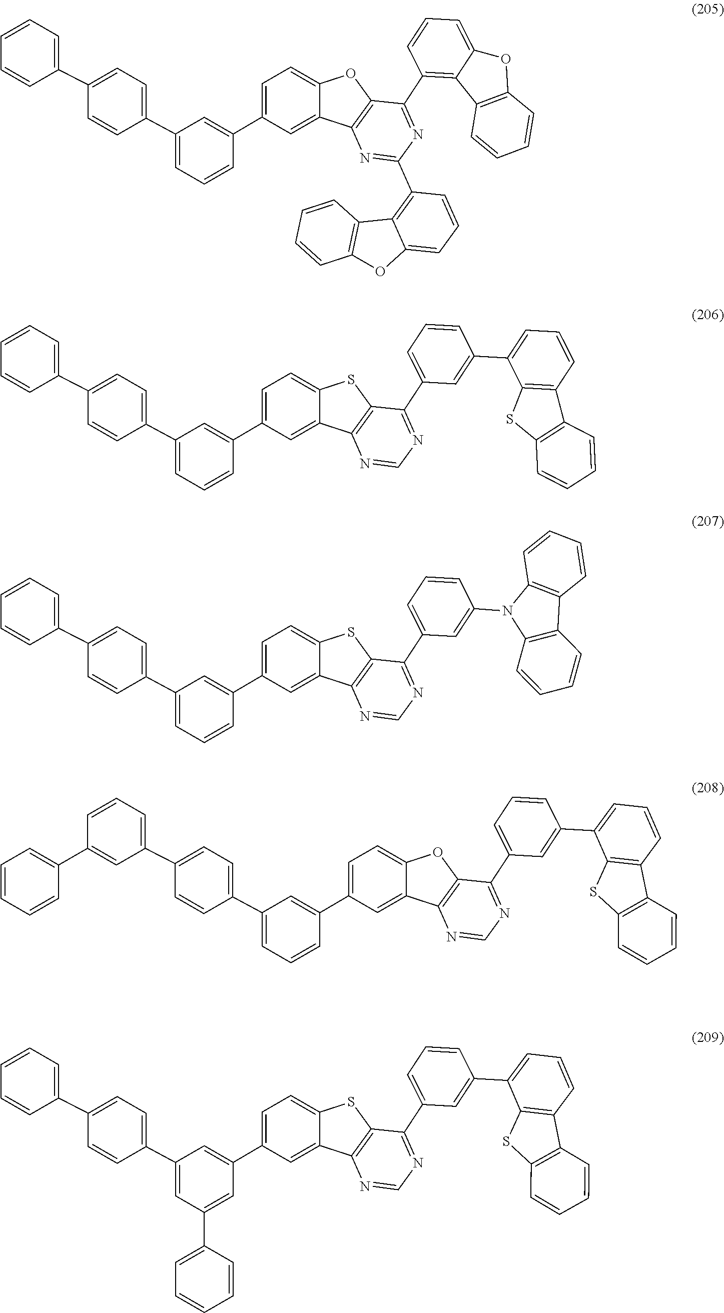

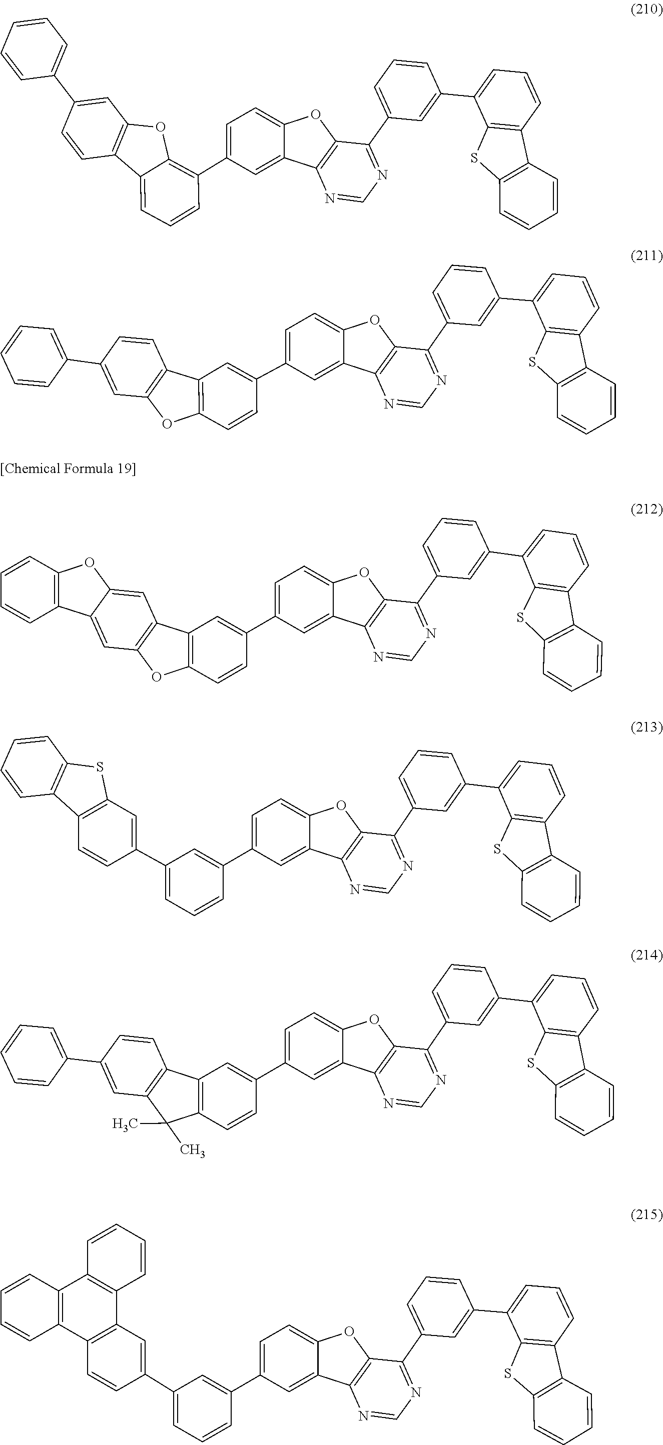

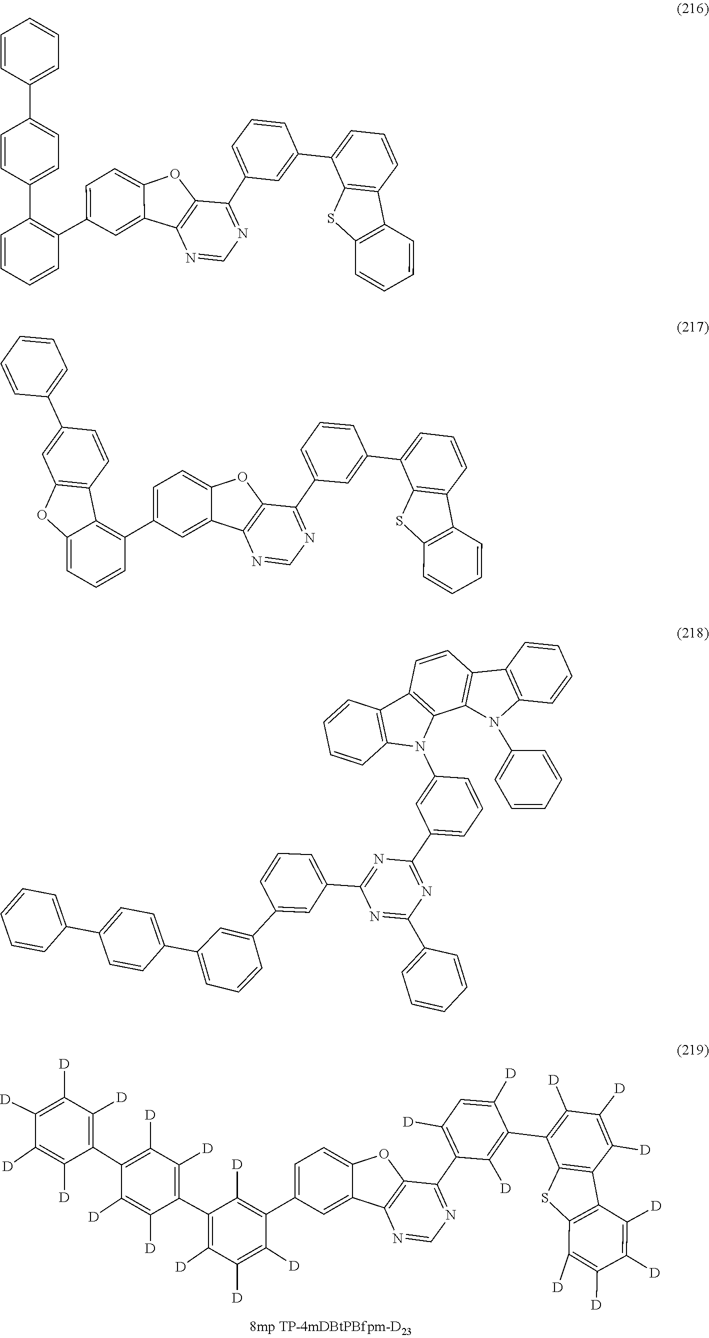

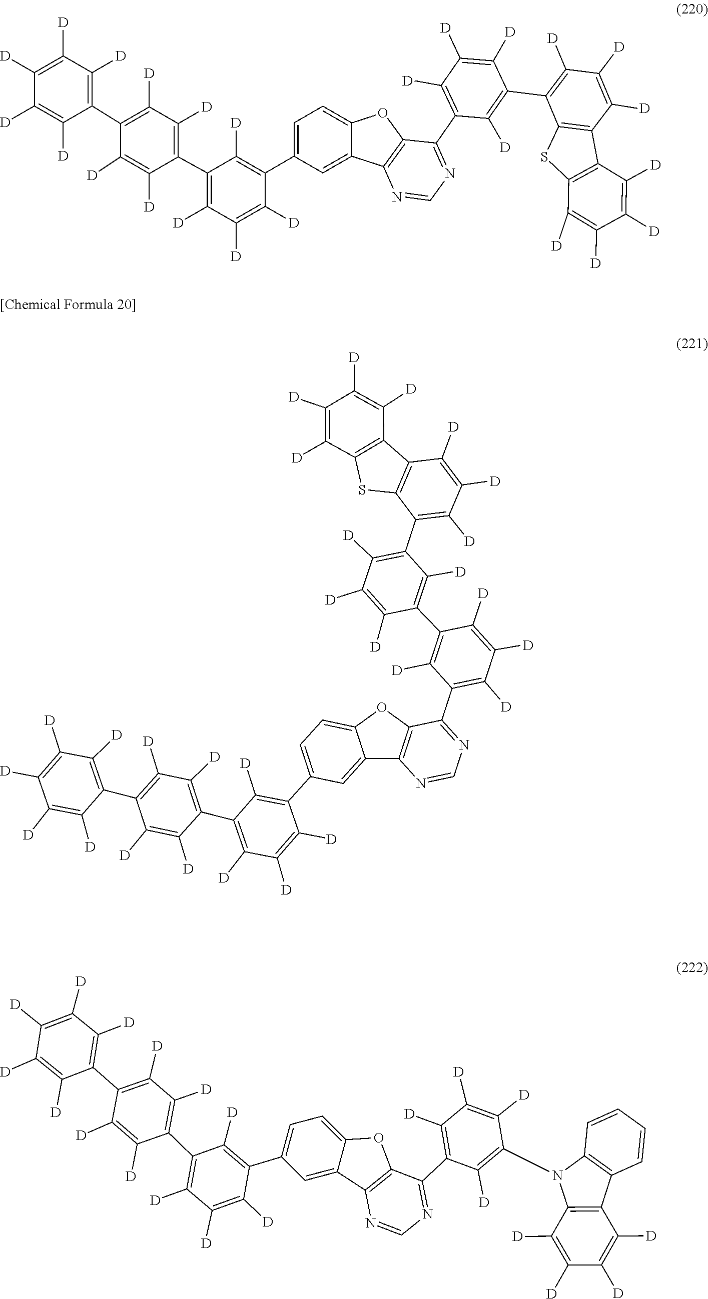

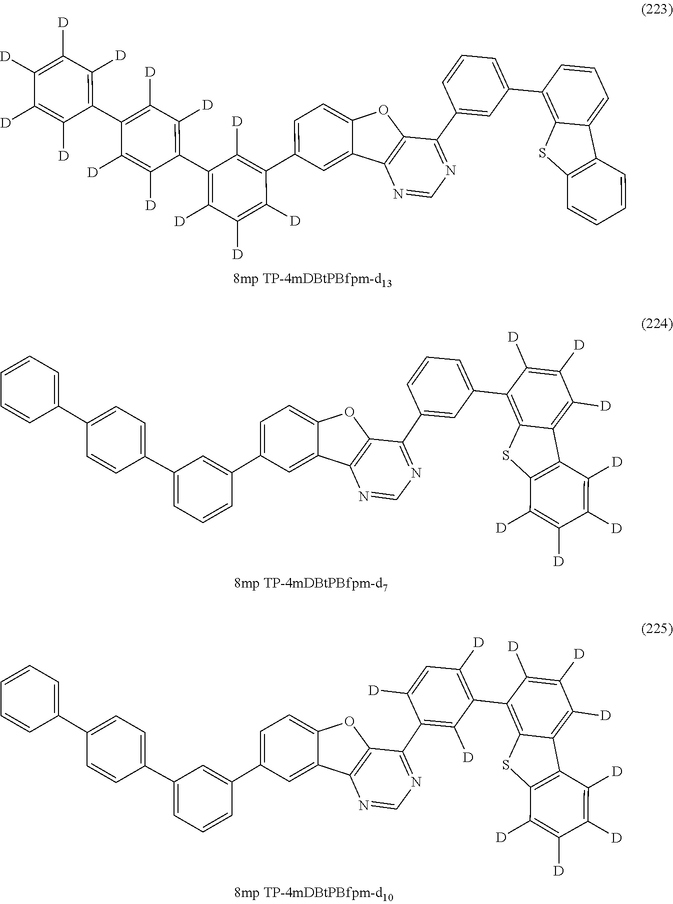 [SMILES: [2H]c1c([2H])c([2H])c(-c2c([2H])c([2H])c(-c3c([2H])c([2H])c([2H])c(-c4ccc5oc6c(-c7cccc(-c8cccc9c8sc8ccccc89)c7)ncnc6c5c4)c3[2H])c([2H])c2[2H])c([2H])c1[2H] ; [2H]c1c([2H])c([2H])c2c(sc3c(-c4cccc(-c5ncnc6c5oc5ccc(-c7cccc(-c8ccc(-c9ccccc9)cc8)c7)cc56)c4)c([2H])c([2H])c([2H])c32)c1[2H] ; [2H]c1cc([2H])c(-c2c([2H])c([2H])c([2H])c3c2sc2c([2H])c([2H])c([2H])c([2H])c23)c([2H])c1-c1ncnc2c1oc1ccc(-c3cccc(-c4ccc(-c5ccccc5)cc4)c3)cc12]

The above is the description of the light-emitting substance and the host material that can be used for the light-emitting device 100. When the light-emitting substance and the host material described above are used in combination for the light-emitting layer, the reliability of the light-emitting device can be improved.

Note that the light-emitting layer may contain an assist material (a second host material) in addition to the light-emitting substance and the host material (a first host material). The energy transfer mechanism when a plurality of host materials are used for the light-emitting layer will be described in Embodiment 2.

### <<Assist Material>>

An example of a material that can be used as the assist material is a second organic compound represented by General Formula (G20).

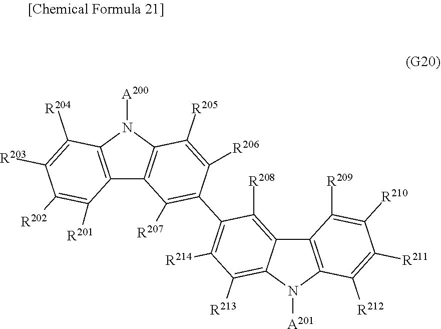

In General Formula (G20), each of R²⁰¹ to R²¹⁴ independently represents hydrogen (including deuterium), an alkyl group having 1 to 6 carbon atoms, a substituted or unsubstituted monocyclic saturated hydrocarbon group having 5 to 7 carbon atoms, a substituted or unsubstituted polycyclic saturated hydrocarbon group having 7 to 10 carbon atoms, a substituted or unsubstituted aryl group having 6 to 13 carbon atoms in a ring, or a substituted or unsubstituted heteroaryl group having 3 to 20 carbon atoms in a ring. Furthermore, each of A²⁰⁰ and A²⁰¹ independently represents any of a substituted or unsubstituted triphenylenyl group, a substituted or unsubstituted phenanthryl group, a substituted or unsubstituted naphthyl group, a substituted or unsubstituted phenyl group, a substituted or unsubstituted biphenyl group, and a substituted or unsubstituted terphenyl group. At least one of A²⁰⁰ and A²⁰¹ is any of a substituted or unsubstituted naphthyl group, a substituted or unsubstituted phenanthryl group, and a substituted or unsubstituted triphenylenyl group.

Another example of the material that can be used as the assist material is the second organic compound represented by General Formula (G21).

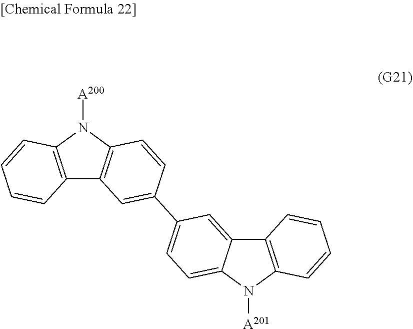

In General Formula (G21), each of A²⁰⁰ and A²⁰¹ independently represents any of an unsubstituted triphenylenyl group, an unsubstituted phenanthryl group, an unsubstituted β-naphthyl group, an unsubstituted phenyl group, an unsubstituted biphenyl group, and an unsubstituted terphenyl group. At least one of A²⁰⁰ and A²⁰¹ is an unsubstituted β-naphthyl group or an unsubstituted triphenylenyl group.

Note that specific examples of the alkyl group having 1 to 6 carbon atoms, the aryl group having 6 to 13 carbon atoms in a ring, the monocyclic saturated hydrocarbon group having 5 to 7 carbon atoms, and the polycyclic saturated hydrocarbon group having 7 to 10 carbon atoms that can be used in General Formula (G20) are similar to specific examples of the alkyl group having 1 to 6 carbon atoms, the aryl group having 6 to 13 carbon atoms in a ring, the monocyclic saturated hydrocarbon group having 5 to 7 carbon atoms, and the polycyclic saturated hydrocarbon group having 7 to 10 carbon atoms that can be used in the organometallic complex or the first organic compound.

Specific examples of the heteroaryl group having 3 to 20 carbon atoms in a ring which can be used in General Formula (G20) are a carbazolyl group, a dibenzofuranyl group, a dibenzothiophenyl group, a benzonaphthofuranyl group, a benzonaphthothiophenyl group, an indolocarbazolyl group, a benzofurocarbazolyl group, a benzothienocarbazolyl group, an indenocarbazolyl group, and a dibenzocarbazolyl group. Note that these groups may each be substituted with deuterium.

In General Formula (G20), in the case where a monocyclic saturated hydrocarbon group having 5 to 7 carbon atoms, a polycyclic saturated hydrocarbon group having 7 to 10 carbon atoms, an aryl group having 6 to 13 carbon atoms in a ring, a heteroaryl group having 3 to 20 carbon atoms in a ring, a triphenylenyl group, a phenanthryl group, a naphthyl group, a phenyl group, a biphenyl group, or a terphenyl group includes a substituent, specific examples of the substituent are an alkyl group having 1 to 6 carbon atoms and a substituted or unsubstituted phenyl group. Note that these groups may each be substituted with deuterium.

Specific examples of the organic compounds represented by General Formulae (G20) and (G21) are shown below.

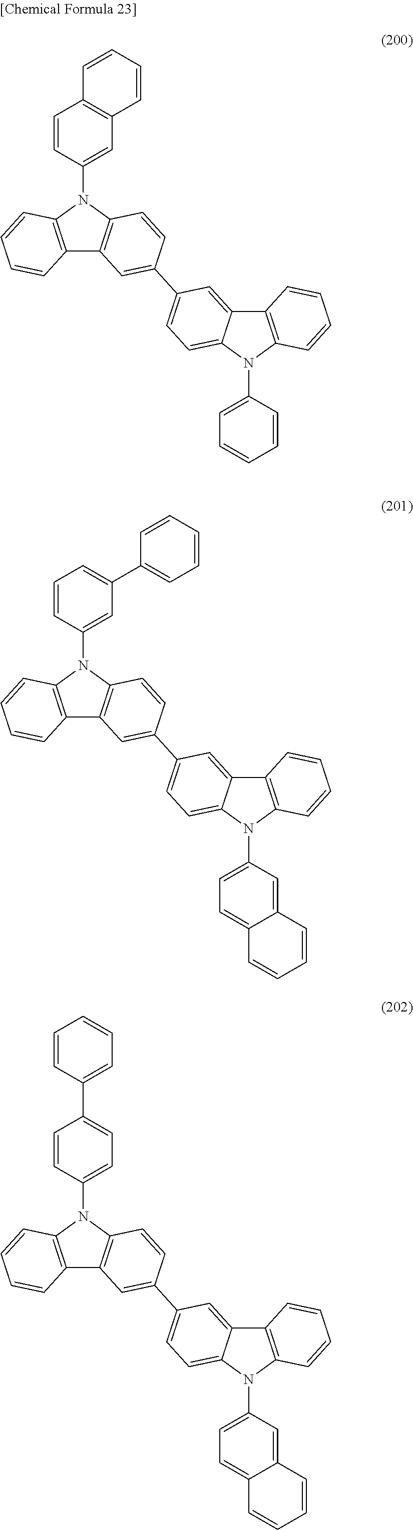

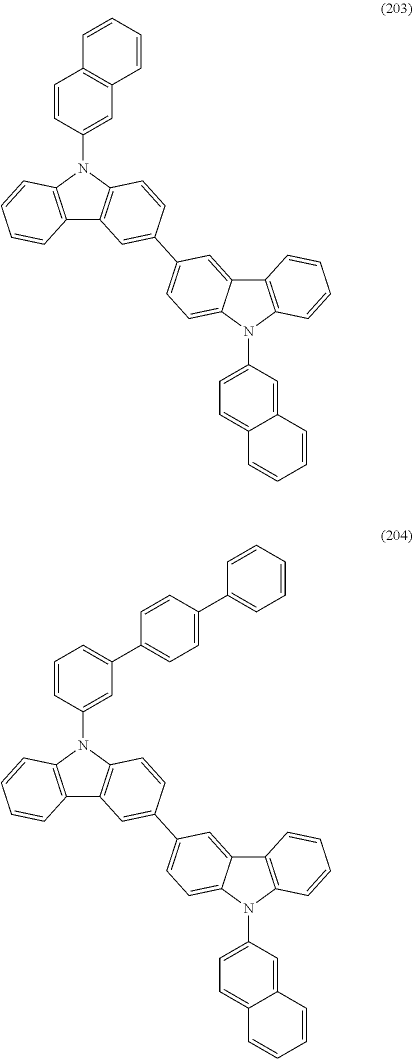

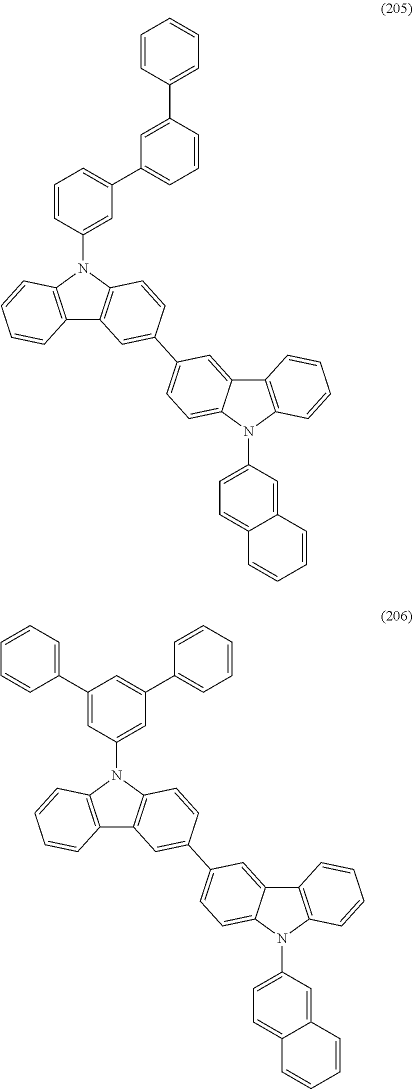

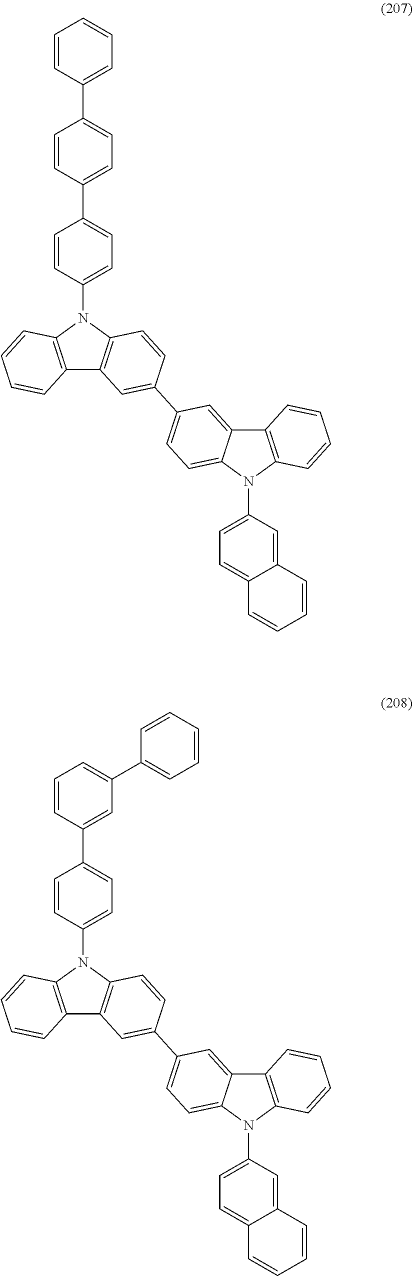

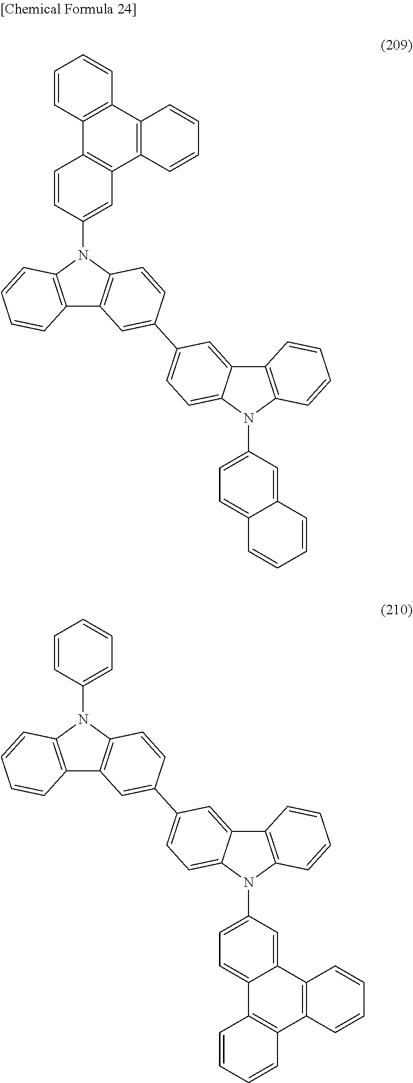

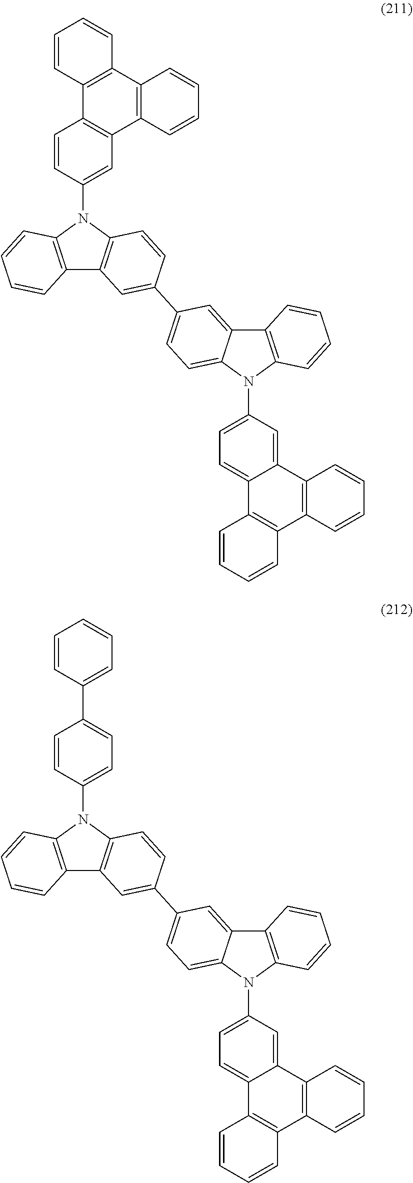

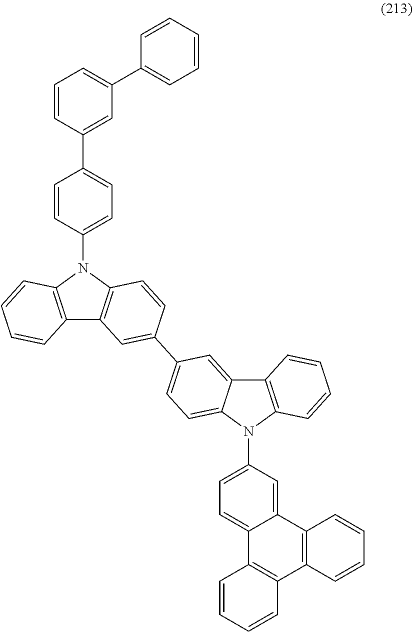

Note that the second organic compound that can be used as the assist material is not limited to the above examples, and any of materials that can be used as a host material, which will be described in Embodiment 2, may be used.

The above is the description of the light-emitting layer of the light-emitting device 100.

The structures described in this embodiment can be used in combination with any of the structures described in the other embodiments as appropriate.

### Embodiment 2

In this embodiment, other structures of the light-emitting device described in Embodiment 1 will be described with reference to FIGS. 1A to 1E.

### <<Basic Structure of Light-Emitting Device>>

Basic structures of the light-emitting device are described. As described in Embodiment 1, FIG. 1A illustrates a light-emitting device including, between a pair of electrodes, an EL layer including a light-emitting layer.

FIG. 1B illustrates a light-emitting device having a structure where a plurality of EL layers (two EL layers of 103a and 103b in FIG. 1B) are provided between a pair of electrodes and a charge generation layer 106 is provided between the EL layers (such a structure is also referred to as a tandem structure). A light-emitting device having a tandem structure enables fabrication of a light-emitting apparatus that has high efficiency without changing the amount of current.

The charge-generation layer 106 has a function of injecting electrons into one of the EL layers 103a and 103b and injecting holes into the other of the EL layers 103a and 103b when a potential difference is caused between the first electrode 101 and the second electrode 102. Thus, when a voltage is applied in FIG. 1B such that the potential of the first electrode 101 can be higher than that of the second electrode 102, electrons are injected into the EL layer 103a from the charge-generation layer 106 and holes are injected into the EL layer 103b from the charge-generation layer 106.

Note that in terms of light extraction efficiency, the charge-generation layer 106 preferably has a property of transmitting visible light (specifically, the charge-generation layer 106 preferably has a visible light transmittance higher than or equal to 40%). The charge-generation layer 106 functions even if it has lower conductivity than the first electrode 101 and the second electrode 102.

FIG. 1C illustrates a stacked-layer structure of the EL layer 103 in the light-emitting device. In this case, the first electrode 101 is regarded as functioning as an anode and the second electrode 102 is regarded as functioning as a cathode. The EL layer 103 has a structure where a hole-injection layer 111, a hole-transport layer 112, a light-emitting layer 113, an electron-transport layer 114, and an electron-injection layer 115 are sequentially stacked over the first electrode 101. Note that, the first electrode 101 may serve as a cathode, and the second electrode 102 may serve as an anode. In that case, the stacking order of the layers in the EL layer 103 is preferably reversed; specifically, it is preferable that the layer 111 over the first electrode 101 serving as the cathode be an electron-injection layer, the layer 112 be an electron-transport layer, the layer 113 be a light-emitting layer, the layer 114 be a hole-transport layer, and the layer 115 be a hole-injection layer.

The light-emitting layer 113 contains an appropriate combination of a light-emitting substance and a plurality of substances, so that fluorescent light of a desired color or phosphorescent light of a desired color can be obtained. The light-emitting layer of the light-emitting device of one embodiment of the present invention preferably employs the structure of the light-emitting layer described in Embodiment 1.

Note that the light-emitting layer 113 may have a stacked-layer structure of a plurality of light-emitting layers that emit light of different colors. When a plurality of light-emitting layers are provided, the use of different light-emitting substances for the light-emitting layers enables a structure that exhibits different emission colors (for example, complementary emission colors are combined to obtain white light emission). For example, a light-emitting layer containing a light-emitting substance that emits red light, a light-emitting layer containing a light-emitting substance that emits green light, and a light-emitting layer containing a light-emitting substance that emits blue light may be stacked with or without a layer containing a carrier-transport material therebetween. Alternatively, a light-emitting layer containing a light-emitting substance that emits yellow light and a light-emitting layer containing a light-emitting substance that emits blue light may be used in combination. In this case, the combination of the light-emitting substance and other substances are different between the stacked light-emitting layers. Alternatively, the plurality of EL layers (103a and 103b) in FIG. 1B may exhibit their respective emission colors. Also in this case, the combination of the light-emitting substance and other substances are different between the stacked light-emitting layers.

Note that the stacked-layer structure of the light-emitting layer 113 is not limited to the above. For example, the light-emitting layer 113 may have a stacked-layer structure of a plurality of light-emitting layers that emit light of the same color. For example, a first light-emitting layer containing a light-emitting substance that emits blue light and a second light-emitting layer containing a light-emitting substance that emits blue light may be stacked with or without a layer containing a carrier-transport material therebetween. Alternatively, the plurality of EL layers (103a and 103b) in FIG. 1B may exhibit the same emission color. The structure where a plurality of light-emitting layers that emit light of the same color are stacked can sometimes achieve higher reliability than a single-layer structure.

In the case where the light-emitting layer 113 has a structure where a plurality of light-emitting layers are stacked, at least one of the plurality of light-emitting layers preferably employs the structure of the light-emitting layer described in Embodiment 1.

The light-emitting device can have a micro optical resonator (microcavity) structure when, for example, the first electrode 101 is a reflective electrode and the second electrode 102 is a transflective electrode in FIG. 1C. Thus, light from the light-emitting layer 113 in the EL layer 103 can be resonated between the electrodes and light emitted through the second electrode 102 can be intensified.

Note that when the first electrode 101 of the light-emitting device is a reflective electrode having a stacked-layer structure of a reflective conductive material and a light-transmitting conductive material (transparent conductive film), optical adjustment can be performed by adjusting the thickness of the transparent conductive film. Specifically, when the wavelength of light obtained from the light-emitting layer 113 is λ, the optical path length between the first electrode 101 and the second electrode 102 (the product of the thickness and the refractive index) is preferably adjusted to be mλ/2 (m is an integer of 1 or more) or close to mλ/2.

To amplify desired light (wavelength: k) obtained from the light-emitting layer 113, it is preferable to adjust each of the optical path length from the first electrode 101 to a region where the desired light is obtained in the light-emitting layer 113 (light-emitting region) and the optical path length from the second electrode 102 to the region where the desired light is obtained in the light-emitting layer 113 (light-emitting region) to be (2m′+1)λ/4 (m′ is an integer of 1 or more) or close to (2m′+1)λ/4. Here, the light-emitting region means a region where holes and electrons are recombined in the light-emitting layer 113.

By such optical adjustment, the spectrum of specific monochromatic light obtained from the light-emitting layer 113 can be narrowed and light emission with high color purity can be obtained.

In the above case, the optical path length between the first electrode 101 and the second electrode 102 is, to be exact, the total thickness from a reflective region in the first electrode 101 to a reflective region in the second electrode 102. However, it is difficult to precisely determine the reflective regions in the first electrode 101 and the second electrode 102; thus, it is assumed that the above effect can be sufficiently obtained wherever the reflective regions may be set in the first electrode 101 and the second electrode 102. Furthermore, the optical path length between the first electrode 101 and the light-emitting layer that emits the desired light is, to be exact, the optical path length between the reflective region in the first electrode 101 and the light-emitting region in the light-emitting layer that emits the desired light. However, it is difficult to precisely determine the reflective region in the first electrode 101 and the light-emitting region in the light-emitting layer that emits the desired light; thus, it is assumed that the above effect can be sufficiently obtained wherever the reflective region and the light-emitting region may be set in the first electrode 101 and the light-emitting layer that emits the desired light, respectively.

FIG. 1D illustrates a stacked-layer structures of the EL layers (103a and 103b) of the light-emitting device having a tandem structure. In this case, the first electrode 101 is regarded as functioning as an anode and the second electrode 102 is regarded as functioning as a cathode. The EL layer 103a has a structure where a hole-injection layer 11a, a hole-transport layer 112a, a light-emitting layer 113a, an electron-transport layer 114a, and an electron-injection layer 115a are sequentially stacked over the first electrode 101. The EL layer 103b has a structure where a hole-injection layer 111b, a hole-transport layer 112b, a light-emitting layer 113b, an electron-transport layer 114b, and an electron-injection layer 115b are sequentially stacked over the electron-generation layer 106. Note that the first electrode 101 may serve as a cathode and the second electrode 102 may serve as an anode; in this case, the stacking order of the layers in the EL layer 103 is preferably reversed.

For example, when the light-emitting device in FIG. 1D has a microcavity structure, the first electrode 101 is formed as a reflective electrode and the second electrode 102 is formed as a transflective electrode. Thus, a single-layer structure or a stacked-layer structure can be formed using one or more kinds of desired electrode materials. Note that the second electrode 102 is formed after formation of the EL layer 103b, with the use of a material selected as appropriate.

In the case where the light-emitting device illustrated in FIG. 1D has a microcavity structure and light-emitting layers that emit light of different colors are used in the EL layers (103a and 103b), light (monochromatic light) with a desired wavelength derived from any of the light-emitting layers can be extracted owing to the microcavity structure. Thus, when such a light-emitting device is used for the light-emitting apparatus and the microcavity structure is adjusted in order to extract light with wavelengths which differ among pixels, separate formation of EL layers for obtaining different emission colors (e.g., R, G, and B) for each pixel is unnecessary. Therefore, higher resolution can be easily achieved. A combination with coloring layers (color filters) is also possible. Furthermore, the emission intensity of light with a specific wavelength in the front direction can be increased, whereby power consumption can be reduced.

The light-emitting device illustrated in FIG. 1E is an example of the light-emitting device having the tandem structure illustrated in FIG. 1B, and includes three EL layers (103a, 103b, and 103c) stacked with charge-generation layers (106a and 106b) therebetween, as illustrated in FIG. 1E. The three EL layers (103a, 103b, and 103c) include respective light-emitting layers (113a, 113b, and 113c), and the emission colors of the light-emitting layers can be selected freely. For example, the light-emitting layer 113a can emit blue light, the light-emitting layer 113b can emit red light, green light, or yellow light, and the light-emitting layer 113c can emit blue light. For another example, the light-emitting layer 113a can emit red light, the light-emitting layer 113b can emit blue light, green light, or yellow light, and the light-emitting layer 113c can emit red light.

In the light-emitting device of one embodiment of the present invention, at least one of the first electrode 101 and the second electrode 102 is a light-transmitting electrode (e.g., a transparent electrode or a transflective electrode). In the case where the light-transmitting electrode is a transparent electrode, the transparent electrode has a visible light transmittance higher than or equal to 40%. In the case where the light-transmitting electrode is a transflective electrode, the transflective electrode has a visible light reflectance higher than or equal to 20% and lower than or equal to 80%, preferably higher than or equal to 40% and lower than or equal to 70%. These electrodes preferably have a resistivity less than or equal to 1×10⁻² Ωcm.

When one of the first electrode 101 and the second electrode 102 is a reflective electrode in the light-emitting device of one embodiment of the present invention, the visible light reflectance of the reflective electrode is higher than or equal to 40% and lower than or equal to 100%, preferably higher than or equal to 70% and lower than or equal to 100%. This electrode preferably has a resistivity less than or equal to 1×10⁻² Ωm.

### <<Specific Structure of Light-Emitting Device>>

Next, specific structures of layers in the light-emitting device of one embodiment of the present invention will be described. Note that for simplicity, reference numerals are sometimes omitted in the description of the layers.

### <First Electrode and Second Electrode>

As materials for the first electrode and the second electrode, any of the following materials can be used in an appropriate combination as long as the above functions of the electrodes can be fulfilled. For example, a metal, an alloy, an electrically conductive compound, a mixture of these, and the like can be used as appropriate. Specifically, an In—Sn oxide (also referred to as ITO), an In—S1-Sn oxide (also referred to as ITSO), an In—Zn oxide, or an In—W—Zn oxide can be used. In addition, it is possible to use a metal such as aluminum (Al), titanium (T₁), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing an appropriate combination of any of these metals. It is also possible to use an element belonging to Group 1 or Group 2 of the periodic table that is not described above (e.g., lithium (Li), cesium (Cs), calcium (Ca), or strontium (Sr)), a rare earth metal such as europium (Eu) or ytterbium (Yb), an alloy containing an appropriate combination of any of these elements, graphene, or the like.

In the light-emitting device illustrated in FIG. 1D, when the first electrode 101 is the anode, the hole-injection layer 111a and the hole-transport layer 112a of the EL layer 103a are sequentially stacked over the first electrode 101 by a vacuum evaporation method. After the EL layer 103a and the charge-generation layer 106 are formed, the hole-injection layer 111b and the hole-transport layer 112b of the EL layer 103b are sequentially stacked over the charge-generation layer 106 in a similar manner.

### <Hole-Injection Layer>

The hole-injection layer injects holes from the first electrode that is an anode and the charge-generation layer to the EL layer, and contains an organic acceptor material and a material having a high hole-injection property.

The organic acceptor material allows holes to be generated in another organic compound whose HOMO level is close to the LUMO level of the organic acceptor material when charge separation is caused between the organic acceptor material and the organic compound. Thus, as the organic acceptor material, a compound having an electron-withdrawing group (e.g., a halogen group or a cyano group), such as a quinodimethane derivative, a chloranil derivative, and a hexaazatriphenylene derivative, can be used. For example, any of the following materials can be used: 7,7,8,8-tetracyano-2,3,5,6-tetrafluoroquinodimethane (abbreviation: F₄-TCNQ), 3,6-difluoro-2,5,7,7,8,8-hexacyanoquinodimethane, chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F₆-TCNNQ), and 2-(7-dicyanomethylene-1,3,4,5,6,8,9,10-octafluoro-7H-pyren-2-ylidene)malononitrile. Note that among organic acceptor materials, a compound in which electron-withdrawing groups are bonded to condensed aromatic rings each having a plurality of heteroatoms, such as HAT-CN, is particularly preferred because it has a high acceptor property and stable film quality against heat. Besides, a [3]radialene derivative having an electron-withdrawing group (particularly a cyano group or a halogen group such as a fluoro group), which has a very high electron-accepting property, is preferred; specific examples are α,α′,α,″-1,2,3-cyclopropanetriylidenetris[4-cyano-2,3,5,6-tetrafluorobenzeneacetonitrile], α,α′,α,″-1,2,3-cyclopropanetriylidenetris[2,6-dichloro-3,5-difluoro-4-(trifluoromethyl)benzeneacetonitrile], and α,α′,α,″-1,2,3-cyclopropanetriylidenetris[2,3,4,5,6-pentafluorobenzeneacetonitrile].

As the material having a high hole-injection property, an oxide of a metal belonging to Group 4 to Group 8 of the periodic table (e.g., a transition metal oxide such as molybdenum oxide, vanadium oxide, ruthenium oxide, tungsten oxide, or manganese oxide) can be used. Specific examples are molybdenum oxide, vanadium oxide, niobium oxide, tantalum oxide, chromium oxide, tungsten oxide, manganese oxide, and rhenium oxide. Among the above oxides, molybdenum oxide is preferable because it is stable in the air, has a low hygroscopic property, and is easily handled. Other examples are phthalocyanine (abbreviation: H₂Pc) and a phthalocyanine-based compound such as copper phthalocyanine (abbreviation: CuPc).

Other examples are aromatic amine compounds, which are low molecular compounds, such as 4,4′,4″-tris(N,N-diphenylamino)triphenylamine (abbreviation: TDATA), 4,4′,4″-tris[N-(3-methylphenyl)-N-phenylamino]triphenylamine (abbreviation: MTDATA), 4,4′-bis[N-(4-diphenylaminophenyl)-N-phenylamino]biphenyl (abbreviation: DPAB), N,N′-bis[4-bis(3-methylphenyl)aminophenyl]-N,N′-diphenyl-4,4′-diaminobiphenyl (abbreviation: DNTPD), 1,3,5-tris[N-(4-diphenylaminophenyl)-N-phenylamino]benzene (abbreviation: DPA3B), 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), and 3-[N-(1-naphthyl)-N-(9-phenylcarbazol-3-yl)amino]-9-phenylcarbazole (abbreviation: PCzPCN1).

Other examples are high-molecular compounds (e.g., oligomers, dendrimers, and polymers) such as poly(N-vinylcarbazole) (abbreviation: PVK), poly(4-vinyltriphenylamine) (abbreviation: PVTPA), poly[N-(4-{N′-[4-(4-diphenylamino)phenyl]phenyl-N′-phenylamino}phenyl)methacrylamide] (abbreviation: PTPDMA), and poly[N,N′-bis(4-butylphenyl)-N,N′-bis(phenyl)benzidine] (abbreviation: Poly-TPD). Other examples are a high-molecular compound to which acid is added, such as poly(3,4-ethylenedioxythiophene)/poly(styrenesulfonic acid) (abbreviation: PEDOT/PSS) and polyaniline/poly(styrenesulfonic acid) (abbreviation: PAni/PSS).

As the material having a high hole-injection property, a mixed material containing a hole-transport material and the above-described organic acceptor material (electron-accepting material) can be used. In this case, the organic acceptor material extracts electrons from the hole-transport material, so that holes are generated in the hole-injection layer 111 and injected into the light-emitting layer 113 through the hole-transport layer 112. Note that the hole-injection layer 111 may be formed to have a single-layer structure using a mixed material containing a hole-transport material and an organic acceptor material (electron-accepting material), or a stacked-layer structure of a layer containing a hole-transport material and a layer containing an organic acceptor material (electron-accepting material).

The hole-transport material preferably has a hole mobility higher than or equal to 1×10⁻⁶ cm²/Vs in the case where the square root of the electric field strength [V/cm] is 600. Note that any other substance can also be used as long as the substance has a hole-transport property higher than an electron-transport property.

As the hole-transport material, a material having a high hole-transport property, such as a compound having a π-electron rich heteroaromatic ring (e.g., a carbazole derivative, a furan derivative, or a thiophene derivative) or an aromatic amine (an organic compound having an aromatic amine skeleton), is preferable. The compound in Embodiment 1 has a hole-transport property and thus can be used as a hole-transport material.

Examples of the carbazole derivative (an organic compound having a carbazole ring) include a bicarbazole derivative (e.g., a 3,3′-bicarbazole derivative) and an aromatic amine having a carbazolyl group.

Specific examples of the bicarbazole derivative (e.g., a 3,3′-bicarbazole derivative) are 3,3′-bis(9-phenyl-9H-carbazole) (abbreviation: PCCP), 9,9′-bis(biphenyl-4-yl)-3,3′-bi-9H-carbazole (abbreviation: BisBPCz), 9,9′-bis(biphenyl-3-yl)-3,3′-bi-9H-carbazole (abbreviation: BismBPCz), 9-(biphenyl-3-yl)-9′-(biphenyl-4-yl)-9H,9′H-3,3′-bicarbazole (abbreviation: mBPCCBP), and 9-(2-naphthyl)-9′-phenyl-9H,9′H-3,3′-bicarbazole (abbreviation: PNCCP).

Specific examples of the aromatic amine having a carbazolyl group are 4-phenyl-4′-(9-phenyl-9H-carbazol-3-yl)triphenylamine (abbreviation: PCBA1BP), N-(4-biphenyl)-N-(9,9-dimethyl-9H-fluoren-2-yl)-9-phenyl-9H-carbazol-3-amine (abbreviation: PCBiF), N-(biphenyl-4-yl)-N-[4-(9-phenyl-9H-carbazol-3-yl)phenyl]-9,9-dimethyl-9H-fluoren-2-amine (abbreviation: PCBBiF), N-[4-(9-phenyl-9H-carbazol-3-yl)phenyl]bis(9,9-dimethyl-9H-fluoren-2-yl)amine (abbreviation: PCBFF), N-(1,1′-biphenyl-4-yl)-N-[4-(9-phenyl-9H-carbazol-3-yl)phenyl]-9,9-dimethyl-9H-fluoren-4-amine, N-[4-(9-phenyl-9H-carbazol-3-yl)phenyl]-(9,9-dimethyl-9H-fluoren-2-yl)-9,9-dimethyl-9H-fluoren-4-amine, N-(1,1′-biphenyl-4-yl)-N-[4-(9-phenyl-9H-carbazol-3-yl)phenyl]-9,9-diphenyl-9H-fluoren-2-amine, N-(1,1′-biphenyl-4-yl)-N-[4-(9-phenyl-9H-carbazol-3-yl)phenyl]-9,9-diphenyl-9H-fluoren-4-amine, N-(1,1′-biphenyl-4-yl)-N-[4-(9-phenyl-9H-carbazol-3-yl)phenyl]-9,9′-spirobi(9H-fluoren)-2-amine, N-(1,1′-biphenyl-4-yl)-N-[4-(9-phenyl-9H-carbazol-3-yl)phenyl]-9,9′-spirobi(9H-fluoren)-4-amine, N-[4-(9-phenyl-9H-carbazol-3-yl)phenyl]-N-[1,1′: 3′,1″-terphenyl-4-yl]-9,9-dimethyl-9H-fluoren-2-amine, N-[4-(9-phenyl-9H-carbazol-3-yl)phenyl]-N-(1,1′: 4′,1″-terphenyl-4-yl)-9,9-dimethyl-9H-fluoren-2-amine, N-[4-(9-phenyl-9H-carbazol-3-yl)phenyl]-N-(1,1′: 3,1″-terphenyl-4-yl)-9,9-dimethyl-9H-fluoren-4-amine, N-[4-(9-phenyl-9H-carbazol-3-yl)phenyl]-N-(1,1′: 4′,1″-terphenyl-4-yl)-9,9-dimethyl-9H-fluoren-4-amine, 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 4-phenyldiphenyl-(9-phenyl-9H-carbazol-3-yl)amine (abbreviation: PCA1BP), N,N′-bis(9-phenylcarbazol-3-yl)-N,N′-diphenylbenzene-1,3-diamine (abbreviation: PCA2B), N,N′,N″-triphenyl-N,N′,N″-tris(9-phenylcarbazol-3-yl)benzene-1,3,5-triamine (abbreviation: PCA3B), 9,9-dimethyl-N-phenyl-N-[4-(9-phenyl-9H-carbazol-3-yl)phenyl]fluoren-2-amine (abbreviation: PCBAF), N-phenyl-N-[4-(9-phenyl-9H-carbazol-3-yl)phenyl]-9,9′-spirobi[9H-fluoren]-2-amine (abbreviation: PCBASF), PCzPCA1, PCzPCA2, PCzPCN1, 3-[N-(4-diphenylaminophenyl)-N-phenylamino]-9-phenylcarbazole (abbreviation: PCzDPA1), 3,6-bis[N-(4-diphenylaminophenyl)-N-phenylamino]-9-phenylcarbazole (abbreviation: PCzDPA2), 3,6-bis[N-(4-diphenylaminophenyl)-N-(1-naphthyl)amino]-9-phenylcarbazole (abbreviation: PCzTPN2), 2-[N-(9-phenylcarbazol-3-yl)-N-phenylamino]spiro-9,9′-bifluorene (abbreviation: PCASF), N-[4-(9H-carbazol-9-yl)phenyl]-N-(4-phenyl)phenylaniline (abbreviation: YGA1BP), N,N′-bis[4-(carbazol-9-yl)phenyl]-N,N′-diphenyl-9,9-dimethylfluorene-2,7-diamine (abbreviation: YGA2F), and 4,4′,4″-tris(carbazol-9-yl)triphenylamine (abbreviation: TCTA).

Other examples of the carbazole derivative include 9-[4-(9-phenyl-9H-carbazol-3-yl)-phenyl]phenanthrene (abbreviation: PCPPn), 3-[4-(1-naphthyl)-phenyl]-9-phenyl-9H-carbazole (abbreviation: PCPN), 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 1,3,5-tris[4-(N-carbazolyl)phenyl]benzene (abbreviation: TCPB), and 9-[4-(10-phenyl-9-anthracenyl)phenyl]-9H-carbazole (abbreviation: CzPA).

Specific examples of the furan derivative (an organic compound having a furan ring) include 4,4′,4″-(benzene-1,3,5-triyl)tri(dibenzofuran) (abbreviation: DBF3P-II) and 4-{3-[3-(9-phenyl-9H-fluoren-9-yl)phenyl]phenyl}dibenzofuran (abbreviation: mmDBFFLBi-II).

Specific examples of the thiophene derivative (an organic compound having a thiophene ring) include an organic compound having a thiophene ring, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), or 4-[4-(9-phenyl-9H-fluoren-9-yl)phenyl]-6-phenyldibenzothiophene (abbreviation: DBTFLP-IV).

Specific examples of the aromatic amine include 4,4′-bis[N-(1-naphthyl)-N-phenylamino]biphenyl (abbreviation: NPB or α-NPD), N,N′-diphenyl-N,N′-bis(3-methylphenyl)-4,4′-diaminobiphenyl (abbreviation: TPD), N,N′-bis(9,9′-spirobi[9H-fluoren]-2-yl)-N,N′-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), N-(9,9-dimethyl-9H-fluoren-2-yl)-N-{9,9-dimethyl-2-[N-phenyl-N-(9,9-dimethyl-9H-fluoren-2-yl)amino]-9H-fluoren-7-yl}phenylamine (abbreviation: DFLADFL), N-(9,9-dimethyl-2-diphenylamino-9H-fluoren-7-yl)diphenylamine (abbreviation: DPNF), 2-[N-(4-diphenylaminophenyl)-N-phenylamino]-spiro-9,9′-bifluorene (abbreviation: DPASF), 2,7-bis[N-(4-diphenylaminophenyl)-N-phenylamino]-spiro-9,9′-bifluorene (abbreviation: DPA2SF), 4,4′,4″-tris[N-(1-naphthyl)-N-phenylamino]triphenylamine (abbreviation: 1′-TNATA), TDATA, 4,4′,4″-tris[N-(3-methylphenyl)-N-phenylamino]triphenylamine (abbreviation: m-MTDATA), N,N′-di(p-tolyl)-N,N′-diphenyl-p-phenylenediamine (abbreviation: DTDPPA), DPAB, DNTPD, DPA3B, N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf(6)), N,N-bis(4-biphenyl)benzo[b]naphtho[1,2-d]furan-8-amine (abbreviation: BBABnf(8)), N,N-bis(4-biphenyl)benzo[b]naphtho[2,3-d]furan-4-amine (abbreviation: BBABnf(II)(4)), N,N-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAβNB), 4-[4-(2-naphthyl)phenyl]-4′,4″-diphenyltriphenylamine (abbreviation: BBAβNBi), 4,4′-diphenyl-4″-(6;1′-binaphthyl-2-yl)triphenylamine (abbreviation: BBAαNβNB), 4,4′-diphenyl-4″-(7;1′-binaphthyl-2-yl)triphenylamine (abbreviation: BBAαNβNB-03), 4,4′-diphenyl-4″-(7-phenyl)naphthyl-2-yltriphenylamine (abbreviation: BBAPβNB-03), 4,4′-diphenyl-4″-(6;2′-binaphthyl-2-yl)triphenylamine (abbreviation: BBA(βN2)B), 4,4′-diphenyl-4″-(7;2′-binaphthyl-2-yl)triphenylamine (abbreviation: BBA(βN2)B-03), 4,4′-diphenyl-4″-(4;2′-binaphthyl-1-yl)triphenylamine (abbreviation: BBAβNαNB), 4,4′-diphenyl-4″-(5;2′-binaphthyl-1-yl)triphenylamine (abbreviation: BBAβNαNB-02), 4-(4-biphenylyl)-4′-(2-naphthyl)-4″-phenyltriphenylamine (abbreviation: TPBiAONB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(biphenyl-4-yl)amine (abbreviation: YGTBi1BP-02), 4-[4′-(carbazol-9-yl)biphenyl-4-yl]-4′-(2-naphthyl)-4″-phenyltriphenylamine (abbreviation: YGTBiONB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), N,N-bis(biphenyl-4-yl)-9,9′-spirobi[9H-fluoren]-2-amine (abbreviation: BBASF), N,N-bis(biphenyl-4-yl)-9,9′-spirobi[9H-fluoren]-4-amine (abbreviation: BBASF(4)), N-(biphenyl-2-yl)-N-(9,9-dimethyl-9H-fluoren-2-yl)-9,9′-spirobi[9H-fluoren]-4-amine (abbreviation: oFBiSF), N-(biphenyl-4-yl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-[4-(9-phenylfluoren-9-yl)phenyl]triphenylamine (abbreviation: BPAFLBi), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, and N,N-bis(9,9-dimethyl-9H-fluoren-2-yl)-9,9′-spirobi-9H-fluoren-1-amine.

Other than the above, PVK, PVTPA, PTPDMA, Poly-TPD, or the like that is a high molecular compound (e.g., an oligomer, a dendrimer, or a polymer) can be used as the hole-transport material. Alternatively, a high molecular compound to which acid is added, such as PEDOT/PSS or PAni/PSS can be used, for example.

Note that the hole-transport material is not limited to the above examples, and any of a variety of known materials may be used alone or in combination as the hole-transport material.

The hole-injection layer can be formed by any of known deposition methods such as a vacuum evaporation method.

### <Hole-Transport Layer>

The hole-transport layer transports holes, which are injected from the first electrode by the hole-injection layer, to the light-emitting layer. The hole-transport layer contains a hole-transport material. Thus, the hole-transport layer can be formed using a hole-transport material that can be used for the hole-injection layer. Furthermore, the hole-transport layer can function even with a single-layer structure, but may have a stacked structure of two or more layers. For example, one of two hole-transport layers which is in contact with the light-emitting layer may also function as an electron-blocking layer.

Note that in the light-emitting device of one embodiment of the present invention, the same organic compound can be used for the hole-transport layer and the light-emitting layer. Using the same organic compound for the hole-transport layer and the light-emitting layer is preferable because holes can be efficiently transported from the hole-transport layer to the light-emitting layer.

### <Light-Emitting Layer>

The light-emitting layer contains a light-emitting substance. Note that as a light-emitting substance that can be used for the light-emitting layer, a substance whose emission color is blue, violet, bluish violet, green, yellowish green, yellow, orange, red, or the like can be used as appropriate. One light-emitting layer may have a stacked-layer structure of layers containing different light-emitting substances. At least one light-emitting layer preferably employs the structure of the light-emitting layer described in Embodiment 1.

The light-emitting layer may contain one or more kinds of organic compounds (e.g., a host material) in addition to the light-emitting substance (a guest material).

In the case where a plurality of host materials are used for the light-emitting layer, a second host material that is additionally used is preferably a substance having a larger energy gap than those of a known guest material and the first host material. Preferably, the lowest singlet excitation energy level (S₁ level) of the second host material is higher than that of the first host material, and the lowest triplet excitation energy level (T₁ level) of the second host material is higher than that of the guest material. Preferably, the lowest triplet excitation energy level (T₁ level) of the second host material is higher than that of the first host material. With such a structure, an exciplex can be formed by the two kinds of host materials. To form an exciplex efficiently, it is particularly preferable to combine a compound that easily accepts holes (hole-transport material) and a compound that easily accepts electrons (electron-transport material). With the above structure, high efficiency, a low voltage, and a long lifetime can be achieved at the same time.

As an organic compound used as the host material (including the first host material and the second host material), organic compounds such as the hole-transport materials usable for the hole-transport layers described above and electron-transport materials usable for electron-transport layers described later can be used as long as they satisfy requirements for the host material used for the light-emitting layer. Another example is an exciplex formed by two or more kinds of organic compounds (the first host material and the second host material). An exciplex whose excited state is formed by two or more kinds of organic compounds has an extremely small difference between the S₁ level and the T₁ level and functions as a TADF material capable of converting triplet excitation energy into singlet excitation energy. In an example of a preferable combination of two or more kinds of organic compounds forming an exciplex, one of the two or more kinds of organic compounds has a π-electron deficient heteroaromatic ring and the other has a π-electron rich heteroaromatic ring. A phosphorescent substance such as an iridium-, rhodium-, or platinum-based organometallic complex or a metal complex may be used as one component of the combination for forming an exciplex. The organic compound described in Embodiment 1 has an electron-transport property and thus can be efficiently used as the first host material. Furthermore, since the organic compound has a hole-transport property, it can be used as the second host material.

There is no particular limitation on the light-emitting substances that can be used for the light-emitting layer, and a light-emitting substance that converts singlet excitation energy into light emission in the visible light range or a light-emitting substance that converts triplet excitation energy into light emission in the visible light range can be used.

<<Light-Emitting Substance that Converts Singlet Excitation Energy into Light>>

The following substances that emit fluorescent light (fluorescent substances) can be given as examples of the light-emitting substance that converts singlet excitation energy into light and can be used in the light-emitting layer: a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative. A pyrene derivative is particularly preferable because it has a high emission quantum yield. Specific examples of the pyrene derivative include N,N′-bis(3-methylphenyl)-N,N′-bis[3-(9-phenyl-9H-fluoren-9-yl)phenyl]pyrene-1,6-diamine (abbreviation: 1,6mMemFLPAPrn), N,N′-diphenyl-N,N′-bis[4-(9-phenyl-9H-fluoren-9-yl)phenyl]pyrene-1,6-diamine (abbreviation: 1,6FLPAPrn), N,N′-bis(dibenzofuran-2-yl)-N,N′-diphenylpyrene-1,6-diamine (abbreviation: 1,6FrAPrn), N,N′-bis(dibenzothiophen-2-yl)-N,N′-diphenylpyrene-1,6-diamine (abbreviation: 1,6ThAPrn), N,N′-(pyrene-1,6-diyl)bis[(N-phenylbenzo[b]naphtho[1,2-d]furan)-6-amine](abbreviation: 1,6BnfAPrn), N,N′-(pyrene-1,6-diyl)bis[(N-phenylbenzo[b]naphtho[1,2-d]furan)-8-amine](abbreviation: 1,6BnfAPrn-02), and N,N′-(pyrene-1,6-diyl)bis[(6,N-diphenylbenzo[b]naphtho[1,2-d]furan)-8-amine](abbreviation: 1,6BnfAPrn-03).

As a light-emitting substance that converts singlet excitation energy into light, it is possible to use, for example, 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N′-bis[4-(9H-carbazol-9-yl)phenyl]-N,N′-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), 4-(10-phenyl-9-anthryl)-4′-(9-phenyl-9H-carbazol-3-yl)triphenylamine (abbreviation: PCBAPA), 4-[4-(10-phenyl-9-anthryl)phenyl]-4′-(9-phenyl-9H-carbazol-3-yl)triphenylamine (abbreviation: PCBAPBA), perylene, 2,5,8,11-tetra-tert-butylperylene (abbreviation: TBP), N,N′-(2-tert-butylanthracene-9,10-diyldi-4,1-phenylene)bis(N,N′,N′-triphenyl-1,4-phenylenediamine) (abbreviation: DPABPA), N,9-diphenyl-N-[4-(9,10-diphenyl-2-anthryl)phenyl]-9H-carbazol-3-amine (abbreviation: 2PCAPPA), and N-[4-(9,10-diphenyl-2-anthryl)phenyl]-N,N′,N′-triphenyl-1,4-phenylenediamine (abbreviation: 2DPAPPA).

As the light-emitting substance that converts singlet excitation energy into light, it is also possible to use, for example, N-[9,10-bis(biphenyl-2-yl)-2-anthryl]-N,9-diphenyl-9H-carbazol-3-amine (abbreviation: 2PCABPhA), N-(9,10-diphenyl-2-anthryl)-N,N′,N′-triphenyl-1,4-phenylenediamine (abbreviation: 2DPAPA), N-[9,10-bis(biphenyl-2-yl)-2-anthryl]-N,N′,N′-triphenyl-1,4-phenylenediamine (abbreviation: 2DPABPhA), 9,10-bis(biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 545T, N,N′-diphenylquinacridone (abbreviation: DPQd), rubrene, 5,12-bis(biphenyl-4-yl)-6,11-diphenyltetracene (abbreviation: BPT), 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N′,N′-tetrakis(4-methylphenyl)tetracene-5,11-diamine (abbreviation: p-mPhTD), 7,14-diphenyl-N,N,N′,N′-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM), 1,6BnfAPrn-03, 3,10-bis[N-(9-phenyl-9H-carbazol-2-yl)-N-phenylamino]naphtho[2,3-b;6,7-b′]bisbenzofuran (abbreviation: 3,10PCA2Nbf(IV)-02), and 3,10-bis[N-(dibenzofuran-3-yl)-N-phenylamino]naphtho[2,3-b;6,7-b′]bisbenzofuran (abbreviation: 3,10FrA2Nbf(IV)-02). In particular, pyrenediamine compounds such as 1,6FLPAPrn, 1,6mMemFLPAPrn, and 1,6BnfAPrn-03 can be used, for example.

<<Light-Emitting Substance that Converts Triplet Excitation Energy into Light>>

Examples of the light-emitting substance that converts triplet excitation energy into light and can be used for the light-emitting layer 113 include substances that emit phosphorescent light (phosphorescent substances) and thermally activated delayed fluorescent (TADF) materials that exhibit thermally activated delayed fluorescence.

A phosphorescent substance is a compound that emits phosphorescent light but does not emit fluorescent light at a temperature higher than or equal to a low temperature (e.g., 77 K) and lower than or equal to room temperature (i.e., higher than or equal to 77 K and lower than or equal to 313 K). The phosphorescent substance preferably contains a metal element with large spin-orbit interaction, and can be an organometallic complex, a metal complex (platinum complex), or a rare earth metal complex, for example. Specifically, the phosphorescent substance preferably contains a transition metal element. It is particularly preferable that the phosphorescent substance contain a platinum group element (ruthenium (Ru), rhodium (Rh), palladium (Pd), osmium (Os), iridium (Ir), or platinum (Pt)), especially iridium, in which case the probability of direct transition between the singlet ground state and the triplet excited state can be increased.

<<Phosphorescent Substance (from 450 nm to 570 nm, Blue or Green)>>

As examples of a phosphorescent substance which emits blue or green light and whose emission spectrum has a peak wavelength of greater than or equal to 450 nm and less than or equal to 570 nm, the following substances can be given.

Examples include organometallic complexes having a 4H-triazole ring, such as tris{2-[5-(2-methylphenyl)-4-(2,6-dimethylphenyl)-4H-1,2,4-triazol-3-yl-κN²]phenyl-κC}iridium(III) (abbreviation: [Ir(mpptz-dmp)₃]), tris(5-methyl-3,4-diphenyl-4H-1,2,4-triazolato)iridium(III) (abbreviation: [Ir(Mptz)₃]), tris[4-(3-biphenyl)-5-isopropyl-3-phenyl-4H-1,2,4-triazolato]iridium(III) (abbreviation: [Ir(iPrptz-3b)₃]), and tris[3-(5-biphenyl)-5-isopropyl-4-phenyl-4H-1,2,4-triazolato]iridium(III) (abbreviation: [Ir(iPr⁵btz)₃]); organometallic complexes having a 1H-triazole ring, such as tris[3-methyl-1-(2-methylphenyl)-5-phenyl-1H-1,2,4-triazolato]iridium(III) (abbreviation: [Ir(Mptz1-mp)₃]) and tris(1-methyl-5-phenyl-3-propyl-1H-1,2,4-triazolato)iridium(III) (abbreviation: [Ir(Prptzl-Me)₃]); organometallic complexes having an imidazole ring, such as fac-tris[1-(2,6-diisopropylphenyl)-2-phenyl-1H-imidazole]iridium(III) (abbreviation: [Ir(iPrpim)₃]) and tris[3-(2,6-dimethylphenyl)-7-methylimidazo[1,2-f]phenanthridinato]iridium(III) (abbreviation: [Ir(dmpimpt-Me)₃]); and organometallic complexes in which a phenylpyridine derivative having an electron-withdrawing group is a ligand, such as bis[2-(4′,6′-difluorophenyl)pyridinato-N,C²′]iridium(III) tetrakis(1-pyrazolyl)borate (abbreviation: FIr6), bis[2-(4′,6′-difluorophenyl)pyridinato-N,C²′]iridium(III) picolinate (abbreviation: FIrpic), bis{2-[3′,5′-bis(trifluoromethyl)phenyl]pyridinato-N,C²′}iridium(III) picolinate (abbreviation: [Ir(CF₃ppy)₂(pic)]), and bis[2-(4′,6′-difluorophenyl)pyridinato-N,C²′]iridium(III) acetylacetonate (abbreviation: FIr(acac)).

<<Phosphorescent Substance (from 495 nm to 590 nm, Green or Yellow)>>

As examples of a phosphorescent substance which emits green or yellow light and whose emission spectrum has a peak wavelength of greater than or equal to 495 nm and less than or equal to 590 nm, the following substances can be given.

Examples include organometallic iridium complexes having a pyrimidine ring, such as tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbornyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), (acetylacetonato)bis{4,6-dimethyl-2-[6-(2,6-dimethylphenyl)-4-pyrimidinyl-κN³]phenyl-κC}iridium(III) (abbreviation: [Ir(dmppm-dmp)₂(acac)]), and (acetylacetonato)bis(4,6-diphenylpyrimidinato)iridium(III) (abbreviation: [Ir(dppm)₂(acac)]); organometallic iridium complexes having a pyrazine ring, such as (acetylacetonato)bis(3,5-dimethyl-2-phenylpyrazinato)iridium(III) (abbreviation: [Ir(mppr-Me)₂(acac)]) and (acetylacetonato)bis(5-isopropyl-3-methyl-2-phenylpyrazinato)iridium(III) (abbreviation: [Ir(mppr-iPr)₂(acac)]); organometallic iridium complexes having a pyridine ring, such as tris(2-phenylpyridinato-N,C²′)iridium(III) (abbreviation: [Ir(ppy)₃]), bis(2-phenylpyridinato-N,C²′)iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C²′)iridium(III) (abbreviation: [Ir(pq)₃]), bis(2-phenylquinolinato-N,C²′)iridium(III) acetylacetonate (abbreviation: [Ir(pq)₂(acac)]), bis[2-(2-pyridinyl-κN)phenyl-κC][2-(4-phenyl-2-pyridinyl-κN)phenyl-κC]iridium(III) (abbreviation: [Ir(ppy)₂(4dppy)]), bis[2-(2-pyridinyl-κN)phenyl-κC][2-(4-methyl-5-phenyl-2-pyridinyl-κN)phenyl-κC], [2-d₃-methyl-8-(2-pyridinyl-κN)benzofuro[2,3-b]pyridine-κC]bis[2-(5-d₃-methyl-2-pyridinyl-κN²)phenyl-κC]iridium(III) (abbreviation: Ir(5mppy-d3)₂(mbfpypy-d3)), {2-(methyl-d₃)-8-[4-(1-methylethyl-1-d)-2-pyridinyl-κN]benzofuro[2,3-b]pyridin-7-yl-κC}bis{5-(methyl-d₃)-2-[5-(methyl-d₃)-2-pyridinyl-K]phenyl-κC}iridium(III) (abbreviation: Ir(5mtpy-d₆)₂(mbfpypy-iPr-d₄)), [2-d₃-methyl-(2-pyridinyl-κN)benzofuro[2,3-b]pyridine-κC]bis[2-(2-pyridinyl-κN)phenyl-κC]iridium(III) (abbreviation: Ir(ppy)₂(mbfpypy-d₃)), and [2-(4-methyl-5-phenyl-2-pyridinyl-κN)phenyl-κC]bis[2-(2-pyridinyl-κN)phenyl-KC]iridium(III) (abbreviation: Ir(ppy)₂(mdppy)); organometallic complexes such as bis(2,4-diphenyl-1,3-oxazolato-N,C²′)iridium(III) acetylacetonate (abbreviation: [Ir(dpo)₂(acac)]), bis{2-[4′-(perfluorophenyl)phenyl]pyridinato-N,C²′}iridium(III) acetylacetonate (abbreviation: [Ir(p-PF-ph)₂(acac)]), and bis(2-phenylbenzothiazolato-N,C²′)iridium(III) acetylacetonate (abbreviation: [Ir(bt)₂(acac)]); and a rare earth metal complex such as tris(acetylacetonato) (monophenanthroline)terbium(III) (abbreviation: [Tb(acac)₃(Phen)]).

<<Phosphorescent Substance (from 570 nm to 750 nm, Yellow or Red)>>

As examples of a phosphorescent substance which emits yellow or red light and whose emission spectrum has a peak wavelength of greater than or equal to 570 nm and less than or equal to 750 nm, the following substances can be given.

Examples include organometallic complexes having a pyrimidine ring, such as (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)₂(dpm)]), and (dipivaloylmethanato)bis[4,6-di(naphthalen-1-yl)pyrimidinato]iridium(III) (abbreviation: [Ir(dlnpm)₂(dpm)]); organometallic complexes having a pyrazine ring, such as (acetylacetonato)bis(2,3,5-triphenylpyrazinato)iridium(III) (abbreviation: [Ir(tppr)₂(acac)]), bis(2,3,5-triphenylpyrazinato) (dipivaloylmethanato)iridium(III) (abbreviation: [Ir(tppr)₂(dpm)]), bis{4,6-dimethyl-2-[3-(3,5-dimethylphenyl)-5-phenyl-2-pyrazinyl-κN]phenyl-κC}(2,6-dimethyl-3,5-heptanedionato-κ²O,O′)iridium(III) (abbreviation: [Ir(dmdppr-P)₂(dibm)]), bis{4,6-dimethyl-2-[5-(4-cyano-2,6-dimethylphenyl)-3-(3,5-dimethylphenyl)-2-pyrazin yl-κN]phenyl-κC}(2,2,6,6-tetramethyl-3,5-heptanedionato-κ²O,O′)iridium(III) (abbreviation: [Ir(dmdppr-dmCP)₂(dpm)]), bis[2-(5-(2,6-dimethylphenyl)-3-(3,5-dimethylphenyl)-2-pyrazinyl-κN)-4,6-dimethylphenyl-κC] (2,2′,6,6′-tetramethyl-3,5-heptanedionato-κ²O,O′)iridium(III) (abbreviation: [Ir(dmdppr-dmp)₂(dpm)]), (acetylacetonato)bis(2-methyl-3-phenylquinoxalinato-N,C²′]iridium(III) (abbreviation: Ir(mpq)₂(acac)), (acetylacetonato)bis(2,3-diphenylquinoxalinato-N,C²′)iridium(III) (abbreviation: [Ir(dpq)₂(acac)]), and (acetylacetonato)bis[2,3-bis(4-fluorophenyl)quinoxalinato]iridium(III) (abbreviation: [Ir(Fdpq)₂(acac)]); organometallic complexes having a pyridine ring, such as tris(1-phenylisoquinolinato-N,C²′)iridium(III) (abbreviation: [Ir(piq)₃]), bis(1-phenylisoquinolinato-N,C²′)iridium(III) acetylacetonate (abbreviation: [Ir(piq)₂(acac)]), and bis[4,6-dimethyl-2-(2-quinolinyl-κN)phenyl-κC](2,4-pentanedionato-κ²O,O′)iridium(III) (abbreviation: [Ir(dmpqn)₂(acac)]); a platinum complex such as 2,3,7,8,12,13,17,18-octaethyl-21H,23H-porphyrin platinum(II) (abbreviation: [PtOEP]); and rare earth metal complexes such as tris(1,3-diphenyl-1,3-propanedionato) (monophenanthroline)europium(III) (abbreviation: [Eu(DBM)₃(Phen)]) and tris[1-(2-thenoyl)-3,3,3-trifluoroacetonato](monophenanthroline)europium(III) (abbreviation: [Eu(TTA)₃(Phen)]).

### <<TADF Material>>

Any of materials described below can be used as the TADF material. The TADF material is a material that has a small difference between its S₁ and T₁ levels (preferably less than or equal to 0.2 eV), enables up-conversion of a triplet excited state into a singlet excited state (i.e., reverse intersystem crossing) using a little thermal energy, and efficiently emits light (fluorescent light) from the singlet excited state. Thermally activated delayed fluorescence is efficiently obtained under the condition where the energy difference between the triplet excited energy level and the singlet excited energy level is greater than or equal to 0 eV and less than or equal to 0.2 eV, preferably greater than or equal to 0 eV and less than or equal to 0.1 eV. Note that delayed fluorescence by the TADF material refers to light emission having a spectrum similar to that of normal fluorescent light and an extremely long lifetime. The lifetime is longer than or equal to 1×10⁻⁶ seconds or longer than or equal to 1×10⁻³ seconds. In addition, the organic compound described in Embodiment 1 can be used.

Note that the TADF material can be also used as an electron-transport material, a hole-transport material, or a host material.

Examples of the TADF material include fullerene, a derivative thereof, an acridine derivative such as proflavine, and eosin. The examples further include a metal-containing porphyrin such as a porphyrin containing magnesium (Mg), zinc (Zn), cadmium (Cd), tin (Sn), platinum (Pt), indium (In), or palladium (Pd). Examples of the metal-containing porphyrin include a protoporphyrin-tin fluoride complex (abbreviation: SnF₂(Proto IX)), a mesoporphyrin-tin fluoride complex (abbreviation: SnF₂(Meso IX)), a hematoporphyrin-tin fluoride complex (abbreviation: SnF₂(Hemato IX)), a coproporphyrin tetramethyl ester-tin fluoride complex (abbreviation: SnF₂(Copro III-4Me)), an octaethylporphyrin-tin fluoride complex (abbreviation: SnF₂(OEP)), an etioporphyrin-tin fluoride complex (abbreviation: SnF₂(Etio I)), and an octaethylporphyrin-platinum chloride complex (abbreviation: PtCl₂OEP).

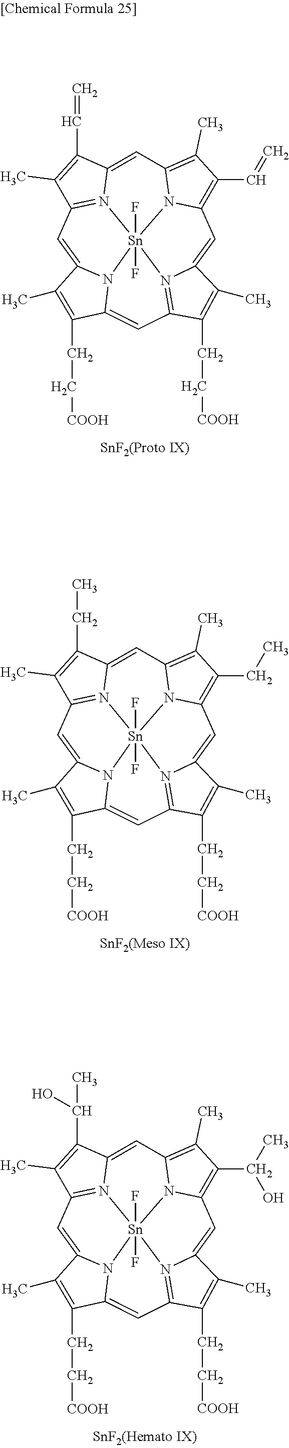

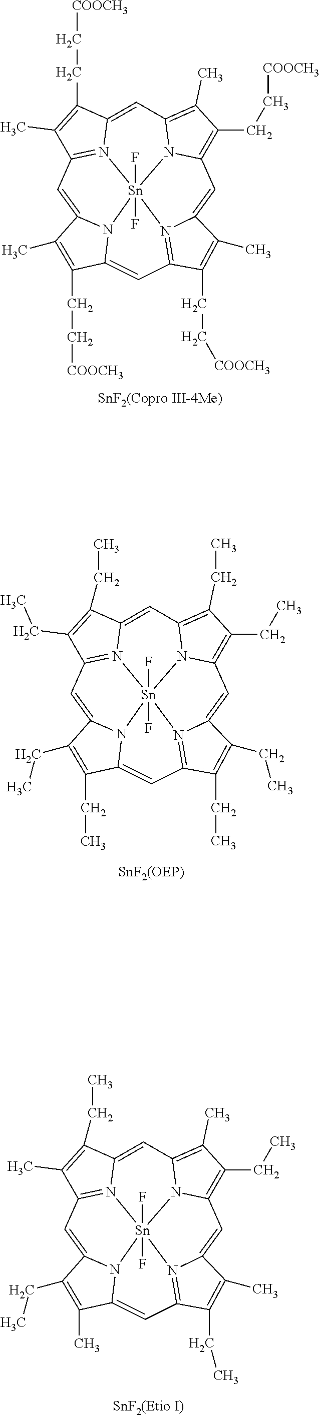

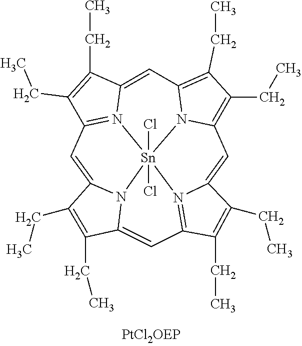

Alternatively, a heteroaromatic compound including a π-electron rich heteroaromatic compound and a π-electron deficient heteroaromatic compound, such as 2-(biphenyl-4-yl)-4,6-bis(12-phenylindolo[2,3-a]carbazol-11-yl)-1,3,5-triazine (abbreviation: PIC-TRZ), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), 10-phenyl-10H,10′H-spiro[acridin-9,9′-anthracen]-10′-one (abbreviation: ACRSA), 4-(9′-phenyl-3,3′-bi-9H-carbazol-9-yl)benzofuro[3,2-d]pyrimidine (abbreviation: 4PCCzBfpm), 4-[4-(9′-phenyl-3,3′-bi-9H-carbazol-9-yl)phenyl]benzofuro[3,2-d]pyrimidine (abbreviation: 4PCCzPBfpm), or 9-[3-(4,6-diphenyl-1,3,5-triazin-2-yl)phenyl]-9′-phenyl-2,3′-bi-9H-carbazole (abbreviation: mPCCzPTzn-02) may be used.

Note that a substance in which a π-electron rich heteroaromatic compound is directly bonded to a π-electron deficient heteroaromatic compound is particularly preferable because both the donor property of the π-electron rich heteroaromatic compound and the acceptor property of the π-electron deficient heteroaromatic compound are improved and the energy difference between the singlet excited state and the triplet excited state becomes small. As the TADF material, a TADF material in which the singlet and triplet excited states are in thermal equilibrium (TADF100) may be used. Since such a TADF material enables a short emission lifetime (excitation lifetime), an efficiency decrease of a light-emitting element in a high-luminance region can be inhibited.

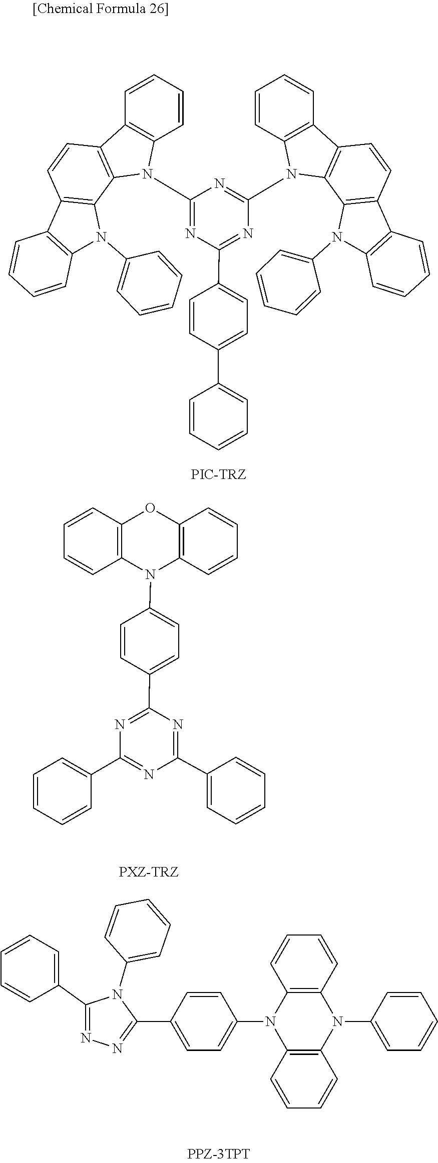 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-c3ccc(N4c5ccccc5Oc5ccccc54)cc3)n2)cc1 ; c1ccc(-c2nnc(-c3ccc(N4c5ccccc5N(c5ccccc5)c5ccccc54)cc3)n2-c2ccccc2)cc1]

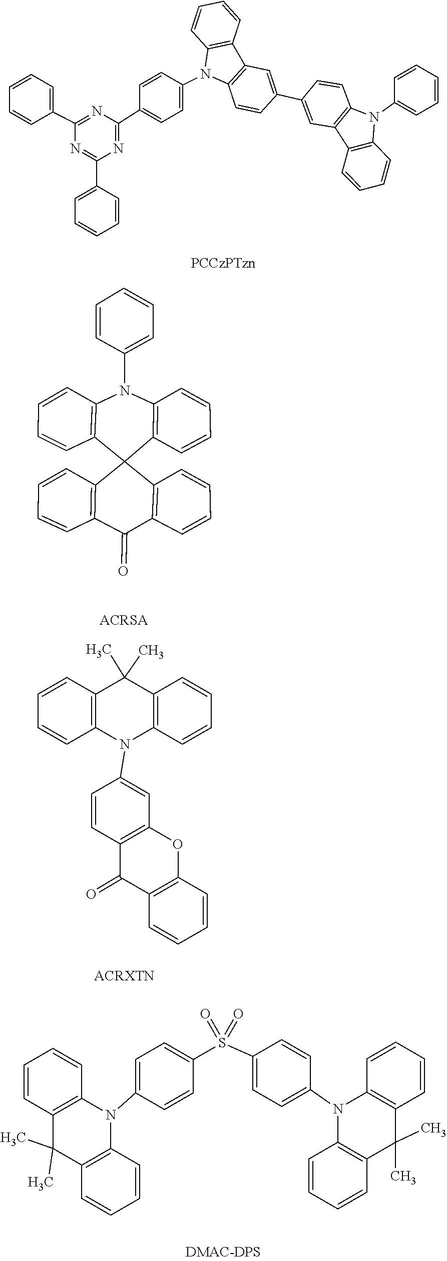

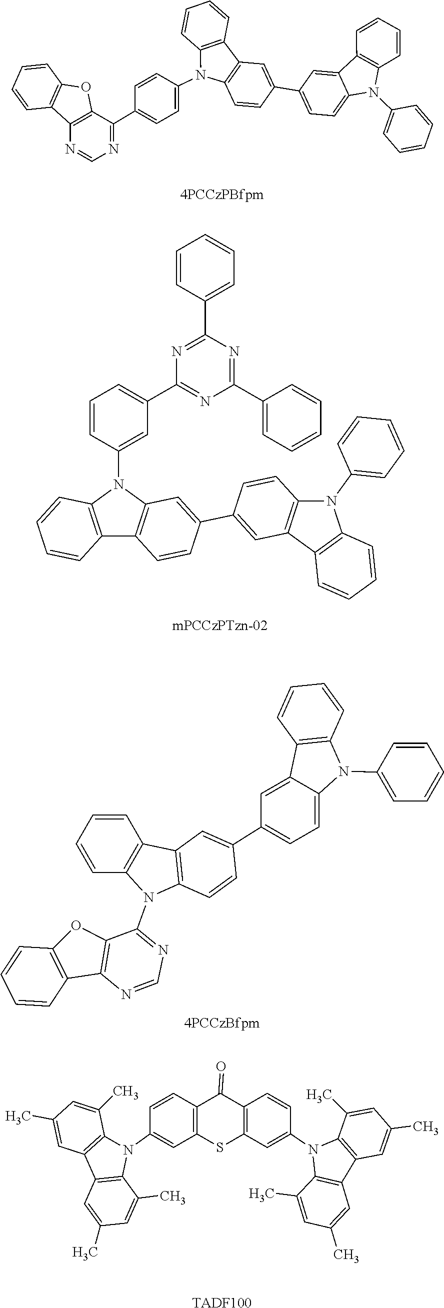

In addition to the above, a nano-structure of a transition metal compound having a perovskite structure can be given as another example of a material having a function of converting triplet excitation energy into light. In particular, a nano-structure of a metal halide perovskite material is preferable. The nano-structure is preferably a nanoparticle or a nanorod.

As the organic compound (e.g., the host material) used in combination with the above-described light-emitting substance (guest material) in the light-emitting layer), one or more kinds selected from substances having a larger energy gap than the light-emitting substance (guest material) are used.

### <<Host Material for Fluorescent Light>>

In the case where the light-emitting substance used for the light-emitting layer is a fluorescent substance, an organic compound (a host material) used in combination with the fluorescent substance is preferably an organic compound that has a high energy level in a singlet excited state and has a low energy level in a triplet excited state or an organic compound that has a high fluorescence quantum yield. Therefore, the hole-transport material (described above) and the electron-transport material (described below) shown in this embodiment, for example, can be used as long as they are organic compounds that satisfy such a condition. In addition, the organic compound described in Embodiment 1 can be used.

In terms of a preferable combination with the light-emitting substance (fluorescent substance), examples of the organic compound (host material), some of which overlap the above specific examples, include condensed polycyclic aromatic compounds such as an anthracene derivative, a tetracene derivative, a phenanthrene derivative, a pyrene derivative, a chrysene derivative, and a dibenzo[g,p]chrysene derivative.

Specific examples of the organic compound (host material) that is preferably used in combination with the fluorescent substance include 9-phenyl-3-[4-(10-phenyl-9-anthryl)phenyl]-9H-carbazole (abbreviation: PCzPA), 3,6-diphenyl-9-[4-(10-phenyl-9-anthryl)phenyl]-9H-carbazole (abbreviation: DPCzPA), PCPN, 9,10-diphenylanthracene (abbreviation: DPAnth), N,N-diphenyl-9-[4-(10-phenyl-9-anthryl)phenyl]-9H-carbazol-3-amine (abbreviation: CzA1PA), 4-(10-phenyl-9-anthryl)triphenylamine (abbreviation: DPhPA), YGAPA, PCAPA, N,9-diphenyl-N-{4-[4-(10-phenyl-9-anthryl)phenyl]phenyl}-9H-carbazol-3-amine (abbreviation: PCAPBA), N-(9,10-diphenyl-2-anthryl)-N,9-diphenyl-9H-carbazol-3-amine (abbreviation: 2PCAPA), 6,12-dimethoxy-5,11-diphenylchrysene, N,N,N′,N′,N″,N″,N′″,N′″-octaphenyldibenzo[g,p]chrysene-2,7,10,15-tetraamine (abbreviation: DBC1), CzPA, 7-[4-(10-phenyl-9-anthryl)phenyl]-7H-dibenzo[c,g]carbazole (abbreviation: cgDBCzPA), 6-[3-(9,10-diphenyl-2-anthryl)phenyl]benzo[b]naphtho[1,2-d]furan (abbreviation: 2mBnfPPA), 9-phenyl-10-[4′-(9-phenyl-9H-fluoren-9-yl)biphenyl-4-yl]anthracene (abbreviation: FLPPA), 9,10-bis(3,5-diphenylphenyl)anthracene (abbreviation: DPPA), 9,10-di(2-naphthyl)anthracene (abbreviation: DNA), 2-tert-butyl-9,10-di(2-naphthyl)anthracene (abbreviation: t-BuDNA), 9-(1-naphthyl)-10-(2-naphthyl)anthracene (abbreviation: α,β-ADN), 2-(10-phenylanthracen-9-yl)dibenzofuran, 2-(10-phenyl-9-anthracenyl)benzo[b]naphtho[2,3-d]furan (abbreviation: Bnf(II)PhA), 9-(1-naphthyl)-10-[4-(2-naphthyl)phenyl]anthracene (abbreviation: α,N-βNPAnth), 2,9-di(1-naphthyl)-10-phenylanthracene (abbreviation: 2αN-αNPhA), 9-(1-naphthyl)-10-[3-(1-naphthyl)phenyl]anthracene (abbreviation: α,N-mαNPAnth), 9-(2-naphthyl)-10-[3-(1-naphthyl)phenyl]anthracene (abbreviation: βN-mαNPAnth), 9-(1-naphthyl)-10-[4-(1-naphthyl)phenyl]anthracene (abbreviation: αN-αNPAnth), 9-(2-naphthyl)-10-[4-(2-naphthyl)phenyl]anthracene (abbreviation: βN-βNPAnth), 2-(1-naphthyl)-9-(2-naphthyl)-10-phenylanthracene (abbreviation: 2αN-βNPhA), 9-(2-naphthyl)-10-[3-(2-naphthyl)phenyl]anthracene (abbreviation: βN-mβNPAnth), 1-{4-[10-(biphenyl-4-yl)-9-anthracenyl]phenyl}-2-ethyl-1H-benzimidazole (abbreviation: EtBImPBPhA), 9,9′-bianthryl (abbreviation: BANT), 9,9′-(stilbene-3,3′-diyl)diphenanthrene (abbreviation: DPNS), 9,9′-(stilbene-4,4′-diyl)diphenanthrene (abbreviation: DPNS2), 1,3,5-tri(1-pyrenyl)benzene (abbreviation: TPB3), 5,12-diphenyltetracene, and 5,12-bis(biphenyl-2-yl)tetracene.

### <<Host Material for Phosphorescent Light>>

In the case where the light-emitting substance used for the light-emitting layer is a phosphorescent substance, an organic compound having triplet excitation energy (an energy difference between a ground state and a triplet excited state) which is higher than that of the light-emitting substance is selected as the organic compound (host material) used in combination with the phosphorescent substance. Note that when a plurality of organic compounds (e.g., a first host material and a second host material (or an assist material)) are used in combination with a light-emitting substance so that an exciplex is formed, the plurality of organic compounds are preferably mixed with the phosphorescent substance. In addition, the organic compound described in Embodiment 1 can be used.

With such a structure, light emission can be efficiently obtained by exciplex-triplet energy transfer (ExTET), which is energy transfer from an exciplex to a light-emitting substance. Note that a combination of the plurality of organic compounds that easily forms an exciplex is preferably employed, and it is particularly preferable to combine a compound that easily accepts holes (hole-transport material) and a compound that easily accepts electrons (electron-transport material).

In terms of a preferable combination with the light-emitting substance (phosphorescent substance), examples of the organic compounds (the host material and the assist material), some of which overlap the above specific examples, include an aromatic amine (an organic compound having an aromatic amine skeleton), a carbazole derivative (an organic compound having a carbazole ring), a dibenzothiophene derivative (an organic compound having a dibenzothiophene ring), a dibenzofuran derivative (an organic compound having a dibenzofuran ring), an oxadiazole derivative (an organic compound having an oxadiazole ring), a triazole derivative (an organic compound having a triazole ring), a benzimidazole derivative (an organic compound having a benzimidazole ring), a quinoxaline derivative (an organic compound having a quinoxaline ring), a dibenzoquinoxaline derivative (an organic compound having a dibenzoquinoxaline ring), a pyrimidine derivative (an organic compound having a pyrimidine ring), a triazine derivative (an organic compound having a triazine ring), a pyridine derivative (an organic compound having a pyridine ring), a bipyridine derivative (an organic compound having a bipyridine ring), a phenanthroline derivative (an organic compound having a phenanthroline ring), a furodiazine derivative (an organic compound having a furodiazine ring), and zinc- and aluminum-based metal complexes.

Among the above organic compounds, specific examples of the aromatic amine and the carbazole derivative, which are organic compounds having a high hole-transport property, are the same as the specific examples of the hole-transport materials described above, and those materials are preferable as the host material.

Among the above organic compounds, specific examples of the dibenzothiophene derivative and the dibenzofuran derivative, which are organic compounds having a high hole-transport property, are mmDBFFLBi-II, DBF3P-II, DBT3P-II, DBTFLP-III, DBTFLP-IV, and 4-[3-(triphenylen-2-yl)phenyl]dibenzothiophene (abbreviation: mDBTPTp-II), and these materials are each preferable as a host material.

Other examples of preferable host materials include metal complexes having an oxazole-based or thiazole-based ligand, such as bis[2-(2-benzoxazolyl)phenolato]zinc(II) (abbreviation: ZnPBO) and bis[2-(2-benzothiazolyl)phenolato]zinc(II) (abbreviation: ZnBTZ).

Among the above organic compounds, specific examples of the oxadiazole derivative, the triazole derivative, the benzimidazole derivative, the quinoxaline derivative, the dibenzoquinoxaline derivative, the quinazoline derivative, and the phenanthroline derivative, which are organic compounds having a high electron-transport property, include an organic compound containing a heteroaromatic ring having a polyazole ring such as 2-(4-biphenylyl)-5-(4-tert-butylphenyl)-1,3,4-oxadiazole (abbreviation: PBD), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 3-(4-biphenylyl)-4-phenyl-5-(4-tert-butylphenyl)-1,2,4-triazole (abbreviation: TAZ), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), or 4,4′-bis(5-methylbenzoxazol-2-yl)stilbene (abbreviation: BzOs); an organic compound containing a heteroaromatic ring having a pyridine ring such as bathophenanthroline (abbreviation: BPhen), bathocuproine (abbreviation: BCP), 2,9-di(naphthalen-2-yl)-4,7-diphenyl-1,10-phenanthroline (abbreviation: NBPhen), or 2,2′-(1,3-phenylene)bis[9-phenyl-1,10-phenanthroline] (abbreviation: mPPhen2P); 2-[3-(dibenzothiophen-4-yl)phenyl]dibenzo[f;h]quinoxaline (abbreviation: 2mDBTPDBq-II); 2-[3′-(dibenzothiophen-4-yl)biphenyl-3-yl]dibenzo[f;h]quinoxaline (abbreviation: 2mDBTBPDBq-II); 2-[3′-(9H-carbazol-9-yl)biphenyl-3-yl]dibenzo[f;h]quinoxaline (abbreviation: 2mCzBPDBq); 2-[4-(3,6-diphenyl-9H-carbazol-9-yl)phenyl]dibenzo[f;h]quinoxaline (abbreviation: 2CzPDBq-III); 7-[3-(dibenzothiophen-4-yl)phenyl]dibenzo[f;h]quinoxaline (abbreviation: 7mDBTPDBq-II); 6-[3-(dibenzothiophen-4-yl)phenyl]dibenzo[f;h]quinoxaline (abbreviation: 6mDBTPDBq-II); 2-{4-[9,10-di(2-naphthyl)-2-anthryl]phenyl}-1-phenyl-1H-benzimidazole (abbreviation: ZADN); and 2-[4′-(9-phenyl-9H-carbazol-3-yl)-3,1′-biphenyl-1-yl]dibenzo[f,h]quinoxaline (abbreviation: 2mpPCBPDBq). Such organic compounds are preferable as the host material.

Among the above organic compounds, specific examples of the pyridine derivative, the diazine derivative (e.g., the pyrimidine derivative, the pyrazine derivative, and the pyridazine derivative), the triazine derivative, the furodiazine derivative, which are organic compounds having a high electron-transport property, include organic compounds including a heteroaromatic ring having a diazine ring such as 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), PCCzPTzn, mPCCzPTzn-02, 3,5-bis[3-(9H-carbazol-9-yl)phenyl]pyridine (abbreviation: 35DCzPPy), 1,3,5-tri[3-(3-pyridyl)phenyl]benzene (abbreviation: TmPyPB), 9,9′-[pyrimidine-4,6-diylbis(biphenyl-3,3′-diyl)]bis(9H-carbazole) (abbreviation: 4,6mCzBP2Pm), 2-[3′-(9,9-dimethyl-9H-fluoren-2-yl)biphenyl-3-yl]-4,6-diphenyl-1,3,5-triazine (abbreviation: mFBPTzn), 8-(biphenyl-4-yl)-4-[3-(dibenzothiophen-4-yl)phenyl]-[1]benzofuro[3,2-d]pyrimidine (abbreviation: 8BP-4mDBtPBfpm), 9-[3′-(dibenzothiophen-4-yl)biphenyl-3-yl]naphtho[1′,2′:4,5]furo[2,3-b]pyrazine (abbreviation: 9mDBtBPNfpr), 9-[3′-(dibenzothiophen-4-yl)biphenyl-4-yl]naphtho[1′,2′:4,5]furo[2,3-b]pyrazine (abbreviation: 9pmDBtBPNfpr), 11-[(3′-dibenzothiophen-4-yl)bipheny-3-yl]phenanthro[9′,10′:4,5]furo[2,3-b]pyrazine (abbreviation: 11mDBtBPPnfpr), 11-[3′-(dibenzothiophen-4-yl)biphenyl-4-yl]phenanthro[9′,10′:4,5]furo[2,3-b]pyrazine, 11-[3′-(9H-carbazol-9-yl)biphenyl-3-yl]phenanthro[9′,10′:4,5]furo[2,3-b]pyrazine, 12-(9′-phenyl-3,3′-bi-9H-carbazol-9-yl)phenanthro[9′,10′:4,5]furo[2,3-b]pyrazine (abbreviation: 12PCCzPnfpr), 9-[(3′-9-phenyl-9H-carbazol-3-yl)biphenyl-4-yl]naphtho[1′,2′:4,5]furo[2,3-b]pyrazine (abbreviation: 9pmPCBPNfpr), 9-(9′-phenyl-3,3′-bi-9H-carbazol-9-yl)naphtho[1′,2′:4,5]furo[2,3-b]pyrazine (abbreviation: 9PCCzNfpr), 10-(9′-phenyl-3,3′-bi-9H-carbazol-9-yl)naphtho[1′,2′:4,5]furo[2,3-b]pyrazine (abbreviation: 1OPCCzNfpr), 9-[3′-(6-phenylbenzo[b]naphtho[1,2-d]furan-8-yl)biphenyl-3-yl]naphtho[1′,2′:4,5]furo[2,3-b]pyrazine (abbreviation: 9mBnfBPNfpr), 9-{3-[6-(9,9-dimethylfluoren-2-yl)dibenzothiophen-4-yl]phenyl}naphtho[1′,2′:4,5]furo[2,3-b]pyrazine (abbreviation: 9mFDBtPNfpr), 9-[3′-(6-phenyldibenzothiophen-4-yl)biphenyl-3-yl]naphtho[1′,2′:4,5]furo[2,3-b]pyrazin e (abbreviation: 9mDBtBPNfpr-02), 9-[3-(9′-phenyl-3,3′-bi-9H-carbazol-9-yl)phenyl]naphtho[1′,2′:4,5]furo[2,3-b]pyrazine (abbreviation: 9mPCCzPNfpr), 9-{(3′-[2,8-diphenyldibenzothiophen-4-yl)biphenyl-3-yl}naphtho[1′,2′:4,5]furo[2,3-b]pyrazine, 11-{(3′-[2,8-diphenyldibenzothiophen-4-yl)biphenyl-3-yl]phenanthro[9′,10′:4,5]furo[2,3-b]pyrazine, 5-[3-(4,6-diphenyl-1,3,5-triazin-2-yl)phenyl]-7,7-dimethyl-5H,7H-indeno[2,1-b]carbazole (abbreviation: mINc(II)PTzn), 2-[3′-(triphenylen-2-yl)biphenyl-3-yl]-4,6-diphenyl-1,3,5-triazine (abbreviation: mTpBPTzn), 2-(biphenyl-4-yl)-4-phenyl-6-(9,9′-spirobi[9H-fluoren]-2-yl)-1,3,5-triazine (abbreviation: BP-SFTzn), 2,6-bis(4-naphthalen-1-ylphenyl)-4-[4-(3-pyridyl)phenyl]pyrimidine (abbreviation: 2,4NP-6PyPPm), 3-[9-(4,6-diphenyl-1,3,5-triazin-2-yl)-2-dibenzofuranyl]-9-phenyl-9H-carbazole (abbreviation: PCDBfTzn), 2-(biphenyl-3-yl)-4-phenyl-6-{8-[(1,1′:4′,1″-terphenyl)-4-yl]-1-dibenzofuranyl}-1,3,5-triazine (abbreviation: mBP-TPDBfTzn), 6-(biphenyl-3-yl)-4-[3,5-bis(9H-carbazol-9-yl)phenyl]-2-phenylpyrimidine (abbreviation: 6mBP-4Cz2PPm), 4-[3,5-bis(9H-carbazol-9-yl)phenyl]-2-phenyl-6-(biphenyl-4-yl)pyrimidine (abbreviation: 6BP-4Cz2PPm), and those materials are preferable as the host material.

Among the above organic compounds, specific examples of metal complexes that are organic compounds having a high electron-transport property include zinc- or aluminum-based metal complexes, such as tris(8-quinolinolato)aluminum(III) (abbreviation: Alq), tris(4-methyl-8-quinolinolato)aluminum(III) (abbreviation: Almq₃), bis(10-hydroxybenzo[h]quinolinato)beryllium(II) (abbreviation: BeBq₂), bis(2-methyl-8-quinolinolato) (4-phenylphenolato)aluminum(III) (abbreviation: BAlq), and bis(8-quinolinolato)zinc(II) (abbreviation: Znq), and metal complexes having a quinoline ring or a benzoquinoline ring. Such metal complexes are preferable as the host material.

Moreover, high molecular compounds such as poly(2,5-pyridinediyl) (abbreviation: PPy), poly[(9,9-dihexylfluorene-2,7-diyl)-co-(pyridine-3,5-diyl)](abbreviation: PF-Py), and poly[(9,9-dioctylfluorene-2,7-diyl)-co-(2,2′-bipyridine-6,6′-diyl)] (abbreviation: PF-BPy) are preferable as the host material.

Furthermore, the following organic compounds having a diazine ring, which have bipolar properties, a high hole-transport property, and a high electron-transport property, can be used as the host material: 9-phenyl-9′-(4-phenyl-2-quinazolinyl)-3,3′-bi-9H-carbazole (abbreviation: PCCzQz), 2mpPCBPDBq, mINc(II)PTzn, 11-[4-(biphenyl-4-yl)-6-phenyl-1,3,5-triazin-2-yl]-11,12-dihydro-12-phenylindolo[2,3-a]carbazole (abbreviation: BP-Icz(II)Tzn), and 7-[4-(9-phenyl-9H-carbazol-2-yl)quinazolin-2-yl]-7H-dibenzo[c,g]carbazole (abbreviation: PC-cgDBCzQz).

### <Electron-Transport Layer>

The electron-transport layer transports electrons, which are injected from the second electrode and the charge-generation layer by the electron-injection layer to be described later, to the light-emitting layer. The material used for the electron-transport layer is preferably a substance having an electron mobility higher than or equal to 1×10⁻⁶ cm²/Vs in the case where the square root of the electric field strength [V/cm] is 600. Note that any other substance can also be used as long as the substance has an electron-transport property higher than a hole-transport property. Furthermore, the electron-transport layer can function even with a single-layer structure, but may have a stacked structure of two or more layers. For example, one of two electron-transport layers which is in contact with the light-emitting layer may also function as a hole-blocking layer. Moreover, when the electron-transport layer has a stacked-layer structure, heat resistance can be increased in some cases. A photolithography process performed over the electron-transport layer including the above-described mixed material, which has heat resistance, can inhibit an adverse effect of thermal process on the device characteristics.

### <<Electron-Transport Material>>

As the electron-transport material that can be used for the electron-transport layer, an organic compound having a high electron-transport property can be used, and for example, a heteroaromatic compound can be used. The heteroaromatic compound refers to a cyclic compound containing at least two different kinds of elements in a ring. Examples of cyclic structures include a three-membered ring, a four-membered ring, a five-membered ring, and a six-membered ring, among which a five-membered ring and a six-membered ring are particularly preferable. The elements contained in the heteroaromatic compound are preferably one or more of nitrogen, oxygen, and sulfur, in addition to carbon. In particular, a heteroaromatic compound containing nitrogen (a nitrogen-containing heteroaromatic compound) is preferable, and any of materials having a high electron-transport property (electron-transport materials), such as a nitrogen-containing heteroaromatic compound and a π-electron deficient heteroaromatic compound including the nitrogen-containing heteroaromatic compound, is preferably used. The compound in Embodiment 1 has an electron-transport property and thus can be used as an electron-transport material.

Note that the electron-transport material can be different from the materials used for the light-emitting layer. Not all excitons formed by recombination of carriers in the light-emitting layer can contribute to light emission and some excitons might be diffused into a layer in contact with the light-emitting layer or a layer in the vicinity of the light-emitting layer. In order to avoid this phenomenon, the energy level (the lowest singlet excitation energy level or the lowest triplet excitation energy level) of a material used for the layer in contact with the light-emitting layer or the layer in the vicinity of the light-emitting layer is preferably higher than that of a material used for the light-emitting layer. Therefore, when a material different from the material of the light-emitting layer is used as the electron-transport material, an element with high efficiency can be obtained.

The heteroaromatic compound is an organic compound having at least one heteroaromatic ring.

The heteroaromatic ring has any one of a pyridine ring, a diazine ring, a triazine ring, a polyazole ring, an oxazole ring, a thiazole ring, and the like. A heteroaromatic ring having a diazine ring includes a heteroaromatic ring having a pyrimidine ring, a pyrazine ring, a pyridazine ring, or the like. A heteroaromatic ring having a polyazole ring includes a heteroaromatic ring having an imidazole ring, a triazole ring, or an oxadiazole ring.

The heteroaromatic ring includes a condensed heteroaromatic ring having a fused ring structure. Examples of the condensed heteroaromatic ring include a quinoline ring, a benzoquinoline ring, a quinoxaline ring, a dibenzoquinoxaline ring, a quinazoline ring, a benzoquinazoline ring, a dibenzoquinazoline ring, a phenanthroline ring, a furodiazine ring, and a benzimidazole ring.

Examples of the heteroaromatic compound having a five-membered ring structure, which is a heteroaromatic compound containing carbon and one or more of nitrogen, oxygen, sulfur, and the like, include a heteroaromatic compound having an imidazole ring, a heteroaromatic compound having a triazole ring, a heteroaromatic compound having an oxazole ring, a heteroaromatic compound having an oxadiazole ring, a heteroaromatic compound having a thiazole ring, and a heteroaromatic compound having a benzimidazole ring.

Examples of the heteroaromatic compound having a six-membered ring structure, which is a heteroaromatic compound containing carbon and one or more of nitrogen, oxygen, sulfur, and the like, include a heteroaromatic compound having a heteroaromatic ring, such as a pyridine ring, a diazine ring (including a pyrimidine ring, a pyrazine ring, a pyridazine ring, or the like), or a triazine ring. Other examples include a heteroaromatic compound having a bipyridine structure and a heteroaromatic compound having a terpyridine structure, although they are included in examples of a heteroaromatic compound in which pyridine rings are bonded.

Examples of the heteroaromatic compound having a fused ring structure including the above six-membered ring structure as a part include a heteroaromatic compound having a fused heteroaromatic ring such as a quinoline ring, a benzoquinoline ring, a quinoxaline ring, a dibenzoquinoxaline ring, a phenanthroline ring, a furodiazine ring (including a structure where an aromatic ring is condensed to a furan ring of a furodiazine ring), or a benzimidazole ring.

Specific examples of the heteroaromatic compound having a 5-membered ring structure (e.g., a polyazole ring (including an imidazole ring, a triazole ring, and an oxadiazole ring), an oxazole ring, a thiazole ring, or a benzimidazole ring) are PBD, OXD-7, CO11, TAZ, 3-(4-tert-butylphenyl)-4-(4-ethylphenyl)-5-(4-biphenylyl)-1,2,4-triazole (abbreviation: p-EtTAZ), TPBI, mDBTBIm-II, and BzOS.

Specific examples of the heteroaromatic compound having a 6-membered ring structure (including a heteroaromatic ring having a pyridine ring, a diazine ring, a triazine ring, or the like) are a heteroaromatic compound including a heteroaromatic ring having a pyridine ring, such as 35DCzPPy or TmPyPB; a heteroaromatic compound including a heteroaromatic ring having a triazine ring, such as PCCzPTzn, mPCCzPTzn-02, mINc(II)PTzn, mTpBPTzn, BP-SFTzn, 2,4NP-6PyPPm, PCDBfTzn, mBP-TPDBfTzn, 2-{3-[3-(dibenzothiophen-4-yl)phenyl]phenyl}-4,6-diphenyl-1,3,5-triazine (abbreviation: mDBtBPTzn), or mFBPTzn; and a heteroaromatic compound including a heteroaromatic ring having a diazine (pyrimidine) ring, such as 4,6mPnP2Pm, 4,6mDBTP2Pm-II, 4,6mCzP2Pm, 4,6mCzBP2Pm, 6mBP-4Cz2PPm, 6BP-4Cz2PPm, 8-(naphthalen-2-yl)-4-[3-(dibenzothiophen-4-yl)phenyl]-[1]benzofuro[3,2-d]pyrimidine (abbreviation: 8PN-4mDBtPBfpm), 8BP-4mDBtPBfpm, 9mDBtBPNfpr, 9pmDBtBPNfpr, 3,8-bis[3-(dibenzothiophen-4-yl)phenyl]benzofuro[2,3-b]pyrazine (abbreviation: 3,8mDBtP2Bfpr), 4,8-bis[3-(dibenzothiophen-4-yl)phenyl]-[1]benzofuro[3,2-d]pyrimidine (abbreviation: 4,8mDBtP2Bfpm), 8-[3′-(dibenzothiophen-4-yl)biphenyl-3-yl]naphtho[1′,2′:4,5]furo[3,2-d]pyrimidine (abbreviation: 8mDBtBPNfpm), and 8-[(2,2′-binaphthalen)-6-yl]-4-[3-(dibenzothiophen-4-yl)phenyl]-[1]benzofuro[3,2-d]pyrimidine (abbreviation: 8(pN2)-4mDBtPBfpm). Note that the above aromatic compounds including a heteroaromatic ring include a heteroaromatic compound having a condensed heteroaromatic ring.

Other examples include a heteroaromatic compound including a heteroaromatic ring having a diazine (pyrimidine) ring, such as 2,2′-(pyridine-2,6-diyl)bis(4-phenylbenzo[h]quinazoline) (abbreviation: 2,6(P-Bqn)₂Py), 2,2′-(2,2′-bipyridine-6,6′-diyl)bis(4-phenylbenzo[h]quinazoline) (abbreviation: 6,6′(P-Bqn)₂BPy), 2,2′-(pyridine-2,6-diyl)bis{4-[4-(2-naphthyl)phenyl]-6-phenylpyrimidine}(abbreviation: 2,6(NP-PPm)₂Py), or 6mBP-4Cz2PPm, and a heteroaromatic compound including a heteroaromatic ring having a triazine ring, such as 2,4,6-tris[3′-(pyridin-3-yl)biphenyl-3-yl]-1,3,5-triazine (abbreviation: TmPPPyTz), 2,4,6-tris(2-pyridyl)-1,3,5-triazine (abbreviation: 2Py3Tz), or 2-[3-(2,6-dimethyl-3-pyridyl)-5-(9-phenanthryl)phenyl]-4,6-diphenyl-1,3,5-triazine (abbreviation: mPn-mDMePyPTzn).

Specific examples of the heteroaromatic compound with a fused structure that partly has a 6-membered ring structure are heteroaromatic compounds each having a quinoxaline ring, such as BPhen, bathocuproine (abbreviation: BCP), NBPhen, mPPhen2P, 2,6(P-Bqn)₂Py, 2mDBTPDBq-II, 2mDBTBPDBq-II, 2mCzBPDBq, 2CzPDBq-III, 7mDBTPDBq-II, 6mDBTPDBq-II, and 2mpPCBPDBq.

For the electron-transport layer, any of the metal complexes given below as well as the heteroaromatic compounds given above can be used. Examples include metal complexes each including a quinoline ring or a benzoquinoline ring, such as tris(8-quinolinolato)aluminum (III) (abbreviation: Alq₃), Almq₃, 8-quinolinolato-lithium (abbreviation: Liq), BeBq₂, BAlq, and Znq; and metal complexes each including an oxazole ring or a thiazole ring, such as ZnPBO and ZnBTZ.

It is also possible to use high-molecular compounds such as PPy, PF-Py, and PF-BPy as the electron-transport material.

### <Electron-Injection Layer>

The electron-injection layer is a layer containing a substance having a high electron-injection property. The electron-injection layer is a layer for increasing the efficiency of electron injection from the second electrode and is preferably formed using a material whose value of the LUMO level has a small difference (0.5 eV or less) from the work function of a material used for the second electrode. Thus, the electron-injection layer can be formed using an alkali metal, an alkaline earth metal, or a compound thereof, such as lithium, cesium, lithium fluoride (LiF), cesium fluoride (CsF), calcium fluoride (CaF₂), Liq, 2-(2-pyridyl)phenolatolithium (abbreviation: LiPP), 2-(2-pyridyl)-3-pyridinolatolithium (abbreviation: LiPPy), 4-phenyl-2-(2-pyridyl)phenolatolithium (abbreviation: LiPPP), an oxide of lithium (LiOₓ), or cesium carbonate. A rare earth metal such as Yb or a rare earth metal compound such as erbium fluoride (ErF₃) can also be used. To form the electron-injection layer, a plurality of kinds of materials given above may be mixed or stacked. For example, the electron-injection layer may be a stack of layers with different electric resistances. Electride may also be used for the electron-injection layer. Examples of the electride include a substance in which electrons are added at high concentration to calcium oxide-aluminum oxide. Any of the above-described substances used for the electron-transport layer can also be used.

A mixed material in which an organic compound and an electron donor (donor) are mixed may also be used for the electron-injection layer. Such a mixed material is excellent in an electron-injection property and an electron-transport property because electrons are generated in the organic compound by the electron donor. The organic compound here is preferably a material excellent in transporting the generated electrons; specifically, for example, electron-transport materials used for an electron-transport layer described above (e.g., a metal complex and a heteroaromatic compound) can be used. As the electron donor, a substance showing an electron-donating property with respect to an organic compound is used. Specifically, an alkali metal, an alkaline earth metal, and a rare earth metal are preferable, and Li, Cs, Mg, Ca, erbium (Er), Yb, and the like are given. In addition, an alkali metal oxide and an alkaline earth metal oxide are preferable, and lithium oxide, calcium oxide, barium oxide, and the like are given. Alternatively, a Lewis base such as magnesium oxide can be used. Further alternatively, an organic compound such as tetrathiafulvalene (abbreviation: TTF) can be used. Alternatively, a stack of two or more of these materials may be used.

Alternatively, the electron-injection layer may be formed using a mixed material in which an organic compound and a metal are mixed. The organic compound used here preferably has a LUMO level higher than or equal to −3.6 eV and lower than or equal to −2.3 eV. Moreover, a material having an unshared electron pair is preferable.

Thus, as the organic compound used in the above mixed material, a mixed material obtained by mixing a metal and the heteroaromatic compound given above as the material that can be used for the electron-transport layer may be used. Preferable examples of the heteroaromatic compound include materials having an unshared electron pair, such as a heteroaromatic compound having a five-membered ring structure (e.g., an imidazole ring, a triazole ring, an oxazole ring, an oxadiazole ring, a thiazole ring, or a benzimidazole ring), a heteroaromatic compound having a six-membered ring structure (e.g., a pyridine ring, a diazine ring (including a pyrimidine ring, a pyrazine ring, a pyridazine ring, or the like), a triazine ring, a bipyridine ring, or a terpyridine ring), and a heteroaromatic compound having a fused ring structure including a six-membered ring structure as a part (e.g., a quinoline ring, a benzoquinoline ring, a quinoxaline ring, a dibenzoquinoxaline ring, or a phenanthroline ring). Since the materials are specifically described above, description thereof is omitted here.

As a metal used for the above mixed material, a transition metal that belongs to Group 5, Group 7, Group 9, or Group 11 or a material that belongs to Group 13 in the periodic table is preferably used, and examples include Ag, Cu, Al, and In. Here, the organic compound forms a singly occupied molecular orbital (SOMO) with the transition metal.

For example, in the case where light emitted from the light-emitting layer 113b is amplified in the light-emitting device illustrated in FIG. 1D, the optical path length between the second electrode 102 and the light-emitting layer 113b is preferably less than one fourth of the wavelength k of light emitted from the light-emitting layer 113b. In this case, the optical path length can be adjusted by changing the thickness of the electron-transport layer 114b or the electron-injection layer 115b.

### <Charge-Generation Layer>

The charge-generation layer has a function of injecting electrons into one of the EL layers and injecting holes into the other of the EL layers when a voltage is applied between the first electrode and the second electrode of the light-emitting device having a tandem structure. The charge-generation layer may be either a p-type layer in which an electron acceptor (acceptor) is added to a hole-transport material or an electron-injection buffer layer in which an electron donor (donor) is added to an electron-transport material. Alternatively, both of these layers may be stacked. Furthermore, an electron-relay layer may be provided between the p-type layer and the electron-injection buffer layer. Note that forming the charge-generation layer with the use of any of the above materials can inhibit an increase in driving voltage caused by the stack of the EL layers.

In the case where the charge-generation layer is a p-type layer in which an electron acceptor is added to a hole-transport material, which is an organic compound, any of the materials described in this embodiment can be used as the hole-transport material. Further, F₄-TCNQ, chloranil, and the like can be given as examples of the electron acceptor. Other examples include oxides of metals that belong to Group 4 to Group 8 of the periodic table. Specific examples include vanadium oxide, niobium oxide, tantalum oxide, chromium oxide, molybdenum oxide, tungsten oxide, manganese oxide, and rhenium oxide. Any of the above-described acceptor materials may be used. Furthermore, a mixed film obtained by mixing materials of a p-type layer or a stack of films containing the respective materials may be used.

In the case where the charge-generation layer is an electron-injection buffer layer in which an electron donor is added to an electron-transport material, any of the materials described in this embodiment can be used as the electron-transport material. As the electron donor, it is possible to use an alkali metal, an alkaline earth metal, a rare earth metal, a metal belonging to Group 2 or Group 13 of the periodic table, or an oxide or a carbonate thereof. Specifically, Li, Cs, Mg, calcium (Ca), Yb, indium (In), lithium oxide (Li₂O), cesium carbonate, or the like is preferably used. An organic compound such as tetrathianaphthacene may be used as the electron donor.

When an electron-relay layer is provided between a p-type layer and an electron-injection buffer layer in the charge-generation layer, the electron-relay layer contains at least a substance having an electron-transport property and has a function of preventing an interaction between the electron-injection buffer layer and the p-type layer and transferring electrons smoothly. The LUMO level of the substance having an electron-transport property in the electron-relay layer is preferably between the LUMO level of the acceptor substance in the p-type layer and the LUMO level of the substance having an electron-transport property in the electron-transport layer in contact with the charge-generation layer. Specifically, the LUMO level of the substance having an electron-transport property in the electron-relay layer is preferably higher than or equal to −5.0 eV, further preferably higher than or equal to −5.0 eV and lower than or equal to −3.0 eV. Note that as the substance having an electron-transport property in the electron-relay layer, a phthalocyanine-based material or a metal complex having a metal-oxygen bond and an aromatic ligand is preferably used.

### <Cap Layer>

Although not illustrated in FIGS. 1A to 1E, a cap layer may be provided over the second electrode 102 of the light-emitting device. For example, a material with a high refractive index can be used for the cap layer. When the cap layer is provided over the second electrode 102, extraction efficiency of light emitted from the second electrode 102 can be improved.

Specific examples of a material that can be used for the cap layer are 5,5′-diphenyl-2,2′-di-5H-[1]benzothieno[3,2-c]carbazole (abbreviation: BisBTc) and DBT3P-II. In addition, the organic compound described in Embodiment 1 can be used.

### <Substrate>

The light-emitting device described in this embodiment can be formed over a variety of substrates. Note that the type of substrate is not limited to a certain type. Examples of the substrate include semiconductor substrates (e.g., a single crystal substrate and a silicon substrate), an SOI substrate, a glass substrate, a quartz substrate, a plastic substrate, a metal substrate, a stainless steel substrate, a substrate including stainless steel foil, a tungsten substrate, a substrate including tungsten foil, a flexible substrate, an attachment film, paper including a fibrous material, and a base material film.

Examples of the glass substrate include a barium borosilicate glass substrate, an aluminoborosilicate glass substrate, and a soda lime glass substrate. Examples of the flexible substrate, the attachment film, and the base material film include plastics typified by polyethylene terephthalate (PET), polyethylene naphthalate (PEN), and polyether sulfone (PES), a synthetic resin such as acrylic resin, polypropylene, polyester, polyvinyl fluoride, polyvinyl chloride, polyamide, polyimide, aramid, an epoxy resin, an inorganic vapor deposition film, and paper.

For manufacturing of the light-emitting device of this embodiment, a gas phase method such as an evaporation method or a liquid phase method such as a spin coating method or an ink-jet method can be used. When an evaporation method is used, a physical vapor deposition method (PVD method) such as a sputtering method, an ion plating method, an ion beam evaporation method, a molecular beam evaporation method, or a vacuum evaporation method, a chemical vapor deposition method (CVD method), or the like can be used. Specifically, the layers having various functions (the hole-injection layer 111, the hole-transport layer 112, the light-emitting layer 113, the electron-transport layer 114, and the electron-injection layer 115) included in the EL layers of the light-emitting device can be formed by an evaporation method (e.g., a vacuum evaporation method), a coating method (e.g., a dip coating method, a die coating method, a bar coating method, a spin coating method, or a spray coating method), a printing method (e.g., an ink-jet method, screen printing (stencil), offset printing (planography), flexography (relief printing), gravure printing, or micro-contact printing), or the like.

In the case where a film formation method such as the coating method or the printing method is employed, a high molecular compound (e.g., an oligomer, a dendrimer, or a polymer), a middle molecular compound (a compound between a low molecular compound and a high molecular compound with a molecular weight of 400 to 4000), an inorganic compound (e.g., a quantum dot material), or the like can be used. The quantum dot material can be a colloidal quantum dot material, an alloyed quantum dot material, a core-shell quantum dot material, a core quantum dot material, or the like.

Materials that can be used for the layers (the hole-injection layer 111, the hole-transport layer 112, the light-emitting layer 113, the electron-transport layer 114, and the electron-injection layer 115) included in the EL layer 103 of the light-emitting device described in this embodiment are not limited to the materials described in this embodiment, and other materials can be used in combination as long as the functions of the layers are fulfilled.

Note that in this specification and the like, the terms “layer” and “film” can be interchanged with each other as appropriate.

The structures described in this embodiment can be used in combination with any of the structures described in the other embodiments as appropriate.

### Embodiment 3

This embodiment will describe a light-emitting and light-receiving apparatus 700 as a specific example of a light-emitting apparatus of one embodiment of the present invention and an example of the manufacturing method. Note that the light-emitting and light-receiving apparatus 700 includes both a light-emitting device and a light-receiving device, and can also be referred to as a light-emitting apparatus including a light-receiving device or a light-receiving apparatus including a light-emitting device. In addition, the light-emitting and light-receiving apparatus 700 can be used for a display portion of an electronic device or the like, and thus can also be referred to as a display panel or a display apparatus.

### Structure Example of Light-Emitting and Light-Receiving Apparatus 700

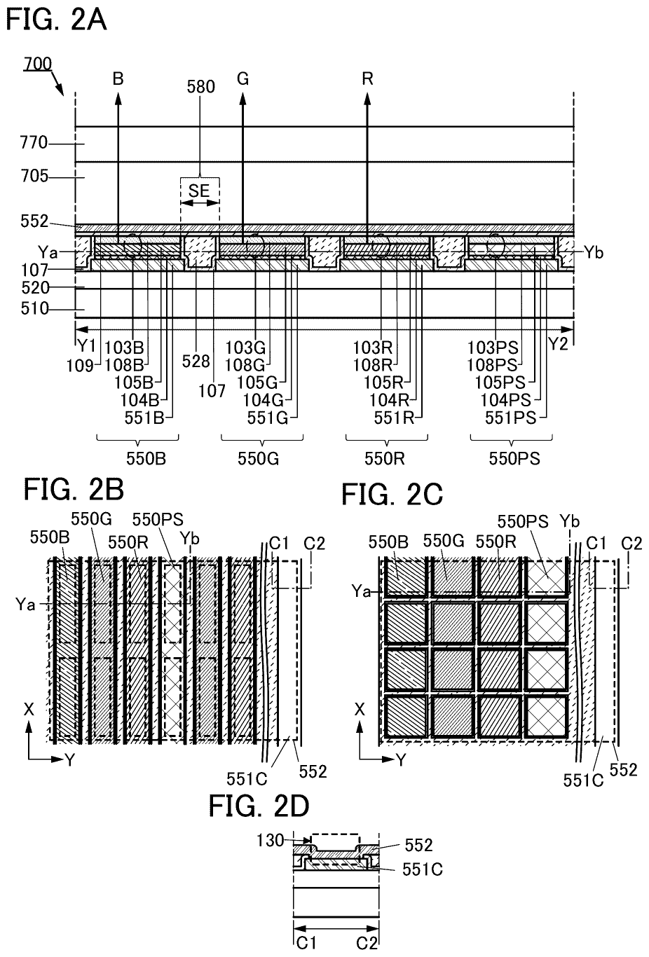

The light-emitting and light-receiving apparatus 700 illustrated in FIG. 2A includes a light-emitting device 550B, a light-emitting device 550G, a light-emitting device 550R, and a light-receiving device 550PS that are formed over a functional layer 520 over a first substrate 510. The functional layer 520 includes, for example, driver circuits such as a gate driver and a source driver that are composed of a plurality of transistors, and wirings that electrically connect these circuits. Note that these driver circuits are electrically connected to the light-emitting device 550B, the light-emitting device 550G, the light-emitting device 550R, and the light-receiving device 550PS, for example, to drive them. The light-emitting and light-receiving apparatus 700 includes an insulating layer 705 over the functional layer 520 and the devices (the light-emitting devices and the light-receiving device), and the insulating layer 705 has a function of attaching a second substrate 770 and the functional layer 520.

The light-emitting devices 550B, 550G, and 550R each have the device structure described in Embodiment 2. In addition, the structure of the EL layer 103 (see FIG. 1A) differs between the light-emitting devices; for example, a light-emitting layer 105B of an EL layer 103B can emit blue light, a light-emitting layer 105G of an EL layer 103G can emit green light, and a light-emitting layer 105R of an EL layer 103R can emit red light.

Note that although in this embodiment, the case where the devices (a plurality of light-emitting devices and a light-receiving device) are formed separately is described, part of an EL layer of a light-emitting device (a hole-injection layer, a hole-transport layer, or an electron-transport layer) and part of an active layer of a light-receiving device (the hole-injection layer, the hole-transport layer, and the electron-transport layer) may be formed using the same material at the same time in the manufacturing process. The detailed description will be made in Embodiment 8.

In this specification and the like, a structure where light-emitting layers in light-emitting devices of different colors (for example, blue (B), green (G), and red (R)) and a light-receiving layer in a light-receiving device are separately formed or separately patterned is sometimes referred to as a side-by-side (SBS) structure. Although the light-emitting device 550B, the light-emitting device 550G, the light-emitting device 550R, and the light-receiving device 550PS are arranged in this order in the light-emitting and light-receiving apparatus 700 illustrated in FIG. 2A, one embodiment of the present invention is not limited to this structure.

In FIG. 2A, the light-emitting device 550B includes an electrode 551B, an electrode 552, and the EL layer 103B interposed between the electrode 551B and the electrode 552. The light-emitting device 550G includes an electrode 551G, the electrode 552, and the EL layer 103G interposed between the electrode 551G and the electrode 552. The light-emitting device 550R includes an electrode 551R, the electrode 552, and the EL layer 103R interposed between the electrode 551R and the electrode 552. The EL layers (103B, 103G, and 103R) each have a stacked-layer structure of layers having different functions including their respective light-emitting layers (105B, 105G, and 105R). Note that a specific structure of each layer of the light-emitting device is as described in Embodiment 2.

In FIG. 2A, the light-receiving device 550PS includes an electrode 551PS, the electrode 552, and a light-receiving layer 103PS interposed between the electrode 551PS and the electrode 552. The light-receiving layer 103PS has a stacked-layer structure of layers having different functions including an active layer 105PS. Note that a specific structure of each layer of the light-receiving device is as described in Embodiment 8.

FIG. 2A illustrates a case where the EL layer 103B includes a hole-injection/transport layer 104B, the light-emitting layer 105B, an electron-transport layer 108B, and an electron-injection layer 109; the EL layer 103G includes a hole-injection/transport layer 104G, the light-emitting layer 105G, an electron-transport layer 108G, and the electron-injection layer 109; the EL layer 103R includes a hole-injection/transport layer 104R, the light-emitting layer 105R, an electron-transport layer 108R, and the electron-injection layer 109; and the light-receiving layer 103PS includes a hole-injection/transport layer 104PS, the active layer 105PS, a second transport layer 108PS, and the electron-injection layer 109. However, the present invention is not limited thereto.

In FIG. 2A, the electron-injection layer 109 and the electrode 552 are layers (common layers) shared by the devices (the light-emitting device 550B, the light-emitting device 550G, the light-emitting device 550R, and the light-receiving device 550PS).

Hereinafter, for simplicity, the light-emitting device 550B, the light-emitting device 550G, and the light-emitting device 550R are collectively referred to as a light-emitting device 550; the electrode 551B, the electrode 551G, and the electrode 551R are collectively referred to as an electrode 551; the EL layer 103B, the EL layer 103G, and the EL layer 103R are collectively referred to as an EL layer 103; the hole-injection/transport layer 104B, the hole-injection/transport layer 104G, and the hole-injection/transport layer 104R are collectively referred to as a hole-injection/transport layer 104; the light-emitting layer 105B, the light-emitting layer 105G, and the light-emitting layer 105R are collectively referred to as a light-emitting layer 105; and the electron-transport layer 108B, the electron-transport layer 108G, and the electron-transport layer 108R are collectively referred to as an electron-transport layer 108, in some cases.

As illustrated in FIG. 2A, an insulating layer 107 may be formed on side surfaces (or end portions) of the hole-injection/transport layer 104, the light-emitting layer 105, and the electron-transport layer 108 included in the EL layer 103, and side surfaces (or end portions) of the hole-injection/transport layer 104PS, the active layer 105PS, and the electron-transport layer 108PS included in the light-receiving layer 103PS. The insulating layer 107 is formed in contact with the side surfaces (or the end portions) of the EL layer 103 and the light-receiving layer 103PS. This can inhibit entry of oxygen, moisture, or constituent elements thereof into the inside through the side surfaces of the EL layer 103 and the light-receiving layer 103PS. Note that the insulating layer 107 continuously covers the side surfaces (or the end portions) of part of the EL layer 103 and part of the light-receiving layer 103PS of adjacent devices. For example, in FIG. 2A, the side surfaces of parts of the EL layer 103B of the light-emitting device 550B and the EL layer 103G of the light-emitting device 550G are covered with the continuous insulating layer 107.

As illustrated in FIG. 2A, a partition 528 is provided between the devices. Note that the electron-injection layer 109 and the electrode 552 that are common layers shared by the devices are provided continuously without being divided by the partition 528. Thus, it can be said that the partition 528 is provided in a region surrounded by the electron-injection layer 109 and the insulating layer 107. In addition, the partitions 528 are positioned along side surfaces (or end portions) of the electrode 551, part of the EL layer 103 (the hole-injection/transport layer 104, the light-emitting layer 105, and the electron-transport layer 108), and part of the light-receiving layer 103PS (the hole-injection/transport layer 104, the active layer 105PS, and the electron-transport layer 108) with the insulating layer 107 therebetween.

In each of the EL layer 103 and the light-receiving layer 103PS, particularly the hole-injection layer, which is included in the hole-transport region between the anode and the light-emitting layer and between the anode and the active layer, often has high conductivity; thus, a hole-injection layer formed as a layer shared by adjacent devices might cause crosstalk. Thus, as described in this structure example, part of the EL layer 103 (the hole-injection/transport layer 104, the light-emitting layer 105, and the electron-transport layer 108) and part of the light-receiving layer 103PS (the hole-injection/transport layer 104, the active layer 105PS, and the electron-transport layer 108) are separated, and the insulating layer 107 and the partition 528 are provided therebetween, so that crosstalk between adjacent devices can be inhibited.

Providing the partition 528 can flatten the surface by reducing a depressed portion formed between adjacent devices. When the depressed portion is reduced, disconnection of the electron-injection layer 109 and the electrode 552 formed over the EL layer 103 and the light-receiving layer 103PS can be inhibited.

For the insulating layer 107, aluminum oxide, magnesium oxide, hafnium oxide, gallium oxide, indium gallium zinc oxide, silicon nitride, or silicon nitride oxide can be used, for example. Some of the above-described materials may be stacked to form the insulating layer 107. The insulating layer 107 can be formed by a sputtering method, a CVD method, an MBE method, a PLD method, an ALD method, or the like and is formed preferably by an ALD method, which achieves favorable coverage.

Examples of an insulating material used to form the partition wall 528 include organic materials such as an acrylic resin, a polyimide resin, an epoxy resin, an imide resin, a polyamide resin, a polyimide-amide resin, a silicone resin, a siloxane resin, a benzocyclobutene-based resin, a phenol resin, and precursors of these resins. Other examples include organic materials such as polyvinyl alcohol (PVA), polyvinyl butyral, polyvinyl pyrrolidone, polyethylene glycol, polyglycerin, pullulan, water-soluble cellulose, and alcohol-soluble polyamide resin. A photosensitive resin such as a photoresist can also be used. Examples of the photosensitive resin include positive-type materials and negative-type materials.

With the use of the photosensitive resin, the partition wall 528 can be fabricated by only light exposure and developing steps. The partition wall 528 may be fabricated using a negative photosensitive resin (e.g., a resist material). In the case where an insulating layer containing an organic material is used as the partition wall 528, a material absorbing visible light is suitably used. When such a material absorbing visible light is used for the partition wall 528, light emission from the EL layer can be absorbed by the partition wall 528, leading to a reduction in light leakage (stray light) to an adjacent EL layer or light-receiving layer. Thus, a light-emitting and light-receiving apparatus having high display quality can be provided.

For example, the difference between the top-surface level of the partition wall 528 and the top-surface level of the EL layer 103 or the light-receiving layer 103PS is preferably 0.5 times or less, further preferably 0.3 times or less the thickness of the partition wall 528. The partition wall 528 may be provided such that the top-surface level of the EL layer 103 or the light-receiving layer 103PS is higher than the top-surface level of the partition wall 528, for example. Alternatively, the partition wall 528 may be provided such that the top-surface level of the partition wall 528 is higher than the top-surface level of the light-emitting layer of the EL layer 103 or the active layer of the light-receiving layer 103PS, for example.

When crosstalk occurs between devices in a light-emitting and light-receiving apparatus with a high resolution exceeding 1000 ppi, a color gamut that the light-emitting and light-receiving apparatus can reproduce is narrowed. In a light-emitting and light-receiving apparatus with a high resolution of 1000 ppi or more, preferably 2000 ppi or more, further preferably 5000 ppi or more, the insulating layer 107 and the partition 528 are provided between part of the EL layer 103 (the hole-injection/transport layer 104, the light-emitting layer 105B, and the electron-transport layer 108) and part of the light-receiving layer 103PS (the hole-injection/transport layer 104, the active layer 105PS, and the electron-transport layer 108), whereby the light-emitting and light-receiving apparatus can display bright colors.

FIGS. 2B and 2C are each a schematic top view of the light-emitting and light-receiving apparatus 700 taken along the dashed-dotted line Ya-Yb in the cross-sectional view of FIG. 2A. That is, the devices are arranged in a matrix. Note that FIG. 2B illustrates what is called a stripe arrangement, in which the light-emitting devices of the same color or the light-receiving devices are arranged in the X-direction. FIG. 2C illustrates a structure where the light-emitting devices of the same color or the light-receiving devices are arranged in the X-direction and separated by patterning for each pixel. Note that the arrangement method of the light-emitting devices is not limited thereto; another method such as a delta, zigzag, PenTile, or diamond arrangement can also be used.

Note that part of the EL layer 103 (the hole-injection/transport layer 104, the light-emitting layer 105, and the electron-transport layer 108) and part of the light-receiving layer 103PS (the hole-injection/transport layer 104, the active layer 105PS, and the electron-transport layer 108) are processed by patterning using a lithography method for separation, so that a light-emitting and light-receiving apparatus (display panel) with a high resolution can be manufactured. End portions (side surfaces) of the layers of the EL layer 103 and the layers of the light-receiving layer 103PS processed by patterning using a photolithography method have substantially one surface (or are positioned on substantially the same plane). In this case, the widths (SE) of spaces 580 between the EL layers and between the EL layer and the light-receiving layer are each preferably 5 μm or less, further preferably 1 μm or less.

FIG. 2D is a schematic cross-sectional view taken along the dashed-dotted line C1-C2 in FIGS. 2B and 2C. FIG. 2D illustrates a connection portion 130 where a connection electrode 551C and the electrode 552 are electrically connected to each other. In the connection portion 130, the electrode 552 is provided over and in contact with the connection electrode 551C. The partition wall 528 is provided to cover an end portion of the connection electrode 551C.

### Manufacturing Method Example of Light-Emitting and Light-Receiving Apparatus

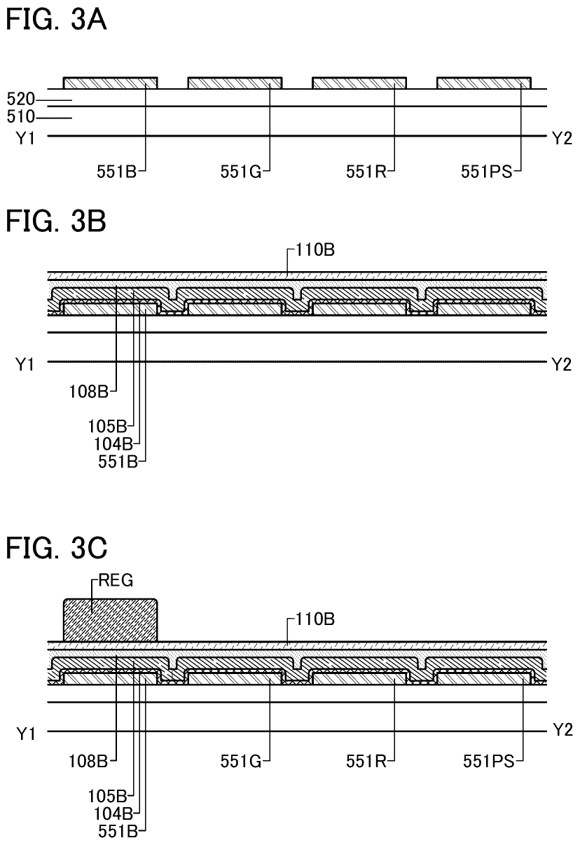

The electrode 551B, the electrode 551G, the electrode 551R, and the electrode 551PS are formed as illustrated in FIG. 3A. For example, a conductive film is formed over the functional layer 520 over the first substrate 510 and processed into predetermined shapes by a photolithography method.

The conductive film can be formed by any of a sputtering method, a chemical vapor deposition (CVD) method, a molecular beam epitaxy (MBE) method, a vacuum evaporation method, a pulsed laser deposition (PLD) method, an atomic layer deposition (ALD) method, and the like. Examples of the CVD method include a plasma-enhanced chemical vapor deposition (PECVD) method and a thermal CVD method. An example of a thermal CVD method is a metal organic CVD (MOCVD) method.

The conductive film may be processed by a nanoimprinting method, a sandblasting method, a lift-off method, or the like as well as a photolithography method described above. Alternatively, island-shaped thin films may be directly formed by a deposition method using a shielding mask such as a metal mask.

There are two typical examples of photolithography methods. In one of the methods, a resist mask is formed over a thin film that is to be processed, the thin film is processed by etching or the like, and then the resist mask is removed. In the other method, a photosensitive thin film is formed and then processed into a desired shape by light exposure and development. The former method involves heat treatment steps such as pre-applied bake (PAB) after resist application and post-exposure bake (PEB) after light exposure. In one embodiment of the present invention, a lithography method is used not only for processing of a conductive film but also for processing of a thin film used for formation of an EL layer (a film made of an organic compound or a film partly including an organic compound).

As light for exposure in a photolithography method, it is possible to use light with the i-line (wavelength: 365 nm), light with the g-line (wavelength: 436 nm), light with the h-line (wavelength: 405 nm), or light in which the i-line, the g-line, and the h-line are mixed. Alternatively, ultraviolet light, KrF laser light, ArF laser light, or the like can be used. Exposure may be performed by liquid immersion exposure technique. As the light for exposure, extreme ultraviolet (EUV) light or X-rays may also be used. Instead of the light for exposure, an electron beam can be used. It is preferable to use EUV, X-rays, or an electron beam because extremely minute processing can be performed. Note that a photomask is not needed when light exposure is performed by scanning with a beam such as an electron beam.

For etching of a thin film using a resist mask, a dry etching method, a wet etching method, a sandblast method, or the like can be used.

Subsequently, as illustrated in FIG. 3B, the hole-injection/transport layer 104B, the light-emitting layer 105B, and the electron-transport layer 108B are formed over the electrode 551i, the electrode 551G, the electrode 551R, and the electrode 551PS. Note that the hole-injection/transport layer 104B, the light-emitting layer 105B, and the electron-transport layer 108B can be formed using a vacuum evaporation method, for example. Furthermore, a sacrificial layer 110B is formed over the electron-transport layer 108B. For the formation of the hole-injection/transport layer 104B, the light-emitting layer 105B, and the electron-transport layer 108B, any of the materials described in Embodiments 1 and 2 can be used.

For the sacrificial layer 110B, it is preferable to use a film highly resistant to etching treatment performed on the hole-injection/transport layer 104B, the light-emitting layer 105B, and the electron-transport layer 108B, i.e., a film having high etching selectivity with respective to the hole-injection/transport layer 104B, the light-emitting layer 105B, and the electron-transport layer 108B. The sacrificial layer 110B preferably has a stacked-layer structure of a first sacrificial layer and a second sacrificial layer which have different etching selectivities. For the sacrificial layer 110B, it is possible to use a film that can be removed by a wet etching method, which causes less damage to the EL layer 103B. In wet etching, oxalic acid or the like can be used as an etching material. Note that in this specification and the like, a sacrificial layer may be called a mask layer.

For the sacrificial layer 110B, an inorganic film such as a metal film, an alloy film, a metal oxide film, a semiconductor film, or an inorganic insulating film can be used, for example. The sacrificial layer 110B can be formed by any of a variety of deposition methods such as a sputtering method, an evaporation method, a CVD method, and an ALD method.

For the sacrificial layer 110B, a metal material such as gold, silver, platinum, magnesium, nickel, tungsten, chromium, molybdenum, iron, cobalt, copper, palladium, titanium, aluminum, yttrium, zirconium, or tantalum or an alloy material containing the metal material can be used, for example. It is particularly preferable to use a low-melting-point material such as aluminum or silver.

A metal oxide such as indium gallium zinc oxide (also referred to as In—Ga—Zn oxide or IGZO) can be used for the sacrificial layer 110B. It is also possible to use indium oxide, indium zinc oxide (In—Zn oxide), indium tin oxide (In—Sn oxide), indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or the like. Alternatively, indium tin oxide containing silicon can also be used, for example.

An element M (M is one or more of aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used instead of gallium. In particular, M is preferably one or more of gallium, aluminum, and yttrium.

For the sacrificial layer 110B, an inorganic insulating material such as aluminum oxide, hafnium oxide, or silicon oxide can be used.

The sacrificial layer 110B is preferably formed using a material that can be dissolved in a solvent chemically stable with respect to at least the electron-transport layer 108B that is in the uppermost position. Specifically, a material that can be dissolved in water or alcohol can be suitably used for the sacrificial layer 110B. In formation of the sacrificial layer 110B, it is preferable that application of such a material dissolved in a solvent such as water or alcohol be performed by a wet process and followed by heat treatment for evaporating the solvent. At this time, the heat treatment is preferably performed under a reduced-pressure atmosphere, in which case the solvent can be removed at a low temperature in a short time and thermal damage to the hole-injection/transport layer 104B, the light-emitting layer 105B, and the electron-transport layer 108B can be accordingly reduced.

In the case where the sacrificial layer 110B having a stacked-layer structure is formed, the stacked-layer structure can include the first sacrificial layer formed using any of the above-described materials and the second sacrificial layer thereover.

The second sacrificial layer in that case is a film used as a hard mask for etching of the first sacrificial layer. In processing the second sacrificial layer, the first sacrificial layer is exposed. Thus, the combination of films having high etching selectivity therebetween is selected for the first sacrificial layer and the second sacrificial layer. Thus, a film that can be used for the second sacrificial layer can be selected in accordance with the etching conditions of the first sacrificial layer and those of the second sacrificial layer.

For example, in the case where the second sacrificial layer is etched by dry etching involving a fluorine-containing gas (also referred to as a fluorine-based gas), the second sacrificial layer can be formed using silicon, silicon nitride, silicon oxide, tungsten, titanium, molybdenum, tantalum, tantalum nitride, an alloy containing molybdenum and niobium, an alloy containing molybdenum and tungsten, or the like. Here, a film of a metal oxide such as IGZO or ITO can be given as an example of a film having a high etching selectivity to the second sacrificial layer (i.e., a film with a low etching rate) in the dry etching involving the fluorine-based gas, and can be used for the first sacrificial layer.

Note that the material for the second sacrificial layer is not limited to the above and can be selected from a variety of materials in accordance with the etching conditions of the first sacrificial layer and those of the second sacrificial layer. For example, any of the films that can be used for the first sacrificial layer can be used for the second sacrificial layer.

For the second sacrificial layer, a nitride film can be used, for example. Specifically, it is possible to use a nitride such as silicon nitride, aluminum nitride, hafnium nitride, titanium nitride, tantalum nitride, tungsten nitride, gallium nitride, or germanium nitride.

Alternatively, an oxide film can be used for the second sacrificial layer. Typically, it is possible to use a film of an oxide or an oxynitride such as silicon oxide, silicon oxynitride, aluminum oxide, aluminum oxynitride, hafnium oxide, or hafnium oxynitride.

Next, as illustrated in FIG. 3C, a resist is applied onto the sacrificial layer 110B, and the resist having a desired shape (a resist mask REG) is formed by a photolithography method. Such a method involves heat treatment steps such as pre-applied bake (PAB) after the resist application and post-exposure bake (PEB) after light exposure. The temperature reaches approximately 100° C. during the PAB, and approximately 120° C. during the PEB, for example. Therefore, the light-emitting device should be resistant to such high treatment temperatures.

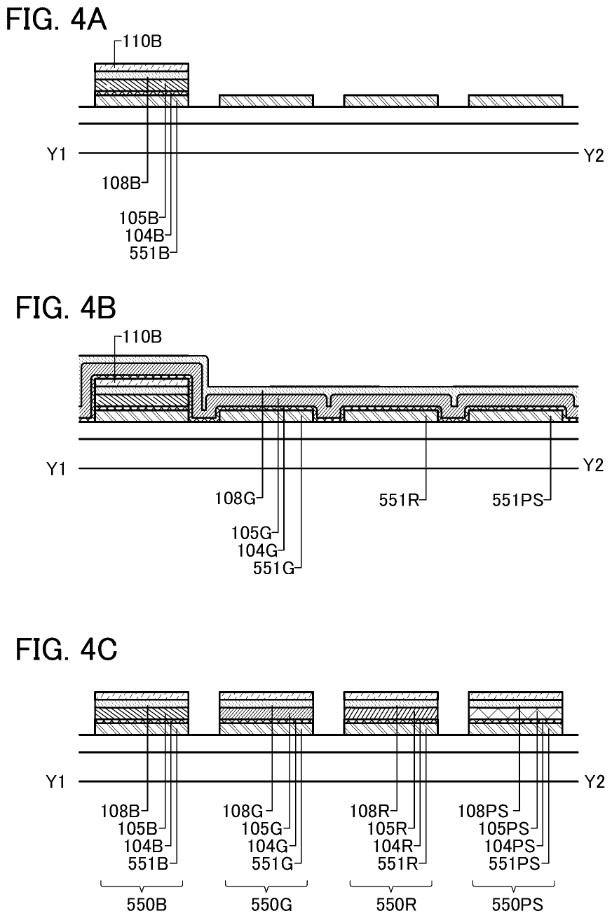

Next, part of the sacrificial layer 110B that is not covered with the resist mask REG is removed by etching using the resist mask REG, the resist mask REG is removed, and then the hole-injection/transport layer 104B, the light-emitting layer 105B, and the electron-transport layer 108B that are not covered with the sacrificial layer 110B are removed by etching, so that the hole-injection/transport layer 104B, the light-emitting layer 105B, and the electron-transport layer 108B are processed to have side surfaces (or have their side surfaces exposed) over the electrode 551B or have belt-like shapes extending in the direction intersecting the sheet of the diagram. Note that dry etching is preferably employed for the etching. Note that in the case where the sacrificial layer 110B has the aforementioned stacked-layer structure of the first sacrificial layer and the second sacrificial layer, the hole-injection/transport layer 104B, the light-emitting layer 105B, and the electron-transport layer 108B may be processed into a predetermined shape in the following manner: part of the second sacrificial layer is etched using the resist mask REG, the resist mask REG is then removed, and part of the first sacrificial layer is etched using the second sacrificial layer as a mask. The structure illustrated in FIG. 4A is obtained through these etching steps.

Subsequently, as illustrated in FIG. 4B, the hole-injection/transport layer 104G, the light-emitting layer 105G, and the electron-transport layer 108G are formed over the sacrificial layer 110B, the electrode 551G, the electrode 551R, and the electrode 551PS. The hole-injection/transport layer 104G, the light-emitting layer 105G, and the electron-transport layer 108G can be formed using any of the materials described in Embodiments 1 and 2. Note that the hole-injection/transport layer 104G, the light-emitting layer 105G, and the electron-transport layer 108G can be formed by a vacuum evaporation method, for example.

Hereinafter, in a manner similar to formation of the hole-injection/transport layer 104B, the light-emitting layer 105B, the electron-transport layer 108B, and the sacrificial layer 110B, the hole-injection/transport layer 104G, the light-emitting layer 105G, the electron-transport layer 108G, and a sacrificial layer 110G are formed over the electrode 551G, the hole-injection/transport layer 104R, the light-emitting layer 105R, the electron-transport layer 108R, and a sacrificial layer 110R are formed over the electrode 551R, and the hole-injection/transport layer 104PS, the active layer 105PS, the electron-transport layer 108PS, and a sacrificial layer 110PS are formed over the electrode 551PS, whereby the shape illustrated in FIG. 4C is obtained.

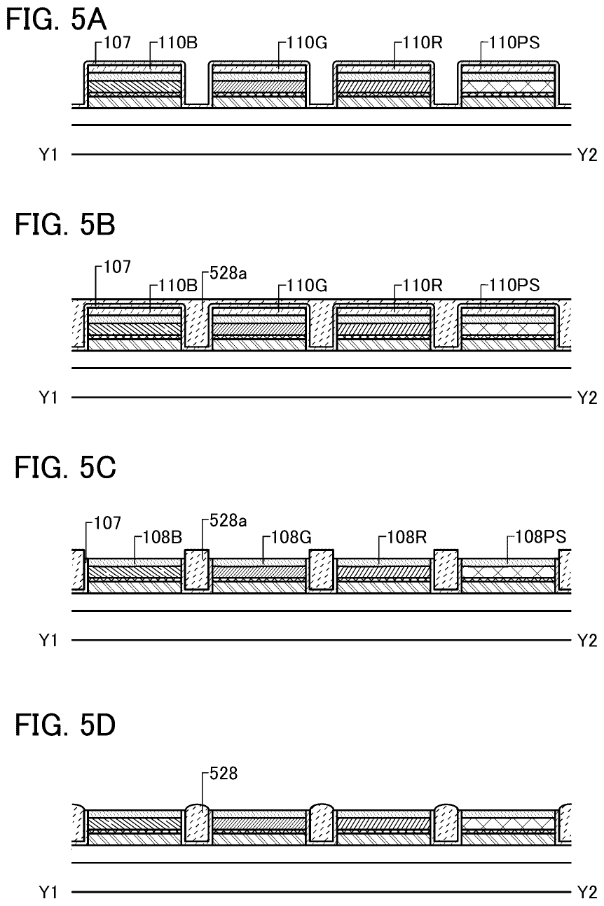

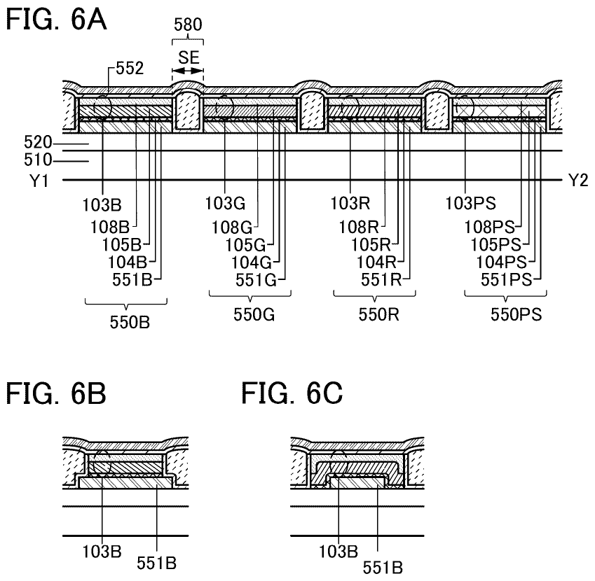

Next, as illustrated in FIG. 5A, the insulating layer 107 is formed over the sacrificial layers 110B, 110G, 110R, and 110PS.

Note that the insulating layer 107 can be formed by an ALD method, for example. In this case, as illustrated in FIG. 5A, the insulating layer 107 is formed to be in contact with the side surfaces (end portions) of the hole-injection/transport layers (104B, 104G, 104R, and 104PS), the light-emitting layers (103R, 103G, and 103R), the active layer 105PS, and the electron-transport layers (108B, 108G, 108R, and 108PS) of the devices. This can inhibit entry of oxygen, moisture, or constituent elements thereof into the inside through the side surfaces of the layers.

Next, as illustrated in FIG. 5B, a resin film 528a is formed over the insulating layer 107. As the resin film 528a, for example, a negative photosensitive resin or a positive photosensitive resin can be used.

Then, as illustrated in FIG. 5C, part of the resin film 528a, part of the insulating layer 107, and the sacrificial layers (110B, 110G, 110R, and 110PS) are removed to expose the top surfaces of the electron-transport layers (108B, 108G, 108R, and 108PS).

Next, heat treatment is performed to process an upper edge portion of the resin film 528a into a curved shape, so that the partition 528 is formed, as illustrated in FIG. 5D. When the upper edge portion of the partition 528 has a curved shape, the coverage with the electron-injection layer 109 to be formed later can be favorable. For example, in the case of using a positive photosensitive acrylic resin as a material for the resin film 528a, the partition 528 is preferably formed so as to have a curved surface with a curvature radius (0.2 μm to 3 μm) at the upper edge portion.

Next, the electron-injection layer 109 is formed over the insulating layer 107, the electron-transport layers (108B, 108G, 108R, and 108PS), and the partition 528. The electron-injection layer 109 can be formed using any of the materials described in Embodiment 2. The electron-injection layer 109 is formed by a vacuum evaporation method, for example.

Next, as illustrated in FIG. 6A, the electrode 552 is formed over the electron-injection layer 109. The electrode 552 is formed by a vacuum evaporation method, for example.

Through the above steps, the EL layer 103B, the EL layer 103G, the EL layer 103R, and the light-receiving layer 103PS in the light-emitting device 550B, the light-emitting device 550G, the light-emitting device 550R, and the light-receiving device 550PS can be processed to be separated from each other.

Note that pattern formation by a photolithography method is performed in separate processing of part of the EL layer 103 and the light-receiving layer 103PS, so that a light-emitting and light-receiving apparatus (display panel) with a high resolution can be manufactured. End portions (side surfaces) of the layers of the EL layer and the light-receiving layer processed by patterning using a photolithography method have substantially one surface (or are positioned on substantially the same plane). The pattern formation using a photolithography method can inhibit crosstalk between adjacent light-emitting devices and between the light-emitting device and the light-receiving device. In addition, the space 580 is provided between adjacent devices processed by patterning using a photolithography method. In FIG. 6C, when the space 580 is denoted by a distance SE between the EL layers of adjacent light-emitting devices, decreasing the distance SE can increase the aperture ratio and the resolution. By contrast, as the distance SE is increased, the effect of the difference in the fabrication process between the adjacent light-emitting devices becomes permissible, which leads to an increase in manufacturing yield. Since the light-emitting device fabricated according to this specification is suitable for a miniaturization process, the distance SE between the EL layers of adjacent light-emitting devices can be longer than or equal to 0.5 μm and shorter than or equal to 5 μm, preferably longer than or equal to 1 μm and shorter than or equal to 3 μm, further preferably longer than or equal to 1 μm and shorter than or equal to 2.5 μm, and still further preferably longer than or equal to 1 μm and shorter than or equal to 2 μm. Typically, the distance SE is preferably longer than or equal to 1 μm and shorter than or equal to 2 μm (e.g., 1.5 μm or a neighborhood thereof).

In this specification and the like, a device formed using a metal mask or a fine metal mask (FMM) is sometimes referred to as a device having a metal mask (MM) structure. In this specification and the like, a device formed without using a metal mask or an FMM is sometimes referred to as a device having a metal maskless (MML) structure. Since a light-emitting and light-receiving apparatus having the MML structure is formed without using a metal mask, the pixel arrangement, the pixel shape, and the like can be designed more flexibly than in a light-emitting and light-receiving apparatus having the FMM structure or the MM structure.

Note that the island-shaped EL layers of the light-emitting and light-receiving apparatus having the MML structure are formed by not patterning using a metal mask but processing after formation of an EL layer. Thus, a light-emitting and light-receiving apparatus with a higher resolution or a higher aperture ratio than a conventional one can be achieved. Moreover, EL layers can be formed separately for each color, which enables extremely clear images; thus, a light-emitting and light-receiving apparatus with a high contrast and high display quality can be achieved. Furthermore, provision of a sacrifice layer over an EL layer can reduce damage on the EL layer during the manufacturing process and increase the reliability of the light-emitting device.

In FIG. 2A and FIG. 6A, the width of the EL layer 103 is substantially equal to that of the electrode 551 in the light-emitting device 550, and the width of the light-receiving layer 103PS is substantially equal to that of the electrode 551PS in the light-receiving device 550PS; however, one embodiment of the present invention is not limited thereto.

In the light-emitting device 550, the width of the EL layer 103 may be smaller than that of the electrode 551. In the light-receiving device 550PS, the width of the light-receiving layer 103PS may be smaller than that of the electrode 551PS. FIG. 6B illustrates an example where the width of the EL layer 103B is smaller than that of the electrode 551B in the light-emitting device 550B.

In the light-emitting device 550, the width of the light-emitting layer 103 may be larger than that of the electrode 551. In the light-receiving device 550PS, the width of the light-receiving layer 103PS may be larger than that of the electrode 551PS. FIG. 6C illustrates an example where the width of the EL layer 103R is larger than that of the electrode 551R in the light-emitting device 550R.

The structures described in this embodiment can be used in combination with any of the structures described in the other embodiments as appropriate.

### Embodiment 4

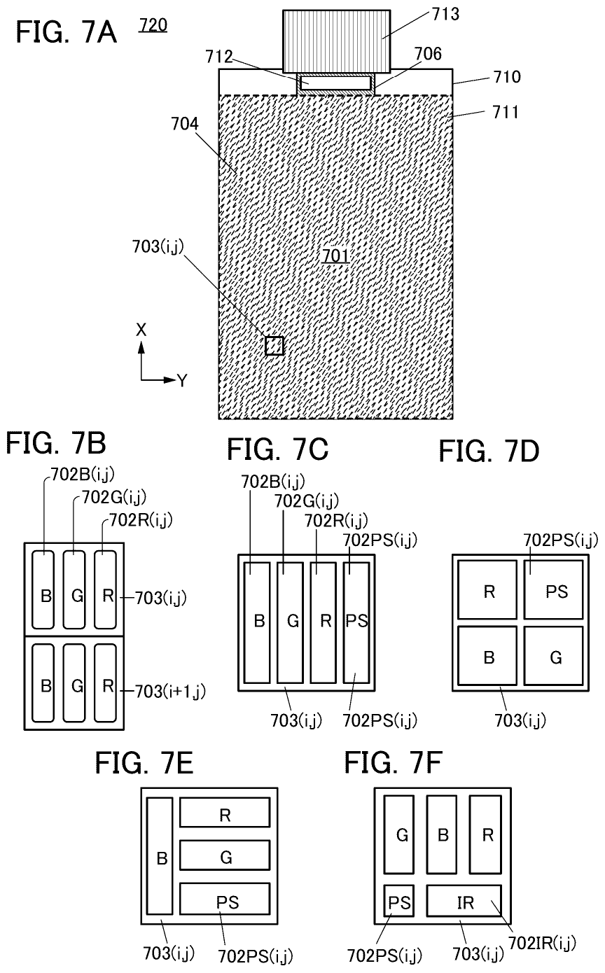

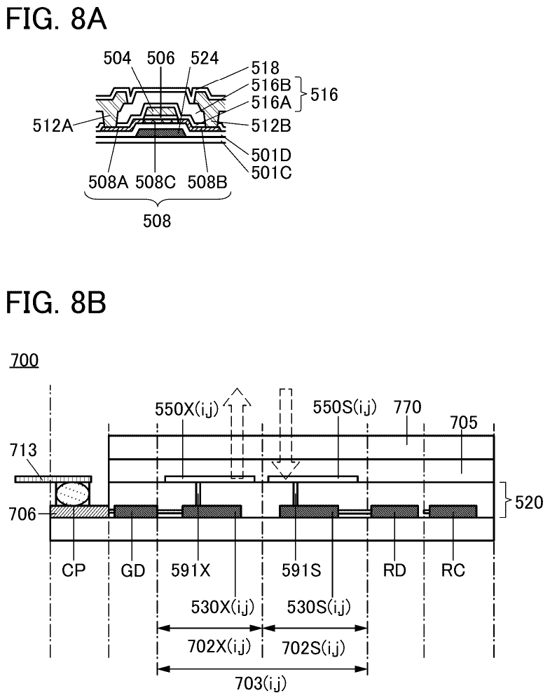

In this embodiment, an apparatus 720 is described with reference to FIGS. 7A to 7F and FIGS. 8A and 8B. The apparatus 720 illustrated in FIGS. 7A to 7F and FIGS. 8A and 8B includes any of the light-emitting devices described in Embodiments 1 and 2 and therefore is a light-emitting apparatus. Furthermore, the apparatus 720 can be used in a display portion of an electronic device or the like and therefore can also be referred to as a display panel or a display apparatus. Moreover, when the apparatus 720 includes the light-emitting device as a light source and a light-receiving device that can receive light from the light-emitting device, the apparatus 720 can be referred to as a light-emitting and light-receiving apparatus. Note that the light-emitting apparatus, the display panel, the display apparatus, and the light-emitting and light-receiving apparatus each include at least a light-emitting device.

Furthermore, the light-emitting apparatus, the display panel, the display apparatus, and the light-emitting and light-receiving apparatus of this embodiment can each have high definition or a large size. Therefore, the light-emitting apparatus, the display panel, the display apparatus, and the light-emitting and light-receiving apparatus of this embodiment can be used, for example, in display portions of electronic devices such as a digital camera, a digital video camera, a digital photo frame, a mobile phone, a portable game console, a smart phone, a wristwatch terminal, a tablet terminal, a portable information terminal, and an audio reproducing apparatus, in addition to display portions of electronic devices with a relatively large screen, such as a television device, a desktop or laptop personal computer, a monitor of a computer or the like, digital signage, and a large game machine such as a pachinko machine.

FIG. 7A is a top view of the apparatus 720.

In FIG. 7A, the apparatus 720 has a structure in which a substrate 710 and a substrate 711 are attached to each other. In addition, the apparatus 720 includes a display region 701, a circuit 704, a wiring 706, and the like. Note that the display region 701 includes a plurality of pixels. As illustrated in FIG. 7B, a pixel 703(i, j) illustrated in FIG. 7A and a pixel 703(i+1, j) are adjacent to each other.

Furthermore, in the example of the apparatus 720 illustrated in FIG. 7A, the substrate 710 is provided with an integrated circuit (IC) 712 by a chip on glass (COG) method, a chip on film (COF) method, or the like. As the IC 712, an IC including a scan line driver circuit, a signal line driver circuit, or the like can be used, for example. In the example illustrated in FIG. 7A, an IC including a signal line driver circuit is used as the IC 712, and a scan line driver circuit is used as the circuit 704.

The wiring 706 has a function of supplying signals and power to the display region 701 and the circuit 704. The signals and power are input to the wiring 706 from the outside through a flexible printed circuit (FPC) 713 or to the wiring 706 from the IC 712. Note that the apparatus 720 is not necessarily provided with the IC. The IC may be mounted on the FPC by a COF method or the like.

FIG. 7B illustrates the pixel 703(i, j) and the pixel 703(i+1, j) of the display region 701. A plurality of kinds of subpixels including light-emitting devices that emit light of different colors can be included in the pixel 703(i, j). Alternatively, a plurality of subpixels including light-emitting devices that emit light of the same color may be included in addition to the above-described subpixels. For example, three kinds of subpixels can be included. The three subpixels can be of three colors of red (R), green (G), and blue (B) or of three colors of yellow (Y), cyan (C), and magenta (M), for example. Alternatively, the pixel can include four kinds of subpixels. The four subpixels can be of four colors of R, G, B, and white (W) or of four colors of R, G, B, and Y, for example. Specifically, the pixel 703(i,j) can consist of a subpixel 702B(i,j) for blue display, a subpixel 702G(i, j) for green display, and a subpixel 702R(i, j) for red display.

Other than the subpixels including the light-emitting devices, a subpixel including a light-receiving device may also be provided. In the case where the subpixel includes a light-receiving device, the apparatus 720 is also referred to as a light-emitting and light-receiving apparatus.

FIGS. 7C to 7F illustrate various layout examples of the pixel 703(i, j) including a subpixel 702PS(i, j) including a light-receiving device. The pixel arrangement in FIG. 7C is stripe arrangement, and the pixel arrangement in FIG. 7D is matrix arrangement. The pixel arrangement in FIG. 7E has a structure where three subpixels (the subpixels R, G, and PS) are vertically arranged next to one subpixel (the subpixel B).

Furthermore, as illustrated in FIG. 7F, a subpixel 702IR(i, j) that emits infrared rays may be added to any of the above-described sets of subpixels in the pixel 703(i, j). In the pixel arrangement in FIG. 7F, the vertically oriented three subpixels G, B, and R are arranged laterally, and the subpixel PS and the horizontally oriented subpixel IR are arranged laterally below the three subpixels. Specifically, the subpixel 702IR(i, j) that emits light including light with a wavelength ranging from 650 nm to 1000 nm, inclusive, may be used in the pixel 703(i, j). Note that the wavelength of light detected by the subpixel 702PS(i, j) is not particularly limited; however, the light-receiving device included in the subpixel 702PS(i, j) preferably has sensitivity to light emitted by the light-emitting device included in the subpixel 702R(i, j), the subpixel 702G(i, j), the subpixel 702B(i, j), or the subpixel 702IR(i, j). For example, the light-receiving device preferably detects one or more kinds of light in blue, violet, bluish violet, green, yellowish green, yellow, orange, red, and infrared wavelength ranges, for example.

Note that the arrangement of subpixels is not limited to the structures illustrated in FIGS. 7B to 7F and a variety of arrangement methods can be employed. The arrangement of subpixels may be stripe arrangement, S stripe arrangement, matrix arrangement, delta arrangement, Bayer arrangement, or pentile arrangement, for example.

Furthermore, top surfaces of the subpixels may have a triangular shape, a quadrangular shape (including a rectangular shape and a square shape), a polygonal shape such as a pentagonal shape, a polygonal shape with rounded corners, an elliptical shape, or a circular shape, for example. The top surface shape of a subpixel herein refers to a top surface shape of a light-emitting region of a light-emitting device.

In the case where not only a light-emitting device but also a light-receiving device is included in a pixel, the pixel has a light-receiving function and thus can detect a contact or approach of an object while displaying an image. For example, an image can be displayed by using all the subpixels included in a light-emitting apparatus; or light can be emitted by some of the subpixels as a light source and an image can be displayed by using the remaining subpixels.

Note that the light-receiving area of the subpixel 702PS(i, j) is preferably smaller than the light-emitting areas of the other subpixels. A smaller light-receiving area leads to a narrower image-capturing range, inhibits a blur in a captured image, and improves the definition. Thus, by using the subpixel 702PS(i, j), high-resolution or high-definition image capturing is possible. For example, image capturing for personal authentication with the use of a fingerprint, a palm print, the iris, the shape of a blood vessel (including the shape of a vein and the shape of an artery), a face, or the like is possible by using the subpixel 702PS(i, j).

Moreover, the subpixel 702PS(i, j) can be used in a touch sensor (also referred to as a direct touch sensor), a near touch sensor (also referred to as a hover sensor, a hover touch sensor, a contactless sensor, or a touchless sensor), or the like. For example, the subpixel 702PS(i, j) preferably detects infrared light. Thus, touch sensing is possible even in a dark place.

Here, the touch sensor or the near touch sensor can detect an approach or contact of an object (e.g., a finger, a hand, or a pen). The touch sensor can detect the object when the light-emitting and light-receiving apparatus and the object come in direct contact with each other. Furthermore, the near touch sensor can detect the object even when the object is not in contact with the light-emitting and light-receiving apparatus. For example, the light-emitting and light-receiving apparatus can preferably detect the object when the distance between the light-emitting and light-receiving apparatus and the object is more than or equal to 0.1 mm and less than or equal to 300 mm, preferably more than or equal to 3 mm and less than or equal to 50 mm. With this structure, the light-emitting and light-receiving apparatus can be controlled without the object directly contacting with the light-emitting and light-receiving apparatus. In other words, the light-emitting and light-receiving apparatus can be controlled in a contactless (touchless) manner. With the above-described structure, the light-emitting and light-receiving apparatus can be controlled with a reduced risk of being dirty or damaged, or without direct contact between the object and a dirt (e.g., dust, bacteria, or a virus) attached to the light-emitting and light-receiving apparatus.

In the case where the subpixel 702PS(i, j) is used for high-resolution image capturing, the subpixel 702PS(i, j) is preferably provided in every pixel. Meanwhile, in the case where the subpixel 702PS(i, j) is used in a touch sensor, a near touch sensor, or the like, high accuracy is not required as compared to the case of capturing an image of a fingerprint or the like; accordingly, the subpixel 702PS(i, j) is provided in some subpixels. When the number of subpixels 702PS(i, j) is smaller than the number of subpixels 702R(i, j) or the like, higher detection speed can be achieved.

FIG. 8A illustrates an example of a specific structure of a transistor that can be used in the pixel circuit of the subpixel including the light-emitting device. As the transistor, a bottom-gate transistor, a top-gate transistor, or the like can be used as appropriate.

The transistor illustrated in FIG. 8A includes a semiconductor film 508, a conductive film 504, an insulating film 506, a conductive film 512A, and a conductive film 512B. The transistor is formed over an insulating film 501C, for example. The transistor also includes an insulating film 516 (an insulating film 516A and an insulating film 516B) and an insulating film 518.

The semiconductor film 508 includes a region 508A electrically connected to the conductive film 512A and a region 508B electrically connected to the conductive film 512B. The semiconductor film 508 includes a region 508C between the region 508A and the region 508B.

The conductive film 504 includes a region overlapping with the region 508C and has a function of a gate electrode.

The insulating film 506 includes a region interposed between the semiconductor film 508 and the conductive film 504. The insulating film 506 has a function of a first gate insulating film.

The conductive film 512A has one of a function of a source electrode and a function of a drain electrode, and the conductive film 512B has the other thereof.

A conductive film 524 can be used in the transistor. The semiconductor film 508 is interposed between the conductive film 504 and a region included in the conductive film 524. The conductive film 524 has a function of a second gate electrode. An insulating film 501D is interposed between the semiconductor film 508 and the conductive film 524 and has a function of a second gate insulating film.

The insulating film 516 functions as, for example, a protective film covering the semiconductor film 508. Specifically, a film including a silicon oxide film, a silicon oxynitride film, a silicon nitride oxide film, a silicon nitride film, an aluminum oxide film, a hafnium oxide film, an yttrium oxide film, a zirconium oxide film, a gallium oxide film, a tantalum oxide film, a magnesium oxide film, a lanthanum oxide film, a cerium oxide film, or a neodymium oxide film can be used as the insulating film 516, for example.

For the insulating film 518, a material that has a function of inhibiting diffusion of oxygen, hydrogen, water, an alkali metal, an alkaline earth metal, and the like is preferably used. Specifically, the insulating film 518 can be formed using silicon nitride, silicon oxynitride, aluminum nitride, or aluminum oxynitride, for example. In each of silicon oxynitride and aluminum oxynitride, the number of nitrogen atoms contained is preferably larger than the number of oxygen atoms contained.

Note that in a step of forming the semiconductor film used in the transistor of the pixel circuit, the semiconductor film used in the transistor of the driver circuit can be formed. A semiconductor film having the same composition as the semiconductor film used in the transistor of the pixel circuit can be used in the driver circuit, for example.

The semiconductor film 508 preferably contains indium, M (M is one or more of gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, Mis preferably one or more of aluminum, gallium, yttrium, and tin.

In particular, an oxide containing In, Ga, and Zn (also referred to as IGZO) is preferably used as the semiconductor film 508. Alternatively, it is preferable to use an oxide containing In, Sn, and Zn. Further alternatively, it is preferable to use an oxide containing In, Ga, Sn, and Zn. Further alternatively, it is preferable to use an oxide containing In, Al, and Zn (also referred to as IAZO). Further alternatively, it is preferable to use an oxide containing In, Al, Ga, and Zn (also referred to as IAGZO).

When the semiconductor film is an In-M-Zn oxide, the atomic proportion of In is preferably greater than or equal to the atomic proportion of M in the In-M-Zn oxide. Examples of the atomic ratio of the metal elements in such an In-M-Zn oxide are In:M:Zn=1:1:1, 1:1:1.2, 1:3:2, 1:3:4, 2:1:3, 3:1:2, 4:2:3, 4:2:4.1, 5:1:3, 5:1:6, 5:1:7, 5:1:8, 6:1:6, and 5:2:5 and a composition in the vicinity of any of the above atomic ratios. Note that the vicinity of the atomic ratio includes ±30% of an intended atomic ratio.

For example, in the case of describing an atomic ratio of In:Ga:Zn=4:2:3 or a composition in the vicinity thereof, the case is included in which with the atomic proportion of In being 4, the atomic proportion of Ga is greater than or equal to 1 and less than or equal to 3 and the atomic proportion of Zn is greater than or equal to 2 and less than or equal to 4. In the case of describing an atomic ratio of In:Ga:Zn=5:1:6 or a composition in the vicinity thereof, the case is included in which with the atomic proportion of In being 5, the atomic proportion of Ga is greater than 0.1 and less than or equal to 2 and the atomic proportion of Zn is greater than or equal to 5 and less than or equal to 7. In the case of describing an atomic ratio of In:Ga:Zn=1:1:1 or a composition in the vicinity thereof, the case is included in which with the atomic proportion of In being 1, the atomic proportion of Ga is greater than 0.1 and less than or equal to 2 and the atomic proportion of Zn is greater than 0.1 and less than or equal to 2.

There is no particular limitation on the crystallinity of a semiconductor material used in the transistor, and an amorphous semiconductor or a semiconductor having crystallinity (a microcrystalline semiconductor, a polycrystalline semiconductor, a single crystal semiconductor, or a semiconductor partly including crystal regions) can be used. It is preferable to use a semiconductor having crystallinity, in which case degradation of transistor characteristics can be inhibited.

In the case of using a metal oxide for the semiconductor film 508, the apparatus 720 includes a light-emitting device including a metal oxide in its semiconductor film and having a metal maskless (MML) structure. With this structure, the leakage current that might flow through the transistor and the leakage current that might flow between adjacent light-emitting devices (also referred to as a lateral leakage current, a side leakage current, or the like) can be extremely low. With the structure, a viewer can observe any one or more of the image crispness, the image sharpness, a high chroma, and a high contrast ratio in an image displayed on the display apparatus. When the leakage current that might flow through the transistor and the lateral leakage current that might flow between light-emitting devices are extremely low, display with little leakage of light at the time of black display (what is called black floating) (such display is also referred to as deep black display) can be achieved.

Alternatively, silicon may be used for the semiconductor film 508. Examples of silicon include single crystal silicon, polycrystalline silicon, and amorphous silicon. In particular, a transistor containing low-temperature polysilicon (LTPS) in its semiconductor layer (hereinafter also referred to as an LTPS transistor) is preferably used. The LTPS transistor has high field-effect mobility and favorable frequency characteristics.

With the use of transistors using silicon such as LTPS transistors, a circuit required to be driven at a high frequency (e.g., a source driver circuit) can be formed on the same substrate as the display portion. This allows simplification of an external circuit mounted on the light-emitting apparatus and a reduction in component costs and component-mounting costs.

The structure of the transistors used in the display panel may be selected as appropriate depending on the size of the screen of the display panel. For example, single crystal Si transistors can be used in the display panel with a screen diagonal greater than or equal to 0.1 inches and less than or equal to 3 inches. In addition, LTPS transistors can be used in the display panel with a screen diagonal greater than or equal to 0.1 inches and less than or equal to 30 inches, preferably greater than or equal to 1 inch and less than or equal to 30 inches. In addition, an LTPO structure (where an LTPS transistor and an OS transistor are used in combination) can be used in the display panel with a screen diagonal greater than or equal to 0.1 inches and less than or equal to 50 inches, preferably greater than or equal to 1 inch and less than or equal to 50 inches. In addition, OS transistors (transistors including a metal oxide in a semiconductor where a channel is formed) can be used in the display panel with a screen diagonal greater than or equal to 0.1 inches and less than or equal to 200 inches, preferably greater than or equal to 50 inches and less than or equal to 100 inches.

With the use of single crystal Si transistors, an increase in screen size is extremely difficult due to the size of a single crystal Si substrate. Furthermore, since a laser crystallization apparatus is used in the manufacturing process, LTPS transistors are unlikely to respond to an increase in screen size (typically to a screen diagonal greater than 30 inches). By contrast, since the manufacturing process does not necessarily require a laser crystallization apparatus or the like or can be performed at a relatively low temperature (typically, lower than or equal to 450° C.), OS transistors can be applied to a display panel with a relatively large area (typically, a screen diagonal greater than or equal to 50 inches and less than or equal to 100 inches). In addition, LTPO can be applied to a display panel with a size (typically, a screen diagonal greater than or equal to 1 inch and less than or equal to 50 inches) midway between the structure using LTPS transistors and the structure using OS transistors.

Next, a cross-sectional view of a light-emitting and light-receiving apparatus is shown. FIG. 8B is a cross-sectional view of the light-emitting and light-receiving apparatus illustrated in FIG. 7A.

FIG. 8B is a cross-sectional view of part of a region including the FPC 713 and the wiring 706 and part of the display region 701 including the pixel 703(i, j).

In FIG. 8B, the light-emitting and light-receiving apparatus 700 includes the functional layer 520 between the first substrate 510 and the second substrate 770. The functional layer 520 includes, as well as the above-described transistors, the capacitors, and the like, wirings electrically connected to these components, for example. Although the functional layer 520 includes a pixel circuit 530X(i, j), a pixel circuit 530S(i, j), and a circuit GD in FIG. 8B, one embodiment of the present invention is not limited thereto.

Furthermore, each pixel circuit (e.g., the pixel circuit 530X(i, j) and the pixel circuit 530S(i, j) in FIG. 8B) included in the functional layer 520 is electrically connected to a light-emitting device and a light-receiving device (e.g., a light-emitting device 550X(i, j) and a light-receiving device 550S(i, j) in FIG. 8B) formed over the functional layer 520. Specifically, the light-emitting device 550X(i, j) is electrically connected to the pixel circuit 530X(i, j) through a wiring 591X, and the light-receiving device 550S(i, j) is electrically connected to the pixel circuit 530S(i, j) through a wiring 591S. The insulating layer 705 is provided over the functional layer 520, the light-emitting devices, and the light-receiving device, and has a function of attaching the second substrate 770 and the functional layer 520.

As the second substrate 770, a substrate where touch sensors are arranged in a matrix can be used. For example, a substrate provided with capacitive touch sensors or optical touch sensors can be used as the second substrate 770. Thus, the light-emitting and light-receiving apparatus of one embodiment of the present invention can be used as a touch panel.

The structures described in this embodiment can be used in appropriate combination with any of the structures described in the other embodiments.

### Embodiment 5

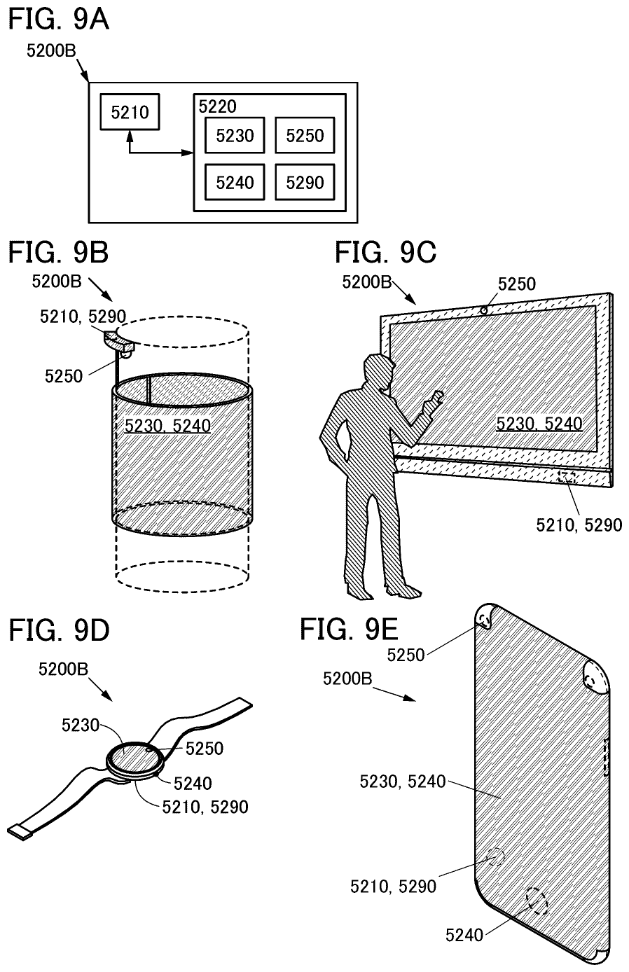

This embodiment will describe structures of electronic devices of embodiments of the present invention with reference to FIGS. 9A to 9E, FIGS. 10A to 10E, and FIGS. 11A and 11B.

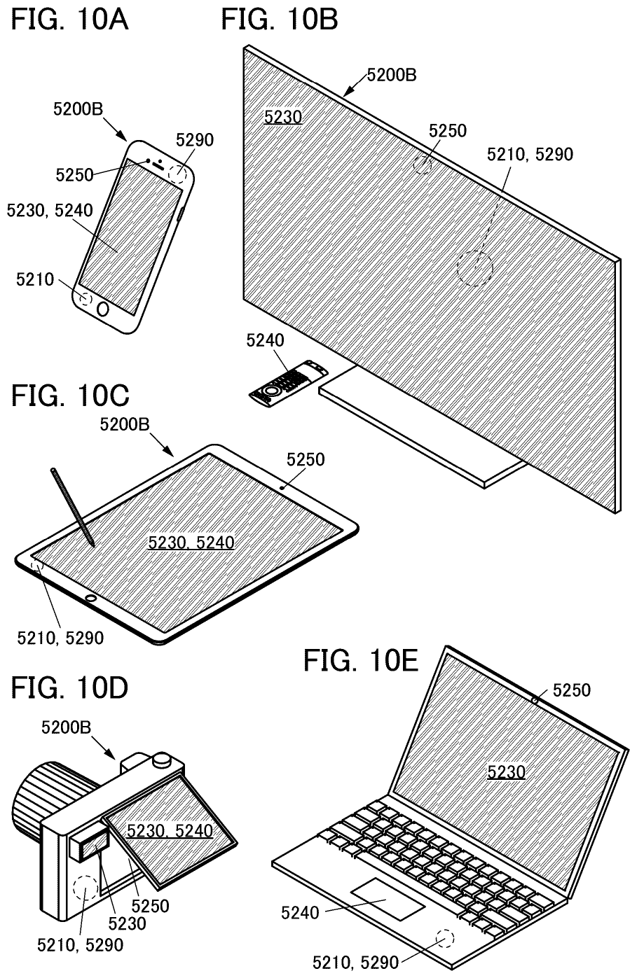

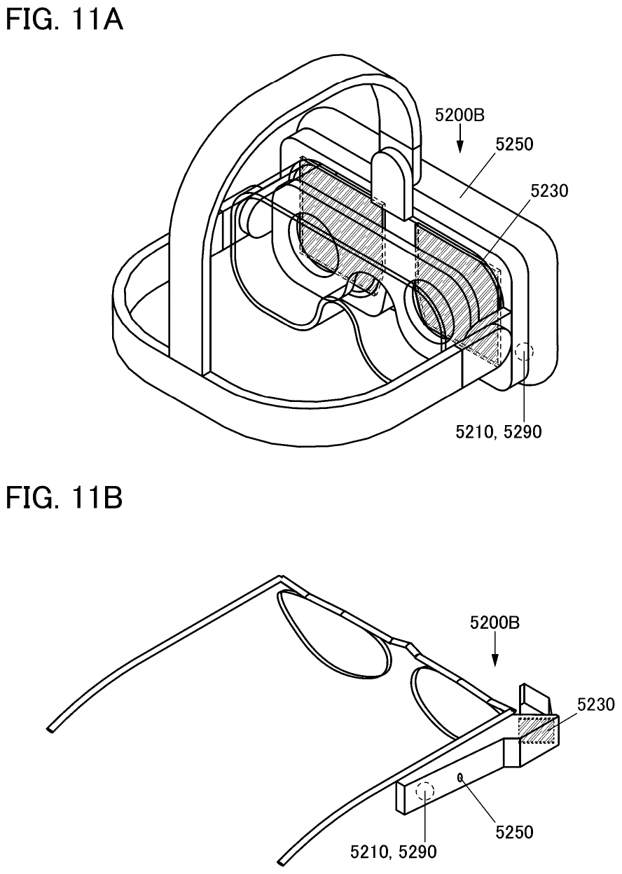

FIGS. 9A to 9E, FIGS. 10A to 10E, and FIGS. 11A and 11B each illustrate a structure of an electronic device of one embodiment of the present invention. FIG. 9A is a block diagram of an electronic device, and FIGS. 9B to 9E are perspective views illustrating structures of the electronic device. FIGS. 10A to 10E are perspective views illustrating structures of electronic devices. FIGS. 11A and 11B are perspective views illustrating structures of electronic devices.

An electronic device 5200B described in this embodiment includes an arithmetic device 5210 and an input/output device 5220 (see FIG. 9A).

The arithmetic device 5210 has a function of receiving handling data and a function of supplying image data on the basis of the handling data.

The input/output device 5220 includes a display portion 5230, an input portion 5240, a sensor portion 5250, and a communication portion 5290, and has a function of supplying handling data and a function of receiving image data. The input/output device 5220 also has a function of supplying sensing data, a function of supplying communication data, and a function of receiving communication data.

The input portion 5240 has a function of supplying handling data. For example, the input portion 5240 supplies handling data on the basis of handling by a user of the electronic device 5200B.

Specifically, a keyboard, a hardware button, a pointing device, a touch sensor, an illuminance sensor, an imaging device, an audio input device, an eye-gaze input device, an attitude sensing device, or the like can be used as the input portion 5240.

The display portion 5230 includes a display panel and has a function of displaying image data. For example, the display panel described in Embodiment 3 can be used for the display portion 5230.

The sensor portion 5250 has a function of supplying sensing data. For example, the sensor portion 5250 has a function of sensing a surrounding environment where the electronic device is used and supplying the sensing data.

Specifically, an illuminance sensor, an imaging device, an attitude sensing device, a pressure sensor, a human motion sensor, or the like can be used as the sensor portion 5250.

The communication portion 5290 has a function of receiving and supplying communication data. For example, the communication portion 5290 has a function of being connected to another electronic device or a communication network by wireless communication or wired communication. Specifically, the communication portion 5290 has a function of wireless local area network communication, telephone communication, near field communication, or the like.

FIG. 9B illustrates an electronic device having an outer shape along a cylindrical column or the like. An example of such an electronic device is digital signage. The display panel of one embodiment of the present invention can be used for the display portion 5230. The electronic device may have a function of changing its display method in accordance with the illuminance of a usage environment. The electronic device has a function of changing the displayed content when sensing the existence of a person. Thus, for example, the electronic device can be provided on a column of a building. The electronic device can display advertising, guidance, or the like.

FIG. 9C illustrates an electronic device having a function of generating image data on the basis of the path of a pointer used by the user. Examples of such an electronic device include an electronic blackboard, an electronic bulletin board, and digital signage. Specifically, a display panel with a diagonal size of 20 inches or longer, preferably 40 inches or longer, further preferably 55 inches or longer can be used. A plurality of display panels can be arranged and used as one display region. Alternatively, a plurality of display panels can be arranged and used as a multiscreen.

FIG. 9D illustrates an electronic device that is capable of receiving data from another device and displaying the data on the display portion 5230. An example of such an electronic device is a wearable electronic device. Specifically, the electronic device can display several options, and the user can choose some from the options and send a reply to the data transmitter. As another example, the electronic device has a function of changing its display method in accordance with the illuminance of a usage environment. Thus, for example, power consumption of the wearable electronic device can be reduced. As another example, the wearable electronic device can display an image so as to be suitably used even in an environment under strong external light, e.g., outdoors in fine weather.

FIG. 9E illustrates an electronic device including the display portion 5230 having a surface gently curved along a side surface of a housing. An example of such an electronic device is a mobile phone. The display portion 5230 includes a display panel that has a function of displaying images on the front surface, the side surfaces, the top surface, and the rear surface, for example. Thus, a mobile phone can display data on not only its front surface but also its side surfaces, top surface, and rear surface, for example.

FIG. 10A illustrates an electronic device that is capable of receiving data via the Internet and displaying the data on the display portion 5230. An example of such an electronic device is a smartphone. For example, the user can check a created message on the display portion 5230 and send the created message to another device. As another example, the electronic device has a function of changing its display method in accordance with the illuminance of a usage environment. Thus, power consumption of the smartphone can be reduced. As another example, it is possible to obtain a smartphone which can display an image such that the smartphone can be suitably used in an environment under strong external light, e.g., outdoors in fine weather.

FIG. 10B illustrates an electronic device that can use a remote controller as the input portion 5240. An example of such an electronic device is a television system. For example, data received from a broadcast station or via the Internet can be displayed on the display portion 5230. The electronic device can take an image of the user with the sensor portion 5250 and transmit the image of the user. The electronic device can acquire a viewing history of the user and provide it to a cloud service. The electronic device can acquire recommendation data from a cloud service and display the data on the display portion 5230. A program or a moving image can be displayed on the basis of the recommendation data. As another example, the electronic device has a function of changing its display method in accordance with the illuminance of a usage environment. Accordingly, for example, it is possible to obtain a television system which can display an image such that the television system can be suitably used even under strong external light entering the room from the outside in fine weather.

FIG. 10C illustrates an electronic device that is capable of receiving an educational material via the Internet and displaying it on the display portion 5230. An example of such an electronic device is a tablet computer. The user can input an assignment with the input portion 5240 and send it via the Internet. The user can obtain a corrected assignment or the evaluation from a cloud service and have it displayed on the display portion 5230. The user can select a suitable educational material on the basis of the evaluation and have it displayed.

For example, an image signal can be received from another electronic device and displayed on the display portion 5230. When the electronic device is placed on a stand or the like, the display portion 5230 can be used as a sub-display. Thus, for example, it is possible to obtain a tablet computer which can display an image such that the tablet computer is favorably used even in an environment under strong external light, e.g., outdoors in fine weather.

FIG. 10D illustrates an electronic device including a plurality of display portions 5230. An example of such an electronic device is a digital camera. For example, the display portion 5230 can display an image that the sensor portion 5250 is capturing. A captured image can be displayed on the sensor portion. A captured image can be decorated using the input portion 5240. A message can be attached to a captured image. A captured image can be transmitted via the Internet. The electronic device has a function of changing shooting conditions in accordance with the illuminance of a usage environment. Accordingly, for example, it is possible to obtain a digital camera that can display a subject such that an image is favorably viewed even in an environment under strong external light, e.g., outdoors in fine weather.

FIG. 10E illustrates an electronic device in which the electronic device of this embodiment is used as a master to control another electronic device used as a slave. An example of such an electronic device is a portable personal computer. For example, part of image data can be displayed on the display portion 5230 and another part of the image data can be displayed on a display portion of another electronic device. Image signals can be supplied. Data written from an input portion of another electronic device can be obtained with the communication portion 5290. Thus, a large display region can be utilized in the case of using a portable personal computer, for example.

FIG. 11A illustrates an electronic device including the sensor portion 5250 that senses an acceleration or a direction. An example of such an electronic device is a goggles-type electronic device. The sensor portion 5250 can supply data on the position of the user or the direction in which the user faces. The electronic device can generate image data for the right eye and image data for the left eye in accordance with the position of the user or the direction in which the user faces. The display portion 5230 includes a display region for the right eye and a display region for the left eye. Thus, a virtual reality image that gives the user a sense of immersion can be displayed on the goggles-type electronic device, for example.

FIG. 11B illustrates an electronic device including an imaging device and the sensor portion 5250 that senses an acceleration or a direction. An example of such an electronic device is a glasses-type electronic device. The sensor portion 5250 can supply data on the position of the user or the direction in which the user faces. The electronic device can generate image data in accordance with the position of the user or the direction in which the user faces. Accordingly, the data can be shown together with a real-world scene, for example. Alternatively, an augmented reality image can be displayed on the glasses-type electronic device.

Note that this embodiment can be combined with any of the other embodiments in this specification as appropriate.

### Embodiment 6

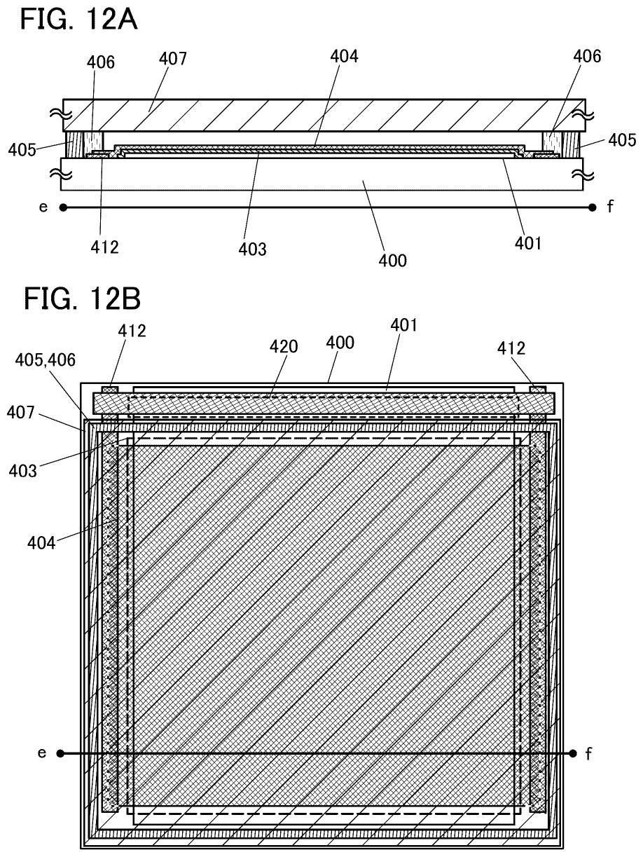

This embodiment will describe a structure in which any of the light-emitting devices described in Embodiment 2 is used as a lighting device with reference to FIGS. 12A and 12B. FIG. 12A is a cross-sectional view taken along the line e-f in a top view of the lighting device in FIG. 12B.

In the lighting device in this embodiment, a first electrode 401 is formed over a substrate 400 that is a support and has a light-transmitting property. The first electrode 401 corresponds to the first electrode 101 in Embodiment 2. When light is extracted from the first electrode 401 side, the first electrode 401 is formed using a material having a light-transmitting property.

A pad 412 for applying voltage to a second electrode 404 is provided over the substrate 400.

An EL layer 403 is formed over the first electrode 401. The structure of the EL layer 403 corresponds to the structure of the EL layer 103 in Embodiment 2. Refer to the corresponding description for these structures.

The second electrode 404 is formed to cover the EL layer 403. The second electrode 404 corresponds to the second electrode 102 in Embodiment 2. The second electrode 404 is formed using a material having high reflectance when light is extracted from the first electrode 401 side. The second electrode 404 is connected to the pad 412 so that voltage is supplied to the second electrode 404.

As described above, the lighting device described in this embodiment includes a light-emitting device including the first electrode 401, the EL layer 403, and the second electrode 404. Since the light-emitting device has high emission efficiency, the lighting device in this embodiment can have low power consumption.

The substrate 400 provided with the light-emitting device having the above structure and a sealing substrate 407 are fixed and sealed with sealing materials 405 and 406, whereby the lighting device is completed. It is possible to use only either the sealing material 405 or the sealing material 406. In addition, the inner sealing material 406 (not illustrated in FIG. 12B) can be mixed with a desiccant that enables moisture to be adsorbed, leading to an improvement in reliability.

When parts of the pad 412 and the first electrode 401 are extended to the outside of the sealing materials 405 and 406, the extended parts can serve as external input terminals. An IC chip 420 mounted with a converter or the like may be provided over the external input terminals.

### Embodiment 7

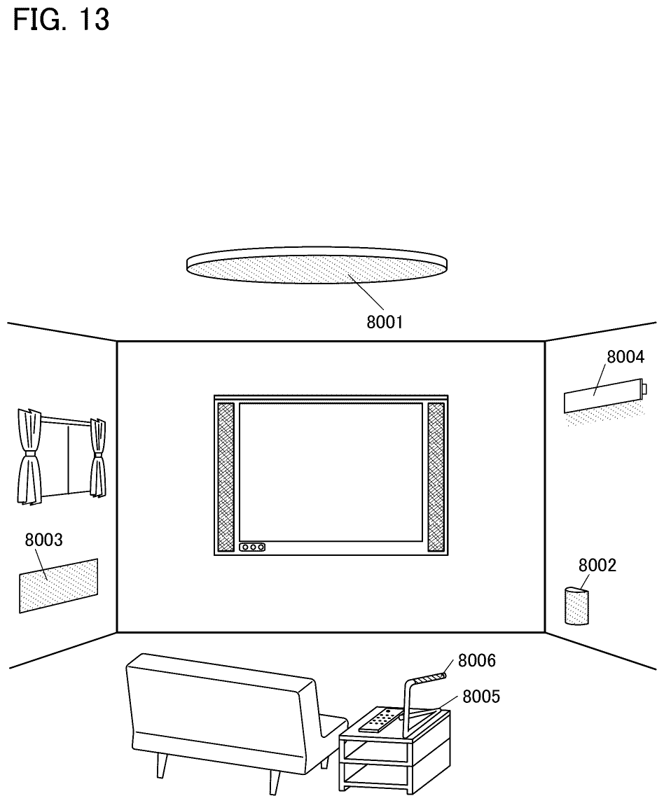

This embodiment will describe application examples of lighting devices fabricated using the light-emitting apparatus of one embodiment of the present invention or the light-emitting device, which is part of the light-emitting apparatus with reference to FIG. 13.

A ceiling light 8001 can be used as an indoor lighting device. Examples of the ceiling light 8001 include a direct-mount light and an embedded light. Such lighting devices are fabricated using the light-emitting apparatus and a housing and a cover in combination. Application to a cord pendant light (light that is suspended from a ceiling by a cord) is also possible.

A foot light 8002 lights a floor so that safety on the floor can be improved. For example, it can be effectively used in a bedroom, on a staircase, and on a passage. In such cases, the size and shape of the foot light can be changed in accordance with the dimensions and structure of a room. The foot light can be a stationary lighting device using the light-emitting apparatus and a support in combination.

A sheet-like lighting 8003 is a thin sheet-like lighting device. The sheet-like lighting, which is attached to a wall when used, is space-saving and thus can be used for a wide variety of uses. Furthermore, the area of the sheet-like lighting can be easily increased. The sheet-like lighting can also be used on a wall or a housing that has a curved surface.

A lighting device 8004 in which the direction of light from a light source is controlled to be only a desired direction can be used.

A desk lamp 8005 includes a light source 8006. As the light source 8006, the light-emitting apparatus of one embodiment of the present invention or the light-emitting device, which is part of the light-emitting apparatus, can be used.

Besides the above examples, when the light-emitting apparatus of one embodiment of the present invention or the light-emitting device, which is part of the light-emitting apparatus, is used as part of furniture in a room, a lighting device that functions as the furniture can be obtained.

As described above, a variety of lighting devices that include the light-emitting apparatus can be obtained. Note that these lighting devices are also embodiments of the present invention.

The structures described in this embodiment can be used in appropriate combination with any of the structures described in the other embodiments.

### Embodiment 8

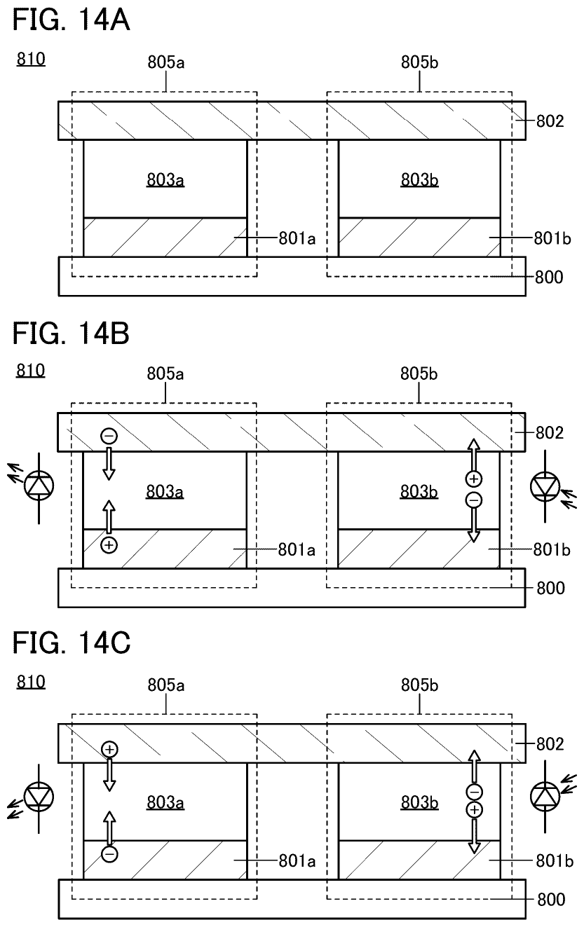

This embodiment will describe a light-emitting device and a light-receiving device that can be used for a light-emitting and light-receiving apparatus of one embodiment of the present invention with reference to FIGS. 14A to 14C.

FIG. 14A is a schematic cross-sectional view of a light-emitting device 805a and a light-receiving device 805b included in a light-emitting and light-receiving apparatus 810 of one embodiment of the present invention.

The light-emitting device 805a has a function of emitting light (hereinafter, also referred to as a light-emitting function). The light-emitting device 805a includes an electrode 801a, an EL layer 803a, and an electrode 802. The light-emitting device 805a is preferably a light-emitting device utilizing organic EL (an organic EL device) described in Embodiment 2. Thus, the EL layer 803a interposed between the electrode 801a and the electrode 802 includes at least a light-emitting layer. The light-emitting layer contains a light-emitting substance. The EL layer 803a emits light when voltage is applied between the electrode 801a and the electrode 802. The EL layer 803a may include any of a variety of layers such as a hole-injection layer, a hole-transport layer, an electron-transport layer, an electron-injection layer, a carrier-blocking (hole-blocking or electron-blocking) layer, and a charge-generation layer, in addition to the light-emitting layer.

The light-receiving device 805b has a function of sensing light (hereinafter, also referred to as a light-receiving function). As the light-receiving device 805b, a PN photodiode or a PIN photodiode can be used, for example. The light-receiving device 805b includes an electrode 801b, a light-receiving layer 803b, and the electrode 802. Thus, the light-receiving layer 803b interposed between the electrode 801b and the electrode 802 includes at least an active layer. Note that for the light-receiving layer 803b, any of materials that are used for the variety of layers (e.g., the hole-injection layer, the hole-transport layer, the light-emitting layer, the electron-transport layer, the electron-injection layer, the carrier-blocking (hole-blocking or electron-blocking) layer, and the charge-generation layer) included in the above-described EL layer 803a can be used. The light-receiving device 805b functions as a photoelectric conversion device. When light is incident on the light-receiving layer 803b, electric charge can be generated and extracted as a current. At this time, voltage may be applied between the electrode 801b and the electrode 802. The amount of generated electric charge depends on the amount of the light incident on the light-receiving layer 803b.

The light-receiving device 805b has a function of sensing visible light. The light-receiving device 805b has sensitivity to visible light. The light-receiving device 805b further preferably has a function of sensing visible light and infrared light. The light-receiving device 805b preferably has sensitivity to visible light and infrared light.

In this specification and the like, a blue (B) wavelength range is greater than or equal to 400 nm and less than 490 nm, and blue (B) light has at least one emission spectrum peak in the wavelength range. A green (G) wavelength range is greater than or equal to 490 nm and less than 580 nm, and green (G) light has at least one emission spectrum peak in the wavelength range. A red (R) wavelength range is greater than or equal to 580 nm and less than 700 nm, and red (R) light has at least one emission spectrum peak in the wavelength range. In this specification and the like, a visible wavelength range is greater than or equal to 400 nm and less than 700 nm, and visible light has at least one emission spectrum peak in the wavelength range. An infrared (IR) wavelength range is greater than or equal to 700 nm and less than 900 nm, and infrared (IR) light has at least one emission spectrum peak in the wavelength range.

The active layer in the light-receiving device 805b includes a semiconductor. Examples of the semiconductor are inorganic semiconductors such as silicon and organic semiconductors such as organic compounds. As the light-receiving device 805b, an organic semiconductor device (or an organic photodiode) including an organic semiconductor in the active layer is preferably used. An organic photodiode, which is easily made thin, lightweight, and large in area and has a high degree of freedom for shape and design, can be used in a variety of display apparatuses. An organic semiconductor is preferably used, in which case the EL layer 803a included in the light-emitting device 805a and the light-receiving layer 803b included in the light-receiving device 805b can be formed by the same method (e.g., a vacuum evaporation method) with the same manufacturing apparatus. Note that any of the organic compounds of one embodiment of the present invention can be used for the light-receiving layer 803b in the light-receiving device 805b.

In the display apparatus of one embodiment of the present invention, an organic EL device and an organic photodiode can be suitably used as the light-emitting device 805a and the light-receiving device 805b, respectively. The organic EL device and the organic photodiode can be formed over one substrate. Thus, the organic photodiode can be incorporated into the display apparatus including the organic EL device. A display apparatus of one embodiment of the present invention has one or both of an image capturing function and a sensing function in addition to a function of displaying an image.

The electrode 801a and the electrode 801b are provided on the same plane. In FIG. 14A, the electrodes 801a and 801b are provided over a substrate 800. The electrodes 801a and 801b can be formed by processing a conductive film formed over the substrate 800 into island shapes, for example. In other words, the electrodes 801a and 801b can be formed through the same process.

As the substrate 800, a substrate having heat resistance high enough to withstand the formation of the light-emitting device 805a and the light-receiving device 805b can be used. When an insulating substrate is used, a glass substrate, a quartz substrate, a sapphire substrate, a ceramic substrate, an organic resin substrate, or the like can be used as the substrate 800. Alternatively, a semiconductor substrate can be used. For example, a single crystal semiconductor substrate or a polycrystalline semiconductor substrate of silicon, silicon carbide, or the like; a compound semiconductor substrate of silicon germanium or the like; an SOI substrate; or the like can be used.

In particular, it is preferable to use, as the substrate 800, the insulating substrate or the semiconductor substrate over which a semiconductor circuit including a semiconductor element such as a transistor is formed. The semiconductor circuit preferably constitutes part of a pixel circuit, a gate line driver circuit (a gate driver), a source line driver circuit (a source driver), or the like. In addition to the above, the semiconductor circuit may constitute part of an arithmetic circuit, a memory circuit, or the like.

The electrode 802 is formed of a layer shared by the light-emitting device 805a and the light-receiving device 805b. As the electrode through which light enters or exits, a conductive film that transmits visible light and infrared light is used. As the electrode through which light neither enters nor exits, a conductive film that reflects visible light and infrared light is preferably used.

The electrode 802 in the display apparatus of one embodiment of the present invention functions as one of the electrodes in each of the light-emitting device 805a and the light-receiving device 805b.

In FIG. 14B, the electrode 801a of the light-emitting device 805a has a potential higher than the electrode 802. In this case, the electrode 801a and the electrode 802 function as an anode and a cathode, respectively, in the light-emitting device 805a. The electrode 801b of the light-receiving device 805b has a lower potential than the electrode 802. For easy understanding of the direction of current flow, FIG. 14B illustrates a circuit symbol of a light-emitting diode on the left of the light-emitting device 805a and a circuit symbol of a photodiode on the right of the light-receiving device 805b. The flow directions of carriers (electrons and holes) in each device are also schematically indicated by arrows.

In the structure illustrated in FIG. 14B, when a first potential is supplied to the electrode 801a through a first wiring, a second potential is supplied to the electrode 802 through a second wiring, and a third potential is supplied to the electrode 801b through a third wiring, the following relationship is satisfied: the first potential>the second potential>the third potential.

In FIG. 14C, the electrode 801a of the light-emitting device 805a has a lower potential than the electrode 802. In this case, the electrode 801a and the electrode 802 function as a cathode and an anode, respectively, in the light-emitting device 805a. The electrode 801b of the light-receiving device 805b has a lower potential than the electrode 802 and a higher potential than the electrode 801a. For easy understanding of the direction of current flow, FIG. 14C illustrates a circuit symbol of a light-emitting diode on the left of the light-emitting device 805a and a circuit symbol of a photodiode on the right of the light-receiving device 805b. The flow directions of carriers (electrons and holes) in each device are also schematically indicated by arrows.

In the structure illustrated in FIG. 14C, when a first potential is supplied to the electrode 801a through a first wiring, a second potential is supplied to the electrode 802 through a second wiring, and a third potential is supplied to the electrode 801b through a third wiring, the following relationship is satisfied: the second potential>the third potential>the first potential.

The resolution of the light-receiving device 805b described in this embodiment can be higher than or equal to 100 ppi, preferably higher than or equal to 200 ppi, further preferably higher than or equal to 300 ppi, still further preferably higher than or equal to 400 ppi, and still further preferably higher than or equal to 500 ppi, and lower than or equal to 2000 ppi, lower than or equal to 1000 ppi, or lower than or equal to 600 ppi, for example. In particular, when the resolution of the light-receiving device 805b is higher than or equal to 200 ppi and lower than or equal to 600 ppi, preferably higher than or equal to 300 ppi and lower than or equal to 600 ppi, the display apparatus of one embodiment of the present invention can be suitably used for image capturing of fingerprints. In fingerprint authentication with the display apparatus of one embodiment of the present invention, the increased resolution of the light-receiving device 805b enables, for example, highly accurate extraction of the minutiae of fingerprints; thus, the accuracy of the fingerprint authentication can be increased. The resolution is preferably higher than or equal to 500 ppi, in which case the authentication conforms to the standard by the National Institute of Standards and Technology (NIST) or the like. On the assumption that the resolution of the light-receiving device is 500 ppi, the size of each pixel is 50.8 μm, which is adequate for image capturing of a fingerprint ridge distance (typically, greater than or equal to 300 μm and less than or equal to 500 μm).

The structures described in this embodiment can be used in appropriate combination with any of the structures described in the other embodiments.

### Example 1

In this example, a light-emitting device 1 and a light-emitting device 2 of embodiments of the present invention were fabricated and the characteristics thereof were compared. The results are shown below. Structural formulae of organic compounds used for the light-emitting devices 1 and 2 are shown below. Furthermore, device structures of the light-emitting devices 1 and 2 are shown.

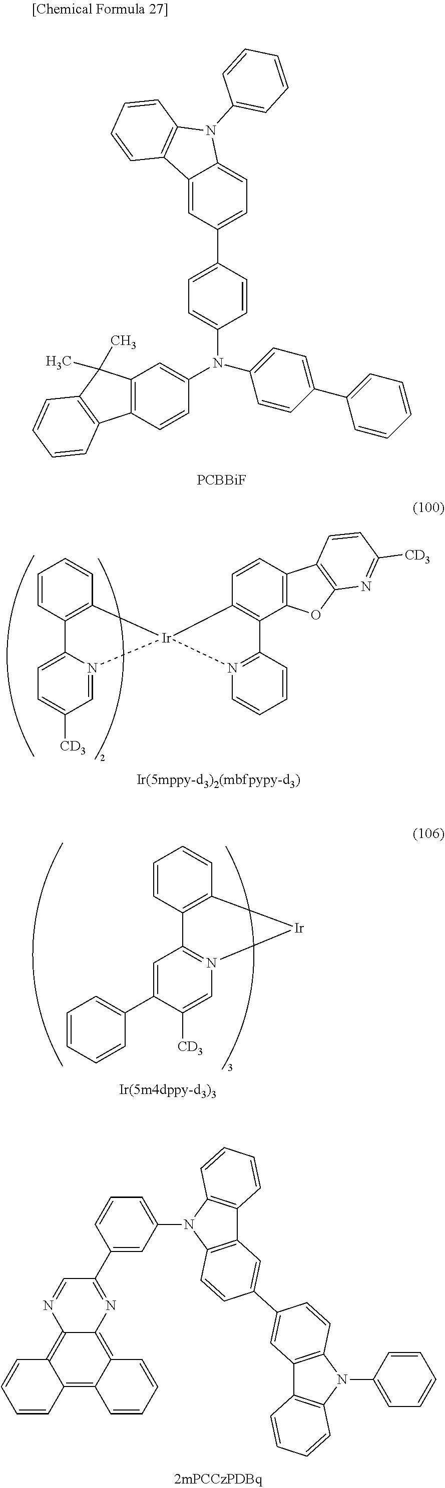

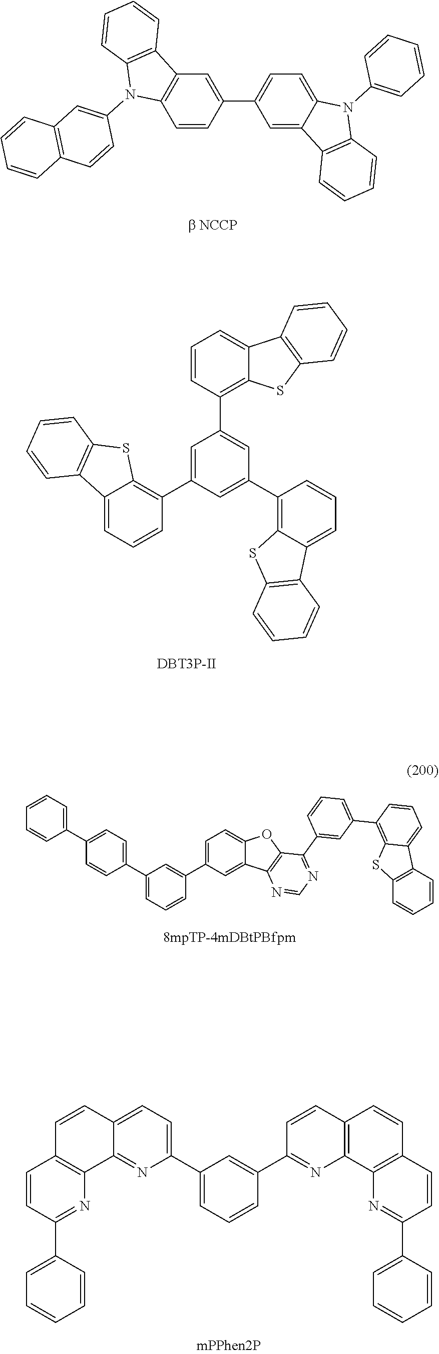 [SMILES: c1ccc(-n2c3ccccc3c3cc(-c4ccc5c(c4)c4ccccc4n5-c4ccc5ccccc5c4)ccc32)cc1 ; c1ccc2c(c1)sc1c(-c3cc(-c4cccc5c4sc4ccccc45)cc(-c4cccc5c4sc4ccccc45)c3)cccc12 ; "DBT3P-II" ; c1ccc(-c2ccc(-c3cccc(-c4ccc5oc6c(-c7cccc(-c8cccc9c8sc8ccccc89)c7)ncnc6c5c4)c3)cc2)cc1 ; c1ccc(-c2ccc3ccc4ccc(-c5cccc(-c6ccc7ccc8ccc(-c9ccccc9)nc8c7n6)c5)nc4c3n2)cc1]

TABLE 1

| | | |
|---|---|---|
| Film | | |
| thickness | Light-emitting device 1 | Light-emitting device 2 |

| Cap layer | | 70 | mm | DBT3P-II |
|---|---|---|---|---|
| Second electrode | | 25 | nm | Ag:Mg (1:0.1) |
| Electron-injection layer | | 1.5 | mm | LiF:Yb (2:1) |
| Electron-transport | 2 | 25 | nm | mPPhen2P |
| layer | 1 | 10 | nm | 2mPCCzPDBq |

| | | | | |
|---|---|---|---|---|
| Light-emitting layer | 40 | nm | 8mpTP-4mDBtPBfpm:βNCCP:Ir(5mppy- | 8mpTP- |
| | | | d₃)₂(mbfpypy-d₃) | 4mDBtPBfpm:βNCCP:Ir(5m4dppy-d₃)₃ |
| | | | (0.6:0.4:0.1) | (0.6:0.4:0.1) |

| | | | |
|---|---|---|---|
| Hole-transport layer | 15 | nm | PCBBiF |
| Hole-injection layer | 10 | nm | PCBBiF:OCHD-003 (1:0.03) |
| First electrode | 10 | nm | ITSO |
| | 100 | nm | Ag |

<<Fabrication of light-emitting device 1>>

In the light-emitting device 1 described in this example, a hole-injection layer, a hole-transport layer, a light-emitting layer, an electron-transport layer (a first electron-transport layer and a second electron-transport layer), and an electron-injection layer are stacked in this order over a first electrode formed over a substrate, a second electrode is stacked over the electron-injection layer, and a cap layer is stacked over the second electrode.

First, the first electrode was formed over the substrate. The electrode area was set to 4 mm² (2 mm×2 mm). A glass substrate was used as the substrate. The first electrode was formed in the following manner: silver was deposited to a thickness of 100 nm by a sputtering method, and then, as a transparent electrode, indium tin oxide containing silicon oxide (ITSO) was deposited to a thickness of 10 nm by a sputtering method. In this example, the first electrode functions as an anode.

For pretreatment, a surface of the substrate was washed with water, baking was performed at 200° C. for one hour, and then UV ozone treatment was performed for 370 seconds. After that, the substrate was transferred into a vacuum evaporation apparatus where the pressure had been reduced to approximately 1×10⁻⁴ Pa, and was subjected to vacuum baking at 170° C. for 30 minutes in a heating chamber of the vacuum evaporation apparatus, and then the substrate was cooled down for approximately 30 minutes.

Next, the hole-injection layer was formed over the first electrode. The hole-injection layer was formed in the following manner: the pressure in the vacuum evaporation apparatus was reduced to 1×10⁻⁴ Pa, and then N-(biphenyl-4-yl)-N-[4-(9-phenyl-9H-carbazol-3-yl)phenyl]-9,9-dimethyl-9H-fluoren-2-amine (abbreviation: PCBBiF) and an electron acceptor material (OCHD-003) that contains fluorine and has a molecular weight of 672 were deposited by co-evaporation to a thickness of 10 nm in a weight ratio of PCBBiF:OCHD-003=1:0.03.

Then, the hole-transport layer was formed over the hole-injection layer. The hole-transport layer was formed to a thickness of 15 nm by evaporation of PCBBiF.

Next, the light-emitting layer was formed over the hole-transport layer. The light-emitting layer was formed using 8-(1,1′:4′,1″-terphenyl-3-yl)-4-[3-(dibenzothiophen-4-yl)phenyl]-[1]benzofuro[3,2-d]pyrimidine (abbreviation: 8mpTP-4mDBtPBfpm, Structure Formula: (200)) as a first organic compound, 9-(2-naphthyl)-9′-phenyl-9H,9′H-3,3′-bicarbazole (abbreviation: PNCCP) as a second organic compound, and [2-d₃-methyl-8-(2-pyridinyl-κN)benzofuro[2,3-b]pyridine-κC]bis[2-(5-d₃-methyl-2-pyridinyl-κN²)phenyl-κC]iridium(III) (abbreviation: Ir(5mppy-d₃)₂(mbfpypy-d₃), Structure Formula: (100)) as a metal complex, and these materials were deposited by co-evaporation to a thickness of 40 nm in a weight ratio of 8mpTP-4mDBtPBfpm:βNCCP:Ir(5mppy-d₃)₂(mbfpypy-d₃)=0.6:0.4:0.1.

Next, the electron-transport layer (the first electron-transport layer and the second electron-transport layer) was formed over the light-emitting layer. The first electron-transport layer was formed to a thickness of 10 nm by evaporation of 2-{3-[3-(N-phenyl-9H-carbazol-3-yl)-9H-carbazol-9-yl]phenyl}dibenzo[f,h]quinoxaline (abbreviation: 2mPCCzPDBq). The second electron-transport layer was formed to a thickness of 25 nm by evaporation of 2,2′-(1,3-phenylene)bis(9-phenyl-1,10-phenanthroline) (abbreviation: mPPhen2P).

Next, the electron-injection layer was formed over the electron-transport layer by co-evaporation of lithium fluoride (LiF) and ytterbium (Yb) to a thickness of 1.5 nm in a volume ratio of LiF:Yb=2:1.

Next, the second electrode was formed over the electron-injection layer. The second electrode was formed by co-evaporation of Ag and Mg to have a thickness of 25 nm in a volume ratio of Ag:Mg=1:0.1. In this example, the second electrode functions as a cathode.

Next, the cap layer was formed over the second electrode. The cap layer was formed to a thickness of 70 nm by evaporation of 4,4′,4″-(benzene-1,3,5-triyl)tri(dibenzothiophene) (abbreviation: DBT3P-II).

Through the above process, the light-emitting device 1 was fabricated. Next, methods for fabricating the light-emitting device 2 and a comparative light-emitting device 4 to a comparative light-emitting device 8 are described.

### <<Fabrication of Light-Emitting Device 2>>

The light-emitting device 2 is different from the light-emitting device 1 in a metal complex used for the light-emitting layer. That is, the light-emitting device 2 was fabricated in a manner similar to that of the light-emitting device 1 except that tris{2-[5-(methyl-d₃)-4-phenyl-2-pyridinyl-κN]phenyl-κC}iridium(III) (abbreviation: Ir(5m4dppy-d₃)₃, Structural Formula: (106)) was used in the light-emitting layer instead of Ir(5mppy-d₃)₂(mbfpypy-d₃) used in the light-emitting layer of the light-emitting device 1.

The light-emitting devices 1 and 2 were sealed using a glass substrate in a glove box containing a nitrogen atmosphere so as not to be exposed to the air (a sealing material was applied to surround the devices and UV treatment and heat treatment at 80° C. for one hour were performed at the time of sealing). Then, the initial characteristics of the light-emitting devices were measured.

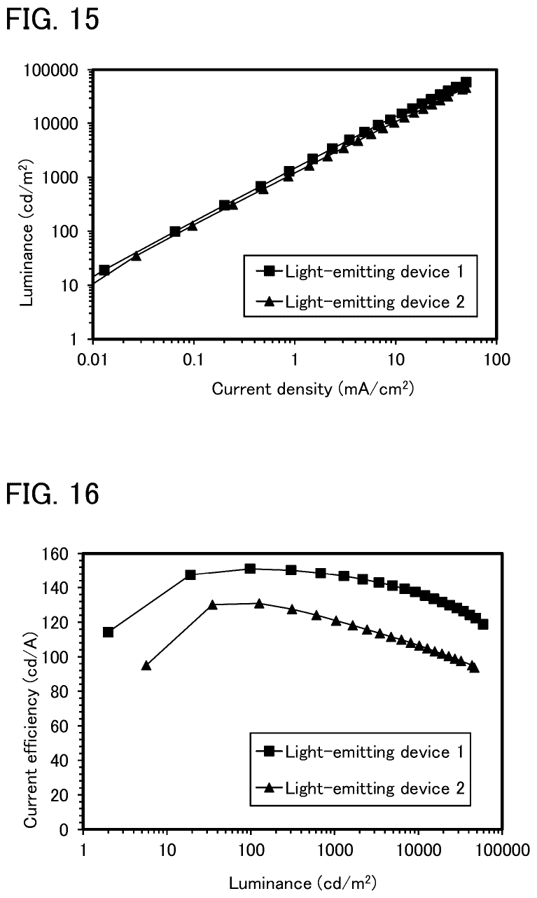

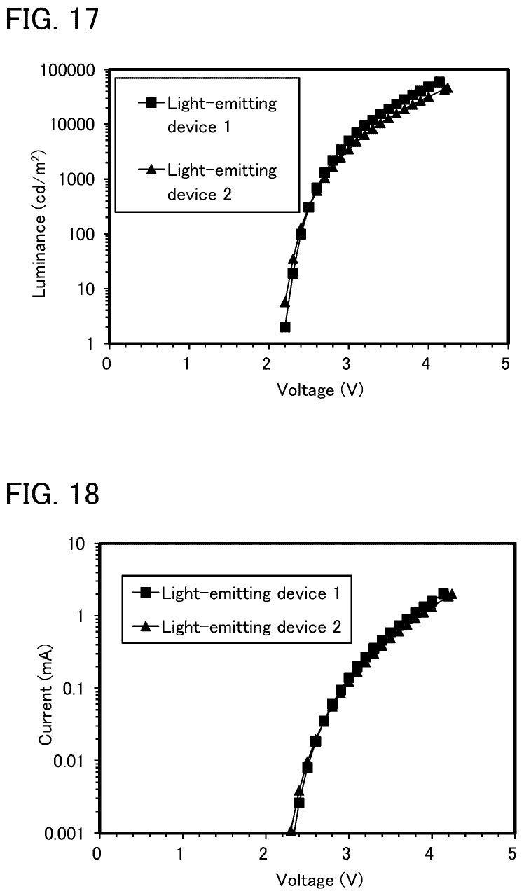

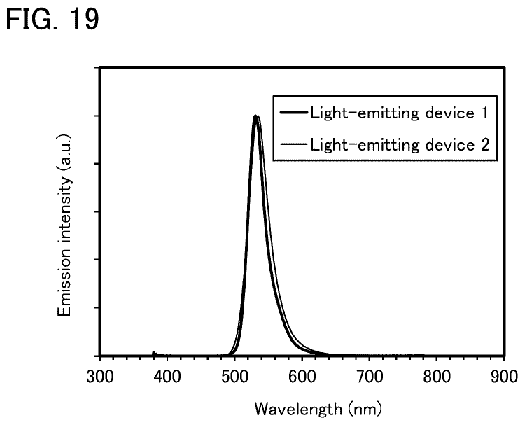

FIG. 15 shows the luminance-current density characteristics of the light-emitting devices 1 and 2. FIG. 16 shows the current efficiency-luminance characteristics thereof. FIG. 17 shows the luminance-voltage characteristics thereof. FIG. 18 shows the current-voltage characteristics thereof. FIG. 19 shows the electroluminescence spectra thereof. Table 2 shows the main characteristics of the light-emitting devices at a luminance of approximately 1000 cd/m². The luminance, CIE chromaticity, and electroluminescence spectra were measured with a spectroradiometer (SR-UL1R produced by TOPCON TECHNOHOUSE CORPORATION).

TABLE 2

| | | | Current | | | | Current |
|---|---|---|---|---|---|---|---|
| | Voltage | Current | density | | | Luminance | efficiency |
| | (V) | (mA) | (mA/cm²) | Chromaticity x | Chromaticity y | (cd/m²) | (cd/A) |
| Light-emitting | 2.7 | 0.035 | 0.88 | 0.255 | 0.712 | 1295 | 147 |
| device 1 | | | | | | | |
| Light-emitting | 2.7 | 0.035 | 0.86 | 0.272 | 0.696 | 1045 | 121 |
| device 2 | | | | | | | |

FIGS. 15 to 19 and the above table reveal that the light-emitting devices 1 and 2 have favorable characteristics.

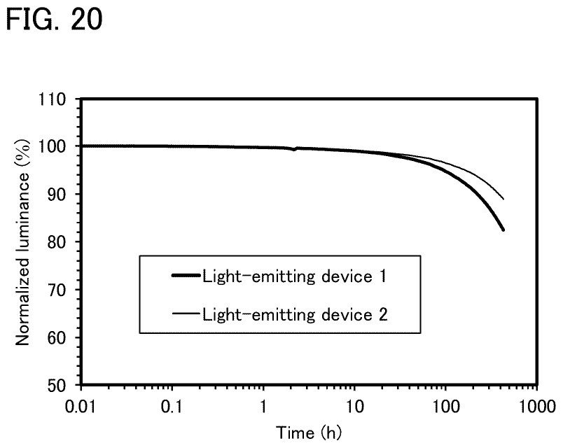

FIG. 20 shows luminance changes over driving time when the light-emitting devices 1 and 2 were driven at a constant current of 2 mA (50 mA/cm²). FIG. 20 reveals that the light-emitting devices 1 and 2 each have a small luminance change over driving time, and thus have high reliability. Comparison between the light-emitting devices 1 and 2 show that the light-emitting device 2 has a smaller luminance change over driving time and higher reliability than the light-emitting device 1.

These results demonstrate that the light-emitting devices of embodiments of the present invention have favorable characteristics and long lifetimes.

### Example 2

In this example, a light-emitting device 3 of one embodiment of the present invention and the comparative light-emitting devices 4 to 8 having structures different from that of the light-emitting device 3 were fabricated and the characteristics thereof were compared. The results are described below. Structural formulae of organic compounds used for the light-emitting device 3 and the comparative light-emitting devices 4 to 8 are shown below. In addition, the device structures of the light-emitting device 3 and the comparative light-emitting devices 4 to 8 are shown in Tables 3 and 4.

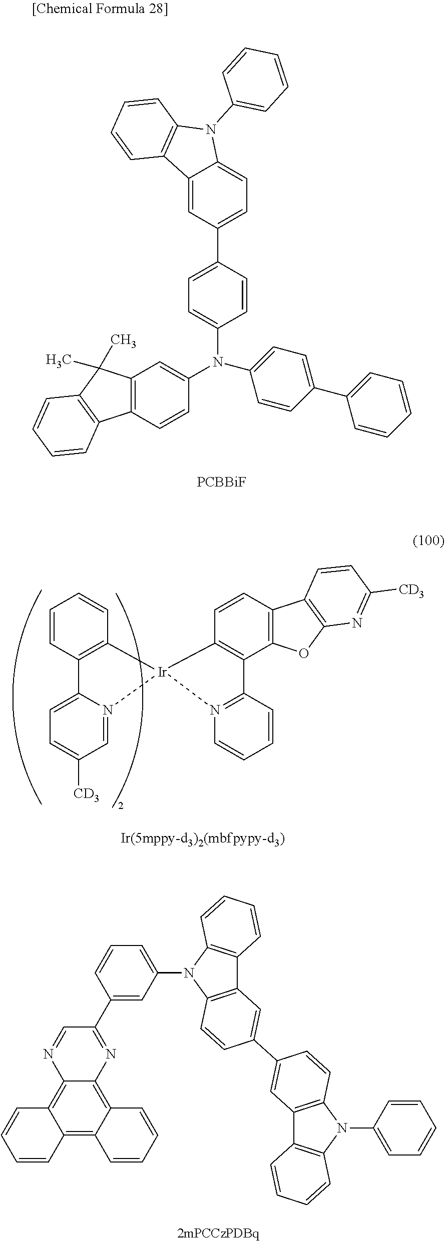

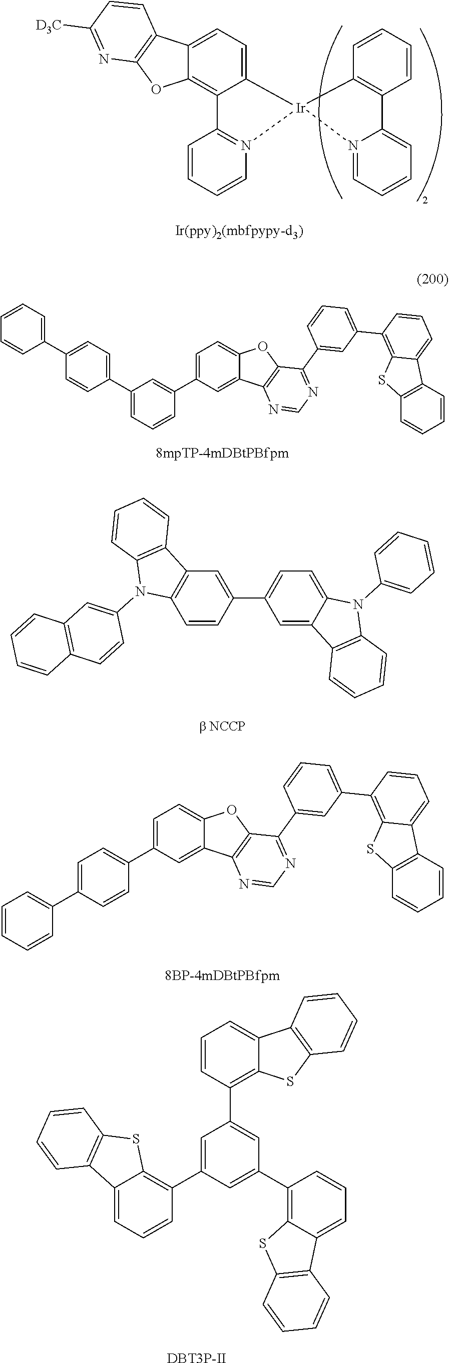

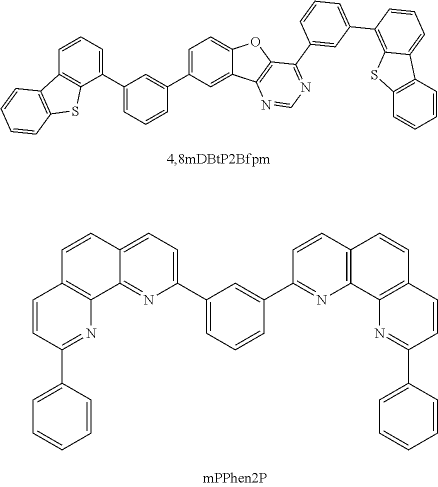 [SMILES: c1cc(-c2ccc3oc4c(-c5cccc(-c6cccc7c6sc6ccccc67)c5)ncnc4c3c2)cc(-c2cccc3c2sc2ccccc23)c1 ; c1ccc(-c2ccc3ccc4ccc(-c5cccc(-c6ccc7ccc8ccc(-c9ccccc9)nc8c7n6)c5)nc4c3n2)cc1]

TABLE 3

| | | | | Light-emitting device 3, |
|---|---|---|---|---|
| | | Film | | Comparative light-emitting |
| | | thickness | | devices 4 to 8 |
| Cap layer | | 70 | nm | DBT3P-II |
| Second electrode | | 25 | mm | Ag:Mg (1:0.1) |
| Electron-injection layer | | 1.5 | nm | LiF:Yb (2:1) |
| Electron-transport | 2 | 20 | nm | mPPhen2P |
| layer | 1 | 10 | nm | 2mPCCzPDBq |

| | | | |
|---|---|---|---|
| Light-emitting layer | 40 | nm | Refer to another table. |
| Hole-transport layer | 15 | nm | PCBBiF |
| Hole-injection layer | 10 | nm | PCBBiF:OCHD-003 (1:0.03) |
| First electrode | 10 | nm | ITSO |
| | 100 | nm | Ag |

TABLE 4

| | First | Second | | |
|---|---|---|---|---|
| | organic | organic | | Mixture |
| | compound | compound | Metal complex | ratio |
| Light-emitting device 3 | 8mpTP- | βNCCP | Ir(5mppy-d₃)₂(mbfpypy-d₃) | First organic |
| Comparative | 4mDBtPBfpm | | Ir(ppy)₂(mbfpypy-d₃) | compound:Second |
| light-emitting device 4 | | | | organic |
| Comparative | 8BP- | | Ir(5mppy-d₃)₂(mbfpypy-d₃) | compound:metal |
| light-emitting device 5 | 4mDBtPBfpm | | | complex = |
| Comparative | | | Ir(ppy)₂(mbfpypy-d₃) | 0.5:0.5:0.1 |
| light-emitting device 6 | | | | |
| Comparative | 4,8mDBtP2Bfpm | | Ir(5mppy-d₃)₂(mbfpypy-d₃) | |
| light-emitting device 7 | | | | |
| Comparative | | | Ir(ppy)₂(mbfpypy-d₃) | |
| light-emitting device 8 | | | | |

### <<Fabrication of Light-Emitting Device 3>>

The light-emitting device 3 described in this example is different from the light-emitting device 1 described in Example 1 in the mixture ratio of the first organic compound, the second organic compound, and the metal complex in the light-emitting layer and the thickness of the second electron-transport layer. That is, the light-emitting device 3 was fabricated in a manner similar to that of the light-emitting device 1 except that the mixture ratio of 8mpTP-4mDBtPBfpm, βNCCP, and Jr(5mppy-d₃)₂(mbfpypy-d₃) in the light-emitting layer was set to a weight ratio of 8mpTP-4mDBtPBfpm:PNCCP:Ir(5mppy-d₃)₂(mbfpypy-d₃)=0.5:0.5:0.1, and the thickness of the second electron-transport layer was set to 20 nm.

### <<Fabrication of Comparative Light-Emitting Devices 4 to 8>>

The comparative light-emitting devices 4 to 8 are different from the light-emitting device 3 in one or both of the first organic compound and the metal complex in the light-emitting layer. The other components of the comparative light-emitting devices 4 to 8 were fabricated in a manner similar to that of the light-emitting device 3.

As the first organic compound, 8mpTP-4mDBtPBfpm was used in the comparative light-emitting device 4 as in the light-emitting device 3, 8-(biphenyl-4-yl)-4-[3-(dibenzothiophen-4-yl)phenyl]-[1]benzofuro[3,2-d]pyrimidine (abbreviation: 8BP-4mDBtPBfpm) was used in the comparative light-emitting devices 5 and 6, and 4,8-bis[3-(dibenzothiophen-4-yl)phenyl]-[1]benzofuro[3,2-d]pyrimidine (abbreviation: 4,8mDBtP2Bfpm) was used in the comparative light-emitting devices 7 and 8.

As the metal complex, Ir(5mppy-d₃)₂(mbfpypy-d₃) was used in the comparative light-emitting devices 5 and 7 as in the light-emitting device 3, and [2-d₃-methyl-(2-pyridinyl-κN)benzofuro[2,3-b]pyridine-κC]bis[2-(2-pyridinyl-κN)phenyl-κC]iridium (III) (abbreviation: Ir(ppy)₂(mbfpypy-d₃)) was used in the comparative light-emitting devices 4, 6, and 8.

The light-emitting device 3 and the comparative light-emitting devices 4 to 8 were sealed using a glass substrate in a glove box containing a nitrogen atmosphere so as not to be exposed to the air (a sealing material was applied to surround the devices and UV treatment and heat treatment at 80° C. for one hour were performed at the time of sealing). Then, the initial characteristics of the light-emitting devices were measured.

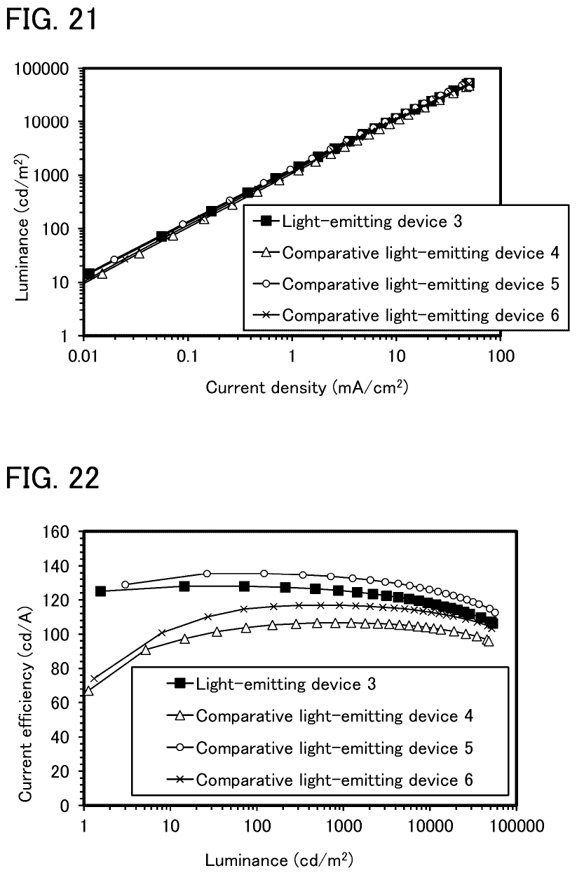

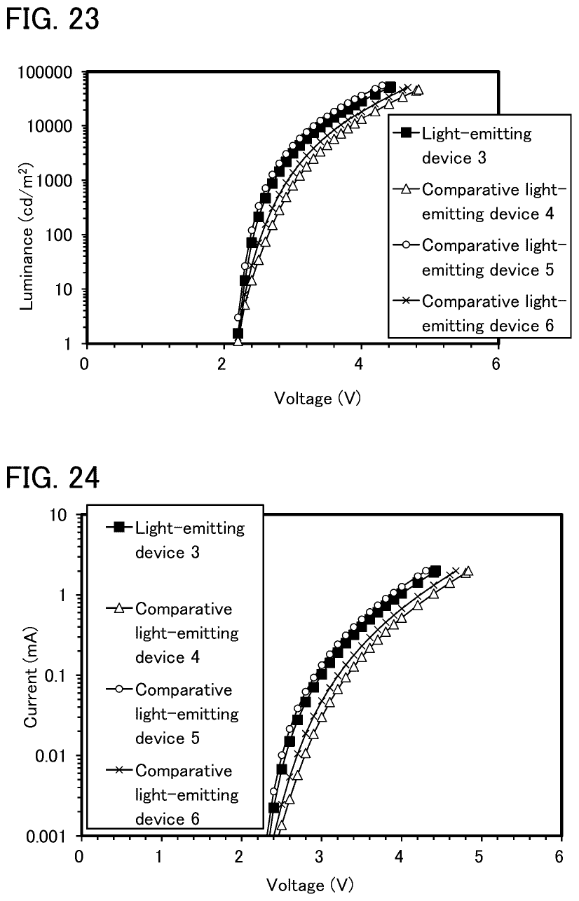

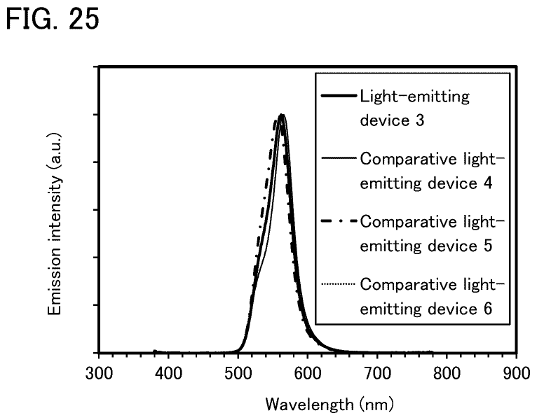

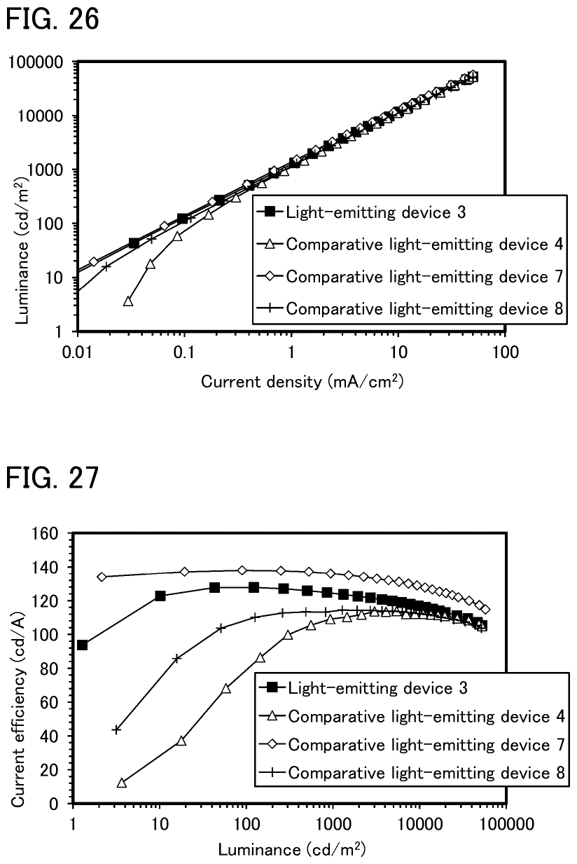

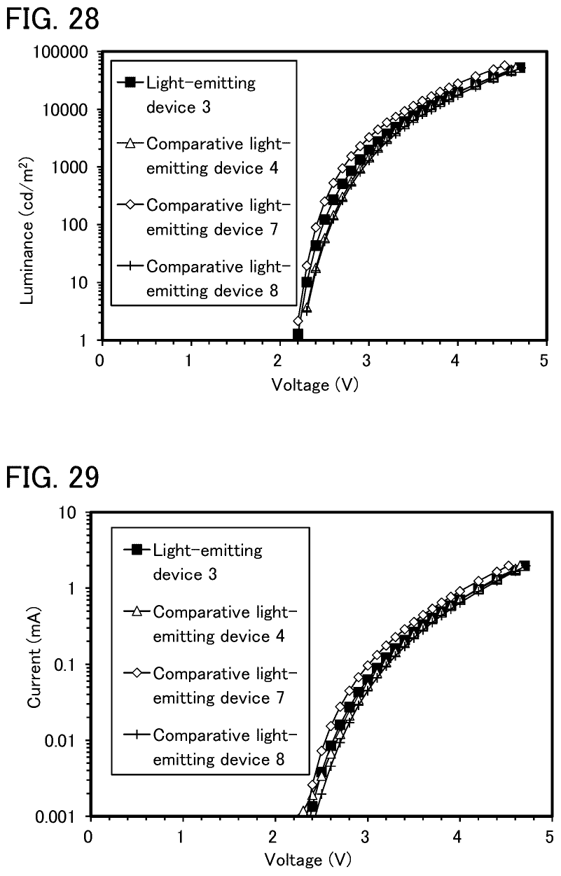

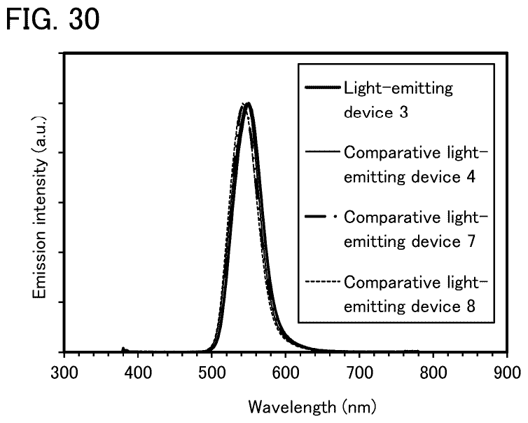

FIG. 21 shows the luminance-current density characteristics of the light-emitting device 3 and the comparative light-emitting devices 4 to 6. FIG. 22 shows the current efficiency-luminance characteristics thereof. FIG. 23 shows the luminance-voltage characteristics thereof. FIG. 24 shows the current-voltage characteristics thereof. FIG. 25 shows the electroluminescence spectra thereof. FIG. 26 shows the luminance-current density characteristics of the light-emitting device 3 and the comparative light-emitting devices 4, 7, and 8. FIG. 27 shows the current efficiency-luminance characteristics thereof. FIG. 28 shows the luminance-voltage characteristics thereof. FIG. 29 shows the current-voltage characteristics thereof. FIG. 30 shows the electroluminescence spectra thereof. Note that the light-emitting device 3 and the comparative light-emitting device 4 used for measurement of the characteristics shown in FIGS. 21 to 25 have the same structures as the light-emitting device 3 and the comparative light-emitting device 4 used for measurement of the characteristics shown in FIGS. 26 to 30; however, they are different samples. Therefore, the characteristics of the light-emitting device 3 and the comparative light-emitting device 4 shown in FIGS. 21 to 25 are not completely the same as those shown in FIGS. 26 to 30.

Table 5 shows the main characteristics of the light-emitting devices at a luminance of approximately 1000 cd/m². The luminance, CIE chromaticity, and electroluminescence spectra were measured with a spectroradiometer (SR-UL1R produced by TOPCON TECHNOHOUSE CORPORATION).

TABLE 5

| | | | Current | | | | Current |
|---|---|---|---|---|---|---|---|
| | Voltage | Current | density | | | Luminance | efficiency |
| | (V) | (mA) | (mA/cm²) | Chromaticity x | Chromaticity y | (cd/m²) | (cd/A) |
| Light-emitting device 3 | 2.7 | 0.028 | 0.70 | 0.380 | 0.610 | 873 | 126 |
| Comparative | 3.0 | 0.030 | 0.75 | 0.398 | 0.592 | 804 | 107 |
| light-emitting device 4 | | | | | | | |
| Comparative | 2.7 | 0.038 | 0.96 | 0.361 | 0.627 | 1274 | 133 |
| light-emitting device 5 | | | | | | | |
| Comparative | 2.9 | 0.031 | 0.77 | 0.374 | 0.614 | 901 | 117 |
| light-emitting device 6 | | | | | | | |
| Comparative | 2.7 | 0.028 | 0.69 | 0.317 | 0.665 | 941 | 136 |
| light-emitting device 7 | | | | | | | |
| Comparative | 2.8 | 0.017 | 0.43 | 0.300 | 0.678 | 486 | 113 |
| light-emitting device 8 | | | | | | | |

FIGS. 21 to 30 show that the light-emitting device 3, the comparative light-emitting device 5, and the comparative light-emitting device 7 have lower driving voltage and higher current efficiency than the comparative light-emitting devices 4, 6, and 8. This demonstrates that the use of Ir(5mppy-d₃)₂(mbfpypy-d₃) as the metal complex of the light-emitting layer can reduce the driving voltage and improve the current efficiency.

This is because Ir(5mppy-d₃)₂(mbfpypy-d₃) is a metal complex including a deuterated methyl group, which is an electron-donating group, in a pyridine ring in a ligand, and thus has a higher (shallower) HOMO level than Ir(ppy)₂(mbfpypy-d₃) that does not include a substituent in a pyridine ring in a ligand. Increasing the HOMO level of the metal complex reduces the hole-injection barrier at an interface between the hole-transport layer and the light-emitting layer, resulting in a decrease in driving voltage of the light-emitting device 3 and an improvement in the current efficiency.

Note that the HOMO levels of Ir(5mppy-d₃)₂(mbfpypy-d₃) and Ir(ppy)₂(mbfpypy-d₃) were obtained by cyclic voltammetry (CV) measurement. An electrochemical analyzer (ALS model 600A or 600C, manufactured by BAS Inc.) was used for the measurement. As a result, the HOMO level of Ir(5mppy-d₃)₂(mbfpypy-d₃) was −5.32 eV and the HOMO level of Ir(ppy)₂(mbfpypy-d₃) was −5.36 eV; that is, Ir(5mppy-d₃)₂(mbfpypy-d₃) has a higher HOMO level than Ir(ppy)₂(mbfpypy-d3).

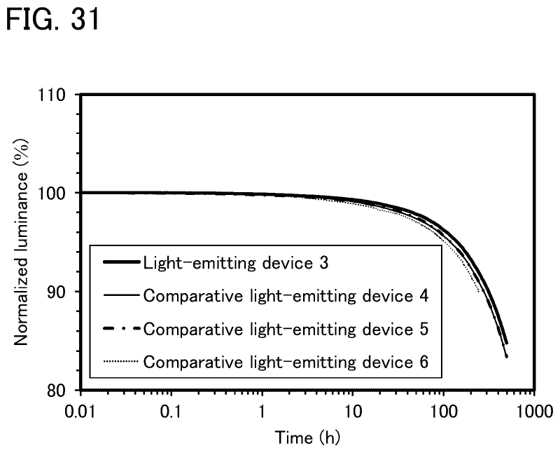

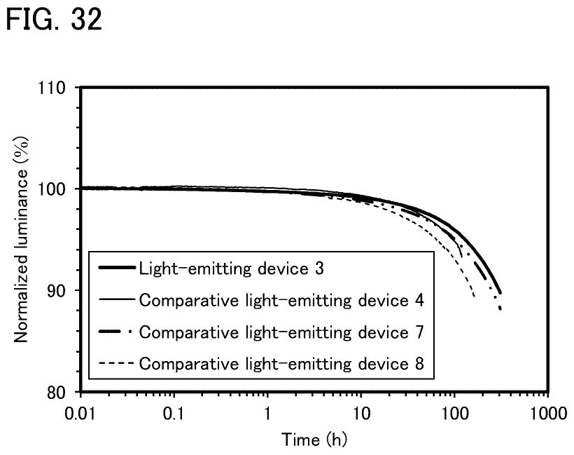

FIGS. 31 and 32 show luminance changes over driving time when the light-emitting device 3 and the comparative light-emitting devices 4 to 8 were driven at a constant current of 2 mA (50 mA/cm²). FIG. 31 shows the results of the light-emitting device 3 and the comparative light-emitting devices 4 to 6, and FIG. 32 shows the results of the light-emitting device 3 and the comparative light-emitting devices 4, 7, and 8.

FIGS. 31 and 32 show that the light-emitting device 3 has a smaller luminance change over driving time and higher reliability than all of the comparative light-emitting devices. From the above, it is found that the use of 8mpTP-4mDBtPBfpm as the first organic compound and Ir(5mppy-d₃)₂(mbfpypy-d₃) as the metal complex can reduce the luminance change over driving time and improve the reliability.

This is because the lowest triplet excitation of 8mpTP-4mDBtPBfpm is derived from a terphenyl group. The T₁ level when a terphenyl group is excited is lower than that when another partial structure is excited; thus, the use of 8mpTP-4mDBtPBfpm can improve the reliability of the light-emitting device.

Next, the T₁ level of 8mpTP-4mDBtPBfpm was calculated. A thin film of 8mpTP-4mDBtPBfpm was formed to a thickness of 50 nm over a quartz substrate, and an emission spectrum (phosphorescent spectrum) was measured at a measurement temperature of 10 K. The measurement was performed by using a PL microscope, LabRAM HR-PL, produced by HORIBA, Ltd. and a He—Cd laser (325 nm) as excitation light. As a result, the peak of 8mpTP-4mDBtPBfpm on the shortest wavelength side was 500 nm (2.48 eV), and the emission edge on the shortest wavelength side was 486 nm (2.55 eV).

In addition, to obtain the T₁ level of Ir(5mppy-d₃)₂(mbfpypy-d₃), an absorption spectrum and an emission spectrum (phosphorescent spectrum) were measured. A toluene solution where Ir(5mppy-d₃)₂(mbfpypy-d₃) was dissolved was prepared, and the absorption spectrum and the emission spectrum were measured at room temperature (in an atmosphere kept at 23° C.). As a result, the absorption edge of the absorption spectrum of Ir(5mppy-d₃)₂(mbfpypy-d₃) on the longest wavelength side was 526 nm (2.36 eV), and the emission edge of the emission spectrum (phosphorescent spectrum) on the shortest wavelength side was 503 nm (2.46 eV).

Note that the absorption edge is determined as the intersection between a tangent and the horizontal axis (representing wavelength) or the baseline. The tangent is drawn to have the minimum slope at a point on a longer wavelength side of the longest-wavelength peak (or the longest-wavelength shoulder peak) of the absorption spectrum. An emission edge was determined as the intersection of a tangent and the horizontal axis (representing wavelength) or the baseline. The tangent is drawn to have the maximum slope at a point on a shorter wavelength side of the shortest-wavelength peak (or the shortest-wavelength shoulder peak) of the emission spectrum.

When the T₁ levels of 8mpTP-4mDBtPBfpm and Ir(5mppy-d₃)₂(mbfpypy-d₃) obtained at the emission edges are compared, the lowest triplet excitation energy of 8mpTP-4mDBtPBfpm is higher than that of Ir(5mppy-d₃)₂(mbfpypy-d₃) by 0.09 eV.

In addition, Ir(5mppy-d₃)₂(mbfpypy-d₃), which includes a deuterated methyl group in the pyridine ring in the ligand, is a stable metal complex where the hydrogen-carbon bond is less likely to be cut due to vibration in the methyl group as compared with the case where a methyl group that is not deuterated is included in the pyridine ring in the ligand. Such high stability and high reliability of the metal complex contribute to an improvement in the reliability of the light-emitting device.

### Example 3

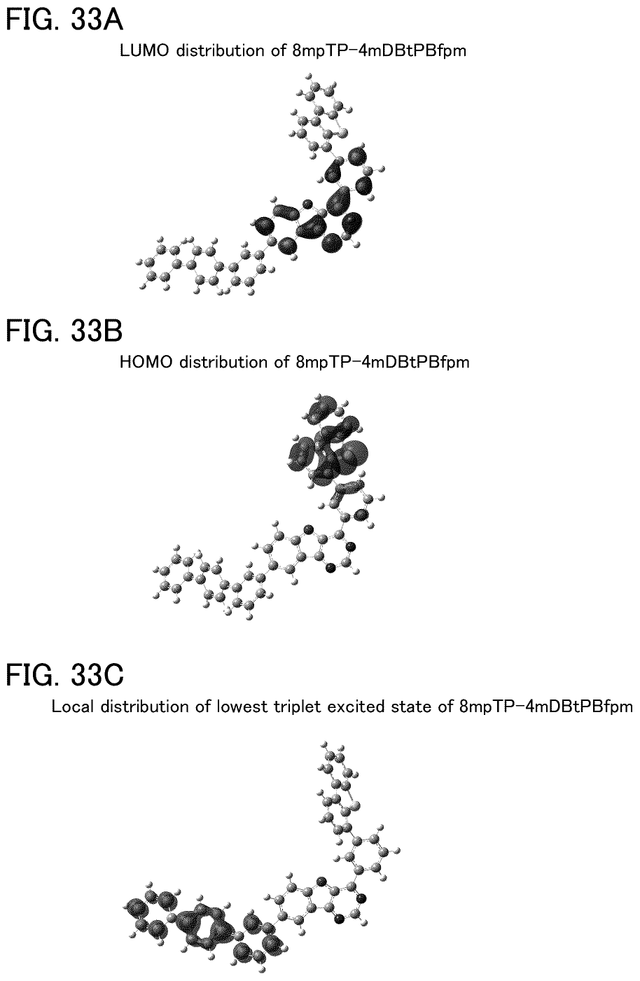

In this example, the first organic compound that can be used for the light-emitting device of one embodiment of the present invention was analyzed by calculation, and the results are described with reference to FIGS. 33A to 33C, FIGS. 34A to 34C, and FIGS. 35A to 35C.

Analysis of the HOMO distribution, the LUMO distribution, and local distribution of the lowest triplet excited state was performed on 8mpTP-4mDBtPBfpm (Structural Formula (200)) that is a specific example of the first organic compound, an organic compound represented by Structural Formula (216), and 8BP-4mDBtPBfpm that is a comparative example.

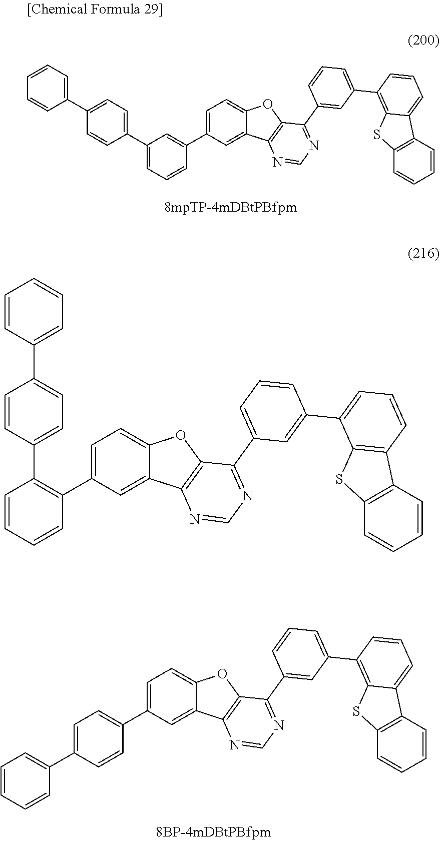 [SMILES: c1ccc(-c2ccc(-c3cccc(-c4ccc5oc6c(-c7cccc(-c8cccc9c8sc8ccccc89)c7)ncnc6c5c4)c3)cc2)cc1 ; c1ccc(-c2ccc(-c3ccccc3-c3ccc4oc5c(-c6cccc(-c7cccc8c7sc7ccccc78)c6)ncnc5c4c3)cc2)cc1 ; c1ccc(-c2ccc(-c3ccc4oc5c(-c6cccc(-c7cccc8c7sc7ccccc78)c6)ncnc5c4c3)cc2)cc1]

### <Calculation Method>

The HOMO and LUMO distributions were analyzed by analyzing vibration (spin density) in the most stable structure where the singlet ground state (S₀) level of the compound is the lowest. Local distribution of the lowest triplet excited state was analyzed by analyzing the spin density in the most stable structure where the lowest triplet excited state (T₁) level of the compound is the lowest. A density functional theory (DFT) method was used as the calculation method. The total energy calculated by the DFT is represented as the sum of potential energy, electrostatic energy between electrons, electronic kinetic energy, and exchange-correlation energy including all the complicated interactions between electrons. In the DFT, an exchange-correlation interaction is approximated by a functional (a function of another function) of one electron potential represented in terms of electron density to enable high-speed calculations. Here, B3LYP which is a hybrid functional was used to specify the weight of each parameter related to exchange-correlation energy. As a basis function, 6-311G (d,p) was used. Gaussian 09 was used as a computational program.

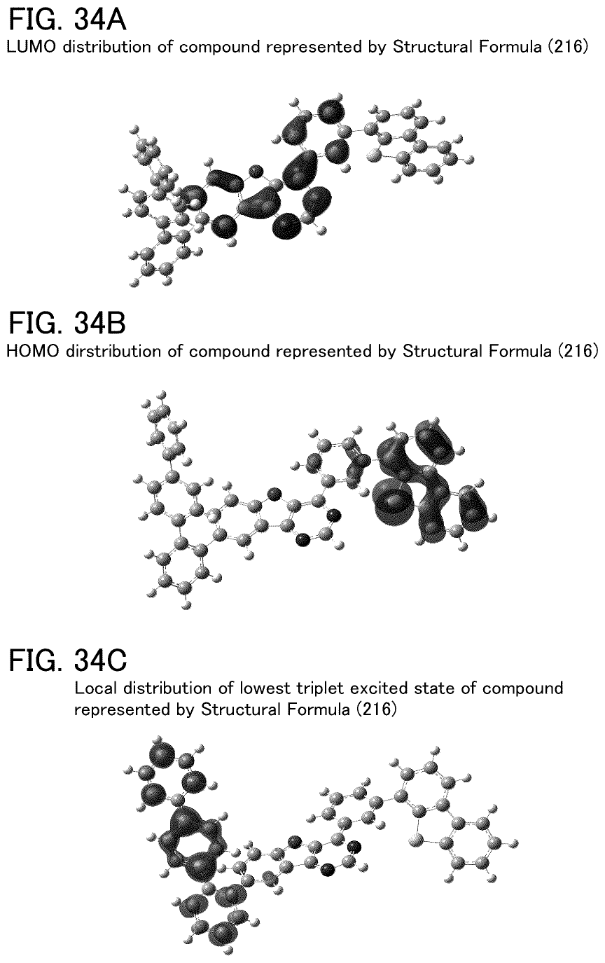

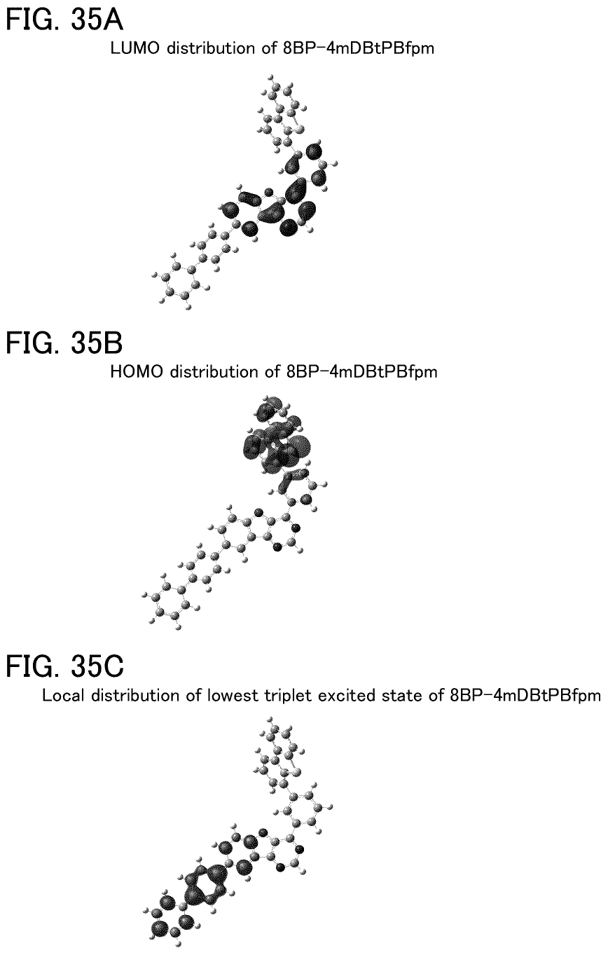

FIGS. 33A to 33C show the analysis results of 8mpTP-4mDBtPBfpm, FIGS. 34A to 34C show the analysis results of the organic compound represented by Structural Formula (216), and FIGS. 35A to 35C show the analysis results of 8BP-4mDBtPBfpm. In FIGS. 33A to 33C, FIGS. 34A to 34C, and FIGS. 35A to 35C, spheres represent atoms that form a compound, and cloud-like objects around the atoms represent the spin density distribution at the density value of 0.003. In FIGS. 33A, 34A, and 35A, cloud-like objects in a molecule show the LUMO distribution in the molecule. In FIGS. 33B, 34B, and 35B, cloud-like objects in a molecule show the HOMO distribution in the molecule. In FIGS. 33C, 34C, and 35C, cloud-like objects in a molecule show local distribution of the lowest triplet excited state of the molecule.

FIGS. 33A to 33C and FIGS. 34A to 34C show that, in 8mpTP-4mDBtPBfpm and the organic compound represented by Structural Formula (216), the lowest triplet excited state is locally distributed in a terphenyl group corresponding to the first substituent of the first organic compound, and the LUMO is distributed in part of a [1]benzofuro[3,2-d]pyrimidine ring corresponding to an electron-transport skeleton and part of a 3-(dibenzothiophen-4-yl)phenyl group corresponding to the second substituent. This reveals that 8mpTP-4mDBtPBfpm and the organic compound represented by Structure Formula (216) are different from each other in the position where the LUMO is distributed and the position where the lowest triplet excited state is locally distributed.

Meanwhile, FIGS. 35A to 35C show that the lowest triplet excited state of 8BP-4mDBtPBfpm is distributed not only in a 1,1′-biphenyl-4-yl group corresponding to the first substituent of the first organic compound, but also in the [1]benzofuro[3,2-d]pyrimidine ring corresponding to the electron-transport skeleton, and LUMO is distributed in part of the [1]benzofuro[3,2-d]pyrimidine ring corresponding to the electron-transport skeleton and part of the 3-(dibenzothiophen-4-yl)phenyl group corresponding to the second substituent. This reveals that, in 8BP-4mDBtPBfpm, the position where the lowest triplet excited state is locally distributed and the position where the LUMO is distributed overlap with each other.

The above results show that, as described in Embodiment 1, a substituent in which either a substituted or unsubstituted aromatic ring or a substituted or unsubstituted heteroaromatic ring is bonded to either a substituted or unsubstituted o-phenylene group or a substituted or unsubstituted m-phenylene group is used as the first substituent of the first organic compound, whereby the lowest triplet excited state can be distributed in the first substituent.

### Example 4

In this example, 2-methyltetrahydrofuran (2Me-THF) solutions of organic compounds that can each be used as the first organic compound were cooled using liquid nitrogen, and the emission spectra and emission quantum yields thereof were measured. The results are described below.

First, measurement was performed using the following samples: 8mpTP-4mDBtPBfpm (Structural Formula (200)) and 8-(1,1′:4′,1″-terphenyl-3-yl-2,4,5,6,2′,3′,5′,6′,2″,3″,4″,5″,6″-d₁₃)-4-[3-(dibenzothiophen-4-yl-1,2,3,6,7,8,9-d₇)phenyl-2,4,6-d₃]-[1]benzofuro[3,2-d]pyrimidine (abbreviation: 8mpTP-4mDBtPBfpm-d₂₃) (Structural Formula (219)), which is a compound obtained by substituting the first and second substituents of 8mpTP-4mDBtPBfpm with deuterium. In a manner similar to that of 8mpTP-4mDBtPBfpm described in Example 2, the T₁ level of 8mpTP-4mDBtPBfpm-d₂₃ was measured. As a result, the shortest-wavelength peak of the emission spectrum of 8mpTP-4mDBtPBfpm-d₂₃ was 501 nm (2.48 eV), and the emission edge on the shortest wavelength side of the emission spectrum was 484 nm (2.56 eV).

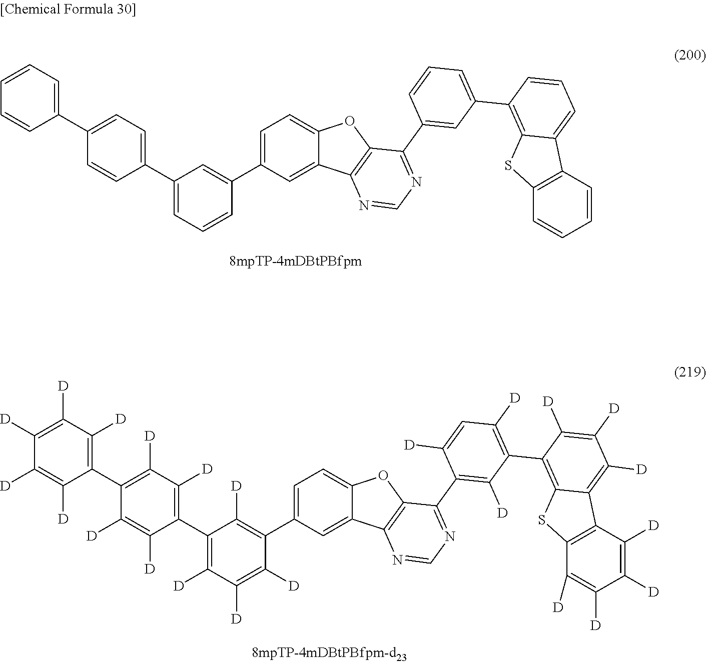 [SMILES: c1ccc(-c2ccc(-c3cccc(-c4ccc5oc6c(-c7cccc(-c8cccc9c8sc8ccccc89)c7)ncnc6c5c4)c3)cc2)cc1 ; [2H]c1cc([2H])c(-c2c([2H])c([2H])c([2H])c3c2sc2c([2H])c([2H])c([2H])c([2H])c23)c([2H])c1-c1ncnc2c1oc1ccc(-c3c([2H])c([2H])c([2H])c(-c4c([2H])c([2H])c(-c5c([2H])c([2H])c([2H])c([2H])c5[2H])c([2H])c4[2H])c3[2H])cc12]

The emission spectrum and the emission quantum yield were measured in the following manner: an absolute PL quantum yield measurement system (C11347-01 manufactured by Hamamatsu Photonics K. K.) was used, a deoxidized 2Me-THF solution (0.0120 mmol/L) of each sample was sealed in a quartz cell under a nitrogen atmosphere in a glove box (LABstar M13 (1250/780) manufactured by Bright Co., Ltd.) and cooled using liquid nitrogen.

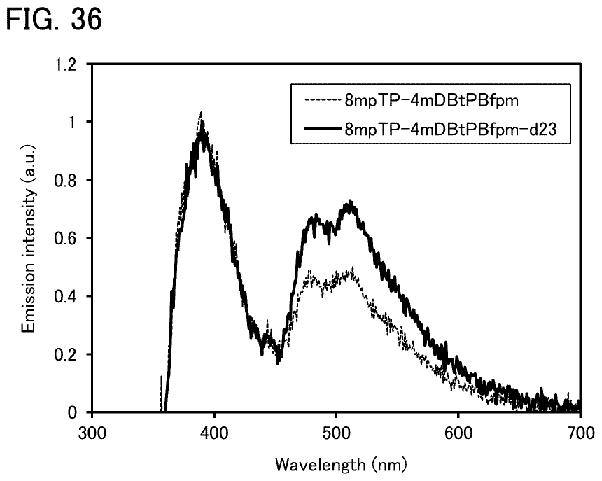

FIG. 36 shows the measurement results of the emission spectra of 8mpTP-4mDBtPBfpm and 8mpTP-4mDBtPBfpm-d₂₃. The horizontal axis represents the wavelength and the vertical axis represents the emission intensity.

As shown in FIG. 36, each sample has an emission spectrum derived from both fluorescence and phosphorescence. From the results of room temperature measurement and emission lifetime measurement, the spectra around 351 nm to 455 nm were confirmed to be derived from fluorescence. In addition, the spectra around 455 nm to 660 nm, which were observed only in low-temperature measurement, were confirmed to be derived from phosphorescence.

Furthermore, the measurement results of the emission quantum yield show that the quantum yield ((D (H)) of fluorescent components (in a wavelength range of 351 nm to 455 nm) of 8mpTP-4mDBtPBfpm at low temperature (temperature cooled using liquid nitrogen) is 8.5%. It is also shown that the quantum yield ((Dp(H)) of phosphorescent components (in a wavelength range of 455 nm to 660 nm) is 10%.

The measurement results of the emission quantum yield show that the quantum yield ((D(D)) of fluorescent components (in a wavelength range of 351 nm to 455 nm) of 8mpTP-4mDBtPBfpm-d₂₃ at low temperature (temperature cooled using liquid nitrogen) is 8.5%. It is also shown that the quantum yield ((p(D)) of phosphorescent components (in a wavelength range of 455 nm to 660 nm) is 15%.

That is, at low temperature (temperature cooled using liquid nitrogen), the quantum yield of the phosphorescent components of 8mpTP-4mDBtPBfpm-d₂₃ is 1.5 times as high as that of the phosphorescent components of 8mpTP-4mDBtPBfpm, and the quantum yields of the fluorescent components are substantially equal to each other.

Furthermore, the 2Me-THF solution (0.120 mmol/L) of 8mpTP-4mDBtPBfpm and that of 8mpTP-4mDBtPBfpm-d₂₃ were cooled using liquid nitrogen and the emission lifetimes were measured. The results are described below.

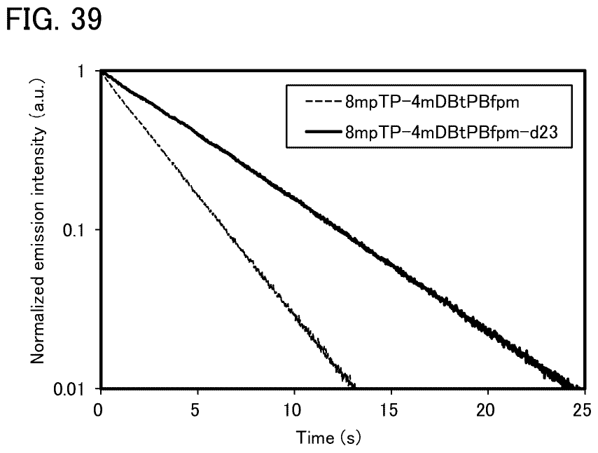

The emission lifetime was measured with a fluorescence spectrophotometer (FP-8600, manufactured by JASCO Corporation). The solutions of the samples were each put in a quartz cell under air, and cooled using liquid nitrogen to be measured. As the measurement, time-resolved measurement was performed in such a manner that the quartz cell containing the solution was irradiated with excitation light for approximately 30 seconds and the emission intensity attenuating after the excitation light was blocked by a shutter was measured at 10 ms intervals. Note that the wavelength of the excitation light was 320 nm, the wavelength of the measured light was 515 nm, and the band widths of the excitation light and the measured light were 10 nm. FIG. 39 shows the time-dependent attenuation curves obtained by the measurement. The horizontal axis represents time and the vertical axis represents the emission intensity.

As shown in FIG. 39, the emission intensity attenuates single-exponentially. The emission lifetime was calculated from the obtained attenuation curve. The emission lifetime of 8mpTP-4mDBtPBfpm was 2.8 s. The emission lifetime of 8mpTP-4mDBtPBfpm-d₂₃ was 5.3 s. Since the wavelength of the light whose emission lifetime was measured is 515 nm, the emission lifetimes can be regarded as the lifetimes of phosphorescent components. This reveals that, at low temperature (temperature cooled using liquid nitrogen), the deuterated substance has a phosphorescence lifetime 1.9 times as long as that of the non-deuterated substance.

Here, a phosphorescent emission quantum yield (Φₚ) and a phosphorescence lifetime (τₚ) can be respectively expressed as Formulae (1) and (2), from a rate constant kᵣₚ of radiative transfer and a rate constant kₙᵣₚ of non-radiative transfer from the lowest triplet excited state (T₁) of the organic compound, and a quantum yield (Φ_{isc}) of intercrossing system from the lowest singlet excited state (S₁) to the lowest triplet excited state (T₁).

$$[ Formula 1 ]$$

$${∅}_{p} = {∅}_{isc} \times \frac{{k}_{rp}}{{k}_{rp} + {k}_{nrp}} \qquad ( 1 )$$

$${τ}_{p} = \frac{1}{{k}_{rp} + {k}_{nrp}} \qquad ( 2 )$$

According to the formulae, kᵣₚ and kₙᵣₚ can be respectively expressed as Formulae (3) and (4) with the use of Φ and τ.

$$[ Formula 2 ]$$

$${k}_{rp} = \frac{1}{{∅}_{isc}} \times \frac{{∅}_{p}}{{τ}_{p}} \qquad ( 3 )$$

$${k}_{nrp} = \frac{1}{{∅}_{isc}} \times \frac{1 - {∅}_{p}}{{τ}_{p}} \qquad ( 4 )$$

The above measurement results show that the phosphorescence quantum yield (Dp(D) of 8mpTP-4mDBtPBfpm-d₂₃ that is deuterated is 1.5 times as high as the phosphorescence quantum yield Φₚ(H) of 8mpTP-4mDBtPBfpm that is not deuterated, and the phosphorescence lifetime τᵣ(D) of 8mpTP-4mDBtPBfpm-d₂₃ is 1.9 times as long as the phosphorescence lifetime τₚ(H) of 8mpTP-4mDBtPBfpm. The fluorescence quantum yield Φ_{f}(D) of 8mpTP-4mDBtPBfpm-d₂₃ and the fluorescence quantum yield Φ_{f}(H) of 8mpTP-4mDBtPBfpm are substantially equal to each other.

Note that at the temperature cooled using liquid nitrogen, the rate constant of non-radiative transfer of fluorescent light is much smaller than the rate constants of radiative transfer and intercrossing; thus, the quantum yield Φ_{isc}(H) of intersystem crossing of 8mpTP-4mDBtPBfpm and the quantum yield Φ_{isc}(D) of intercrossing system of 8mpTP-4mDBtPBfpm-d₂₃ can be expressed with the use of the fluorescence quantum yields (H) and (D) of the corresponding substances as follows:

Φ_{isc}(H)=1−Φ_{f}(H)

Φ_{isc}(D)=1−Φ_{f}(D),

where since Φ_{f}(H) and Φ_{f}(D) have substantially the same value, Φ_{isc}(H) and Φ_{isc}(D) can be regarded as being substantially equal to each other.

That is, with the use of the phosphorescence quantum yield Φₚ(H), the rate constant τₚ(H), the intercrossing system quantum yield Φ_{isc}(H), the radiative transfer rate constant kᵣₚ(H), and the non-radiative transfer rate constant kₙᵣₚ(H) of 8mpTP-4mDBtPBfpm, and the phosphorescence quantum yield Φₚ(D), the rate constant τₚ(D), the intercrossing system quantum yield Φ_{isc}(D), the radiative transfer rate constant kᵣₚ(D), and the non-radiative transfer rate constant kₙᵣₚ(D) of 8mpTP-4mDBtPBfpm-d₂₃, kᵣₚ(H), kᵣₚ(D), kₙᵣₚ(H), and kₙᵣₚ(D) can be expressed as Formulae (3-1), (3-2), (4-1), and (4-2), respectively.

$$[ Formula 3 ]$$

$${k}_{rp} ( H ) = \frac{1}{{∅}_{isc} ( H )} \times \frac{{∅}_{p} ( H )}{{τ}_{p} ( H )} \qquad ( 3 - 1 )$$

$${k}_{rp} ( D ) = \frac{1}{{∅}_{isc} ( D )} \times \frac{{∅}_{p} ( D )}{{τ}_{p} ( D )} = \frac{1}{{∅}_{isc} ( H )} \times \frac{1.5 {∅}_{p} ( H )}{1.9 {τ}_{p} ( H )} \qquad ( 3 - 2 )$$

$${k}_{nrp} ( H ) = \frac{1}{{∅}_{isc} ( H )} \times \frac{1 - {∅}_{p} ( H )}{{τ}_{p} ( H )} \qquad ( 4 - 1 )$$

$${k}_{nrp} ( D ) = \frac{1}{{∅}_{isc} ( D )} \times \frac{1 - {∅}_{p} ( D )}{{τ}_{p} ( D )} = \frac{1}{{∅}_{isc} ( H )} \times \frac{1 - 1.5 {∅}_{p} ( H )}{1.9 {τ}_{p} ( H )} \qquad ( 4 - 2 )$$

As shown above, kₙᵣₚ(D) is 0.50 times as large as kₙᵣₚ(H), i.e., kₙᵣₚ(D)<kₙᵣₚ(H), and kᵣₚ(D) is 0.79 times as large as kᵣₚ(H), i.e., kᵣₚ(D)<kᵣₚ(H). This shows that both the non-radiative transfer rate constant and the radiative transfer rate constant of 8mpTP-4mDBtPBfpm-d₂₃, which is deuterated, are smaller than those of 8mpTP-4mDBtPBfpm; meanwhile, the non-radiative transfer rate constant has a larger decrease than the radiative transfer rate constant, and thus the radiative transfer is inhibited more than the non-radiative transfer.

Although a deuterated organic compound has a small radiative transfer rate constant and a small non-radiative transfer rate constant as described above, the non-radiative transfer is more inhibited, which results in radiative transfer of more triplet excitons. Since the radiative transition relates to energy transfer, a deuterated organic compound has higher efficiency of excitation energy transfer to another compound (here, a phosphorescent light-emitting substance that is a guest material) than a non-deuterated organic compound. An improvement in energy efficiency can inhibit deterioration of the deuterated organic compound; thus, a light-emitting device using the organic compound as the host material can inhibit deterioration of the host material and can have favorable reliability.

At low temperature (temperature cooled using liquid nitrogen), the radiative transfer rate constant kᵣₚ(D) of 8mpTP-4mDBtPBfpm-d₂₃ is 0.79 times as large as the radiative transfer rate constant kᵣₚ(H) of 8mpTP-4mDBtPBfpm, and the non-radiative transfer rate constant kₙᵣₚ(D) of 8mpTP-4mDBtPBfpm-d₂₃ is 0.50 times as large as the non-radiative transfer rate constant kₙᵣₚ(H) of 8mpTP-4mDBtPBfpm; thus, a decrease in the non-radiative transfer rate constant kₙᵣₚ(D) is relatively large. Since the proportion of triplet excitons of radiative transition in 8mpTP-4mDBtPBfpm-d₂₃ is high even when the decrease in the radiative transfer rate constant kᵣₚ(D) is taken into consideration, it can be said that deuteration improves the energy transfer efficiency.

As for the fluorescence quantum yield, there was no significant difference between 8mpTP-4mDBtPBfpm-d₂₃ and 8mpTP-4mDBtPBfpm. In addition, the rate constant of non-radiative transition at a low temperature of 77K is much smaller than the rate constants of radiative transition and intercrossing system. From this, it can be said that deuteration does not cause significant difference in the rate constants of radiative transition and non-radiative transition in fluorescent emission process of 8mpTP-4mDBtPBfpm-d₂₃ and 8mpTP-4mDBtPBfpm, and deuteration mainly affects the behavior of triplet excitons.

Here, 8mpTP-4mDBtPBfpm-d₁₃ (Structural Formula (223)) obtained by substituting only the first substituent of 8mpTP-4mDBtPBfpm with deuterium and 8mpTP-4mDBtPBfpm-d₁₀ (Structural Formula (225)) obtained by substituting only the second substituent of 8mpTP-4mDBtPBfpm with deuterium were subjected to measurement in a similar manner.

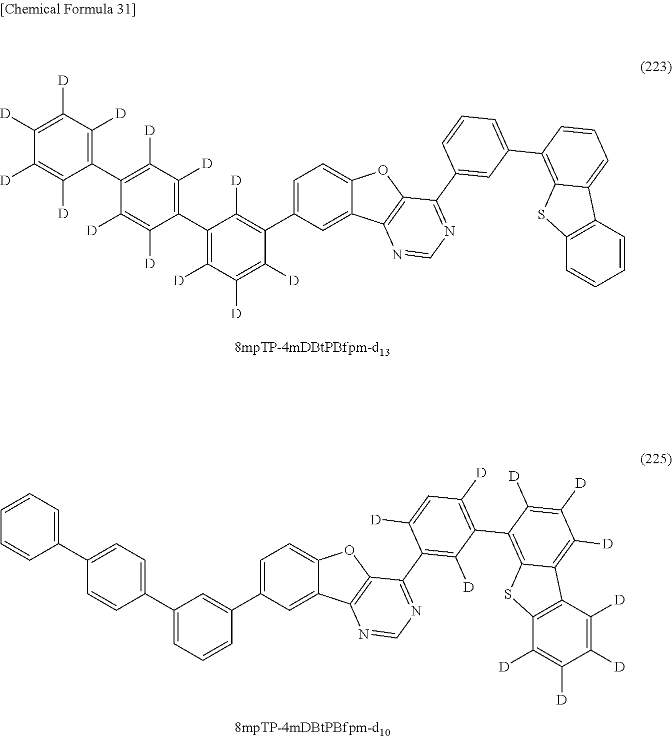 [SMILES: [2H]c1c([2H])c([2H])c(-c2c([2H])c([2H])c(-c3c([2H])c([2H])c([2H])c(-c4ccc5oc6c(-c7cccc(-c8cccc9c8sc8ccccc89)c7)ncnc6c5c4)c3[2H])c([2H])c2[2H])c([2H])c1[2H] ; [2H]c1cc([2H])c(-c2c([2H])c([2H])c([2H])c3c2sc2c([2H])c([2H])c([2H])c([2H])c23)c([2H])c1-c1ncnc2c1oc1ccc(-c3cccc(-c4ccc(-c5ccccc5)cc4)c3)cc12]

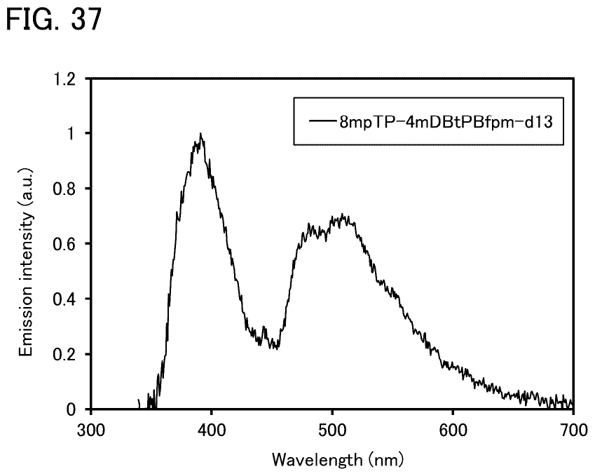

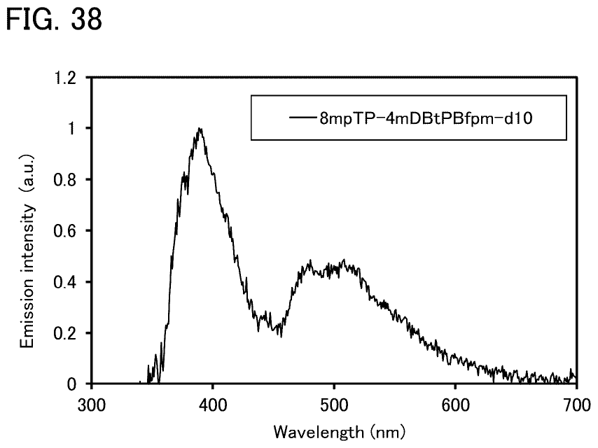

FIG. 37 shows the measurement result of the emission spectrum of 8mpTP-4mDBtPBfpm-d₁₃, and FIG. 38 shows the measurement result of the emission spectrum of 8mpTP-4mDBtPBfpm-d₁₀. The horizontal axis represents the wavelength and the vertical axis represents the emission intensity.

As shown in FIGS. 37 and 38, 8mpTP-4mDBtPBfpm-d₁₃ (Structural Formula (223)) and 8mpTP-4mDBtPBfpm-d₂₃ exhibited substantially the same results, and 8mpTP-4mDBtPBfpm-d₁₀ (Structural Formula (225)) and 8mpTP-4mDBtPBfpm exhibited substantially the same results.

Note that 8mpTP-4mDBtPBfpm-d₁₃ that exhibited substantially the same result as 8mpTP-4mDBtPBfpm-d₂₃ is an organic compound obtained by substituting only the first substituent of the first organic compound with deuterium. This reveals that substituting only the first substituent of the first organic compound with deuterium can inhibit non-radiative transition in a phosphorescent emission process. This is probably because, in the first organic compound where T₁ is locally distributed in the first substituent, deuteration of the first substituent inhibits vibration in the molecule in the lowest triplet excited state and accordingly can inhibit non-radiative transition from T₁ in the first organic compound.

In view of the efficiency ϕ_{ET} of energy transfer from the host material to the guest material, the energy transfer efficiency ϕ_{ET} is expressed as Formula (5), and what is needed to increase the energy transfer efficiency ϕ_{ET} is increasing the energy transfer rate constant k_{h*→g} to make another rate constant kᵣ+kₙᵣ(=l/τ) relatively small.

In Formula (5), kᵣ represents the rate constant of a light emission process (a fluorescent emission process in the case where energy transfer from a singlet excited state is discussed, and a phosphorescent emission process in the case where energy transfer from a triplet excited state is discussed) of the host material, kₙᵣ represents the rate constant of a non-light-emission process (thermal deactivation and intersystem crossing) of the host material, and τ represents a measured lifetime of an excited state of the host material. In addition, k_{h*→g} represents the rate constant of energy transfer (Förster mechanism or Dexter mechanism).

$$[ Formula 4 ]$$

$${∅}_{ET} = \frac{{k}_{{h}^{*} \to g}}{{k}_{r} + {k}_{nr} + {k}_{{h}^{*} \to g}} = \frac{{k}_{{h}^{*} \to g}}{( \frac{1}{τ} ) + {k}_{{h}^{*} \to g}} \qquad ( 5 )$$

The atomic arrangement in a molecule, the spectrum shape, and the like do not differ between the deuterated organic compound (8mpTP-4mDBtPBfpm-d₂₃) and the non-deuterated organic compound (8mpTP-4mDBtPBfpm), which indicates that these two organic compounds have substantially the same energy transfer rate constants k_{h*→g}(see Formula (6) or (7)). It is thus found that a significant difference between the deuterated organic compound and the non-deuterated organic compound is the emission lifetime (phosphorescence lifetime) τ.

As described above, the phosphorescence lifetime measured at low temperature (temperature cooled using liquid nitrogen) of the deuterated organic compound (8mpTP-4mDBtPBfpm-d₂₃) was 1.9 times as long as that of the non-deuterated organic compound (8mpTP-4mDBtPBfpm). On the assumption that the phosphoresce lifetime differs between the deuterated organic compound and the non-deuterated organic compound also at room temperature, it can be said that a light-emitting device using the deuterated organic compound (8mpTP-4mDBtPBfpm-d₂₃) as a host material has higher energy transfer efficiency than a light-emitting device using the non-deuterated organic compound (8mpTP-4mDBtPBfpm) as a host material, as found from Formula (5) of the energy transfer efficiency ϕ_{ET}.

An improvement in energy transfer efficiency can inhibit deterioration of the deuterated organic compound. Accordingly, the light-emitting device using the deuterated organic compound as the host material can inhibit deterioration of the host material more than the light-emitting device using the non-deuterated organic compound as the host material, and thus can have favorable reliability.

$$[ Formula 5 ]$$

$${k}_{{h}^{*} \to g} = \frac{9000 {K}^{2} ∅ln 10}{128 {π}^{5} {n}^{4} N τ {R}^{6}} \int \frac{{f}_{h}^{′} ( v ) {ε}_{g} ( v )}{{v}^{4}} dv \qquad ( 6 )$$

$$[ Formula 6 ]$$

$${k}_{{h}^{*} \to g} = ( \frac{2 π}{h} ) {K}^{2} exp ( - \frac{2 R}{L} ) \int {f}_{h}^{′} ( v ) {ε}_{g}^{′} ( v ) dv \qquad ( 7 )$$

Formula (6) is a formula of the rate constant k_{h*→g} of the Förster mechanism and Formula (7) is a formula of the rate constant k_{h*→g} of the Dexter mechanism.

In Formula (6), v represents a frequency, f′ₕ(v) denotes a normalized emission spectrum of the host material (a fluorescent spectrum in the case where energy transfer from a singlet excited state is discussed, and a phosphorescent spectrum in the case where energy transfer from a triplet excited state is discussed), ε_{g}(v) represents a molar absorption coefficient of the guest material, N represents Avogadro's number, n denotes a refractive index of a medium, R represents an intermolecular distance between the host material and the guest material, τ represents a measured lifetime of an excited state (fluorescence lifetime or phosphorescence lifetime), ϕ represents an emission quantum yield (a fluorescence quantum yield in energy transfer from a singlet excited state, and a phosphorescence quantum yield in energy transfer from a triplet excited state), and K² represents a coefficient (0 to 4) of orientation of a transition dipole moment between the host material and the guest material. Note that K²=⅔ in random orientation.

In Formula (7), h represents a Planck constant, K represents a constant having an energy dimension, v represents a frequency, f′ₕ(v) represents a normalized emission spectrum of the host material (a fluorescent spectrum in the case where energy transfer from a singlet excited state is discussed, and a phosphorescent spectrum in the case where energy transfer from a triplet excited state is discussed), ε′_{g}(v) represents a normalized absorption spectrum of the guest material, L represents an effective molecular radius, and R represents an intermolecular distance between the host material and the guest material.

In the case where the triplet exciton has high energy and a long lifetime, deterioration might be promoted. However, the T₁ level of the first organic compound of one embodiment of the present invention is relatively low, and thus the triplet exciton having a long lifetime does not much affect the reliability. A substance obtained by deuterating the first and second substituents of the first organic compound (host material) inhibits non-radiative transition, which increases the efficiency of energy transfer from the substance to the light-emitting material and improves the reliability of the light-emitting device.

### Example 5

In this example, a light-emitting device 9 and a light-emitting device 10 of embodiments of the present invention were fabricated and the characteristics thereof were compared. The results are described below. Structural formulae of organic compounds used for the light-emitting devices 9 and 10 are shown below. Furthermore, device structures of the light-emitting devices 9 and 10 are shown in Table 6.

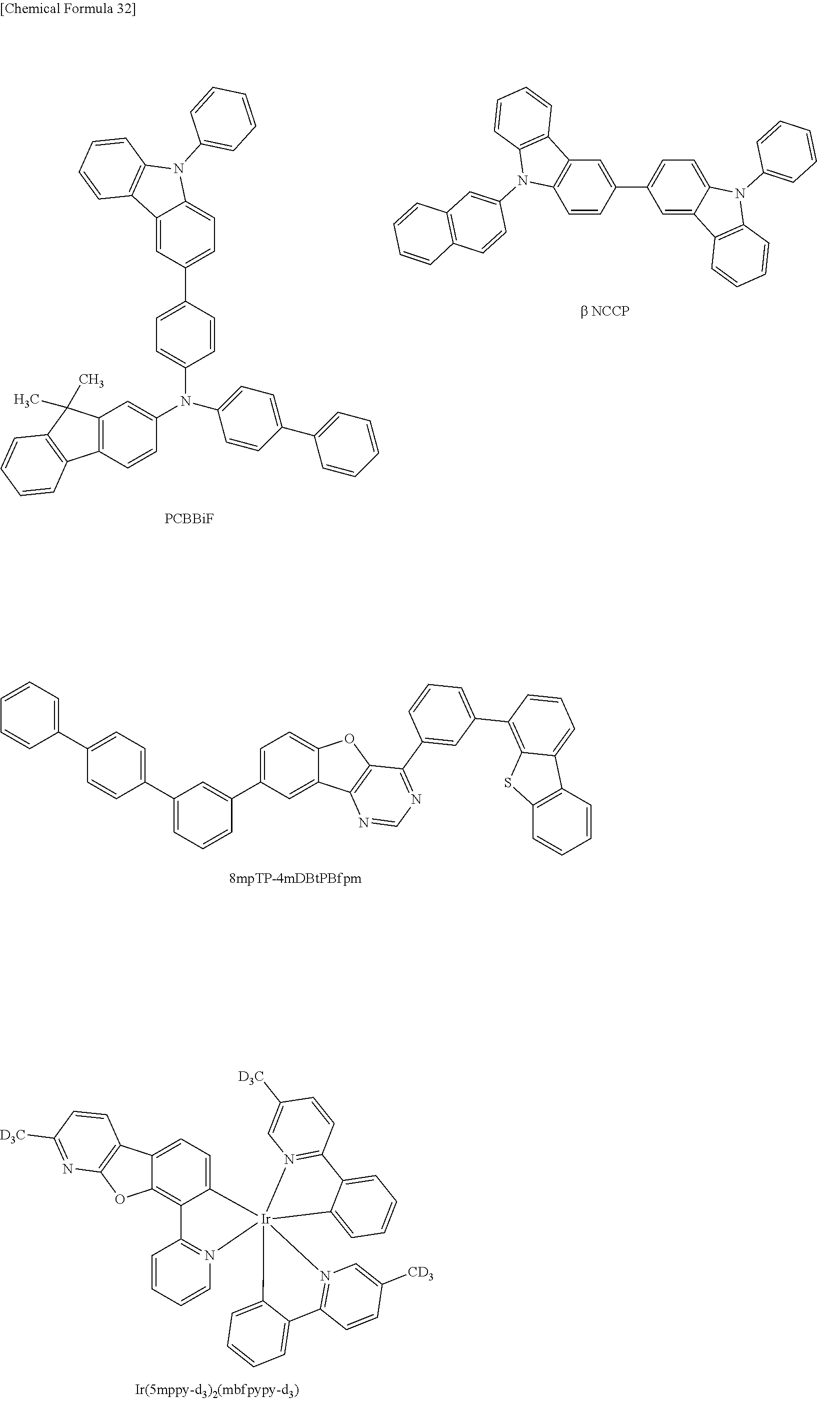

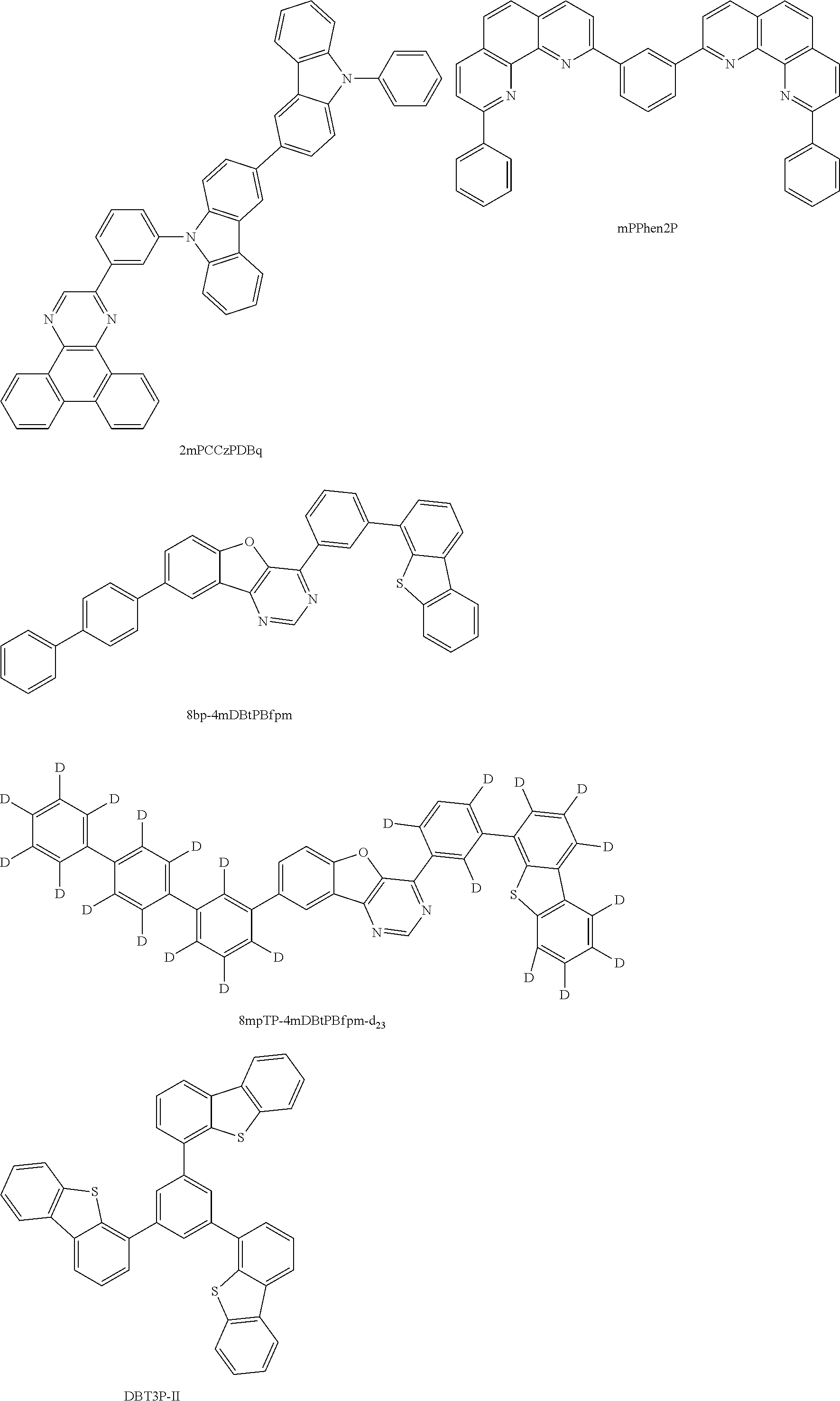

TABLE 6

| | | |
|---|---|---|
| Film | | |
| thickness | Light-emitting device 9 | Light-emitting device 10 |

| Cap layer | | 70 | nm | DBT3P-II |
|---|---|---|---|---|
| Second electrode | | 25 | nm | Ag:Mg (1:0.1) |
| Electron-injection layer | | 1.5 | mm | LiF:Yb (1:0.5) |
| Electron-transport | 2 | 10 | nm | mPPhen2P |
| layer | 1 | 10 | nm | 2mPCCzPDBq |

| | | | | |
|---|---|---|---|---|
| Light-emitting layer | 50 | nm | 8mpTP-4mDBtPBfpm:βNCCP:Ir(5mppy- | 8mpTP-4mDBtPBfpm- |
| | | | d₃)₂(mbfpypy-d₃) | d₂₃:βNCCP:Ir(5mppy-d₃)₂(mbfpypy-d₃) |
| | | | (0.5:0.5:0.1) | (0.5:0.5:0.1) |

| | | | |
|---|---|---|---|
| Hole-transport layer | 10 | nm | PCBBiF |
| Hole-injection layer | 10 | nm | PCBBiF:OCHD-003 (1:0.03) |
| First electrode | 10 | mm | ITSO |
| | 100 | nm | Ag |

### <<Fabrication of Light-Emitting Device 9>>

The light-emitting device 9 is different from the light-emitting device 3 described in Example 2 in the thickness of the second electron-transport layer. That is, the light-emitting device 9 was fabricated in a manner similar to that of the light-emitting device 3 except that the thickness of the second electron-transport layer was set to 10 nm.

### <<Fabrication of Light-Emitting Device 10>>

The light-emitting device 10 was fabricated in a manner similar to that of the light-emitting device 9 except that 8mpTP-4mDBtPBfpm-d₂₃ was used instead of 8mpTP-4mDBtPBfpm as the first organic compound in the light-emitting layer.

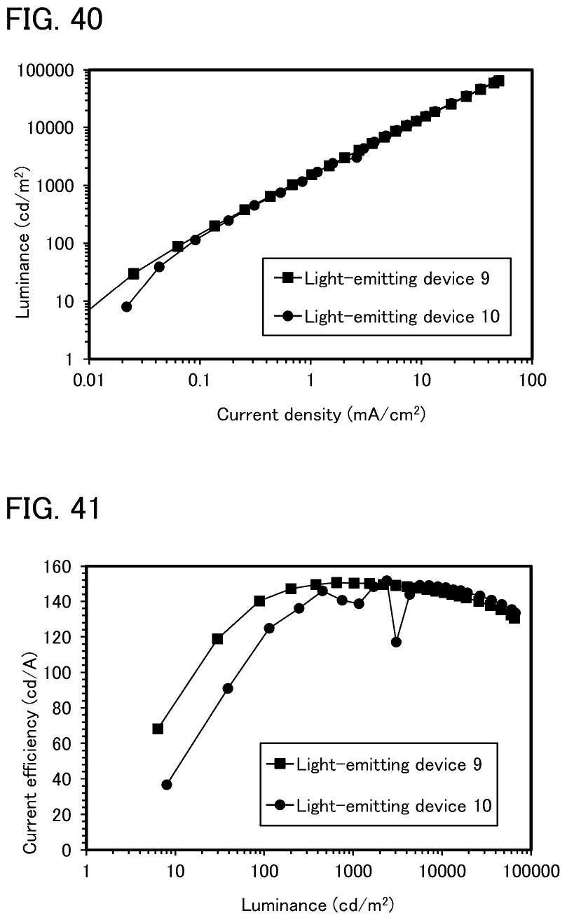

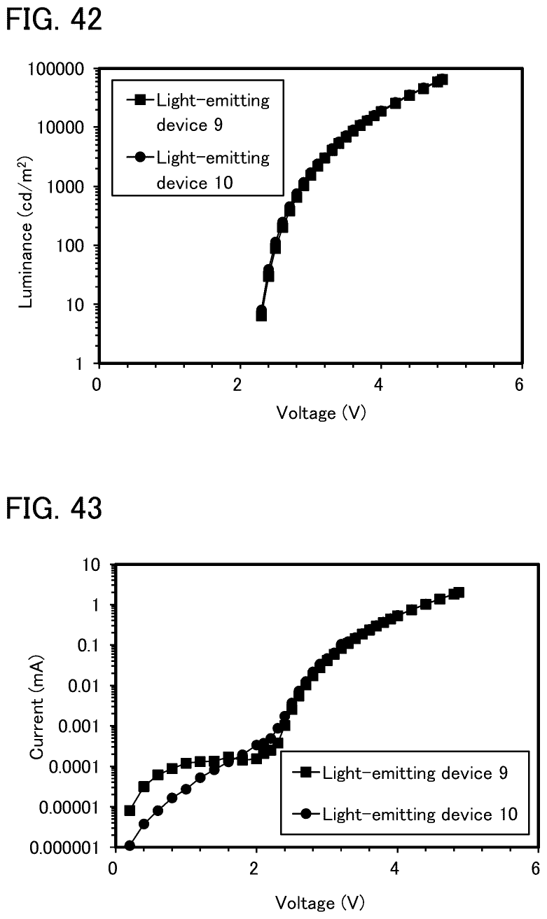

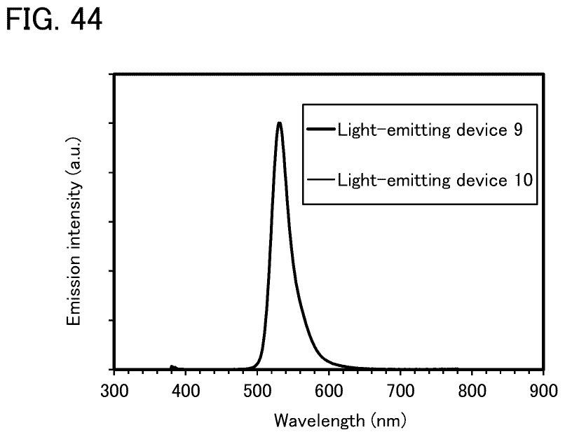

FIG. 40 shows the luminance-current density characteristics of the light-emitting devices 9 and 10. FIG. 41 shows the current efficiency-luminance characteristics thereof. FIG. 42 shows the luminance-voltage characteristics thereof. FIG. 43 shows the current-voltage characteristics thereof. FIG. 44 shows the emission spectra thereof. In addition, the voltage, current, current density, CIE chromaticity, and current efficiency at a luminance of approximately 1000 cd/cm² are shown below. The luminance, CIE chromaticity, and emission spectra were measured at normal temperature with a spectroradiometer (SR-UL1R manufactured by TOPCON TECHNOHOUSE CORPORATION).

TABLE 7

| | | | Current | | | Current |
|---|---|---|---|---|---|---|
| | Voltage | Current | density | | | efficiency |
| | (V) | (mA) | (mA/cm²) | Chromaticity x | Chromaticity y | (cd/A) |
| Light-emitting | 2.9 | 0.027 | 0.68 | 0.26 | 0.71 | 150 |
| device 9 | | | | | | |
| Light-emitting | 2.8 | 0.021 | 0.54 | 0.25 | 0.71 | 141 |
| device 10 | | | | | | |

FIGS. 40 to 44 show that the light-emitting devices 9 and 10 both have favorable characteristics.

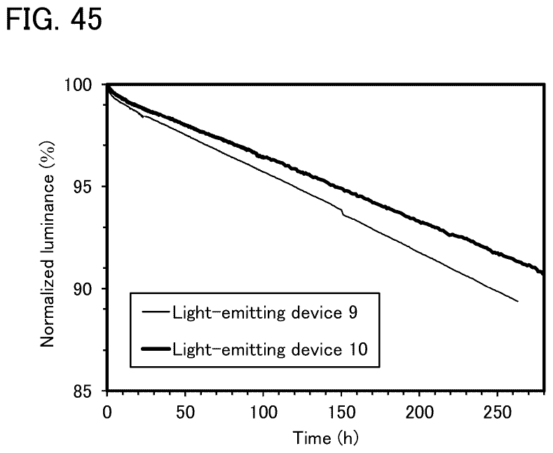

FIG. 45 shows the results of measuring luminance changes of the light-emitting devices 9 and 10 over driving time in constant-current driving at a current density of 50 mA/cm². FIG. 45 shows that the light-emitting devices 9 and 10 both have favorable reliability.

It is also shown that the light-emitting device 10 has a longer lifetime than the light-emitting device 9. That is, the light-emitting device using 8mpTP-4mDBtPBfpm-d₂₃, which is obtained by deuterating the first and second substituents of the first organic compound, has higher reliability than the light-emitting device using 8mpTP-4mDBtPBfpm, which is not deuterated. As described in Example 4, the substance obtained by deuterating the first and second substituents of the first organic compound (host material) inhibits non-radiative transition, which increases the efficiency of energy transfer from the substance to the light-emitting material and improves the reliability of the light-emitting device.

This application is based on Japanese Patent Application Serial No. 2022-104863 filed with Japan Patent Office on Jun. 29, 2022 and Japanese Patent Application Serial No. 2023-096181 filed with Japan Patent Office on Jun. 12, 2023, the entire contents of which are hereby incorporated by reference.

1. A light-emitting device comprising:
an anode;
a cathode; and
a light-emitting layer,
wherein the light-emitting layer is between the anode and the cathode,
wherein the light-emitting layer comprises a light-emitting substance and a first organic compound,
wherein the light-emitting substance is an organometallic complex comprising a central metal and ligands,
wherein at least one of the ligands comprises a skeleton formed by a ring A¹ and a pyridine ring bonded to each other,
wherein the ring A¹ represents an aromatic ring or a heteroaromatic ring,
wherein the pyridine ring comprises an alkyl group comprising 1 to 6 carbon atoms and being substituted with deuterium,
wherein the ligand is coordinated to the central metal with any atom of the ring A¹ and nitrogen of the pyridine ring,
wherein the first organic compound comprises an electron-transport skeleton, a first substituent bonded to the electron-transport skeleton, and a second substituent bonded to the electron-transport skeleton,
wherein the electron-transport skeleton comprises a heteroaromatic ring comprising two or more nitrogen atoms,
wherein the first substituent is a group comprising one or both of an aromatic ring and a heteroaromatic ring,
wherein the second substituent comprises a skeleton having a hole-transport property, and
wherein a lowest triplet excited state of the first organic compound is locally distributed in the first substituent.

2. A light-emitting device comprising:
an anode;
a cathode; and
a light-emitting layer,
wherein the light-emitting layer is between the anode and the cathode,
wherein the light-emitting layer comprises a light-emitting substance and a first organic compound,
wherein the light-emitting substance is an organometallic complex comprising a central metal and ligands,
wherein at least one of the ligands comprises a structure represented by General Formula (L1),
wherein the first organic compound is an organic compound represented by General Formula (G10), 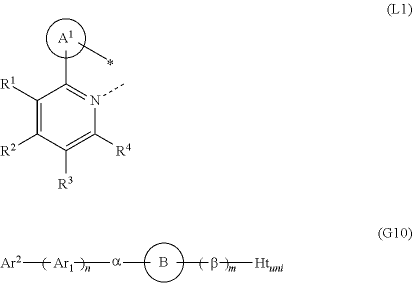
wherein * represents a bond for the central metal,
wherein a dashed line represents coordination to the central metal,
wherein a ring A¹ represents an aromatic ring or a heteroaromatic ring,
wherein at least one of R¹ to R⁴ represents an alkyl group comprising 1 to 6 carbon atoms and being substituted with deuterium,
wherein each of the others of R¹ to R⁴ independently represents any of hydrogen, an alkyl group comprising 1 to 6 carbon atoms, and a substituted or unsubstituted aryl group comprising 6 to 13 carbon atoms in a ring,
wherein a ring B represents a heteroaromatic ring comprising two or more nitrogen atoms;
wherein each of Ar¹ and Ar² independently represents an aromatic ring or a heteroaromatic ring,
wherein each of α and β independently represents a substituted or unsubstituted phenyl group,
wherein Htᵤₙᵢ represents a skeleton having a hole-transport property, and
wherein each of n and m independently represents an integer of 0 to 4.

3. A light-emitting device comprising:
an anode;
a cathode; and
a light-emitting layer,
wherein the light-emitting layer is between the anode and the cathode,
wherein the light-emitting layer comprises a light-emitting substance and a first organic compound,
wherein the light-emitting substance is an organometallic complex represented by General Formula (G1),
wherein the first organic compound is an organic compound represented by General 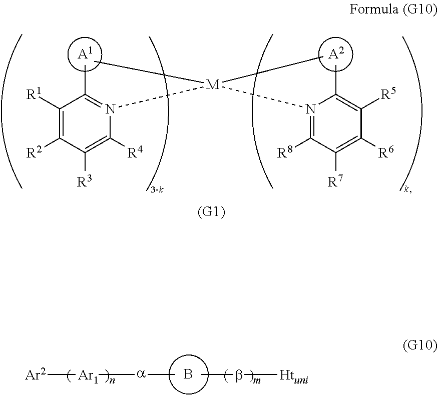
wherein M represents a central metal,
wherein a dashed line represents coordination,
wherein each of a ring A¹ and a ring A² independently represents an aromatic ring or a heteroaromatic ring,
wherein at least one of R¹ to R⁴ represents an alkyl group comprising 1 to 6 carbon atoms and being substituted with deuterium,
wherein each of the others of R¹ to R⁴ independently represents any of hydrogen, an alkyl group comprising 1 to 6 carbon atoms, and a substituted or unsubstituted aryl group comprising 6 to 13 carbon atoms in a ring,
wherein each of R⁵ to R⁸ independently represents any of hydrogen, an alkyl group comprising 1 to 6 carbon atoms, and a substituted or unsubstituted aryl group comprising 6 to 13 carbon atoms in a ring,
wherein k represents an integer of 0 to 2,
wherein a ring B represents a heteroaromatic ring comprising two or more nitrogen atoms,
wherein each of Ar¹ and Ar² independently represents an aromatic ring or a heteroaromatic ring,
wherein each of α and β independently represents a substituted or unsubstituted phenyl group,
wherein Htᵤₙᵢ represents a skeleton having a hole-transport property, and
wherein each of n and m independently represents an integer of 0 to 4.

4. The light-emitting device according to claim 3,
wherein the organometallic complex is represented by General Formula (G2), 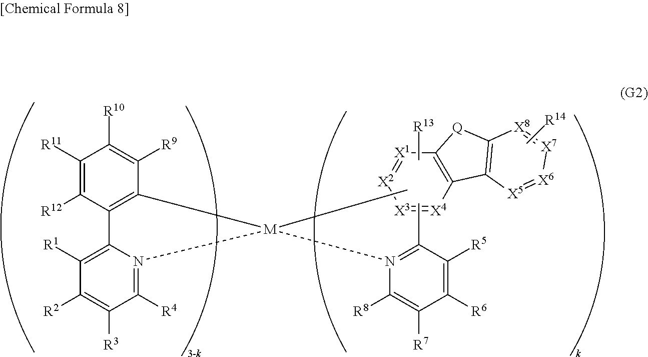
wherein M represents a central metal,
wherein a dashed line represents coordination,
wherein Q represents oxygen or sulfur,
wherein each of X¹ to X⁸ independently represents any of nitrogen and carbon,
wherein at least one of R¹ to R⁴ represents an alkyl group comprising 1 to 6 carbon atoms and being substituted with deuterium,
wherein each of the others of R¹ to R⁴ independently represents hydrogen, an alkyl group comprising 1 to 6 carbon atoms, or a substituted or unsubstituted aryl group comprising 6 to 13 carbon atoms in a ring,
wherein each of R⁵ to R¹⁴ independently represents hydrogen, an alkyl group comprising 1 to 6 carbon atoms, or a substituted or unsubstituted aryl group comprising 6 to 13 carbon atoms in a ring, and
wherein k represents an integer of 0 to 2.

5. The light-emitting device according to claim 1,
wherein a lowest triplet excitation energy of the first organic compound is higher than a lowest triplet excitation energy of the organometallic complex.

6. The light-emitting device according to claim 5,
wherein a difference between the lowest triplet excitation energy of the first organic compound and the lowest triplet excitation energy of the organometallic complex is greater than 0 eV and less than or equal to 0.40 eV.

7. The light-emitting device according to claim 1,
wherein the central metal is iridium.

8. The light-emitting device according to claim 1,
wherein the heteroaromatic ring comprising two or more nitrogen atoms is any one of Structural Formulae (B-1) to (B-32),

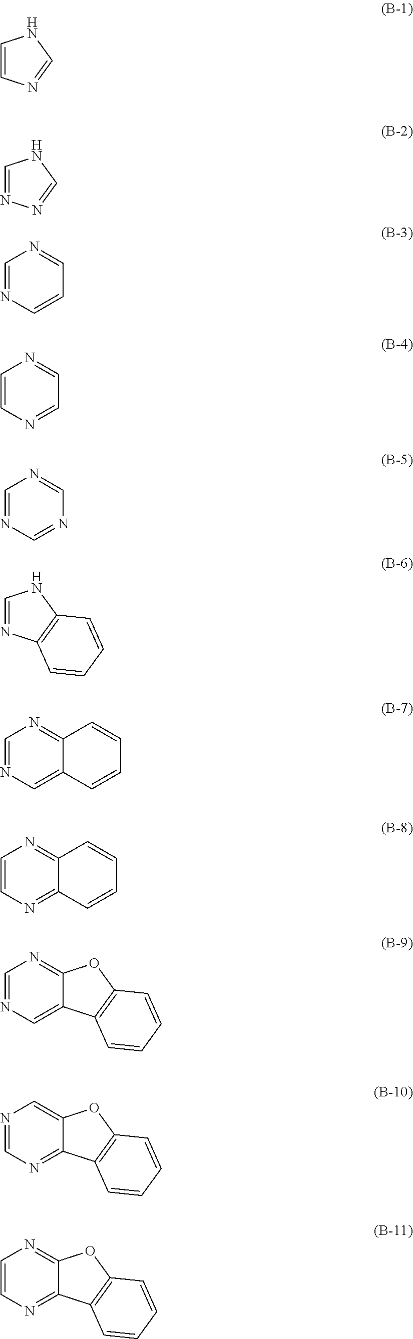

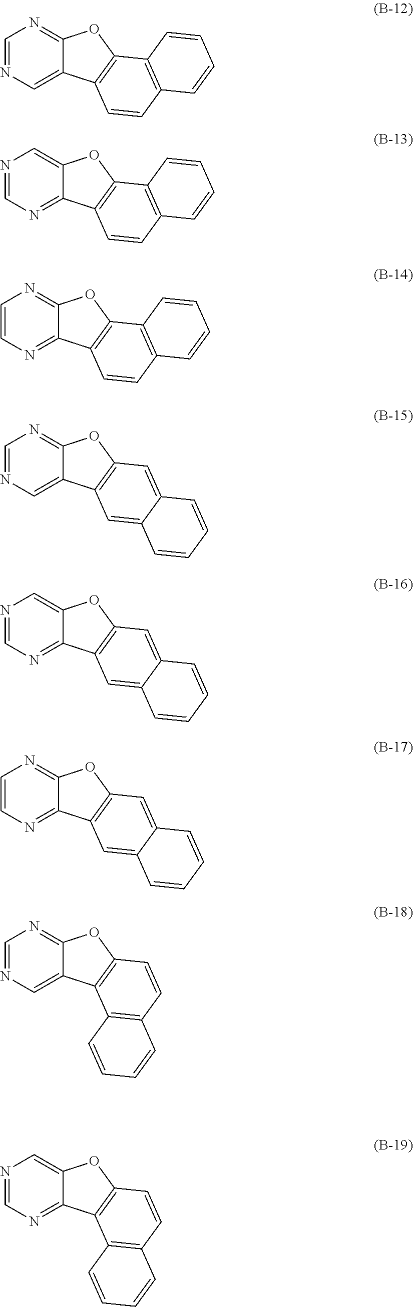

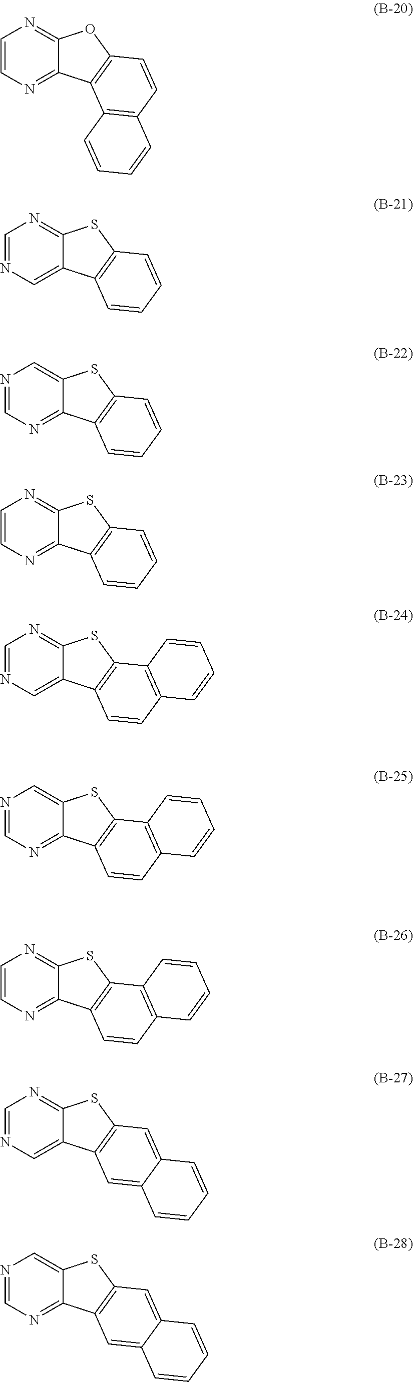

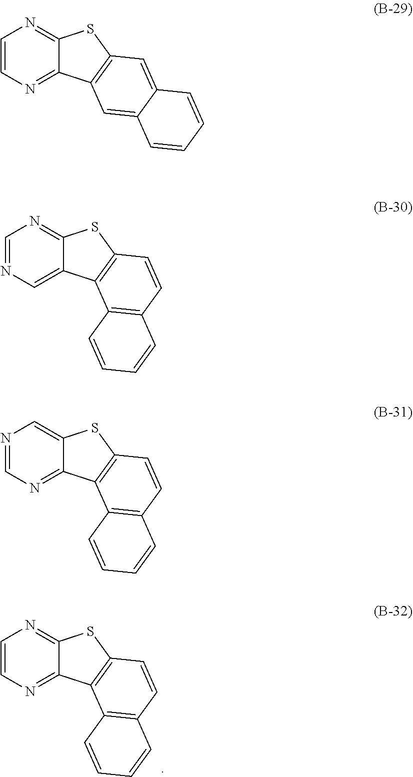 [SMILES: c1ccc2cc3c(cc2c1)sc1nccnc13 ; c1ccc2c(c1)ccc1sc3ncncc3c12 ; c1ccc2c(c1)ccc1sc3cncnc3c12 ; c1ccc2c(c1)ccc1sc3nccnc3c12]

9. A light-emitting apparatus comprising:
the light-emitting device according to claim 1; and
at least one of a transistor and a substrate.

10. An electronic device comprising:
the light-emitting apparatus according to claim 9; and
at least one of a sensor unit, an input unit, and a communication unit.

11. A lighting device comprising:
the light-emitting apparatus according to claim 9; and
a housing.

12. The light-emitting device according to claim 2,
wherein a lowest triplet excitation energy of the first organic compound is higher than a lowest triplet excitation energy of the organometallic complex.

13. The light-emitting device according to claim 12,
wherein a difference between the lowest triplet excitation energy of the first organic compound and the lowest triplet excitation energy of the organometallic complex is greater than 0 eV and less than or equal to 0.40 eV.

14. The light-emitting device according to claim 2,
wherein the central metal is iridium.

15. The light-emitting device according to claim 2,
wherein the heteroaromatic ring comprising two or more nitrogen atoms is any one of Structural Formulae (B-1) to (B-32),

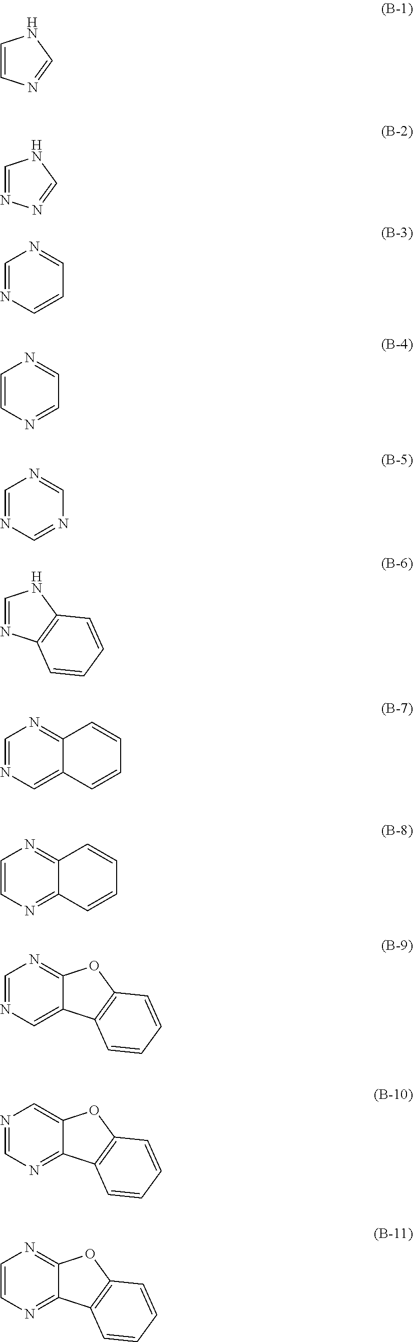

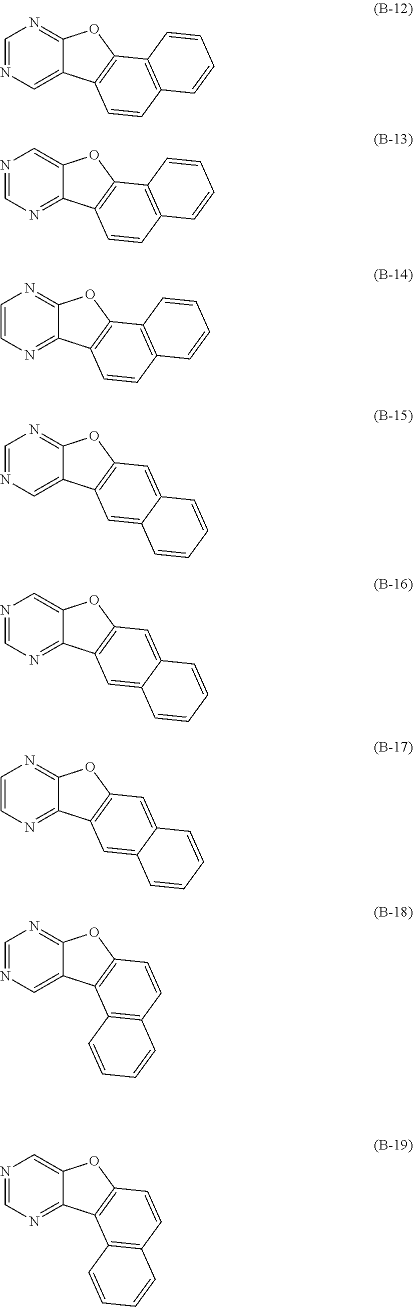

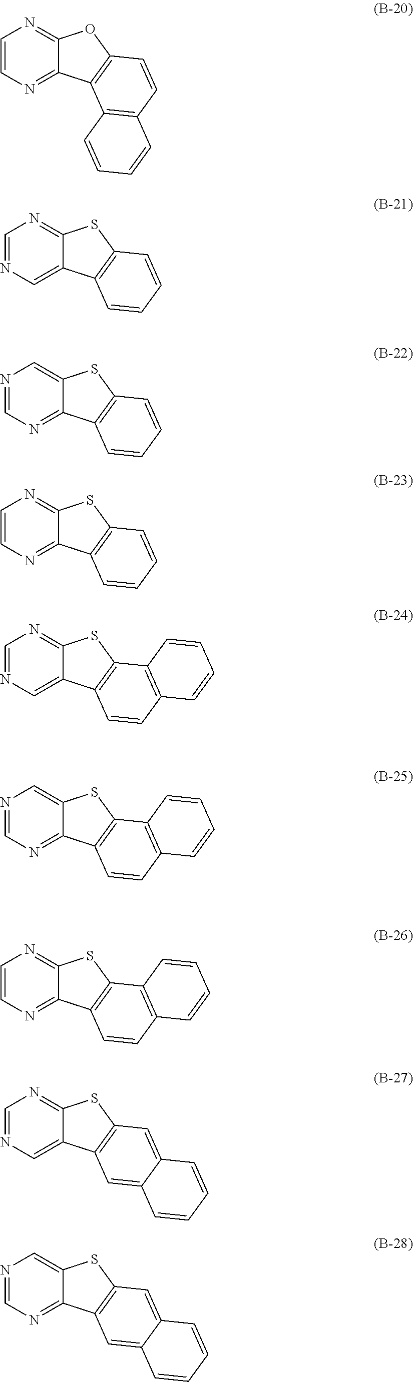

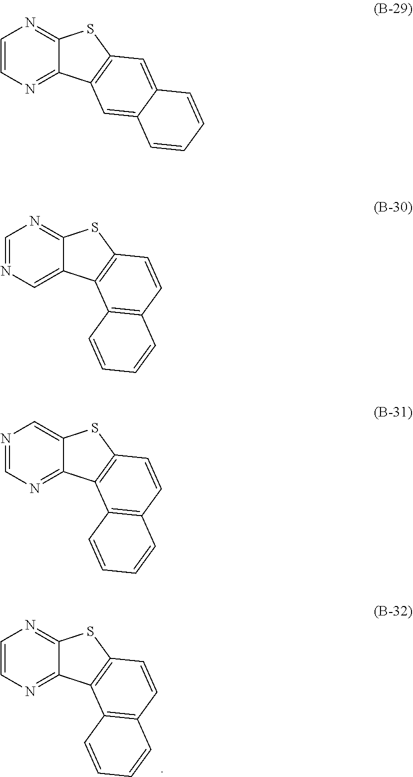 [SMILES: c1ccc2cc3c(cc2c1)sc1nccnc13 ; c1ccc2c(c1)ccc1sc3ncncc3c12 ; c1ccc2c(c1)ccc1sc3cncnc3c12 ; c1ccc2c(c1)ccc1sc3nccnc3c12]

16. The light-emitting device according to claim 3,
wherein a lowest triplet excitation energy of the first organic compound is higher than a lowest triplet excitation energy of the organometallic complex.

17. The light-emitting device according to claim 16,
wherein a difference between the lowest triplet excitation energy of the first organic compound and the lowest triplet excitation energy of the organometallic complex is greater than 0 eV and less than or equal to 0.40 eV.

18. The light-emitting device according to claim 3,
wherein the central metal is iridium.

19. The light-emitting device according to claim 3,
wherein the heteroaromatic ring comprising two or more nitrogen atoms is any one of Structural Formulae (B-1) to (B-32), 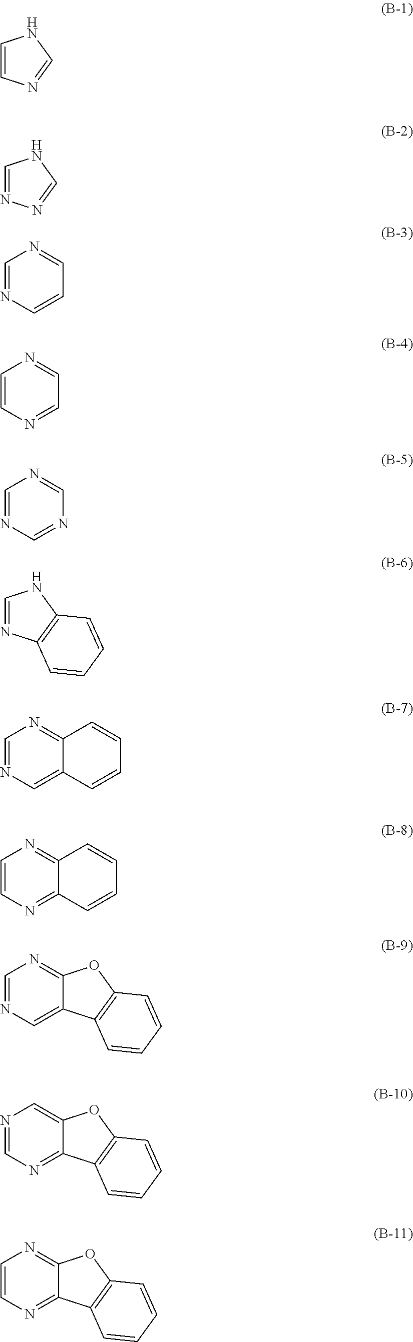 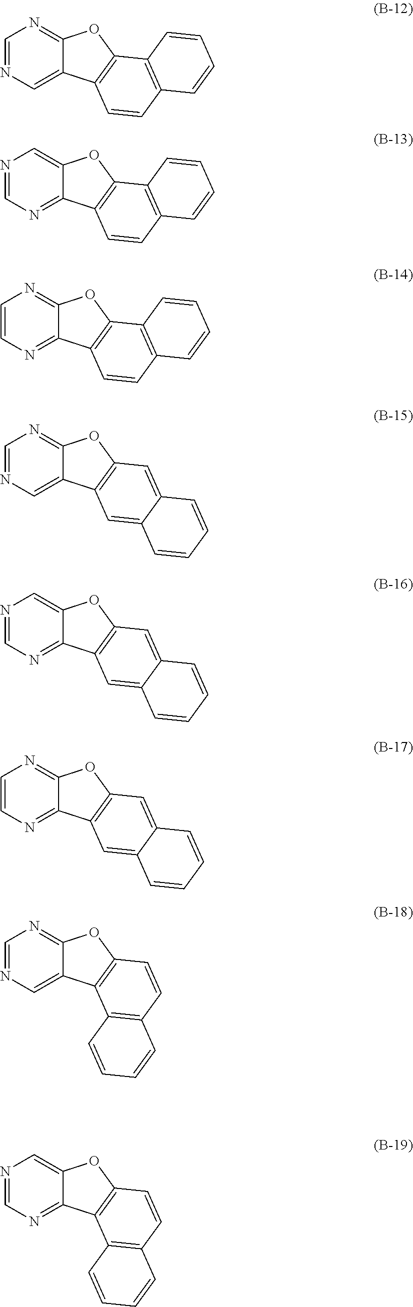 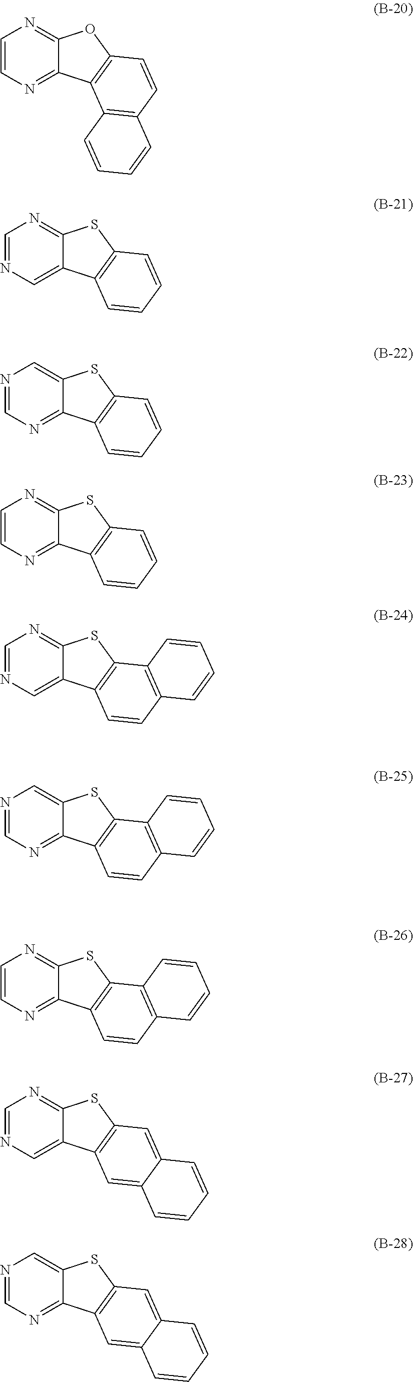 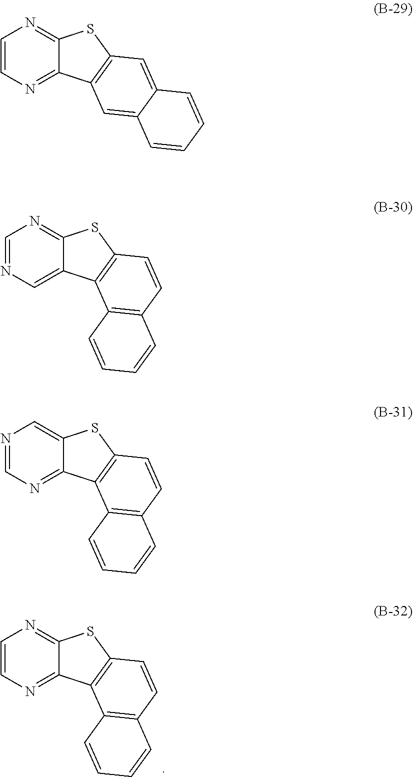 [SMILES: c1ccc2cc3c(cc2c1)sc1nccnc13 ; c1ccc2c(c1)ccc1sc3ncncc3c12 ; c1ccc2c(c1)ccc1sc3cncnc3c12 ; c1ccc2c(c1)ccc1sc3nccnc3c12]
